(19) United States
(12) Patent Application Publication
(10) Pub. No.: US 2024/0138262 A1
(43) Pub. Date: Apr. 25, 2024

(54) CONDENSED CYCLIC COMPOUND, LIGHT-EMITTING DEVICE INCLUDING THE CONDENSED CYCLIC COMPOUND, AND ELECTRONIC APPARATUS INCLUDING THE LIGHT-EMITTING DEVICE

(71) Applicant: Samsung Display Co., Ltd., Yongin-si, Gyeonggi-do (KR)

(72) Inventors: Kyoung Sunwoo, Yongin-si (KR); Taeil Kim, Yongin-si (KR); Jangyeol Baek, Yongin-si (KR); Minjae Sung, Yongin-si (KR); Minjung Jung, Yongin-si (KR); Seonhyoung Hur, Yongin-si (KR)

(73) Assignee: Samsung Display Co., Ltd., Yongin-si, Gyeonggi-do (KR)

(21) Appl. No.: 18/355,699

(22) Filed: Jul. 20, 2023

(30) Foreign Application Priority Data
Sep. 23, 2022 (KR) 10-2022-0121113

(51) Int. Cl. H10K 85/60; C07F 5/02; C09K 11/06

(52) U.S. Cl. CPC H10K 85/658; C07F 5/027; C09K 11/06; H10K 50/121

(57) ABSTRACT

Embodiments provide a condensed cyclic compound, a light-emitting device including the condensed cyclic compound, an electronic apparatus including the light-emitting device, and an electronic device including the light-emitting device. The light-emitting device includes a first electrode, a second electrode facing the first electron, and an interlayer between the first electrode and the second electrode and including an emission layer. The condensed cyclic compound is represented by Formula 1, which is explained in the specification:

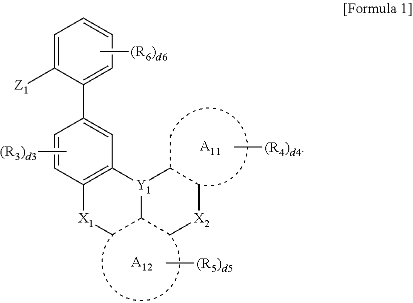

### CROSS-REFERENCE TO RELATED APPLICATION(S)

This application claims priority to and benefits of Korean Patent Application No. 10-2022-0121113 under 35 U.S.C. § 119, filed on Sep. 23, 2022, in the Korean Intellectual Property Office, the entire contents of which are incorporated herein by reference.

### BACKGROUND

### 1. Technical Field

Embodiments relate to a condensed cyclic compound, a light-emitting device including the condensed cyclic compound, and an electronic apparatus including the light-emitting device.

### 2. Description of the Related Art

From among light-emitting devices, self-emissive devices (for example, organic light-emitting devices, etc.) have wide viewing angles, excellent contrast ratios, fast response time, and excellent characteristics in terms of luminance, driving voltage and response speed.

In a light-emitting device, a first electrode is disposed on a substrate, and a hole transport region, an emission layer, an electron transport region, and a second electrode are disposed on the first electrode. Holes provided from the first electrode may move toward the emission layer through the hole transport region, and electrons provided from the second electrode may move toward the emission layer through the electron transport region. Carriers, such as holes and electrons, may recombine in such an emission layer region to produce excitons. These excitons transition from an excited state to a ground state to generate light.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

According to embodiments, a condensed cyclic compound may be represented by Formula 1.

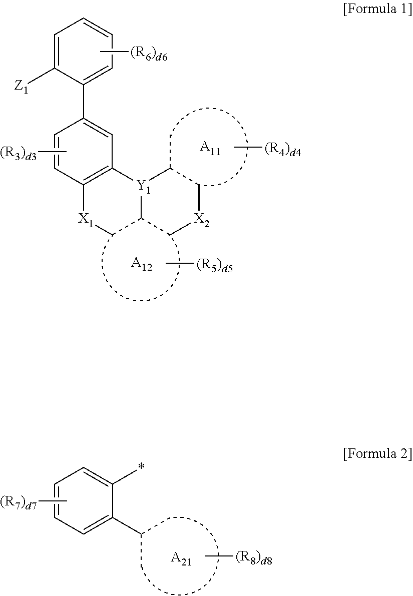

In Formulae 1 and 2,
X₁ may be O, S, Se, C(E₁₁)(E₁₂), Si(E₁₁)(E₁₂), or N(E₁₁),
X₂ may be O, S, Se, C(E₂₁)(E₂₂), Si(E₂₁)(E₂₂), or N(E₂₁),
Y₁ may be N, B, P(═O), or P(═S),
A₁₁, A₁₂, and A₂₁ may each independently be a C₅-C₃₀ carbocyclic group or a C₂-C₃₀ heterocyclic group,
E₁₁ may be *′-(L₁₁)ₙ₁₁-R₁₁,
E₁₂ may be *′-(L₁₂)ₙ₁₂-R₁₂,
E₂₁ may be *′-(L₂₁)ₙ₂₁-R₂₁,
E₂₂ may be *′-(L₂₂)ₙ₂₂-R₂₂,
L₁₁, L₁₂, L₂₁, and L₂₂ may each independently be a C₅-C₃₀ carbocyclic group that is unsubstituted or substituted with at least one R₁₀ₐ or a C₂-C₃₀ heterocyclic group that is unsubstituted or substituted with at least one R₁₀ₐ,
n11, n12, n21, and n22 may each independently be an integer from 0 to 3,
R₃ to R₈, R₁₁, R₁₂, R₂₁, and R₂₂ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —Si(Q₁)(Q₂)(Q₃), —B(Q₁)(Q₂), —C(═O)(Q₁), —S(═O)₂(Q₁), —O (Q₁), —S(Q₁), —Se(Q₁), —P(═O)(Q₁)(Q₂), or a group represented by Formula 2,
d3 may be an integer from 0 to 3,
d4, d5, and d8 may each independently be an integer from 0 to 10,
d6 and d7 may each independently be an integer from 0 to 4,
Z₁ may be a C₂-C₆₀ alkyl group that is unsubstituted or substituted with at least one R₁₀ₐ, a C₂-C₆₀ alkenyl group that is unsubstituted or substituted with at least one R₁₀ₐ, or a C₂-C₆₀ alkynyl group that is unsubstituted or substituted with at least one R₁₀ₐ,
two or more groups of Z₁, R₃ in the number of d3, R₄ in the number of d4, R₅ in the number of d5, R₆ in the number of d6, R₇ in the number of d7, R₈ in the number of d8, R₁₁, R₁₂, R₂₁, and R₂₂ may optionally be bonded together to form a C₅-C₃₀ carbocyclic group that is unsubstituted or substituted with at least one R₁₀ₐ or a C₂-C₃₀ heterocyclic group that is unsubstituted or substituted with at least one R₁₀ₐ,
* and *′ may each indicate a binding site to a neighboring atom,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —O (Q₁₁), —S(Q₁₁), —Se(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —O (Q₂₁), —S(Q₂₁), —Se(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —O (Q₃₁), —S(Q₃₁), —Se(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof, and
the condensed cyclic compound represented by Formula 1 may satisfy at least one of Condition 1 and Condition 2:
[Condition 1]
X₁ is N(E₁₁), and R₁₁ is a group represented by Formula 2;
[Condition 2]
X₂ is N(E₂₁), and R₂₁ is a group represented by Formula 2.

In an embodiment, the condensed cyclic compound represented by Formula 1 may be represented by one of Formulae 1-1 to 1-3, which are explained below.

In an embodiment, the group represented by Formula 2 may be a group represented by one of Formulae 2-1 to 2-16, which are explained below.

In an embodiment, in Formula 1, a moiety represented by

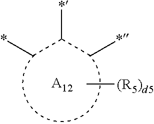

may be a moiety represented by one of Formulae 3-1 to 3-8, which are explained below.

In an embodiment, Z₁ may be:
a C₂-C₆₀ alkyl group, a C₂-C₆₀ alkenyl group, or a C₂-C₆₀ alkynyl group;
a C₂-C₂₀ alkyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a C₂-C₂₀ alkenyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof; or
a C₂-C₂₀ alkynyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof.

In an embodiment, in Formula 1, a moiety represented by

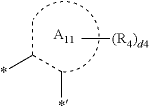

may be a moiety represented by one of Formulae 4-1 to 4-16, which are explained below.

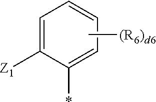

In an embodiment, in Formula 1, a moiety represented by may be a moiety represented by one of Formulae 5-1 to 5-3, which are explained below.

In an embodiment, the condensed cyclic compound may be one of Compounds 1 to 109, which are explained below.

According to embodiments, a light-emitting device may include a first electrode, a second electrode facing the first electrode, an interlayer between the first electrode and the second electrode and including an emission layer, and at least one condensed cyclic compound represented by Formula 1, which is explained herein.

In an embodiment, the first electrode may be an anode; the second electrode may be a cathode; the interlayer may include the condensed cyclic compound; the interlayer may further include a hole transport region between the first electrode and the emission layer, and an electron transport region between the emission layer and the second electrode; the hole transport region may include a hole injection layer, a hole transport layer, an emission auxiliary layer, an electron blocking layer, or any combination thereof; and the electron transport region may include a hole blocking layer, an electron transport layer, an electron injection layer, or any combination thereof.

In an embodiment, the emission layer may include the condensed cyclic compound.

In an embodiment, an amount of the condensed cyclic compound may be in a range of about 0.01 parts by weight to about 49.99 parts by weight, based on 100 parts by weight of the emission layer.

In an embodiment, the emission layer may further include a first compound, and a second compound; the first compound may be a hole transport compound including at least one electron donating group; and the second compound may be an electron transport compound including at least one electron withdrawing group.

In an embodiment, the emission layer may further include a third compound, and the third compound may be a metal-containing compound.

In an embodiment, the emission layer may emit light having a maximum emission wavelength in a range of about 400 nm to about 500 nm.

According to embodiments, an electronic apparatus may include the light-emitting device.

In an embodiment, the electronic apparatus may further include a thin-film transistor, wherein the thin-film transistor may include a source electrode and a drain electrode, and the first electrode of the light-emitting device may be electrically connected to at least one of the source electrode and the drain electrode.

In an embodiment, the electronic apparatus may further include a color filter, a color conversion layer, a touch screen layer, a polarizing layer, or any combination thereof.

In an embodiment, the electronic apparatus may further include: a thin-film transistor; and a color filter, a color conversion layer, a touch screen layer, a polarizing layer, or any combination thereof. The thin-film transistor may include a source electrode and a drain electrode, and the first electrode of the light-emitting device may be electrically connected to at least one of the source electrode and the drain electrode.

According to embodiments, an electronic device may include the light-emitting device.

In an embodiment, the electronic device may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

It is to be understood that the embodiments above are described in a generic and explanatory sense only and not for the purpose of limitation, and the disclosure is not limited to the embodiments described above.

Additional aspects will be set forth in part in the description which follows and, in part, will be apparent from the description, or may be learned by practice of the embodiments of the disclosure.

### BRIEF DESCRIPTION OF THE DRAWINGS

The above and other aspects and features of the disclosure will be more apparent by describing in detail embodiments thereof with reference to the accompanying drawings, in which:

FIG. 1 is a schematic cross-sectional view of a light-emitting device according to an embodiment;

FIG. 2 is a schematic cross-sectional view of an electronic apparatus according to an embodiment;

FIG. 3 is a schematic cross-sectional view of an electronic apparatus according to an embodiment;

FIG. 4 is a schematic perspective view of an electronic device including a light-emitting device, according to an embodiment;

FIG. 5 is a schematic perspective view of an exterior of a vehicle as an electronic device including a light-emitting device, according to an embodiment; and

FIGS. 6A to 6C are each a schematic diagram of an interior of the vehicle, according to embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

A condensed cyclic compound may be represented by Formula 1:

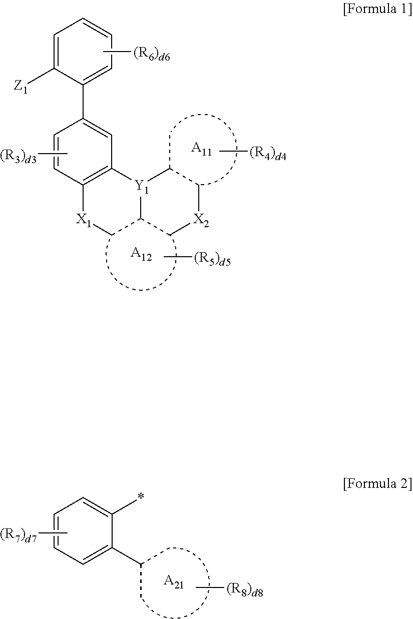

In Formulae 1 and 2,
X₁ may be O, S, Se, C(E₁₁)(E₁₂), Si(E₁₁)(E₁₂), or N(E₁₁), and
X₂ may be O, S, Se, C(E₂₁)(E₂₂), Si(E₂₁)(E₂₂), or N(E₂₁).

For example, X₁ may be N(E₁₁), and X₂ may be N(E₂₁).

In an embodiment, X₁ may be N(E₁₁), and X₂ may be N(E₂₁), wherein E₁₁ and E₂₁ may be identical to or different from each other.

In Formulae 1 and 2, Y₁ may be N, B, P(═O), or P(═S).

For example, Y₁ may be B.

In Formulae 1 and 2, A₁₁, A₁₂, and A₂₁ may each independently be a C₅-C₃₀ carbocyclic group or a C₂-C₃₀ heterocyclic group.

In an embodiment, A₁₁, A₁₂, and A₂₁ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzotriazole, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In Formulae 1 and 2, E₁₁ may be *′-(L₁₁)ₙ₁₁-R₁₁,
E₁₂ may be *′-(L₁₂)ₙ₁₂-R₁₂,
E₂₁ may be *′-(L₂₁)ₙ₂₁-R₂₁, and
E₂₂ may be *′-(L₂₂)ₙ₂₂-R₂₂.

In Formulae 1 and 2, LiI, L₁₂, L₂₁, and L₂₂ may each independently be a C₅-C₃₀ carbocyclic group that is unsubstituted or substituted with at least one R₁₀ₐ or a C₂-C₃₀ heterocyclic group that is unsubstituted or substituted with at least one R₁₀ₐ.

In an embodiment, L₁₁, L₁₂, L₂₁, and L₂₂ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzotriazole, a benzoxazole group, a benzothiazole group, a benzoxadiazole group, a benzothiadiazole group, a 5,6,7,8-tetrahydroisoquinoline group, or a 5,6,7,8-tetrahydroquinoline group, each unsubstituted or substituted with at least one R₁₀ₐ, and

R₁₀ₐ may be the same as described in the specification.

In an embodiment, L₁₁, L₁₂, L₂₁, and L₂₂ may each independently be one of groups represented by Formulae 8-1 to 8-40:

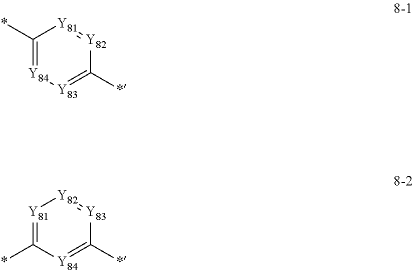

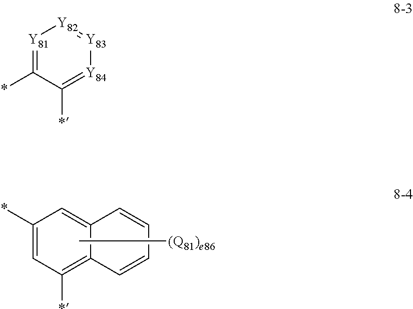

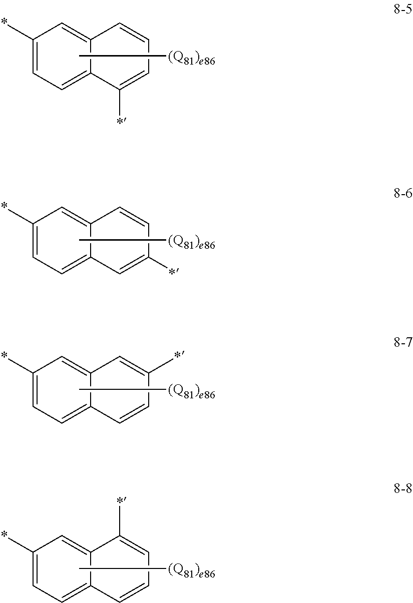

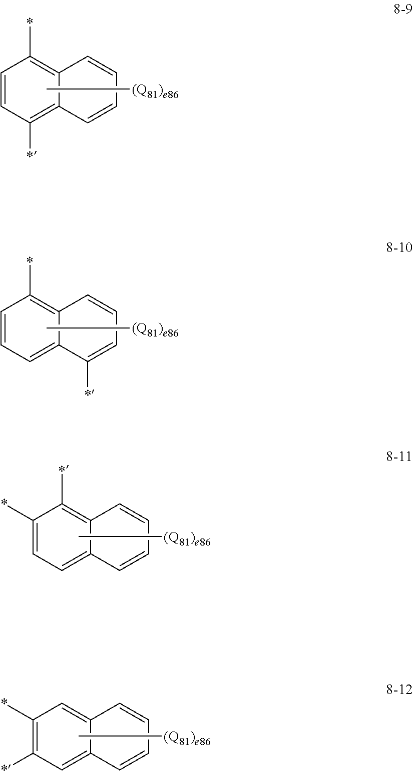

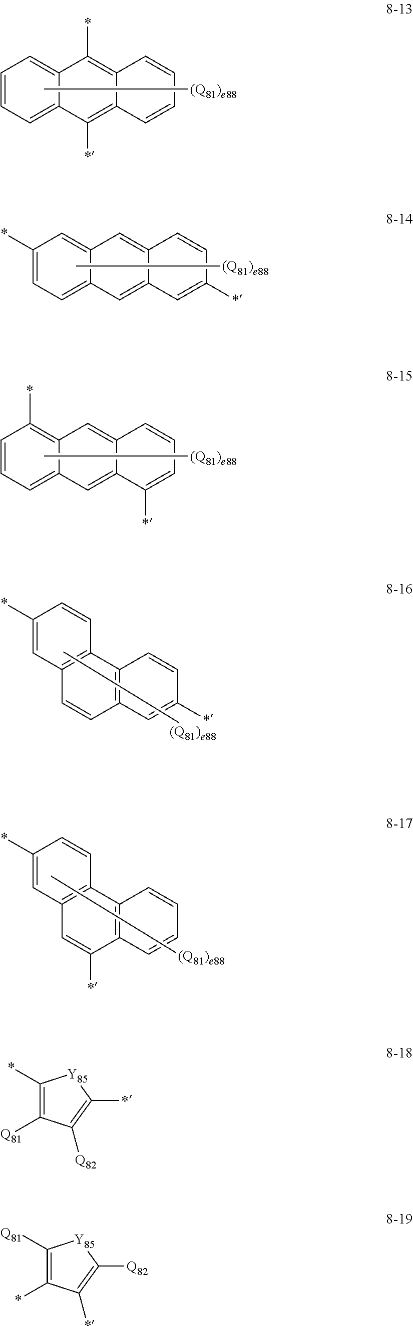

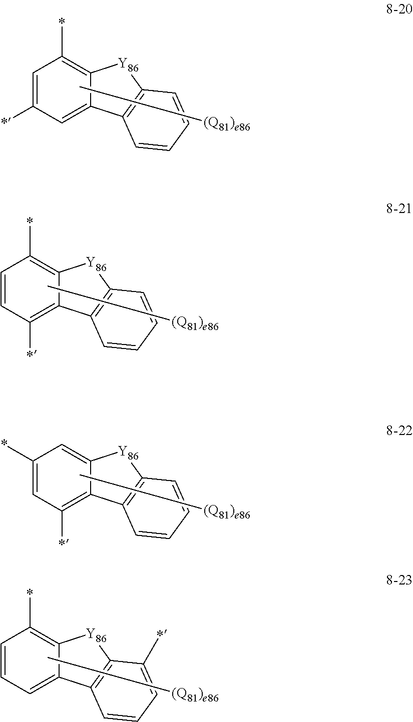

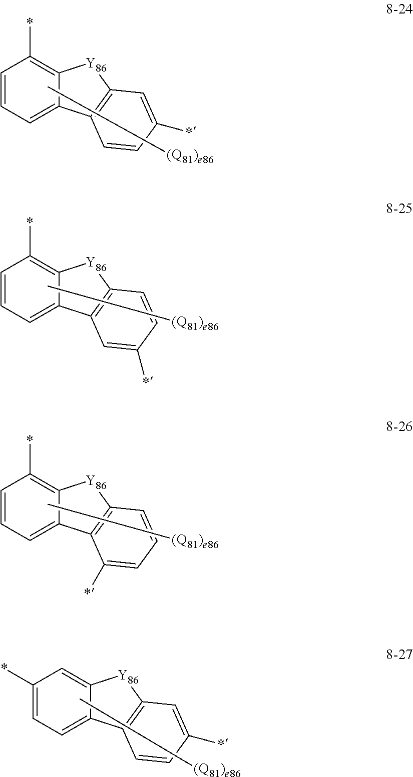

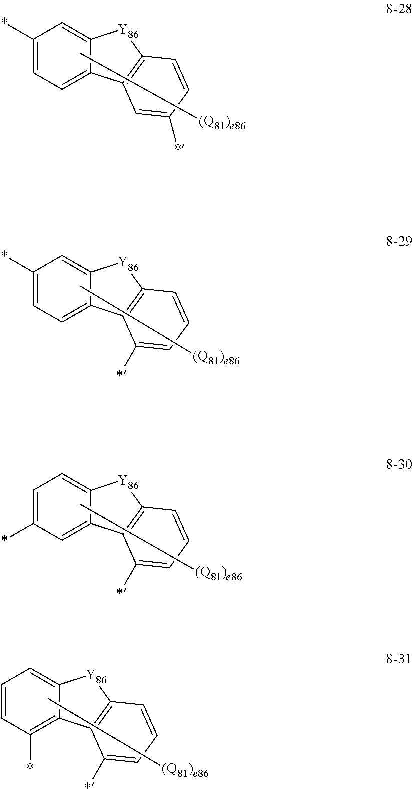

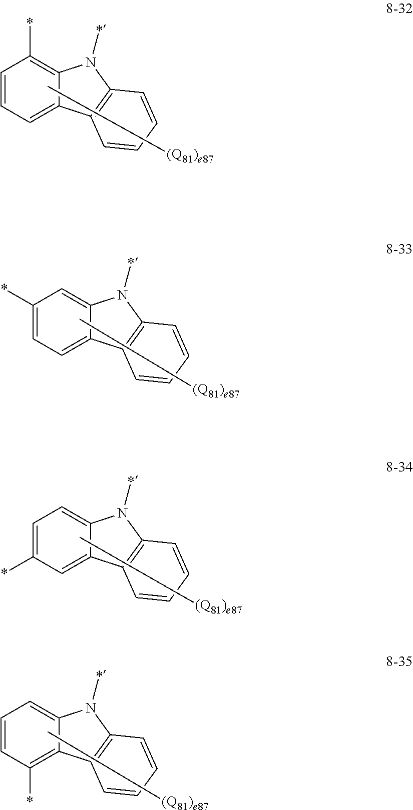

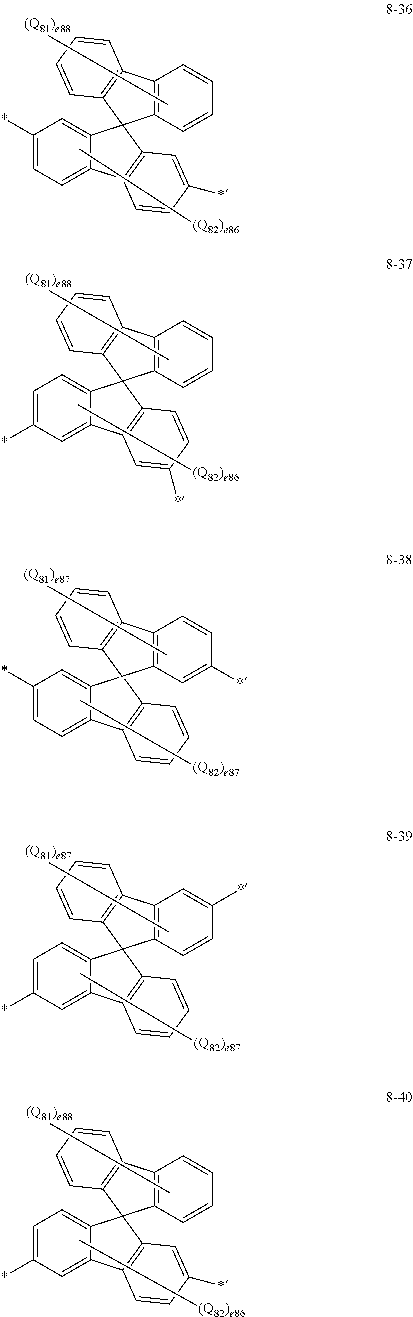

In Formulae 8-1 to 8-40,
Y₈₁ may be N or C(Q₈₃),
Y₈₂ may be N or C(Q₈₄),
Y₈₃ may be N or C(Q₈₅),
Y₈₄ may be N or C(Q₈₆),
Y₈₅ may be O, S, or Se,
Y₈₆ may be O, S, Se, N(Q₈₇), or C(Q₈₇)(Q₈₈),
e86 may be an integer from 0 to 6,
e87 may be an integer from 0 to 7,
e88 may be an integer from 0 to 8,
Q₈₁ to Q₈₈ may each independently be:
hydrogen, deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —B(Q₃₁)(Q₃₂), —C(═O)(Q₃₁), —S(═O)₂(Q₃₁), or —P(═O)(Q₃₁)(Q₃₂), and
Q₁₁ to Q₁₃, Q₂₁ to Q₂₃, and Q₃₁ to Q₃₃ may each be the same as described in the specification.

In Formulae 1 and 2, n11, n12, n21, and n22 may each independently be an integer from 0 to 3.

In Formulae 1 and 2, n11, n12, n21, and n22 indicate numbers of L₁₁, L₁₂, L₂₁, and L₂₂, respectively, and n11, n12, n21, and n22 may each independently be an integer from 0 to 3. When n11 is 0, L₁₁ may be a single bond, when n11 is 2 or more, two or more L₁₁(s) may be identical to or different from each other, when n12 is 0, L₁₂ may be a single bond, when n21 is 2 or more, two or more L₂₁(5) may be identical to or different from each other, when n22 is 0, L₂₂ may be a single bond, and when n22 is 2 or more, two or more L₂₂(5) may be identical to or different from each other.

In an embodiment, X₁ may be N(E₁₁), and X₂ may be N(E₂₁), wherein the sum of n11 and n21 may be 0, 1, 2, or 3.

In Formulae 1 and 2, R₃ to R₈, R₁₁, R₁₂, R₂₁, and R₂₂ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —Si(Q₁)(Q₂)(Q₃), —B(Q₁)(Q₂), —C(═O)(Q₁), —S(═O)₂(Q₁), —O(Q₁), —S(Q₁), —Se(Q₁), —P(═O)(Q₁)(Q₂), or a group represented by Formula 2.

In an embodiment, R₃ to R₈, R₁₁, R₁₂, R₂₁, and R₂₂ may each independently be:
hydrogen, deuterium, —F, —Cl, —Br, —I, a hydroxyl group, a cyano group, a nitro group, an amidino group, a hydrazine group, a hydrazone group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a thiadiazolyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a thiadiazolyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, —Si(Q₃₁)(Q₃₂)(Q₃₃), —B(Q₃₁)(Q₃₂), —P(Q₃₁)(Q₃₂), —C(═O)(Q₃₁), —S(═O)₂(Q₃₁), —O (Q₃₁), —S(Q₃₁), —Se(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), —O (Q₁), —S(Q₁), —Se(Q₁), or —P(═O)(Q₁)(Q₂), or
R₃ to R₈, R₁₁, R₁₂, R₂₁, and R₂₂ may each independently be: hydrogen;
deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, R₃ to R₈, R₁₁, R₁₂, R₂₁, and R₂₂ may each independently be:
hydrogen, deuterium, —F, —Cl, —Br, —I, —CD₃, —CD₂H, —CDH₂, —CF₃, —CF₂H, —CFH₂, a cyano group, a nitro group, a C₁-C₆₀ alkyl group, a C₂-C₆₀ alkenyl group, a C₂-C₆₀ alkynyl group, or a C₁-C₆₀ alkoxy group;
a group represented by one of Formulae 9-1 to 9-61;
a group represented by one of Formulae 10-1 to 10-348; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), —O(Q₁), —S(Q₁), —Se(Q₁), or —P(═O)(Q₁)(Q₂):

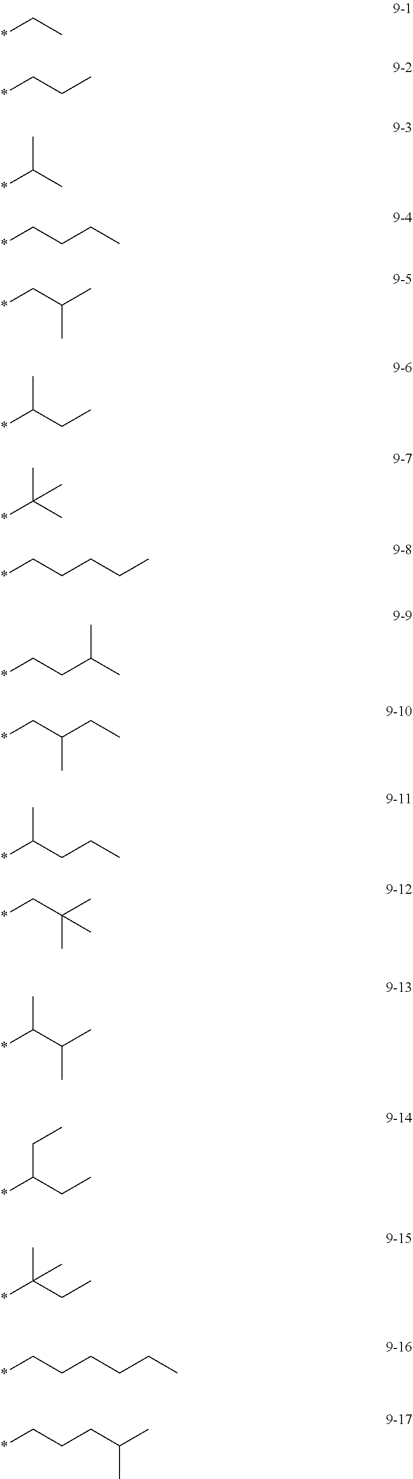

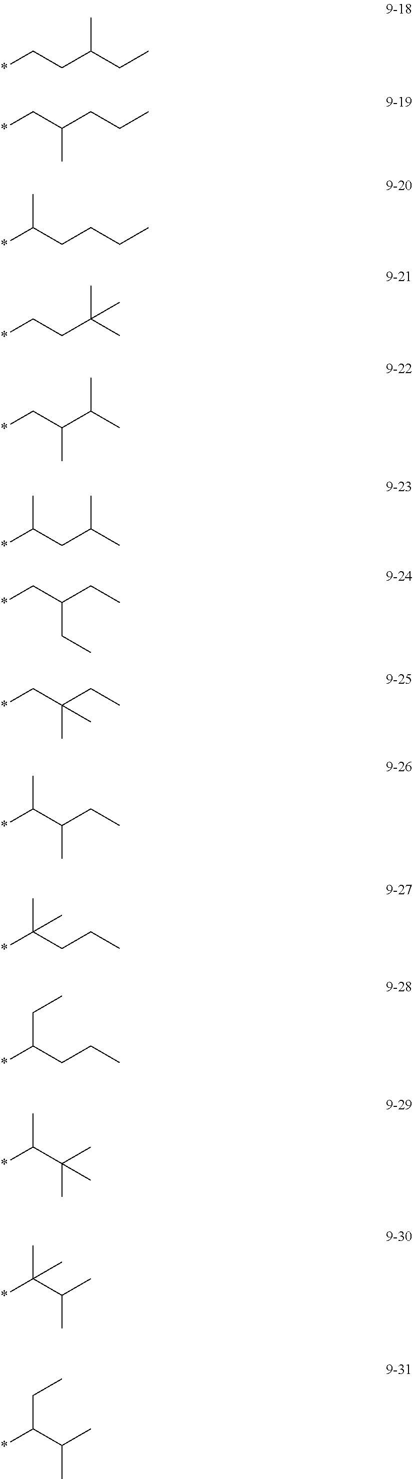

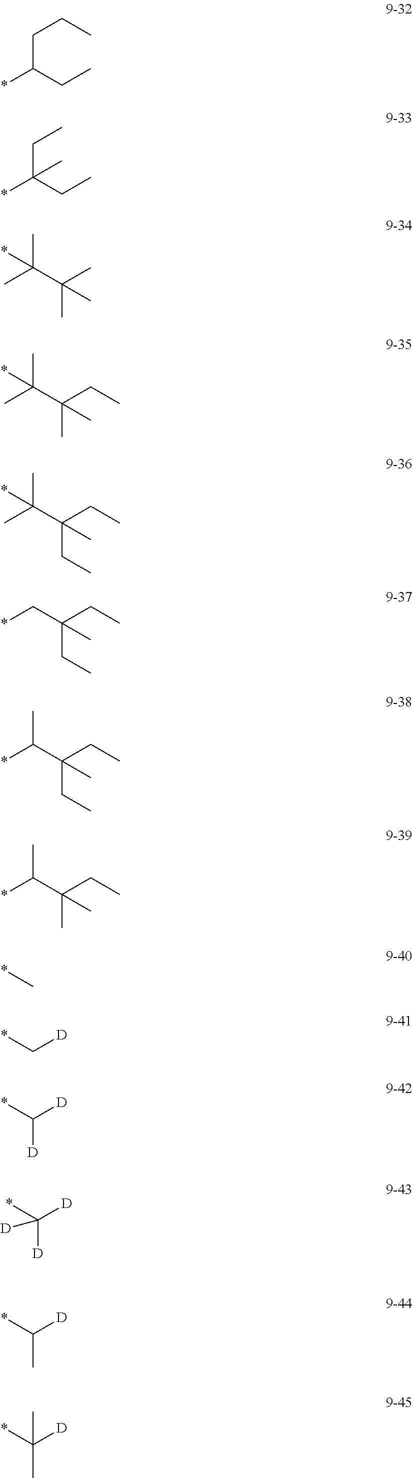

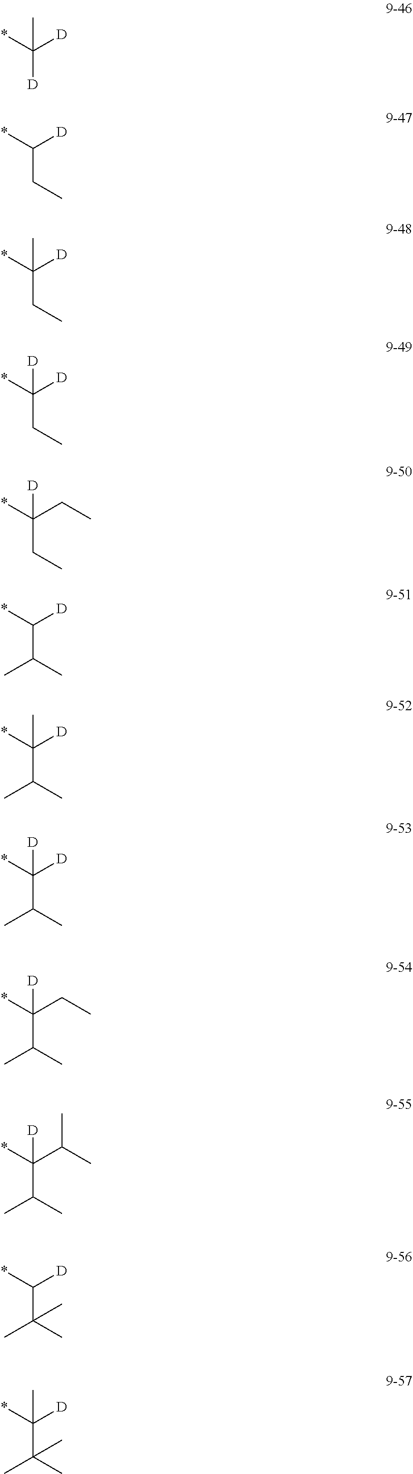

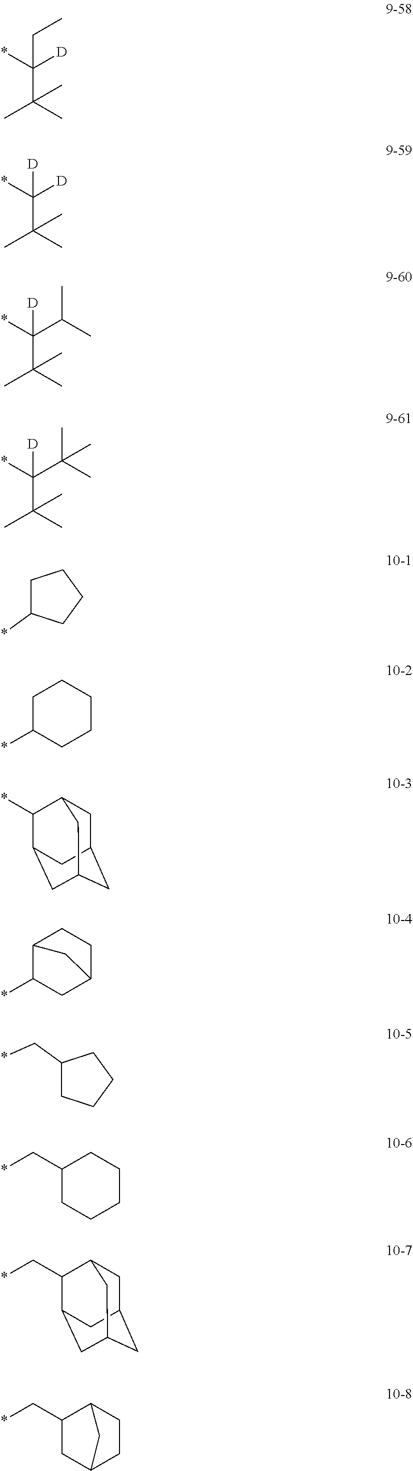

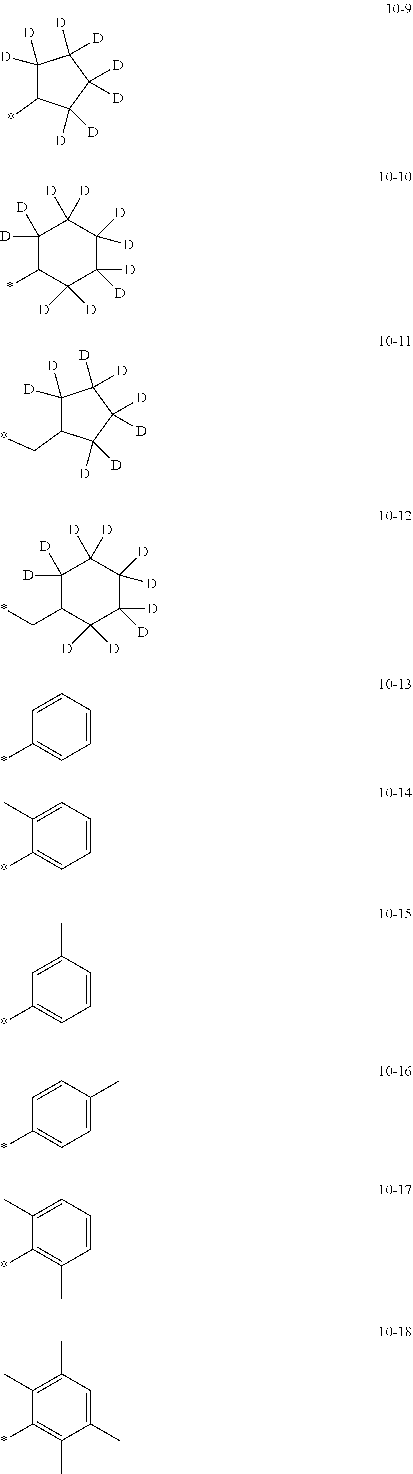

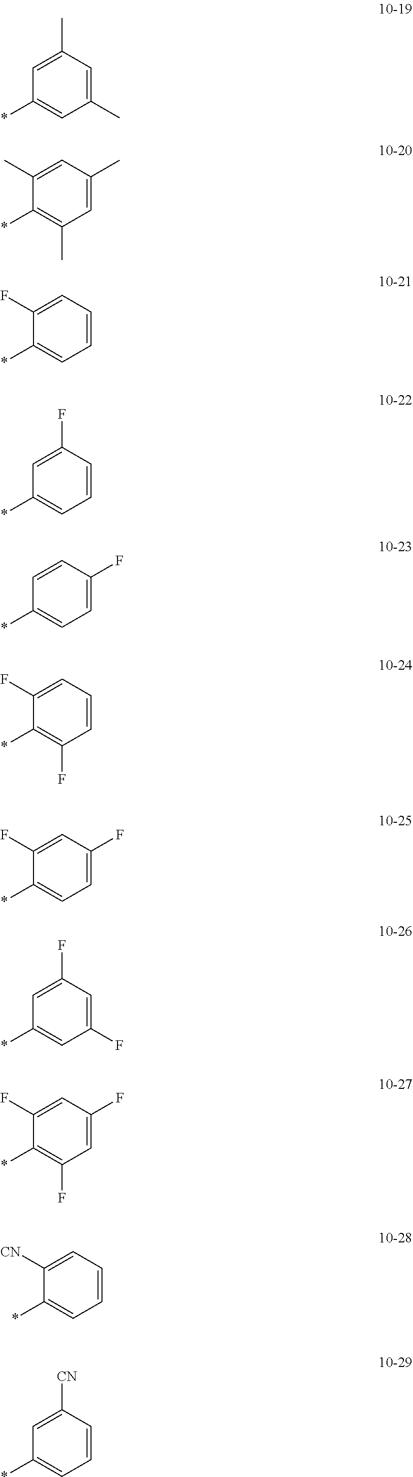

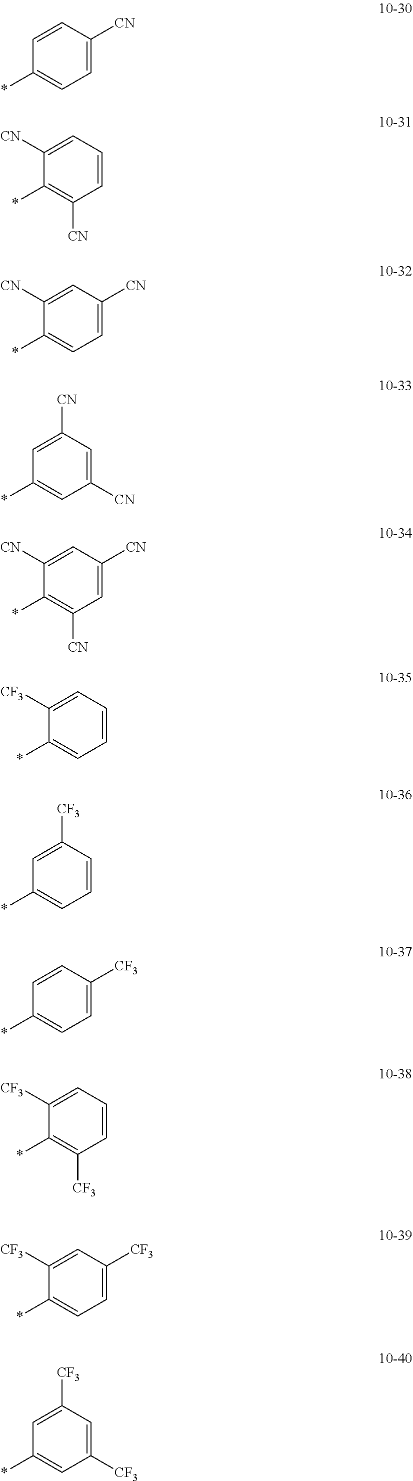

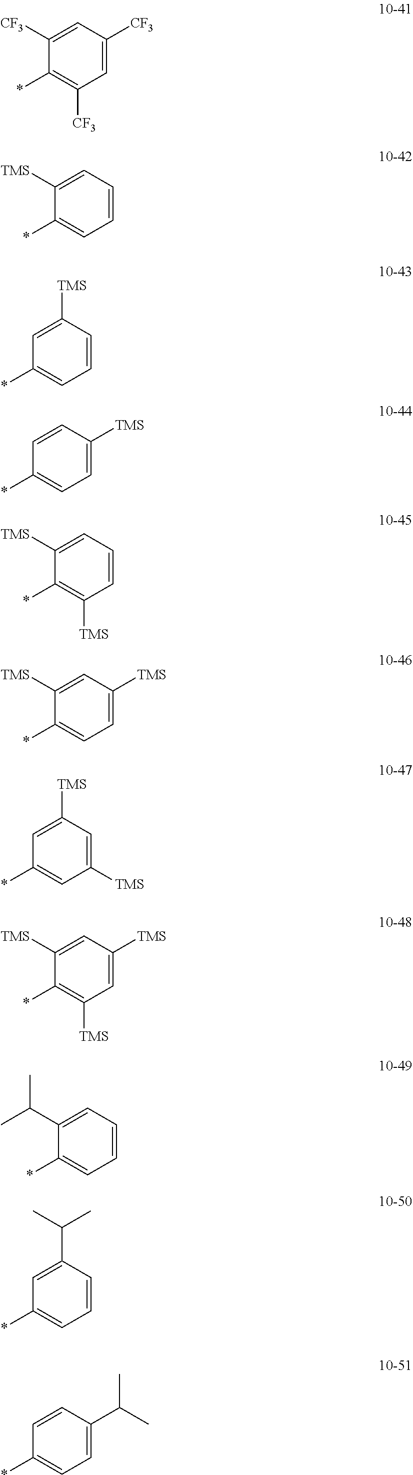

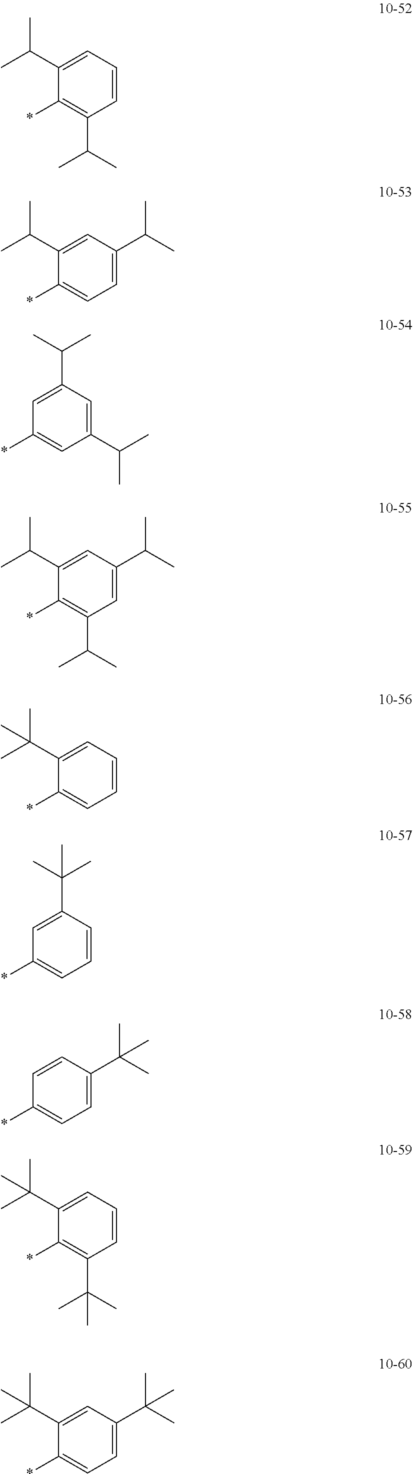

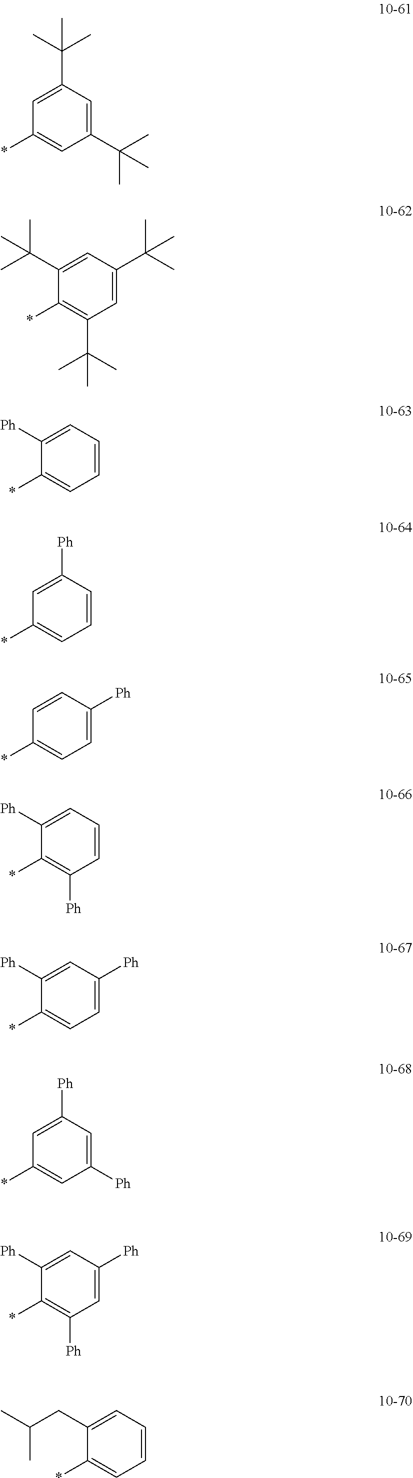

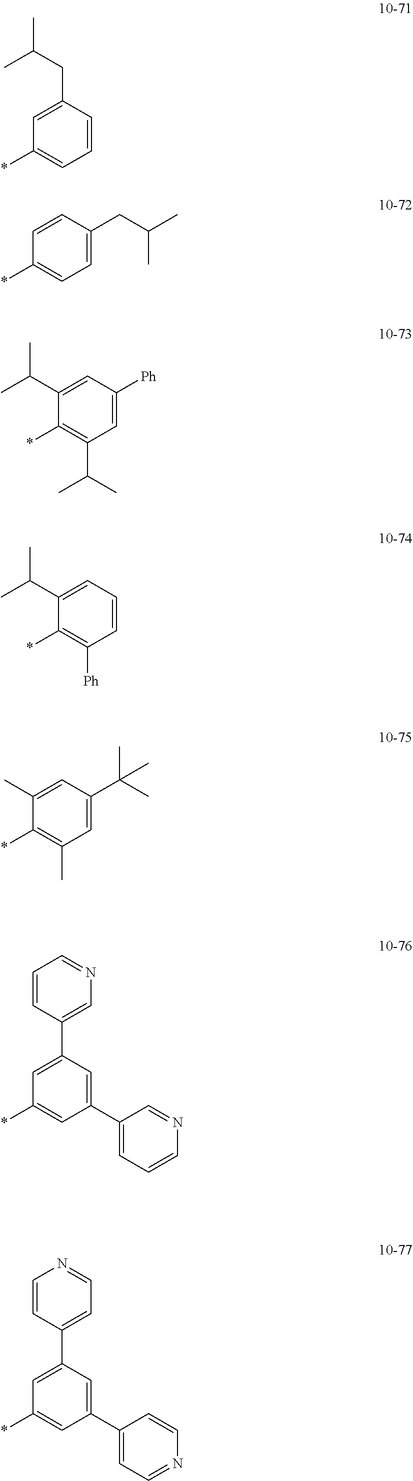

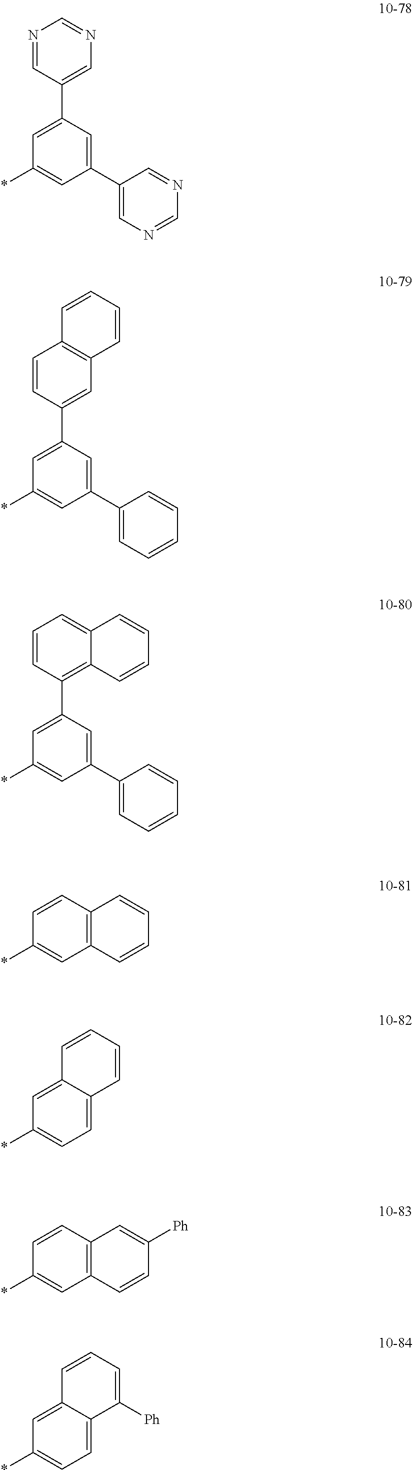

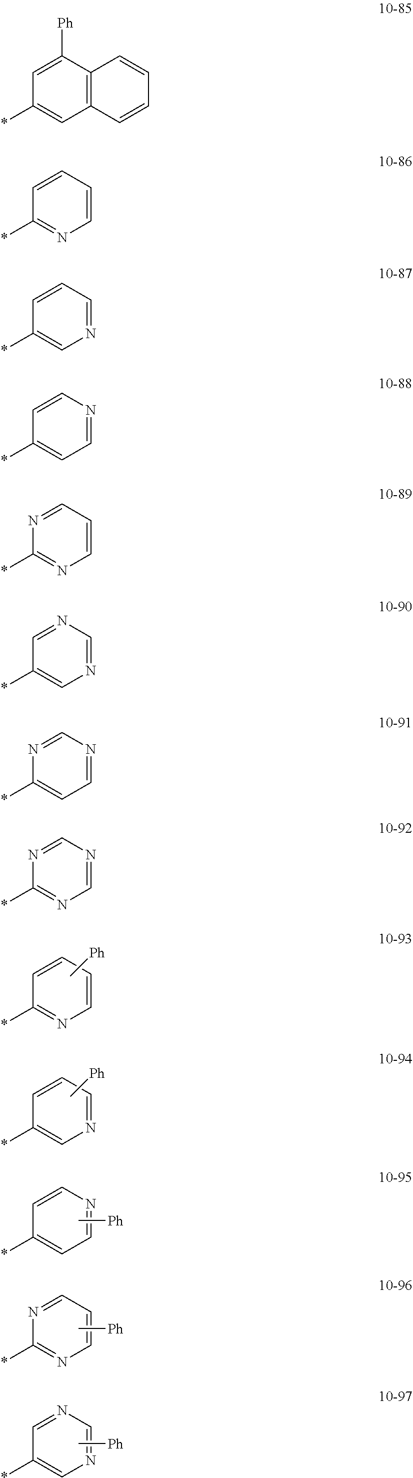

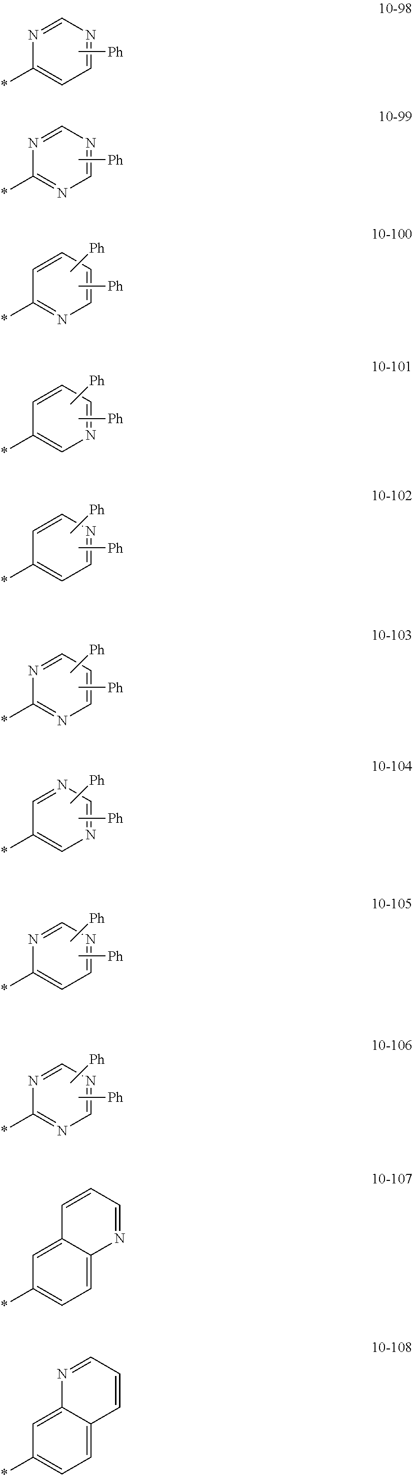

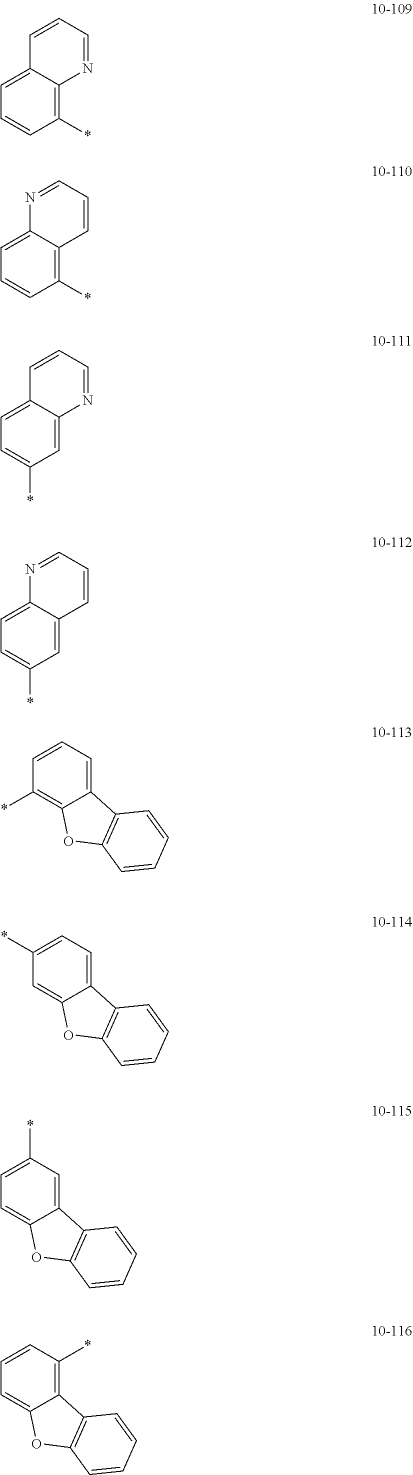

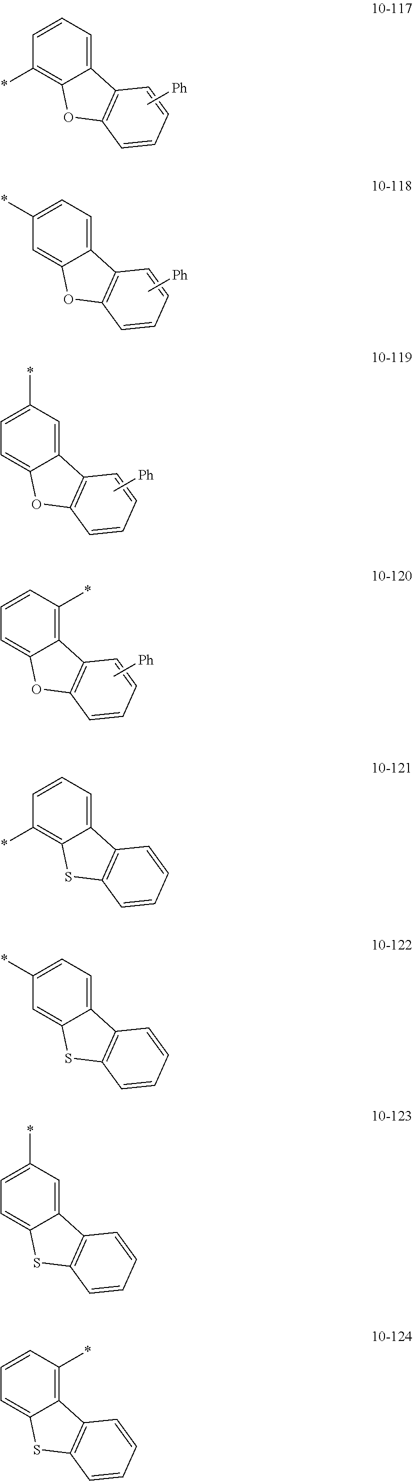

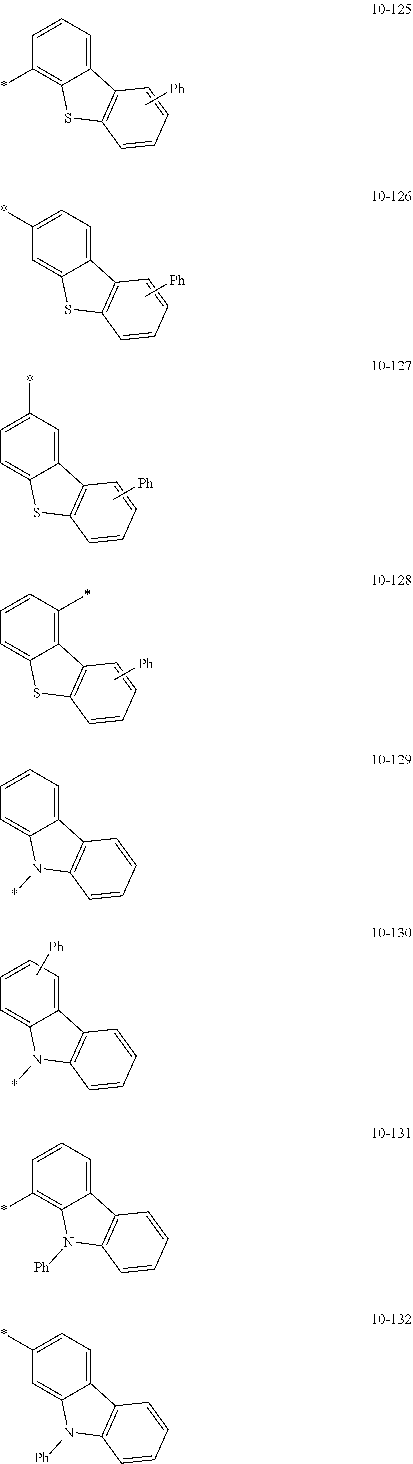

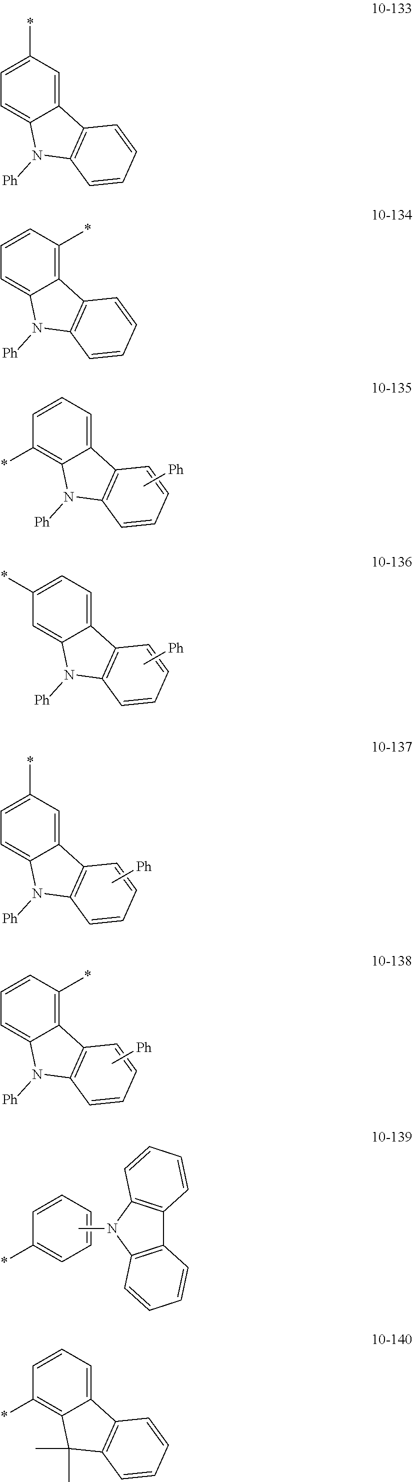

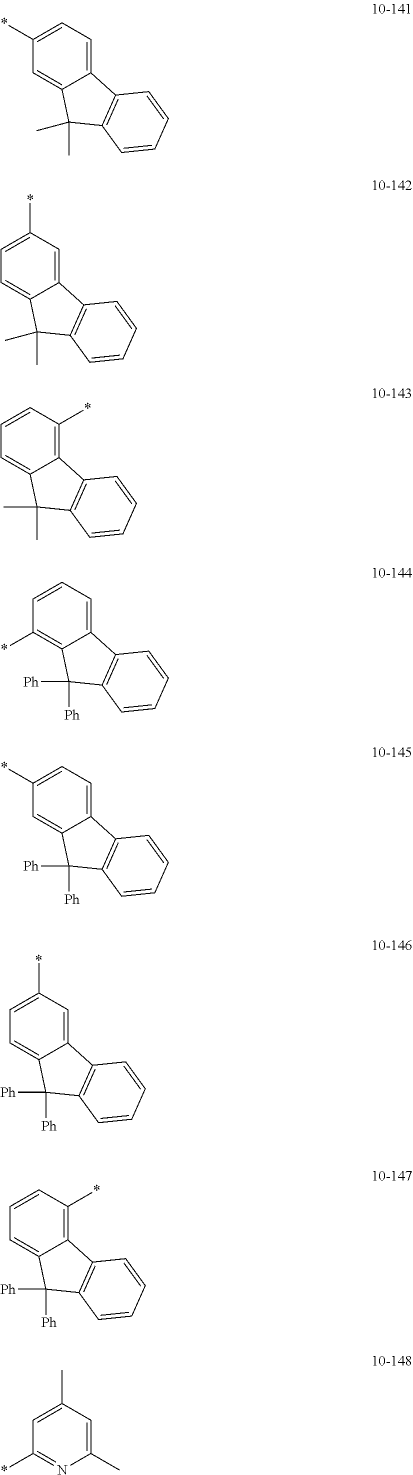

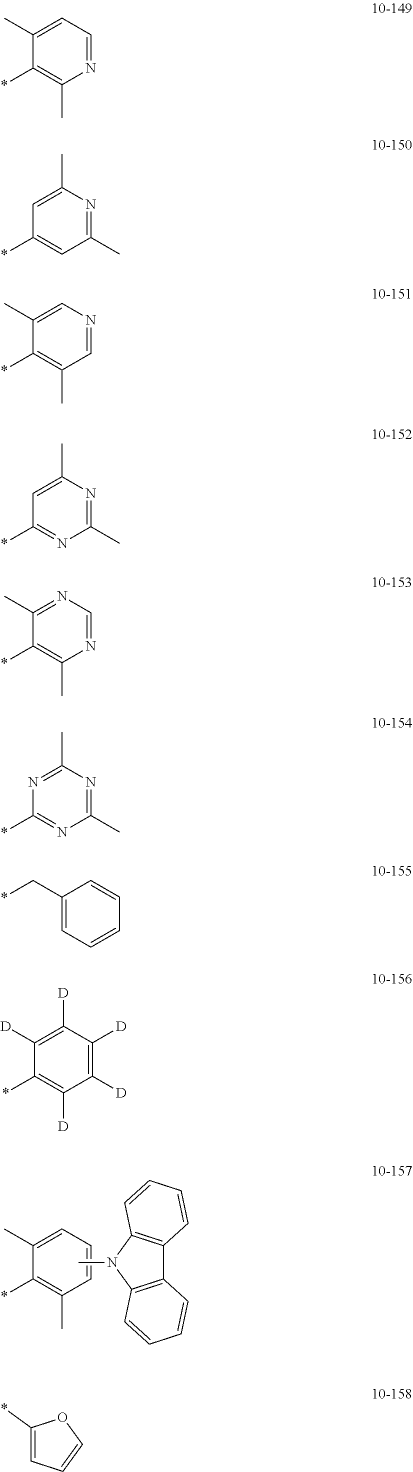

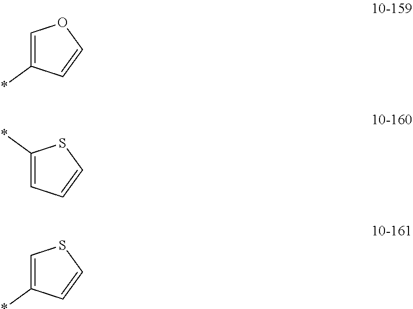 [SMILES: *c1ccoc1 ; *c1cccs1 ; *c1ccsc1]

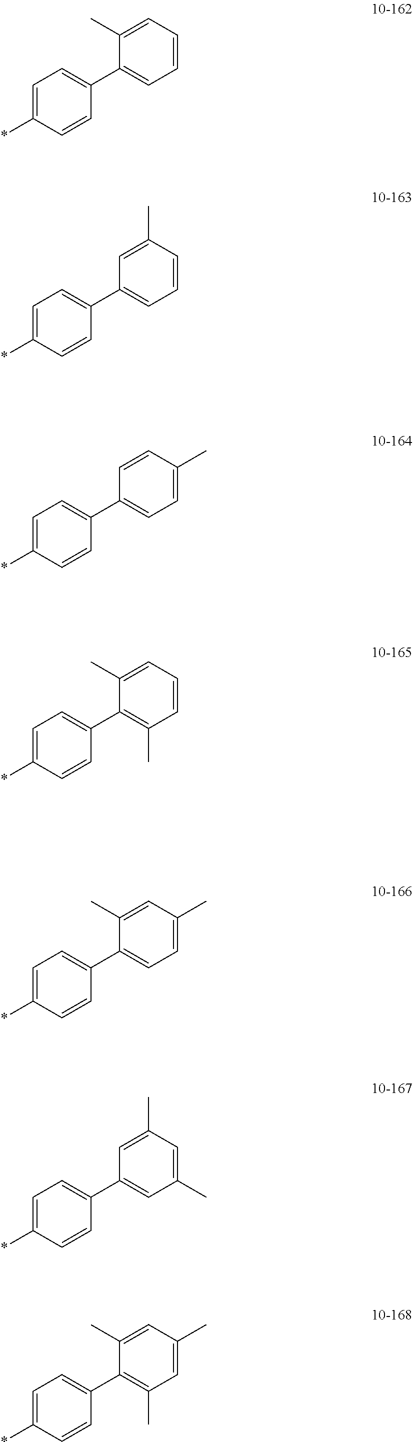

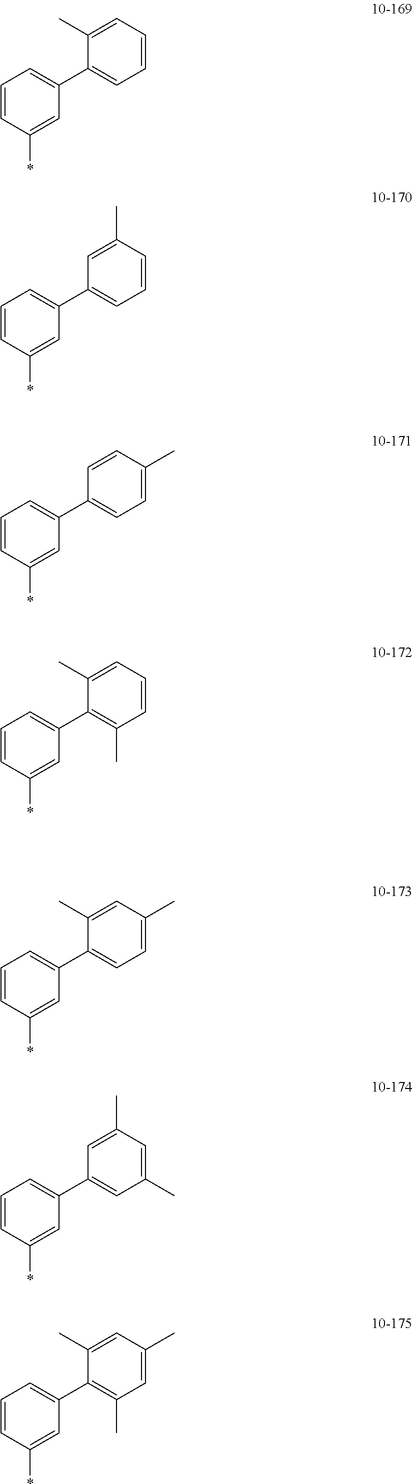

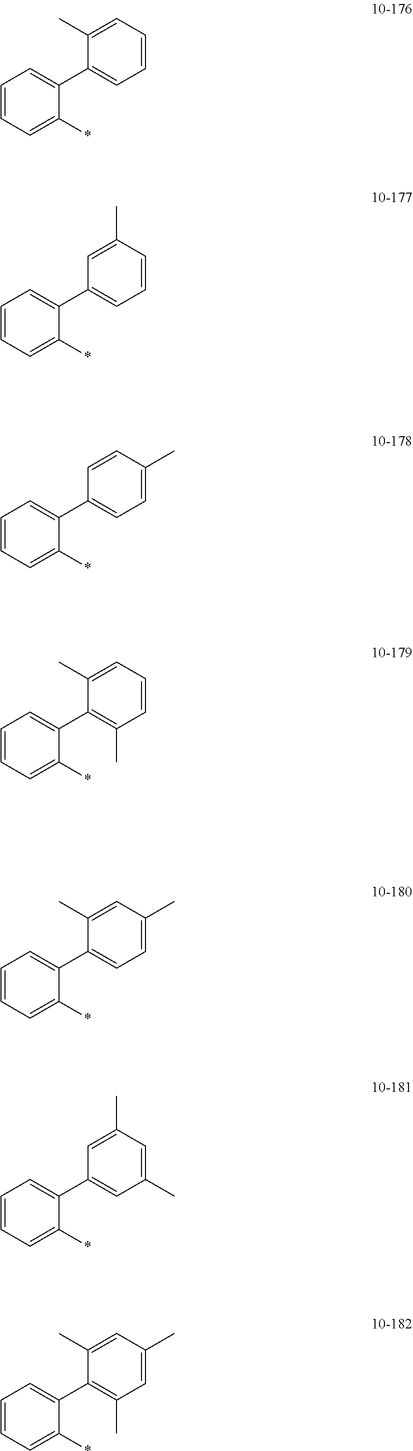

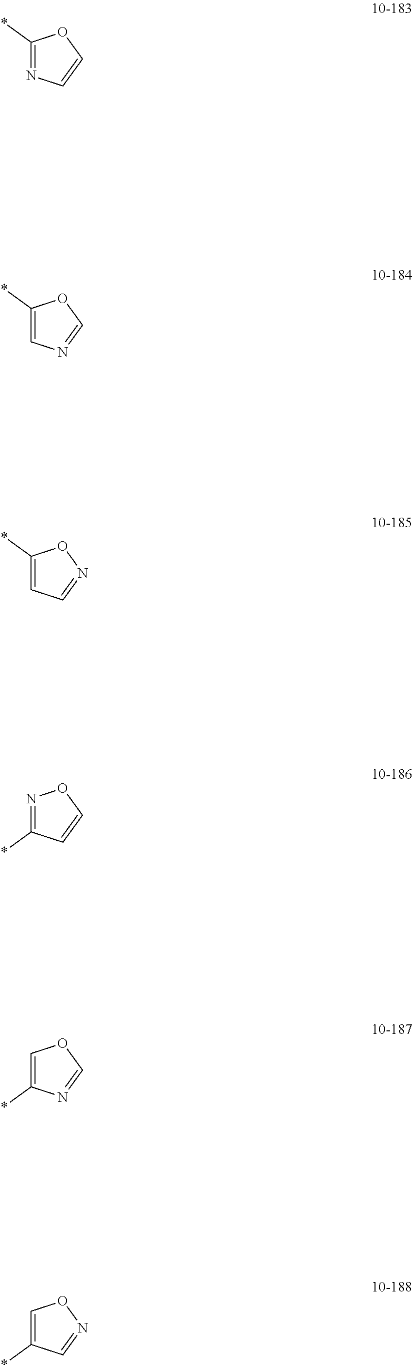 [SMILES: *c1ncco1 ; *c1cnco1 ; *c1ccno1 ; *c1ccon1 ; *c1cocn1 ; *c1cnoc1]

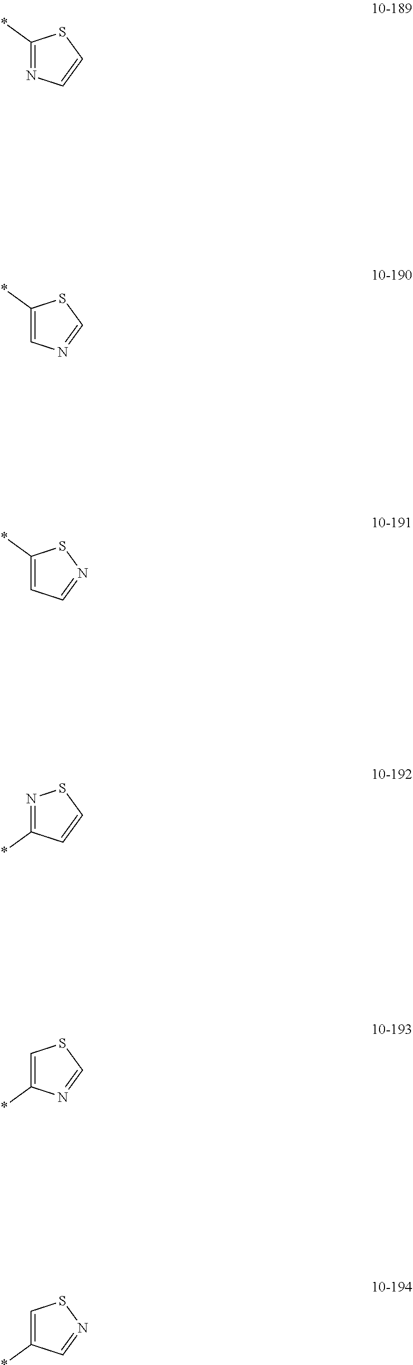 [SMILES: *c1nccs1 ; *c1cncs1 ; *c1ccns1 ; *c1ccsn1 ; *c1cscn1 ; *c1cnsc1]

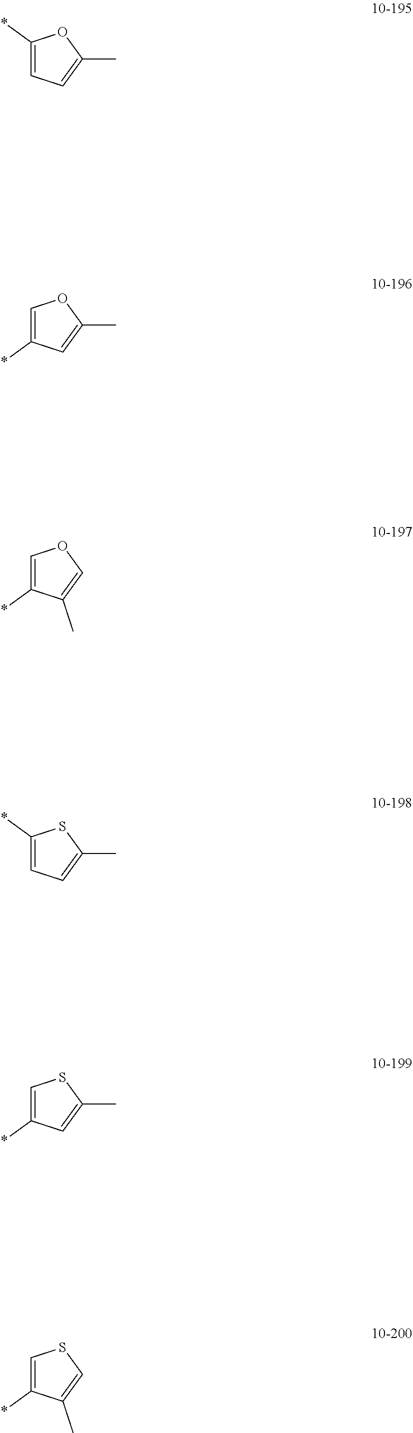

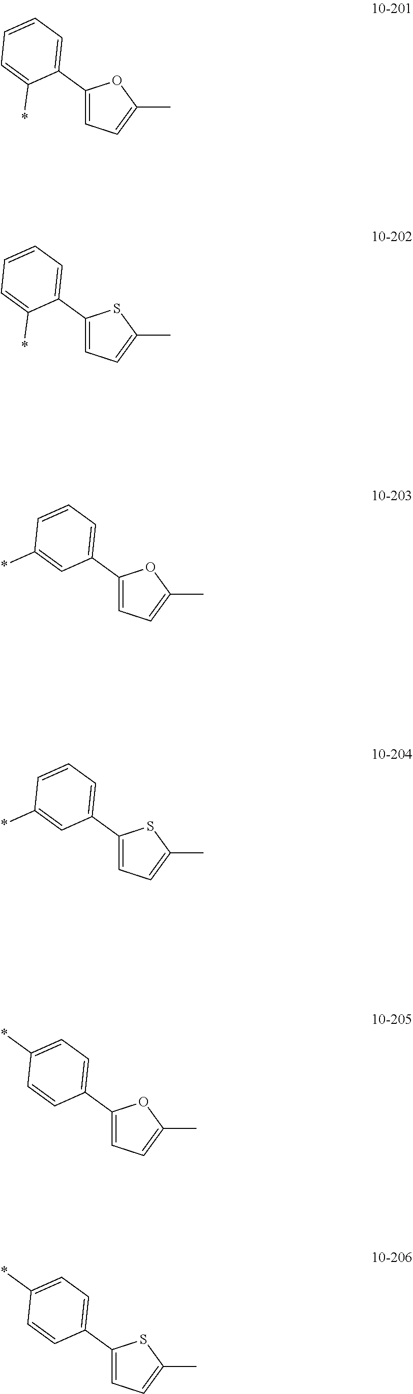 [SMILES: *c1ccccc1-c1ccc(C)o1 ; *c1ccccc1-c1ccc(C)s1 ; *c1cccc(-c2ccc(C)o2)c1 ; *c1cccc(-c2ccc(C)s2)c1 ; *c1ccc(-c2ccc(C)o2)cc1 ; *c1ccc(-c2ccc(C)s2)cc1]

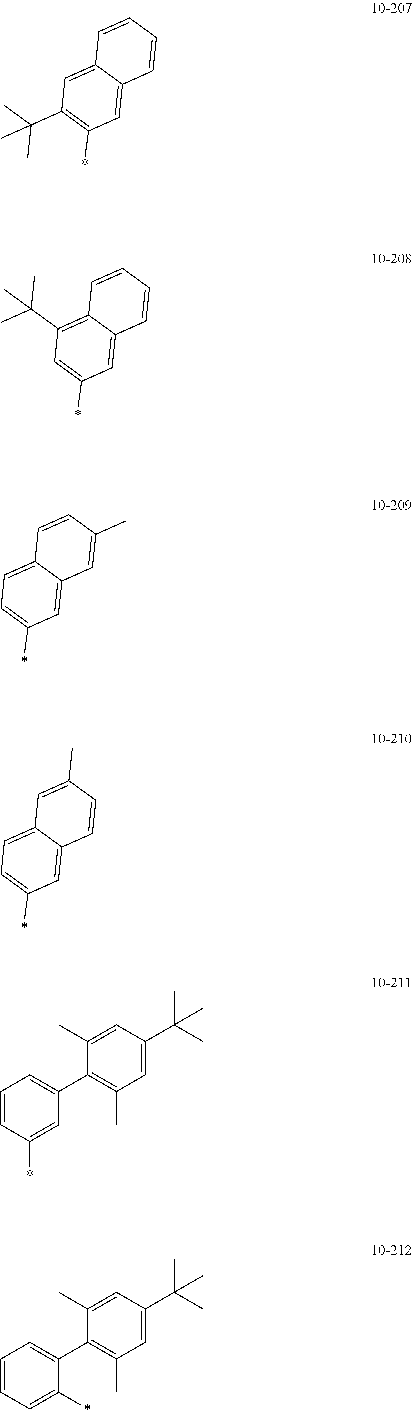 [SMILES: *c1cc2ccccc2cc1C(C)(C)C ; *c1cc(C(C)(C)C)c2ccccc2c1 ; *c1ccc2ccc(C)cc2c1 ; *c1ccc2cc(C)ccc2c1 ; *c1cccc(-c2c(C)cc(C(C)(C)C)cc2C)c1 ; *c1ccccc1-c1c(C)cc(C(C)(C)C)cc1C]

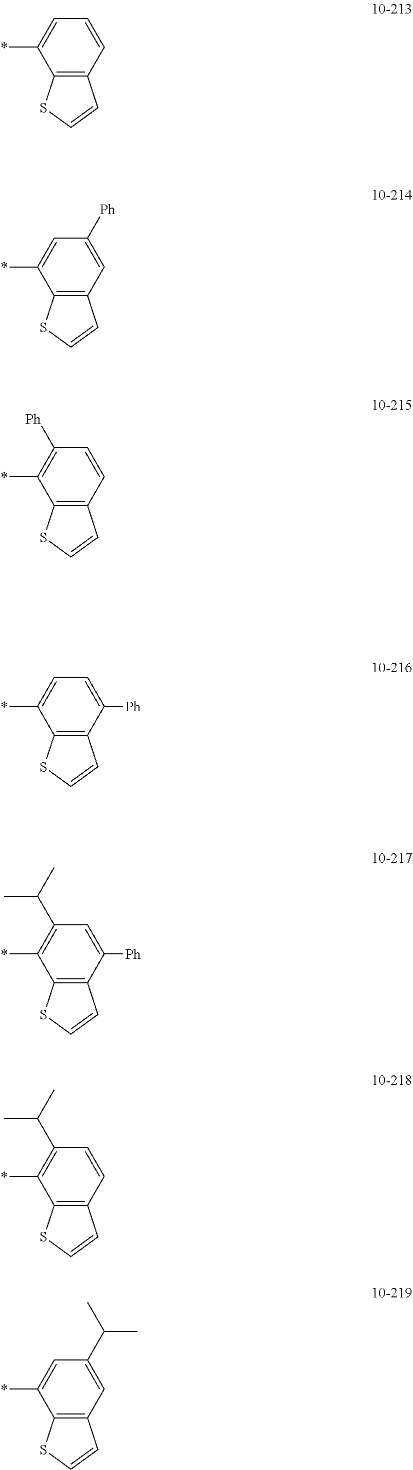

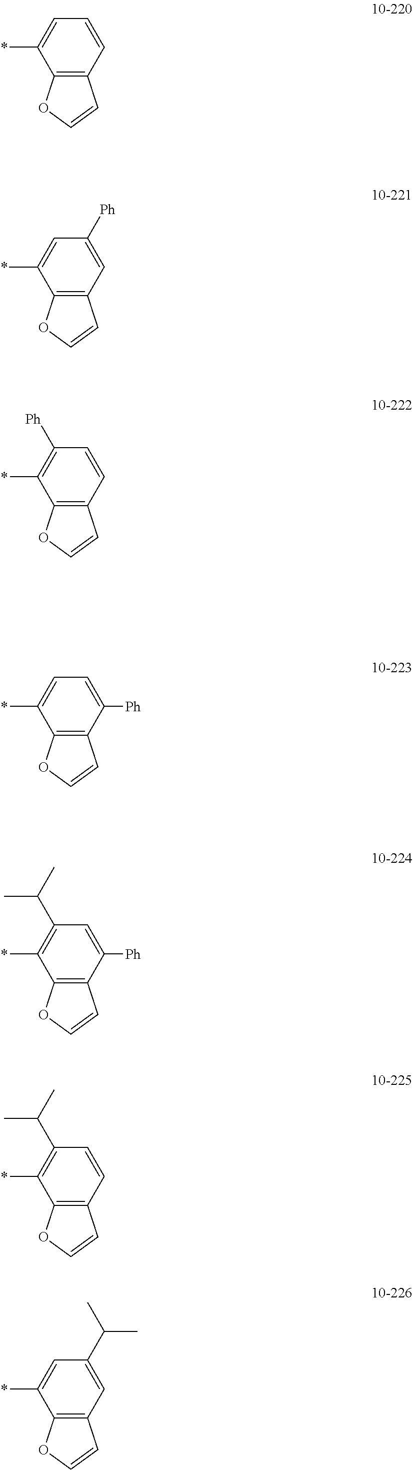

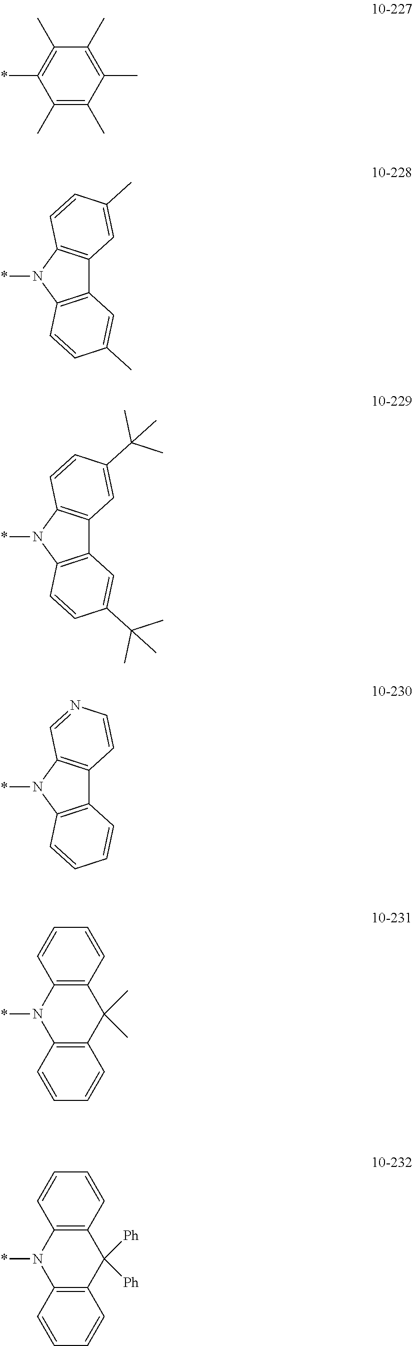

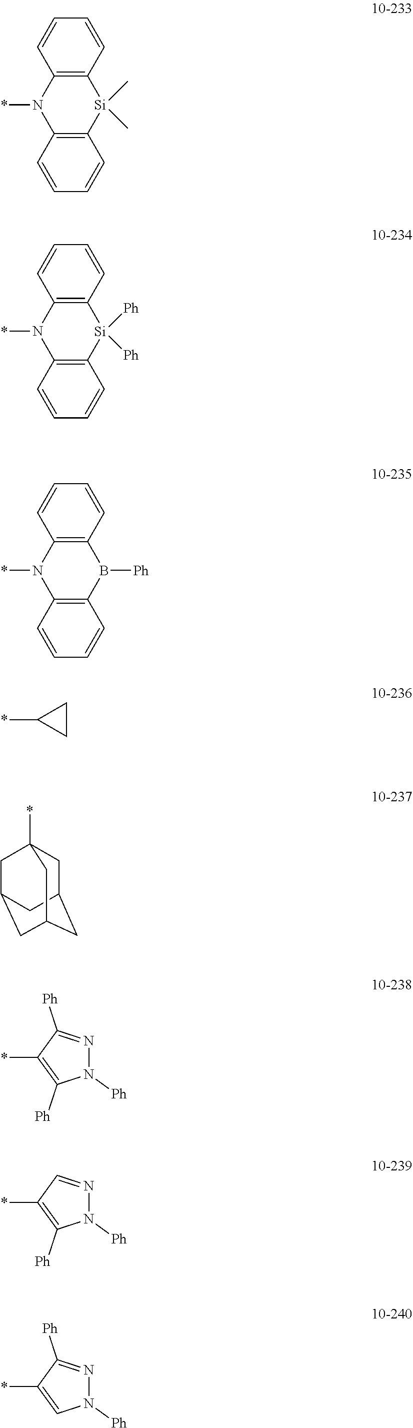

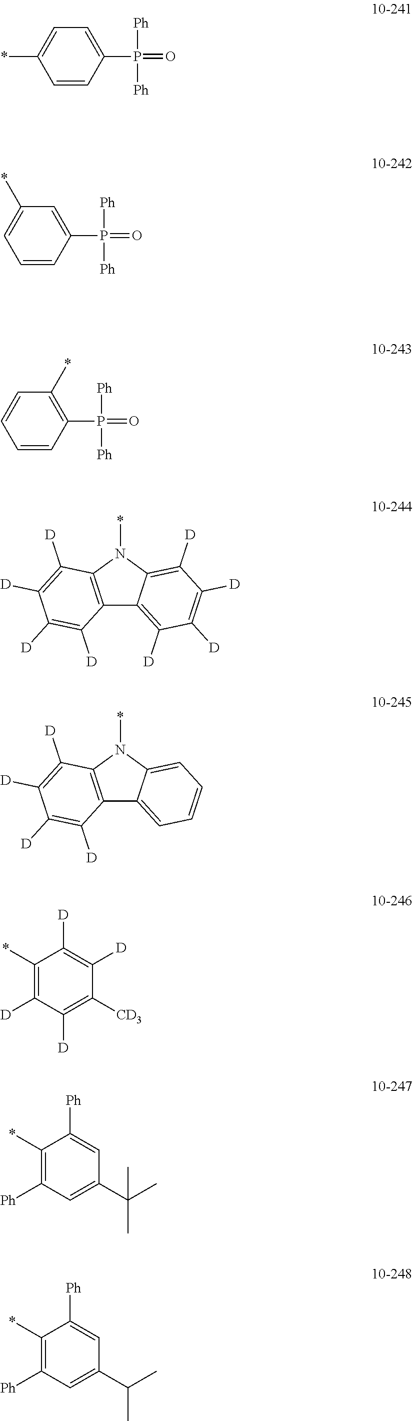

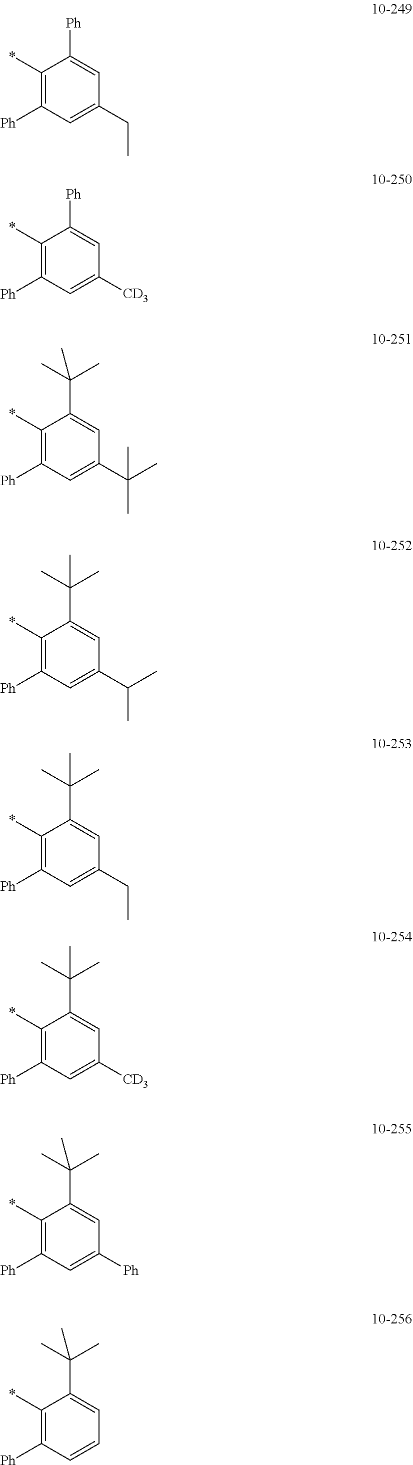

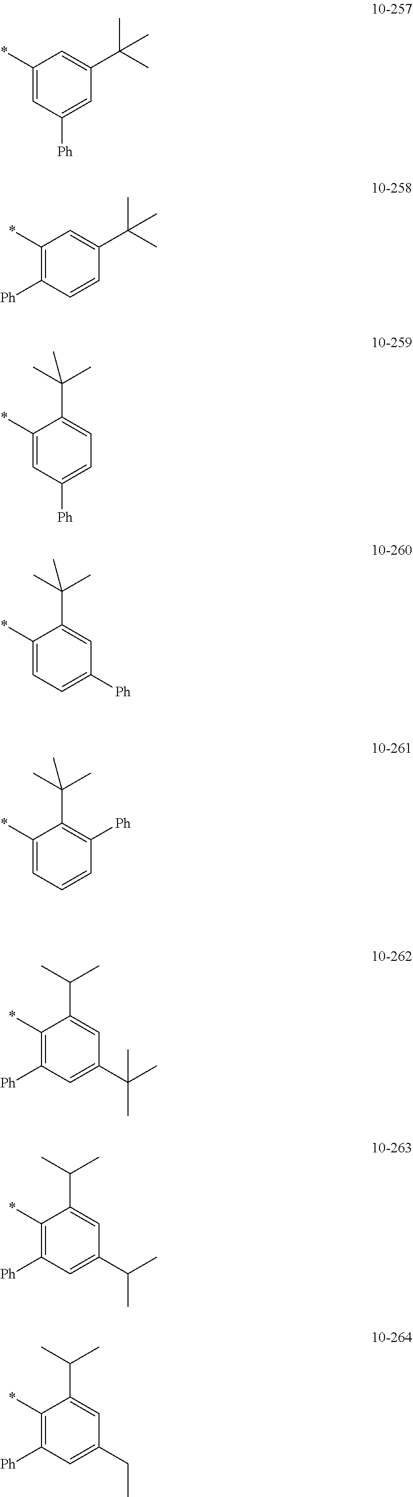

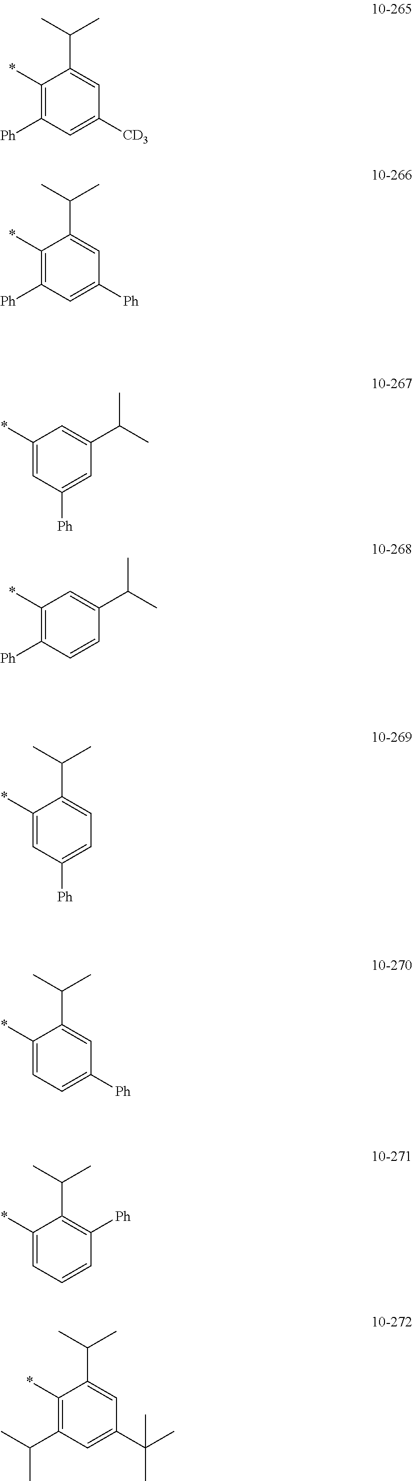

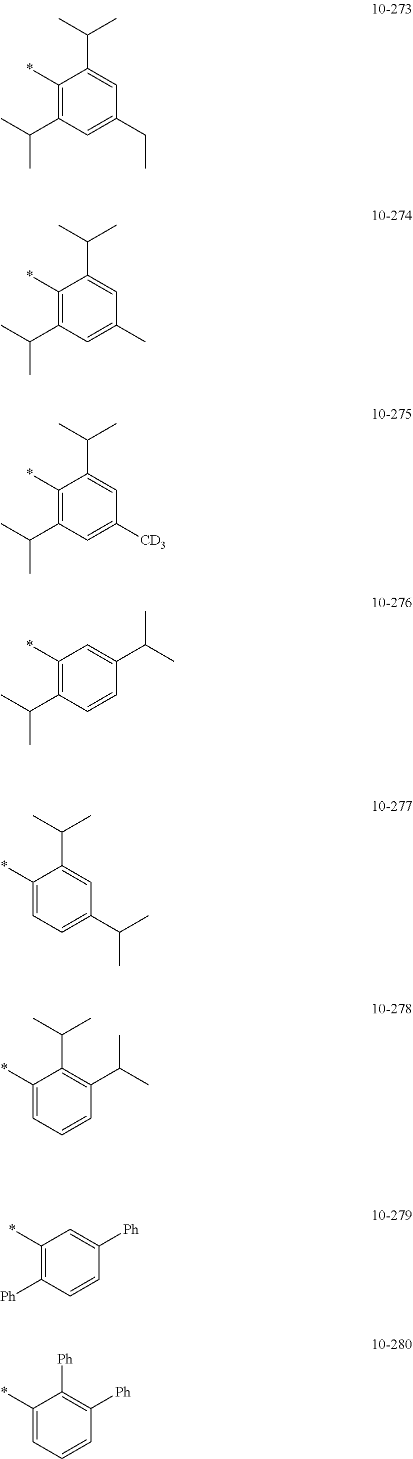

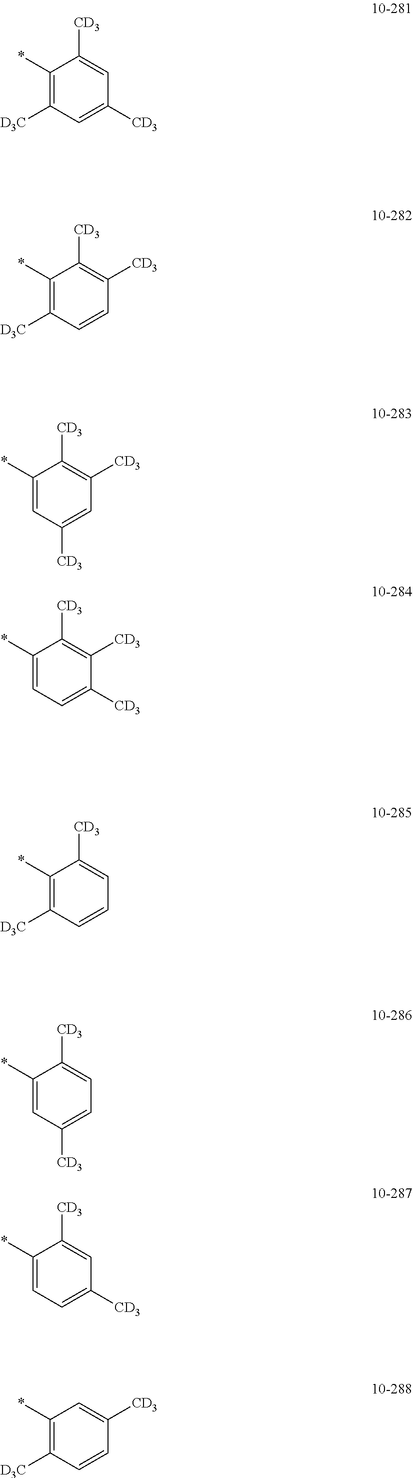

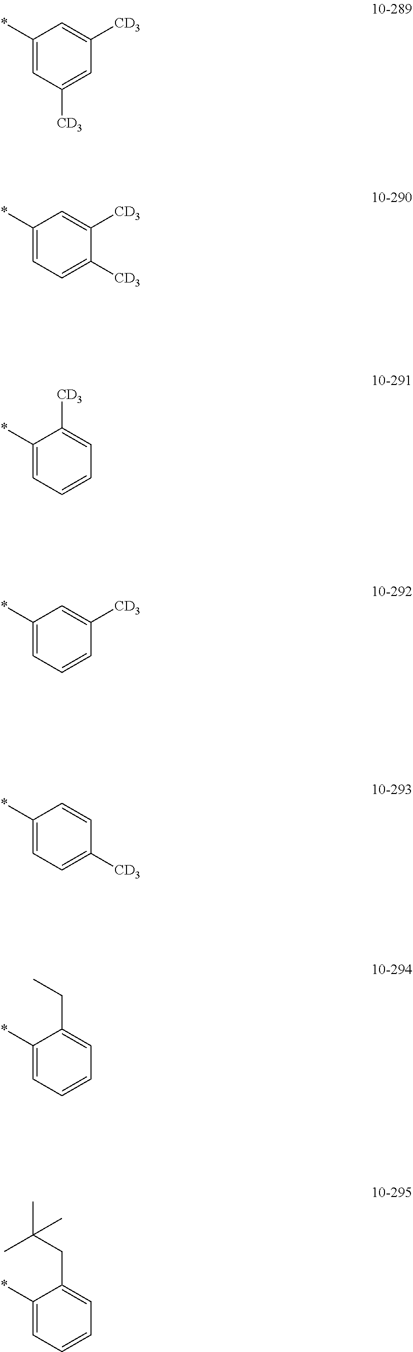

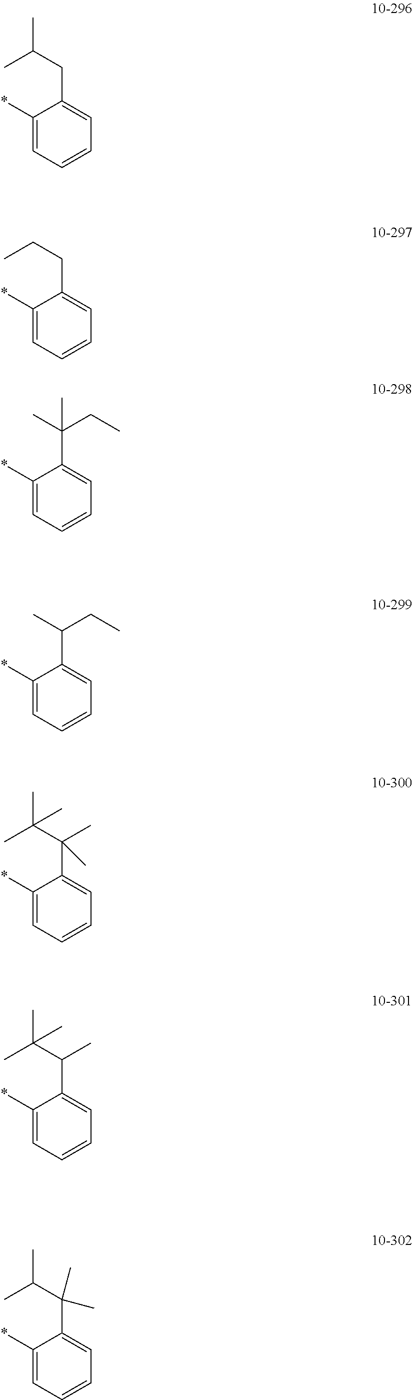

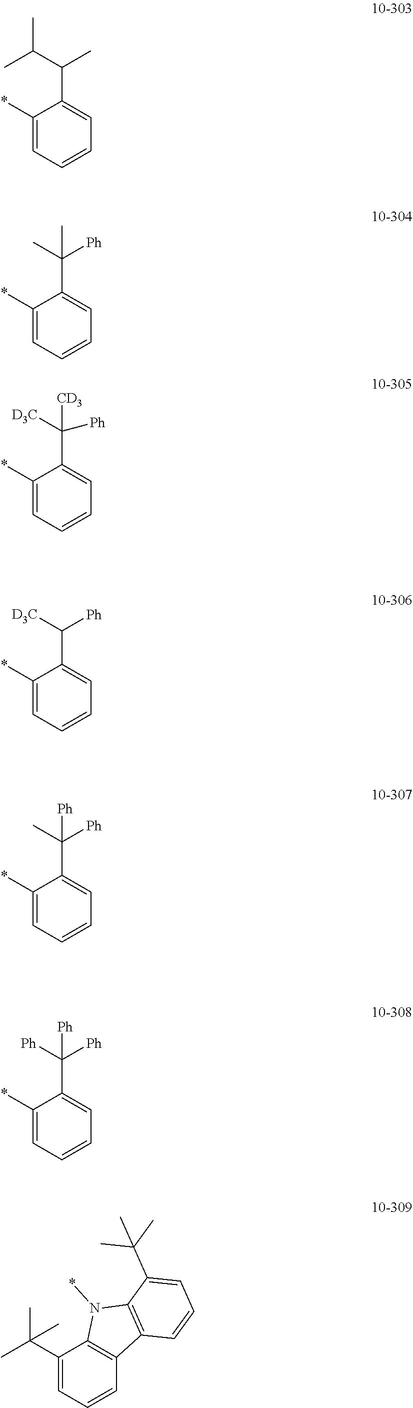

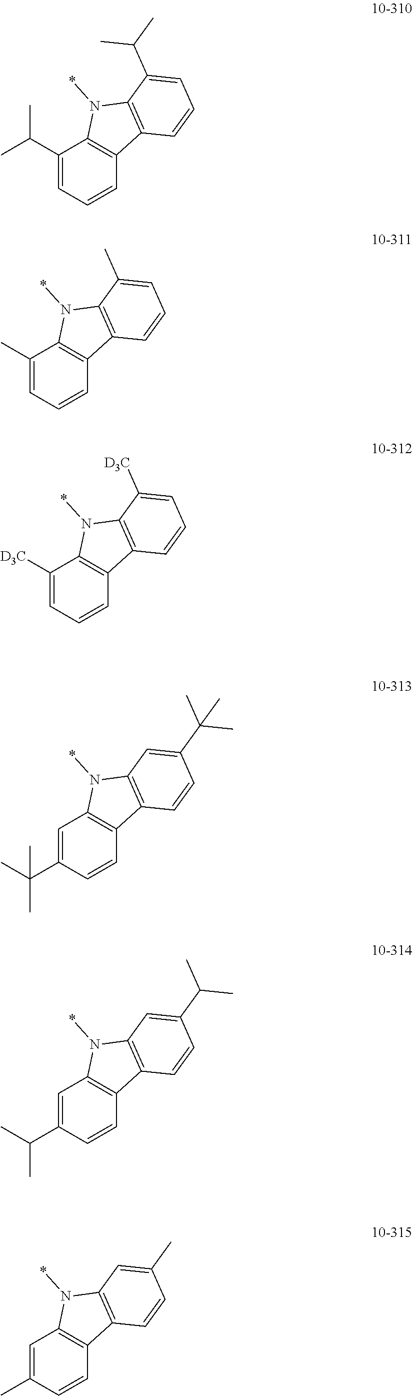

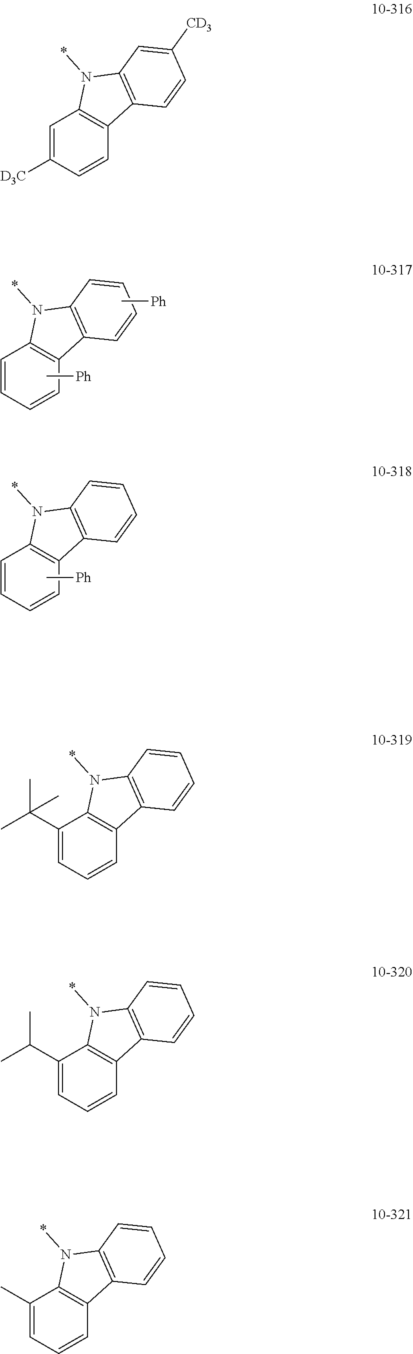

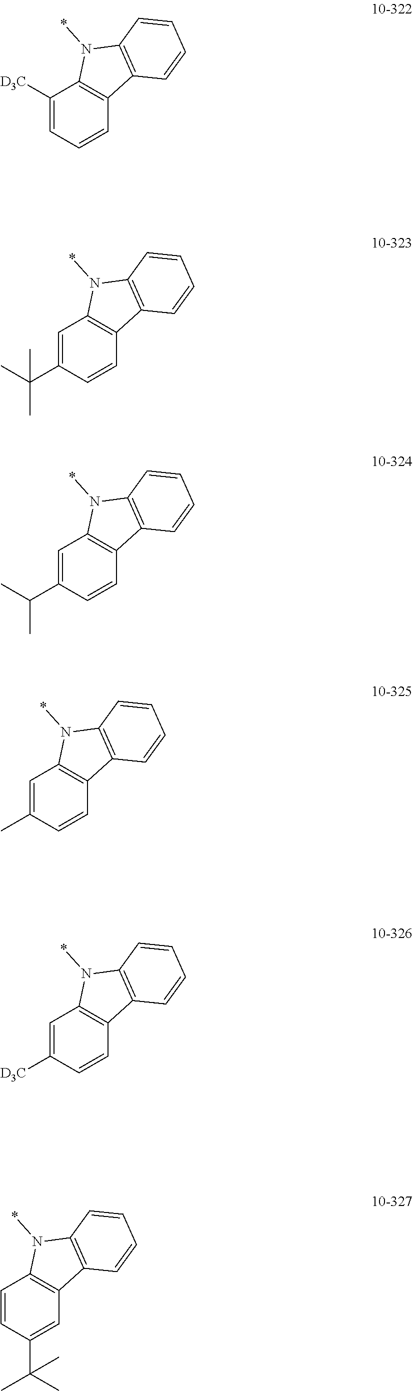 [SMILES: *n1c2ccccc2c2cccc(C([2H])([2H])[2H])c21 ; *n1c2ccccc2c2ccc(C(C)(C)C)cc21 ; *n1c2ccccc2c2ccc(C(C)C)cc21 ; *n1c2ccccc2c2ccc(C)cc21 ; *n1c2ccccc2c2ccc(C([2H])([2H])[2H])cc21 ; *n1c2ccccc2c2cc(C(C)(C)C)ccc21]

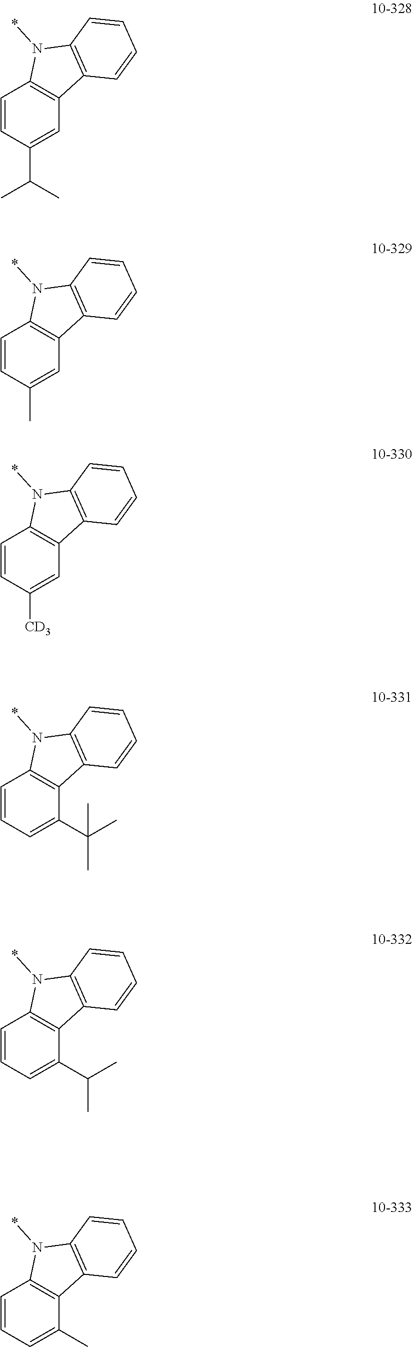 [SMILES: *n1c2ccccc2c2cc(C(C)C)ccc21 ; *n1c2ccccc2c2cc(C)ccc21 ; *n1c2ccccc2c2cc(C([2H])([2H])[2H])ccc21 ; *n1c2ccccc2c2c(C(C)(C)C)cccc21 ; *n1c2ccccc2c2c(C(C)C)cccc21 ; *n1c2ccccc2c2c(C)cccc21]

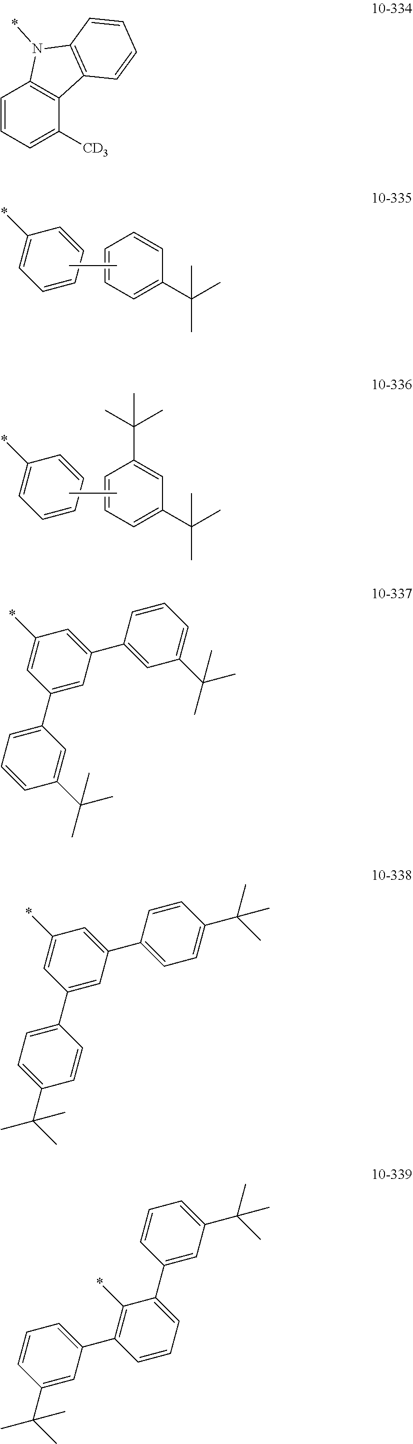

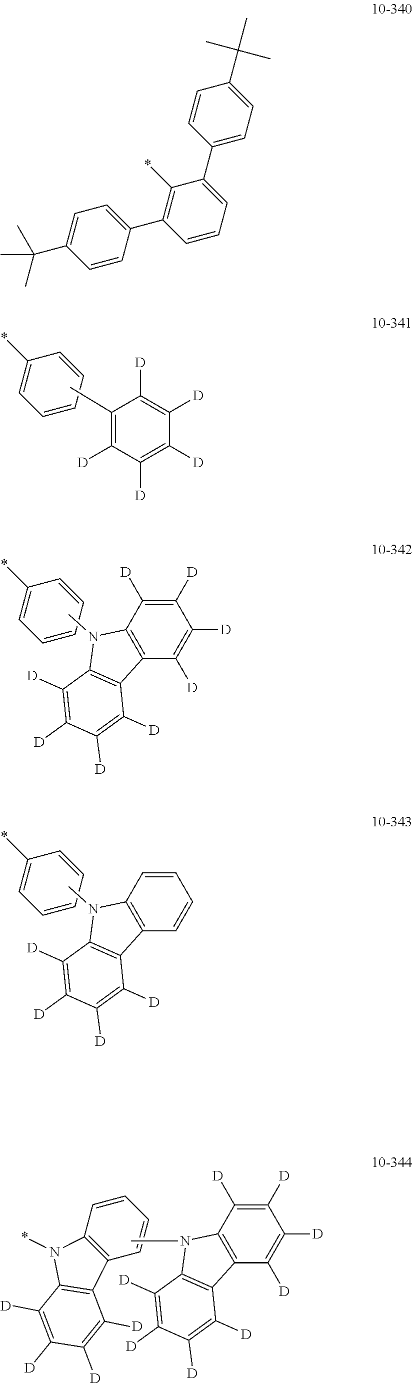

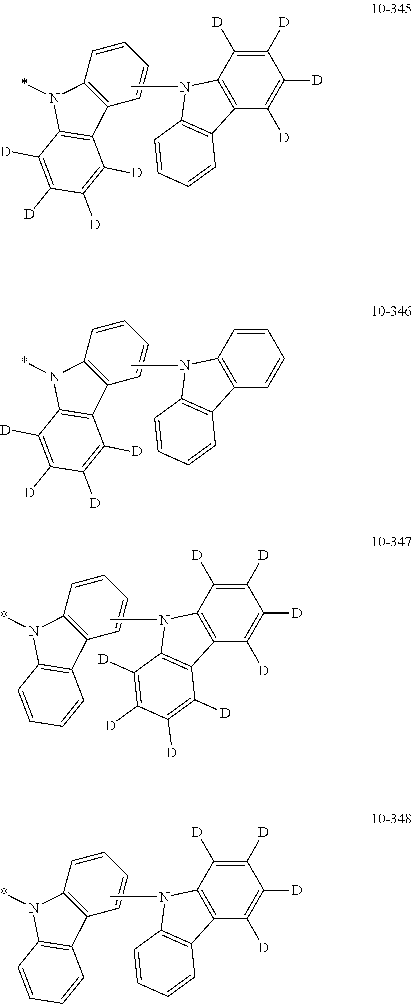

In Formulae 9-1 to 9-61 and 10-1 to 10-348, * indicates a binding site to a neighboring atom, Ph is a phenyl group, TMS is a trimethylsilyl group, D is a deuterium atom, and Q₁ to Q₃ are each the same as described in the specification.

In Formulae 1 and 2, d3 to d8 may indicate numbers of R₃ to R₈, respectively, d3 may be an integer from 0 to 3, d4, d5, and d8 may each independently be an integer from 0 to 10, and d6 and d7 may each independently be an integer from 0 to 4. When d3 is 2 or more, two or more R₃(s) may be identical to or different from each other, when d4 is 2 or more, two or more R₄(5) may be identical to or different from each other, when d5 is 2 or more, two or more R₅(5) may be identical to or different from each other, when d6 is 2 or more, two or more R₆(s) may be identical to or different from each other, when d7 is 2 or more, two or more R₇(5) may be identical to or different from each other, and when d8 is 2 or more, two or more R₅(5) may be identical to or different from each other.

In Formulae 1 and 2, Z₁ may be a C₂-C₆₅ alkyl group that is unsubstituted or substituted with at least one R₁₀ₐ, a C₂-C₆₅ alkenyl group that is unsubstituted or substituted with at least one R₁₀ₐ, or a C₂-C₆₀ alkynyl group that is unsubstituted or substituted with at least one R₁₀ₐ.

In an embodiment, Z₁ may be:
a C₂-C₆₀ alkyl group, a C₂-C₆₀ alkenyl group, or a C₂-C₆₀ alkynyl group; or
a C₂-C₂₀ alkyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a C₂-C₂₀ alkenyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof; or
a C₂-C₂₀ alkynyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof.

In an embodiment, Z₁ may be:
a C₁-C₆₀ alkyl group, a C₂-C₆₀ alkenyl group, or a C₂-C₆₀ alkynyl group; or a group represented by one of Formulae 9-1 to 9-61:

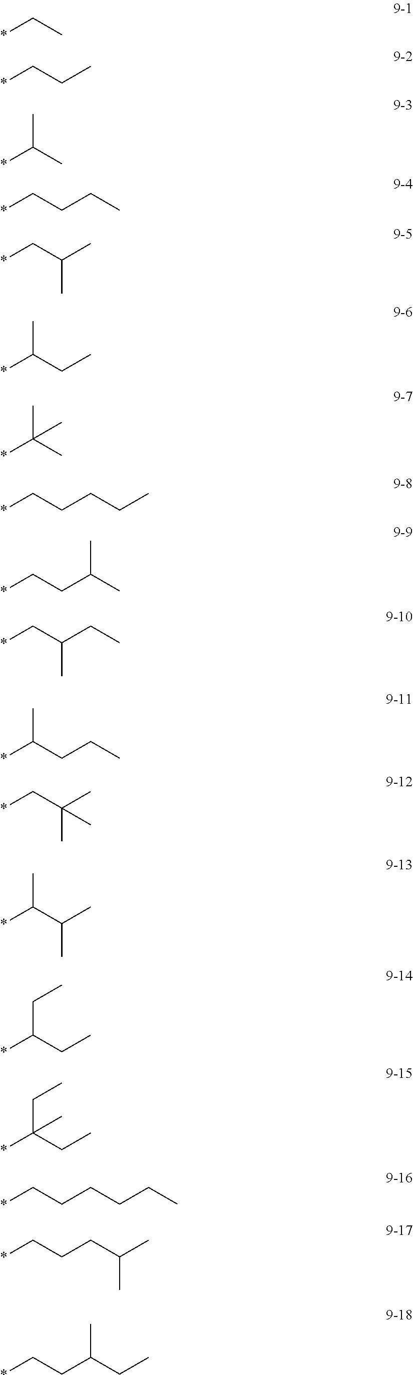

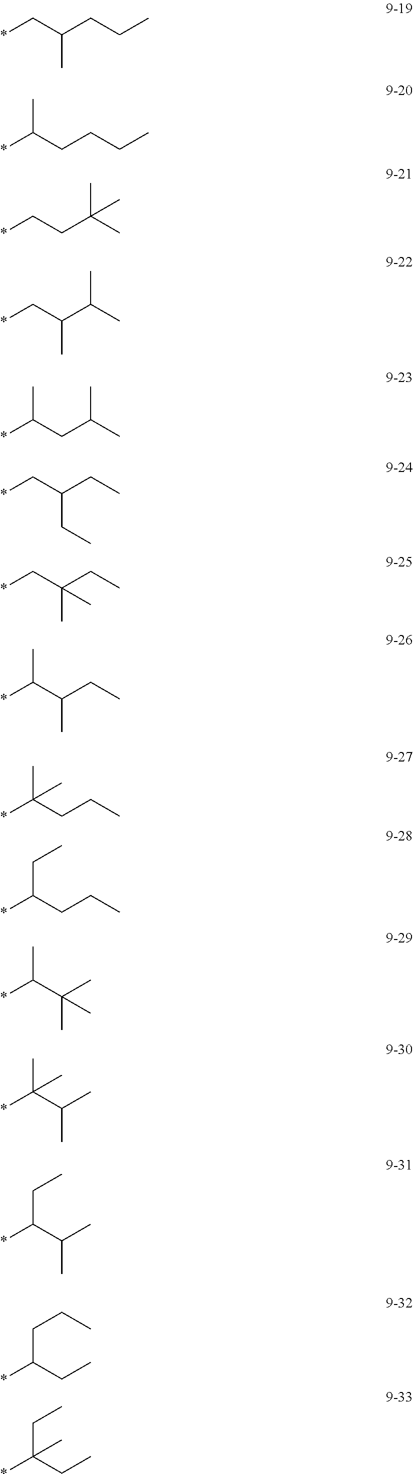

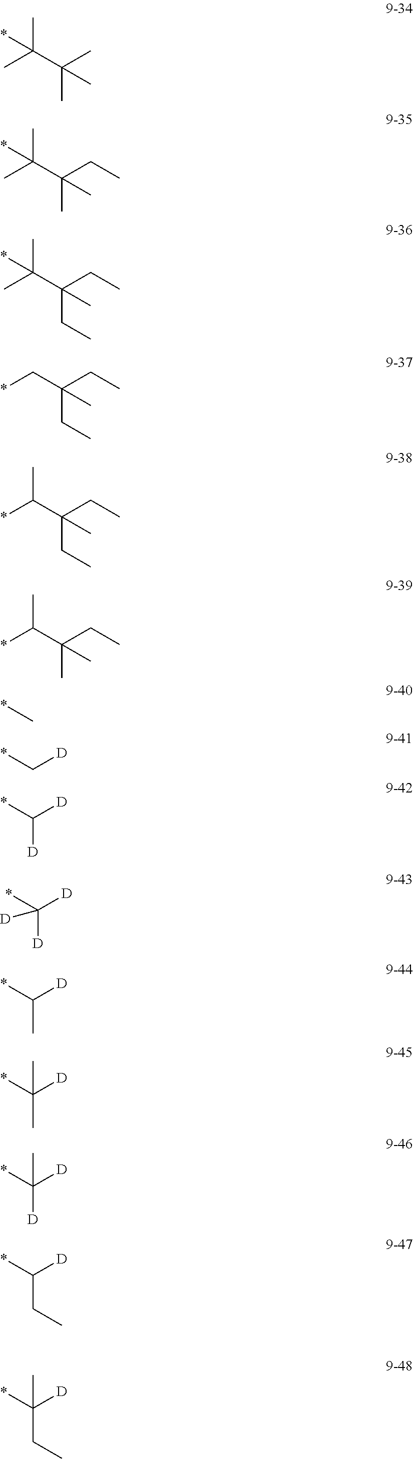

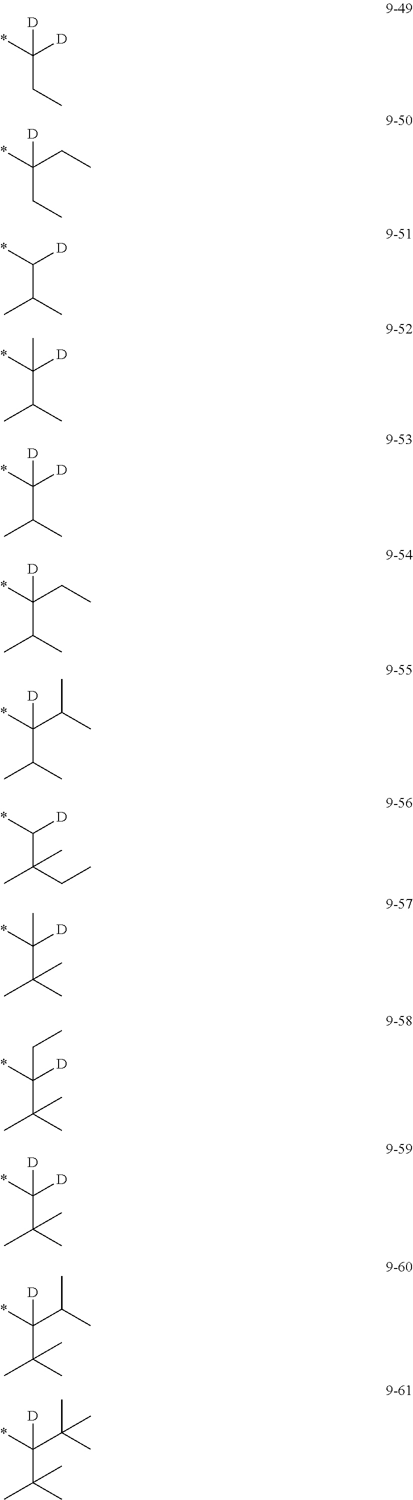

In Formulae 9-1 to 9-61, D is a deuterium atom.

In Formulae 1 and 2, two or more groups of Z₁, R₃ in the number of d3, R₄ in the number of d4, R₅ in the number of d5, R₆ in the number of d6, R₇ in the number of d7, R₈ in the number of d8, R₁₁, R₁₂, R₂₁, and R₂₂ may optionally be bonded together to form a C₅-C₃₀ carbocyclic group that is unsubstituted or substituted with at least one R₁₀ₐ or a C₂-C₃₀ heterocyclic group that is unsubstituted or substituted with at least one R₁₀ₐ.

For example, in Formulae 1 and 2, two or more of R₃(5) in the number of d3 may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ; two or more of R₄(5) in the number of d4 may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ; two or more of R₅(5) in the number of d5 may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ; two or more of R₆(5) in the number of d6 may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ; two or more of R₇(5) in the number of d7 may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ; two or more of R₈(5) in a number of d8 may optionally be bonded together to form a C₃-C₆₀ carbocyclic group that is unsubstituted or substituted with at least one R₁₀ₐ or a C₁-C₆₀ heterocyclic group that is unsubstituted or substituted with at least one R₁₀ₐ; and two or more groups of Z₁ and R₆ in the number of d6 may be bonded together to form a C₅-C₃₀ carbocyclic group that is unsubstituted or substituted with at least one R₁₀ₐ or a C₂-C₃₀ heterocyclic group that is unsubstituted or substituted with at least one R₁₀ₐ, wherein R₁₀ₐ may be the same as described in the specification.

In Formulae 1 and 2, * and *′ may each indicate a binding site to a neighboring atom.

In Formulae 1 and 2, R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —O (Q₁₁), —S(Q₁₁), —Se(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group; each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₁₁), —S(Q₁₁), —Se(Q₁₁), —P(═O)(Q₁₁)(Q₁₂), or any combination thereof; or
—Si(Q₃₁)(Q₃₂) (Q₃₃), —N(Q₃₁)(Q₃₂), —B(Q₃₁)(Q₃₂), —C(═O)(Q₃₁), —S(═O)₂(Q₃₁), —O (Q₃₁), —S(Q₃₁), —Se(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₂₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₂₀ alkyl group, a C₁-C₂₀ alkoxy group, a phenyl group, a biphenyl group, or any combination thereof.

In an embodiment, Q₁ to Q₃, Q₁₁ to Q₁₃, Q₂₁ to Q₂₃, and Q₃₁ to Q₃₃ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, a triazinyl group, a carbazolyl group, a dibenzofuranyl group, or a dibenzothiophenyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, a carbazolyl group, a dibenzofuranyl group, a dibenzothiophenyl group, or any combination thereof.

In Formulae 1 and 2, the condensed cyclic compound represented by Formula 1 may satisfy at least one of Condition 1 and Condition 2:

[Condition 1]

X₁ is N(E₁₁), and R₁₁ is a group represented by Formula 2;

[Condition 2]

X₂ is N(E₂₁), and R₂₁ is a group represented by Formula 2.

In an embodiment, the condensed cyclic compound represented by Formula 1 may satisfy at least one of Condition 1-1 and Condition 2-1:

[Condition 1-1]

X₁ is N(E₁₁), n11 is 0, and R₁₁ is a group represented by Formula 2;

[Condition 2-1]

X₂ is N(E₂₁), n21 is 0, and R₂₁ is a group represented by Formula 2.

In an embodiment, the condensed cyclic compound represented by Formula 1 may be represented by one of Formulae 1-1 to 1-3:

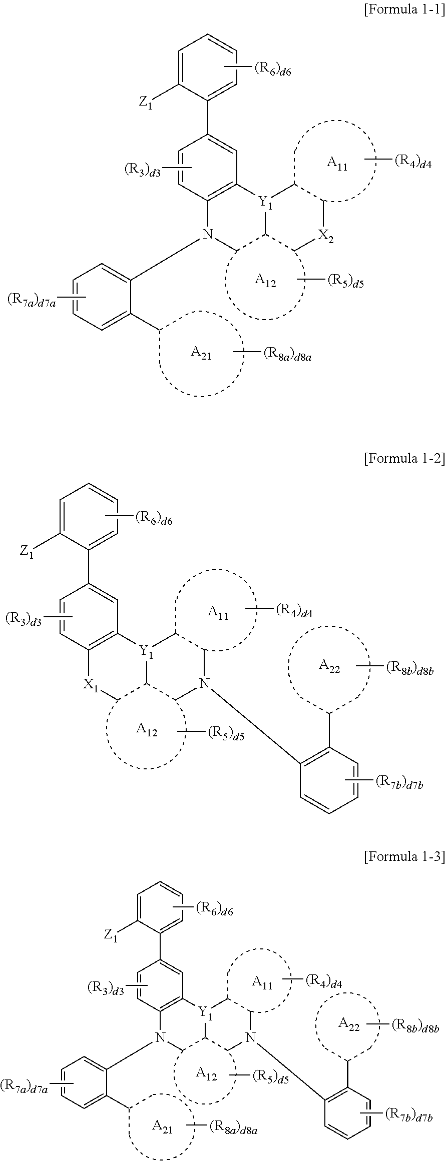

In Formulae 1-1 to 1-3,
A₁₁, A₁₂, A₂₁, X₁, X₂, Y₁, Z₁, R₃ to R₆, and d3 to d6 may each be the same as described in the specification,
A₂₂ may independently be the same as described in connection with A₂₁,
R₇ₐ and R_{7b} may each independently be the same as described in connection with R₇,
R₈ₐ and R_{8b} may each independently be the same as described in connection with R₈,
d7a and d7b may each independently be the same as described in connection with d7, and
d8a and d8b may each independently be the same as described in connection with d8.

In an embodiment, the group represented by Formula 2 may be a group represented by one of Formulae 2-1 to 2-16:

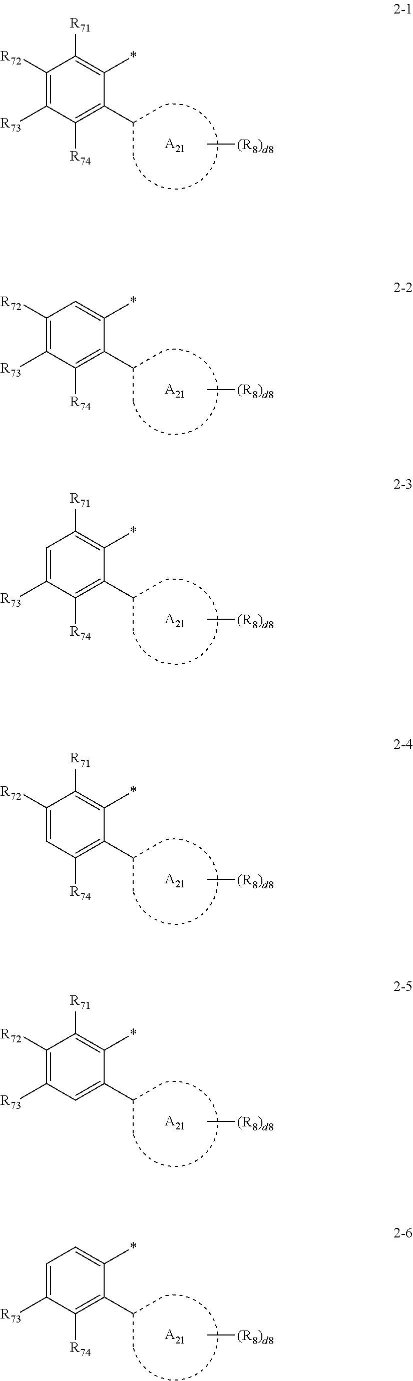

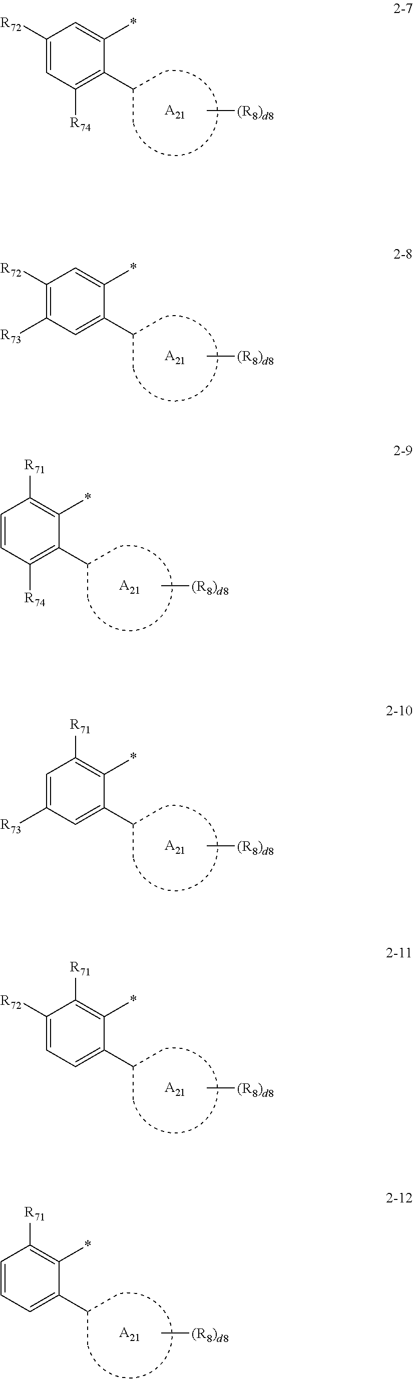

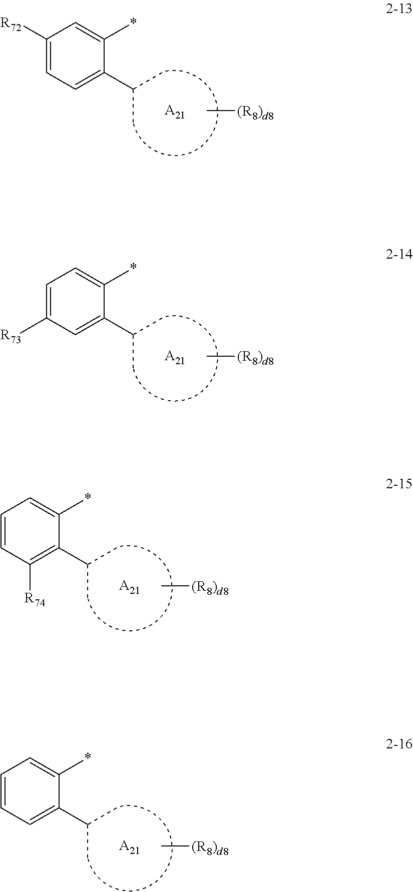

In Formulae 2-1 to 2-16,
A₂₁, R₈, and d8 may each be the same as described in the specification, and
R₇₁ to R₇₄ may each independently be the same as described in connection with R₇ and may each not be hydrogen, and * may indicate a binding site to a neighboring atom.

In an embodiment, E₁₁ and E₁₂ may each independently be a group represented by one of Formulae 2-1 to 2-16 and 7-1 to 7-22, and at least one of E₁₁ and E₁₂ may be a group represented by one of Formulae 2-1 to 2-16:

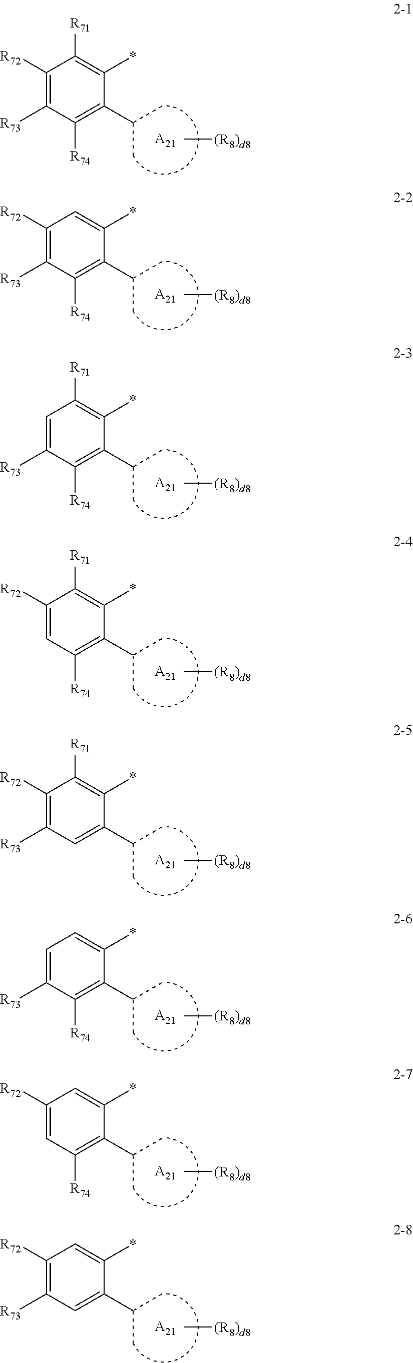

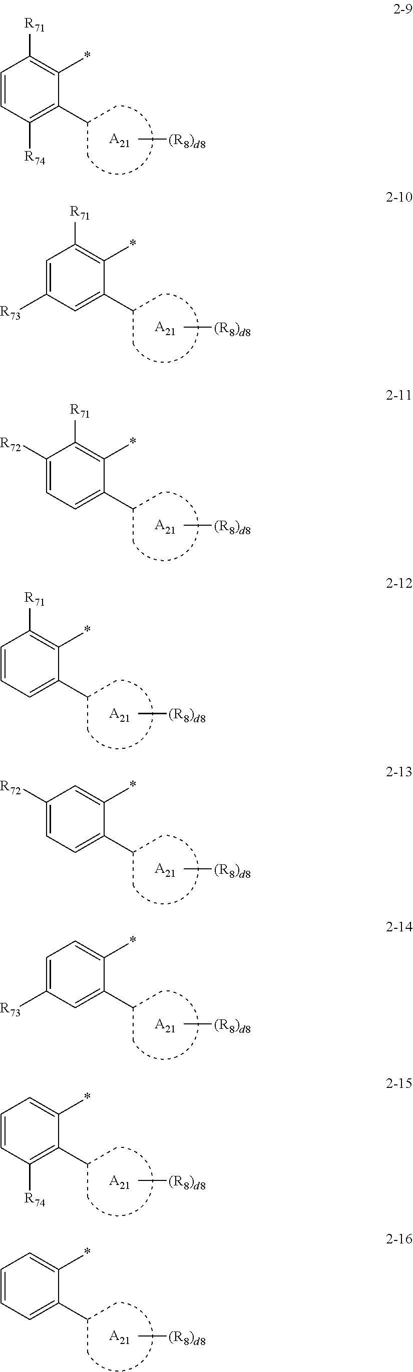

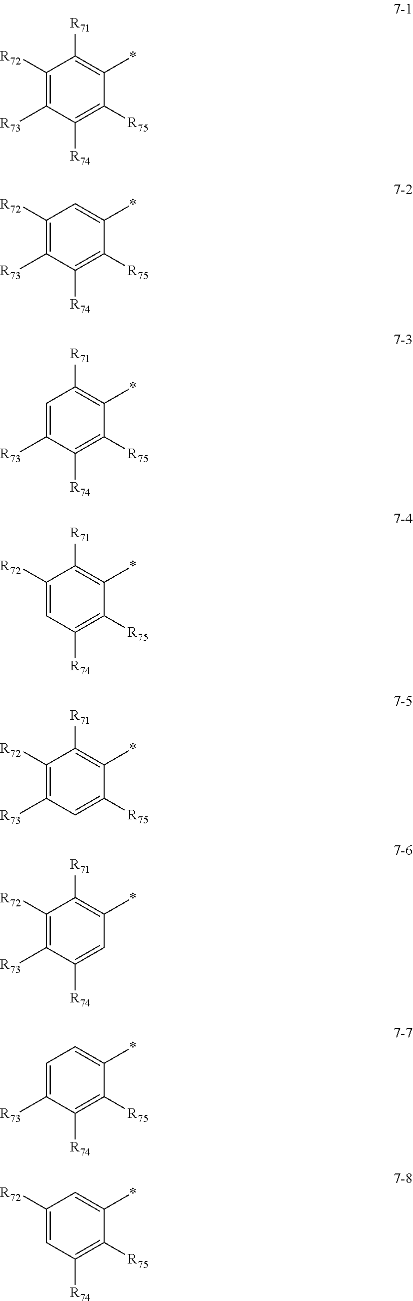

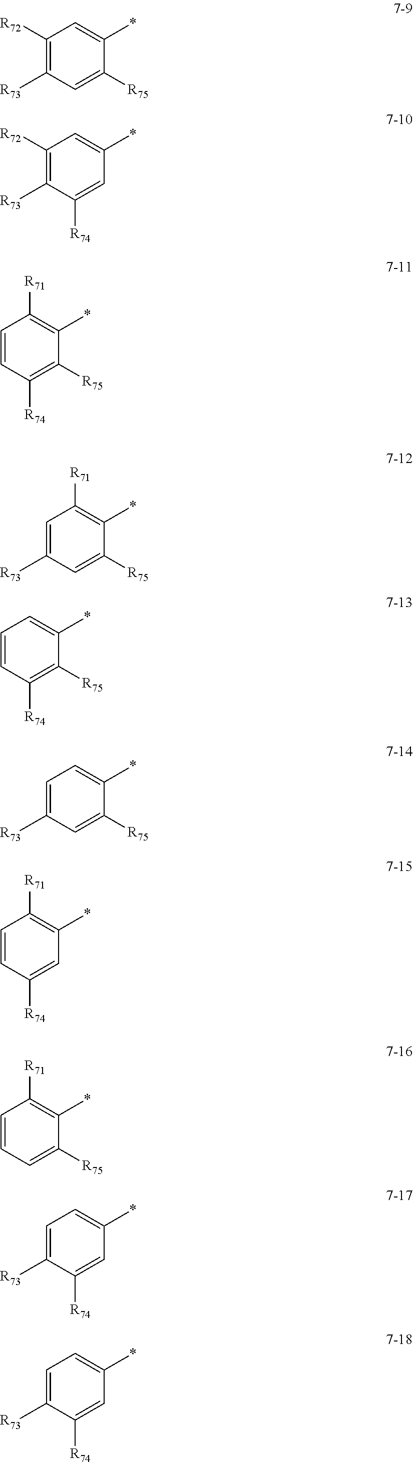

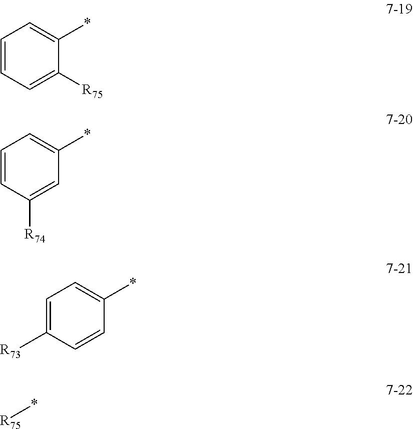

In Formulae 2-1 to 2-16 and 7-1 to 7-22,

A₂₁, R₈, and d8 may each independently the same as described in the specification, and

R₇₁ to R₇₅ may each independently be the same as described in connection with R₇ and may each not be hydrogen, and * may indicate a binding site to a neighboring atom.

In an embodiment, in Formula 1, a moiety represented by

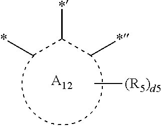

may be a moiety represented by one of Formulae 3-1 to 3-8:

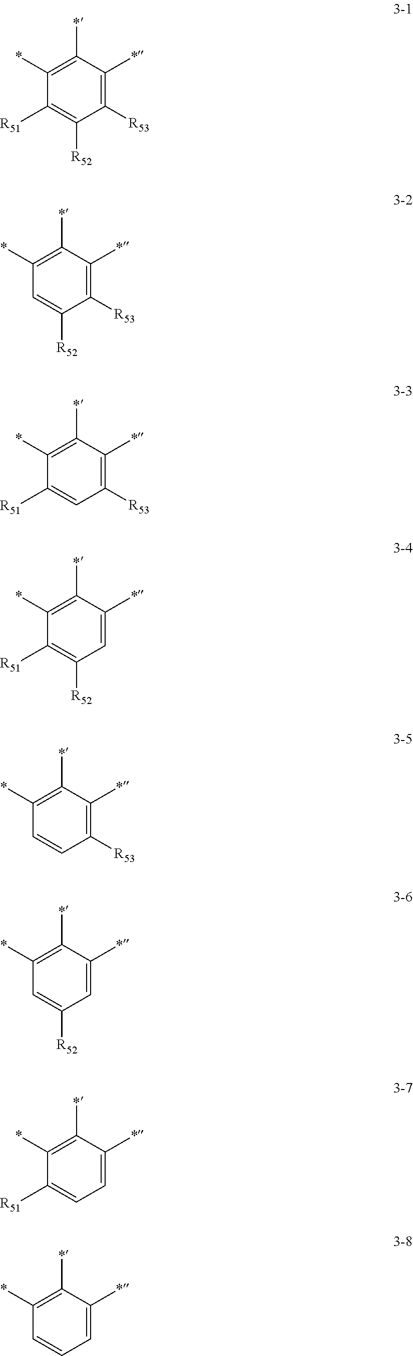

In Formulae 3-1 to 3-8,

R₅₁ to R₅₃ may each independently be the same as described in connection with R₅ and may each not be hydrogen, and *, *′, and *″ may each indicate a binding site to a neighboring atom.

In an embodiment, in Formula 1, a moiety represented by

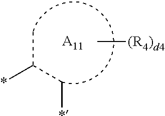

may be a moiety represented by one of Formulae 4-1 to 4-16:

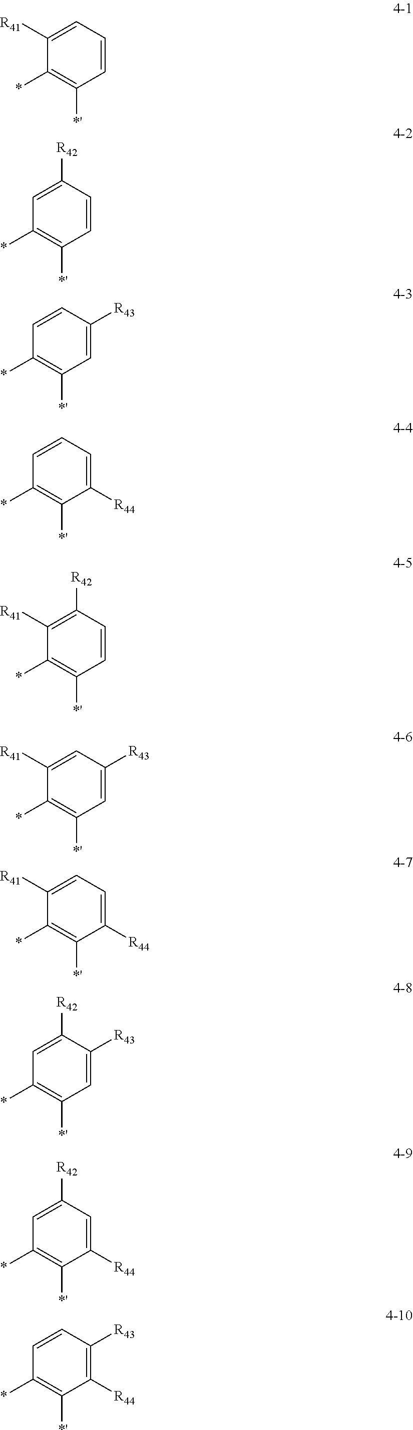

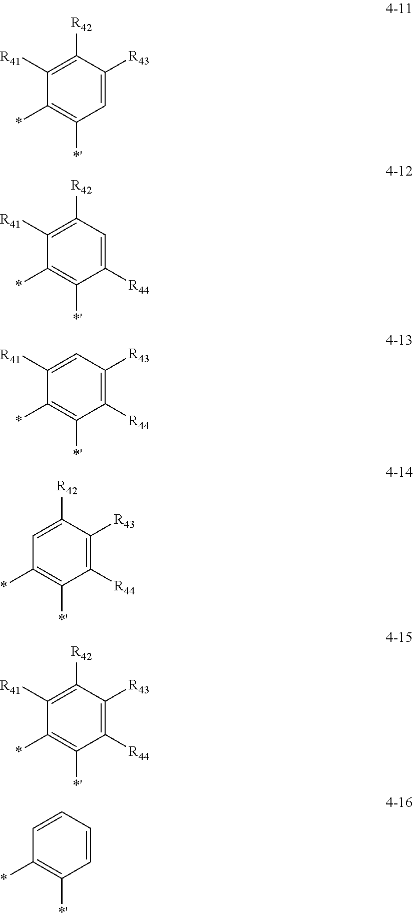

In Formulae 4-1 to 4-16,

R₄₁ to R₄₄ may each independently be the same as described in connection with R₄ and may each not be hydrogen, and * and *′ may each indicate a binding site to a neighboring atom.

In an embodiment, in Formula 1, a moiety represented by

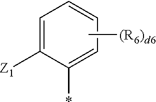

may be a moiety represented by one of Formulae 5-1 to 5-3:

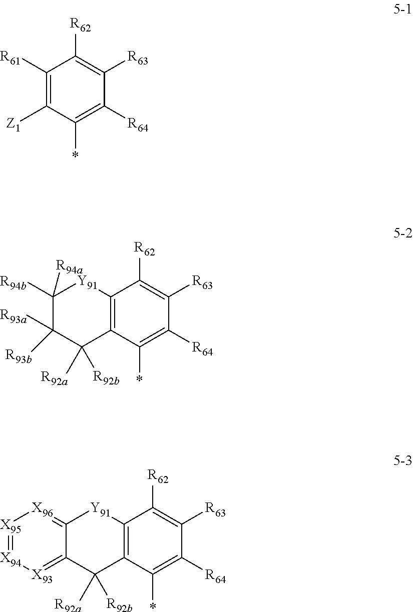

In Formulae 5-1 to 5-3,
X₉₃ may be N or C(R₉₃),
X₉₄ may be N or C(R₉₄),
X₉₅ may be N or C(R₉₅),
X₉₆ may be N or C(R₉₆),
Y₉₁ may be a single bond, O, S, Se, C(R₉₁ₐ)(R_{91b}), Si(R₉₁ₐ)(R_{91b}), or N(R₉₁ₐ),
R₆₁ to R₆₄, R₉₁ₐ, R_{91b}, R₉₂ₐ, R_{92b}, R₉₃ₐ, R_{93b}, R₉₄ₐ, R_{94b}, and R₉₃ to R₉₆ may each independently be the same as described in connection with R₆,
Z₁ may be the same as described in the specification, and
* may indicate a binding site to a neighboring atom.

In an embodiment, in Formula 5-2, at least one of R₉₂ₐ and R_{92b} may be a C₁-C₂₀ alkyl group that is unsubstituted or substituted with at least one R₁₀ₐ, a C₂-C₂₀ alkenyl group that is unsubstituted or substituted with at least one R₁₀ₐ, or a C₂-C₂₀ alkynyl group that is unsubstituted or substituted with at least one R₁₀ₐ.

In an embodiment, in Formula 5-3, at least one of R₉₂ₐ and R_{92b} may be a C₁-C₅₉ alkyl group that is unsubstituted or substituted with at least one R₁₀ₐ, a C₁-C₅₉ alkenyl group that is unsubstituted or substituted with at least one R₁₀ₐ, or a C₁-C₅₉ alkynyl group that is unsubstituted or substituted with at least one R₁₀ₐ.

In an embodiment, in Formula 1, a moiety represented by

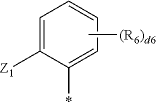

may be a moiety represented by one of Formulae 6-1 to 6-32:

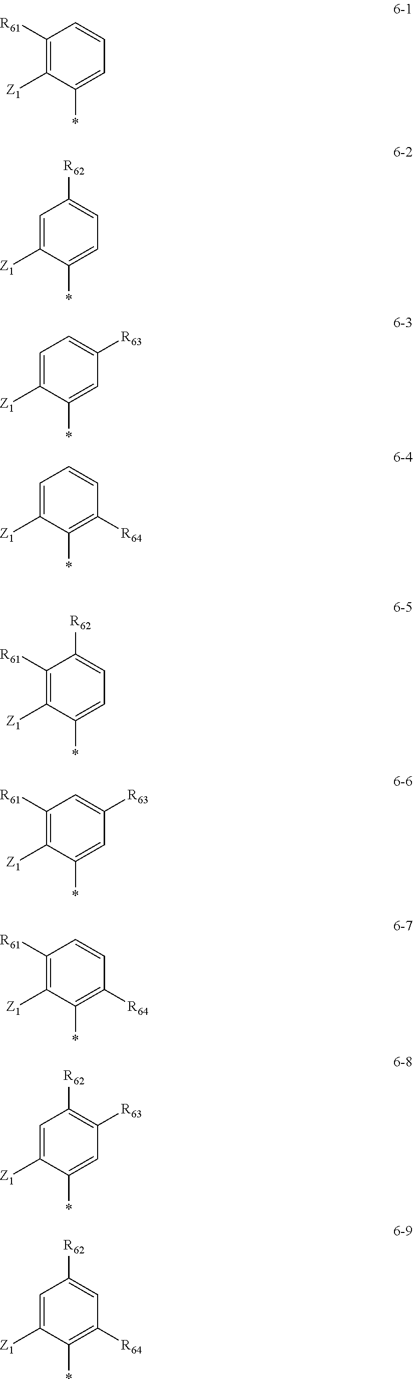

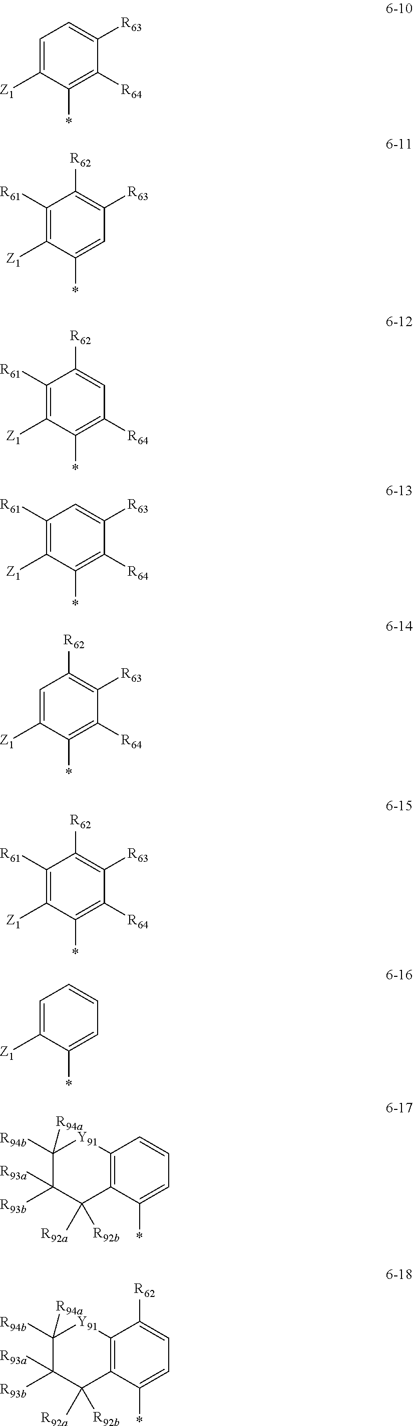

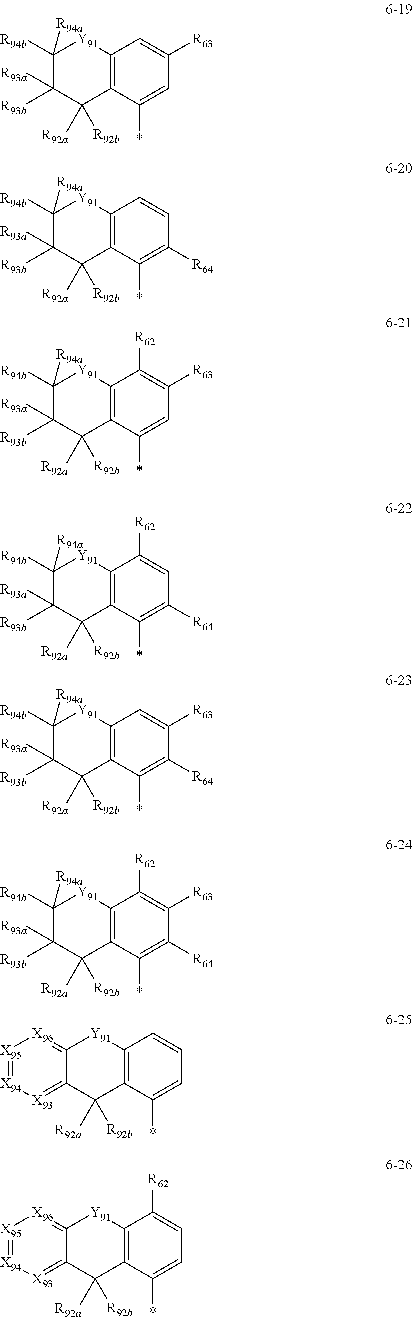

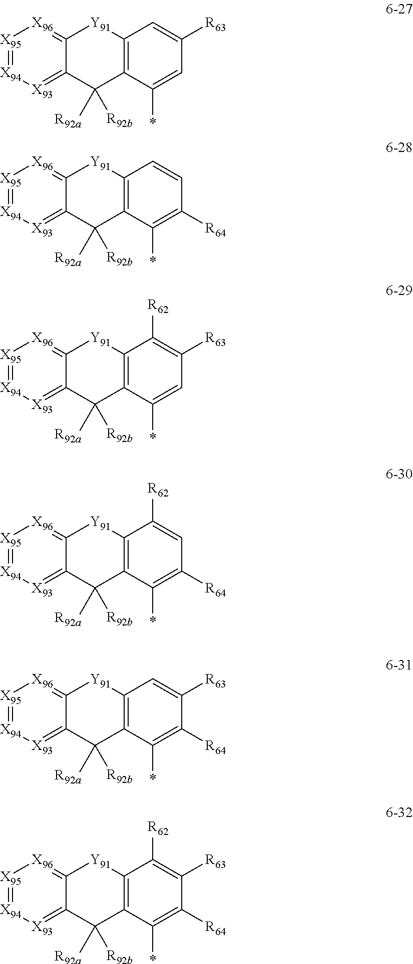

In Formulae 6-1 to 6-32,
X₉₃ may be N or C(R₉₃),
X₉₄ may be N or C(R₉₄),
X₉₅ may be N or C(R₉₅),
X₉₆ may be N or C(R₉₆),
Y₉₁ may be a single bond, O, S, Se, C(R₉₁ₐ)(R_{91b}), Si(R₉₁ₐ)(R_{91b}), or N(R₉₁ₐ),
R₆₁ to R₆₄, R₉₁ₐ, R_{91b}, R₉₂ₐ, R_{92b}, R₉₃ₐ, R_{93b}, R₉₄ₐ, R_{94b}, and R₉₃ to R₉₆ may each independently be the same as described in connection with R₆, R₆₁ to R₆₄ may each not be hydrogen,
Z₁ may be the same as described in the specification, and
* may indicate a binding site to a neighboring atom.

In an embodiment, the condensed cyclic compound represented by Formula 1 may satisfy Equation 1:

2.4eV≤T1(D1)≤2.6eV [Equation 1]

In Equation 1, T1(D1) may be a lowest excitation triplet energy level (eV) of the condensed cyclic compound.

In an embodiment, T1 of the condensed cyclic compound may be measured from a photoluminescence (PL) spectrum in a solution state. The PL spectrum may be measured using LS-55 of Perkin Elmer Inc., and the emission spectrum at an excitation wavelength of 300 nm may be in a range of about 400 nm to about 700 nm.

In an embodiment, T1 of the condensed cyclic compound may be a lowest excitation triplet energy level at the onset wavelength of the low-temperature PL spectrum of the condensed cyclic compound.

The term “lowest excitation triplet energy level at the onset wavelength” as used herein may be a triplet energy at the beginning of the low-temperature PL spectrum, and may be calculated from the triplet energy at a point (for example, at an x-intercept) where the curve of the function obtained by plotting the PL spectrum as a quadratic function meets the wavelength axis.

In an embodiment, the condensed cyclic compound represented by Formula 1 may satisfy Equation 2:

ΔE_{ST}=S1(D1)−T1(D1)≤0.2eV [Equation 2]

In Equation 2, S1(D1) may be a lowest excitation singlet energy level (eV) of the condensed cyclic compound, and T1(D1) may be a lowest excitation triplet energy level (eV) of the condensed cyclic compound.

In an embodiment, T1(D1) represents a lowest excitation triplet energy level at the onset wavelength of the low-temperature PL spectrum of the condensed cyclic compound, and may be measured in the same manner as the measurement method described above, S1(D1) represents a lowest excitation singlet energy level at the onset wavelength of the room temperature PL spectrum of the condensed cyclic compound, and the term “lowest excitation singlet energy level at the onset wavelength” as used herein may be a singlet energy at the beginning of the room temperature PL spectrum, and may be calculated from the singlet energy at a point (for example, the x intercept) where the curve of the function obtained by plotting the PL spectrum as a quadratic function meets the wavelength axis.

In an embodiment, the condensed cyclic compound represented by Formula 1 may be a delayed fluorescence material.

In an embodiment, the condensed cyclic compound represented by Formula 1 may be, but is not limited to, one of Compounds 1 to 109:

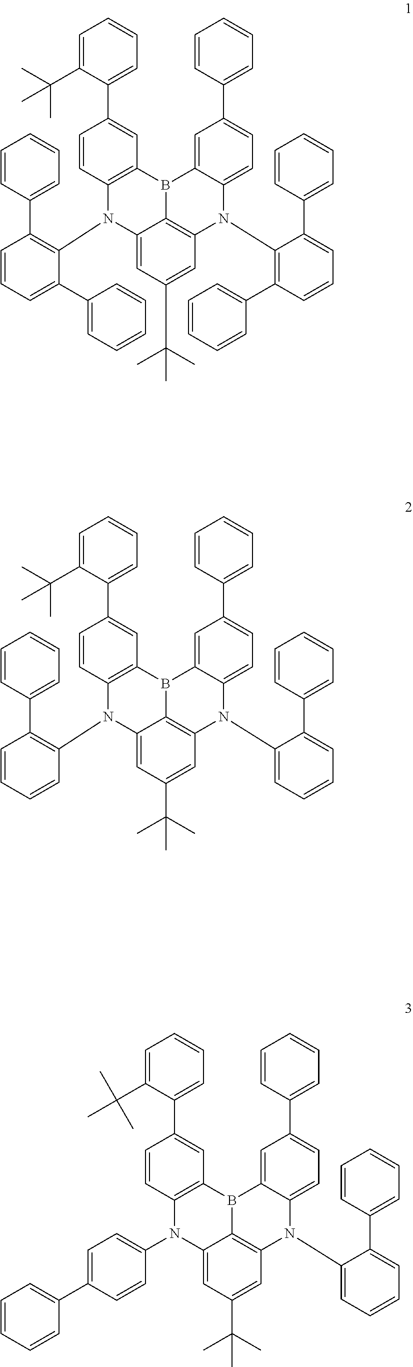 [SMILES: CC(C)(C)c1cc2c3c(c1)N(c1c(-c4ccccc4)cccc1-c1ccccc1)c1ccc(-c4ccccc4C(C)(C)C)cc1B3c1cc(-c3ccccc3)ccc1N2c1c(-c2ccccc2)cccc1-c1ccccc1 ; CC(C)(C)c1cc2c3c(c1)N(c1ccccc1-c1ccccc1)c1ccc(-c4ccccc4C(C)(C)C)cc1B3c1cc(-c3ccccc3)ccc1N2c1ccccc1-c1ccccc1 ; CC(C)(C)c1cc2c3c(c1)N(c1ccccc1-c1ccccc1)c1ccc(-c4ccccc4)cc1B3c1cc(-c3ccccc3C(C)(C)C)ccc1N2c1ccc(-c2ccccc2)cc1]

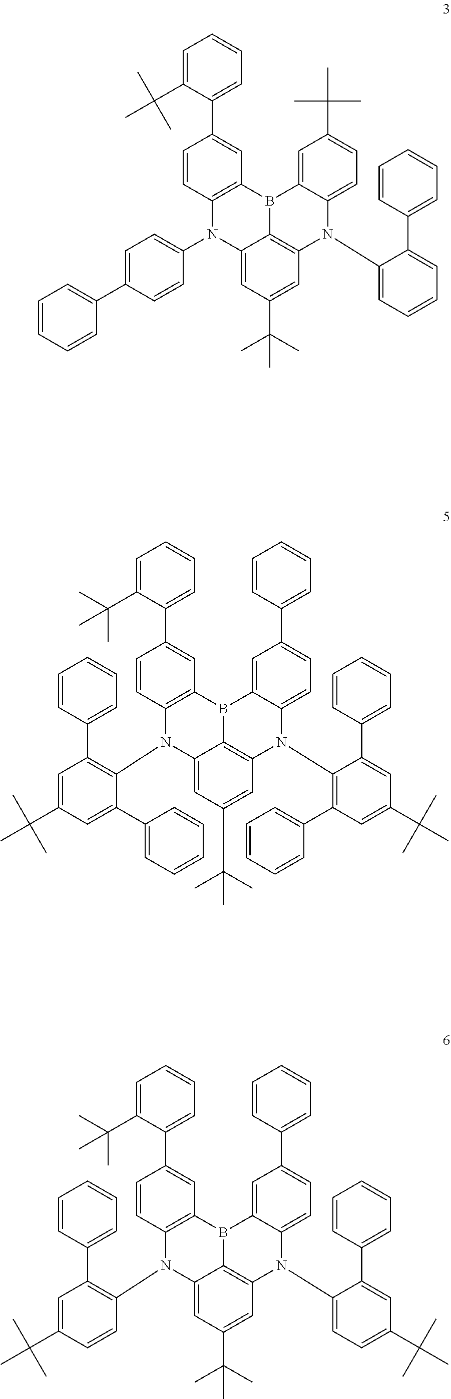

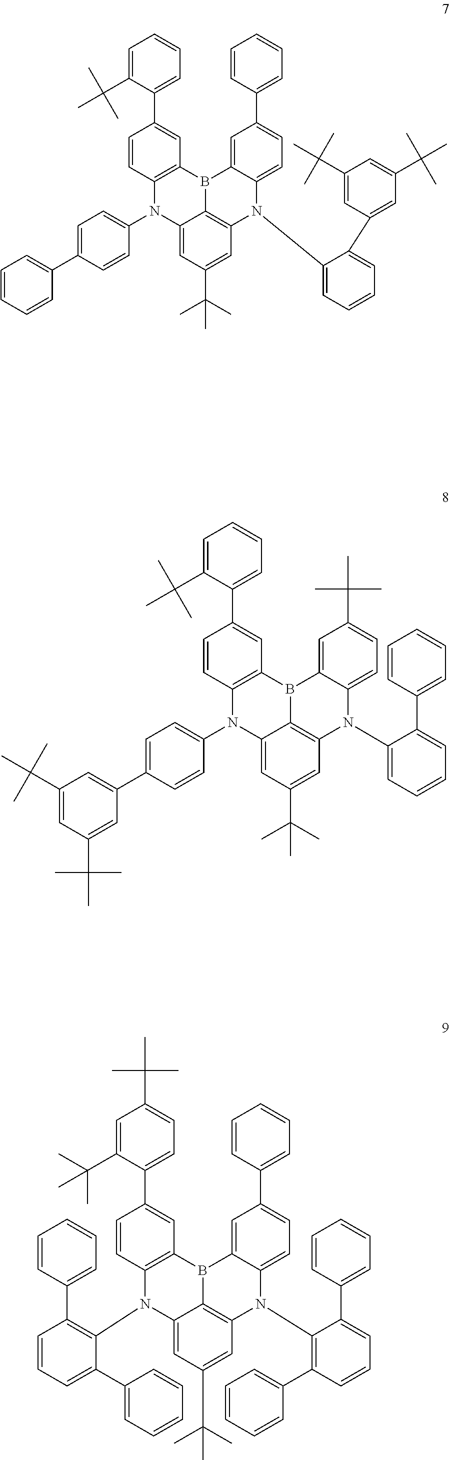

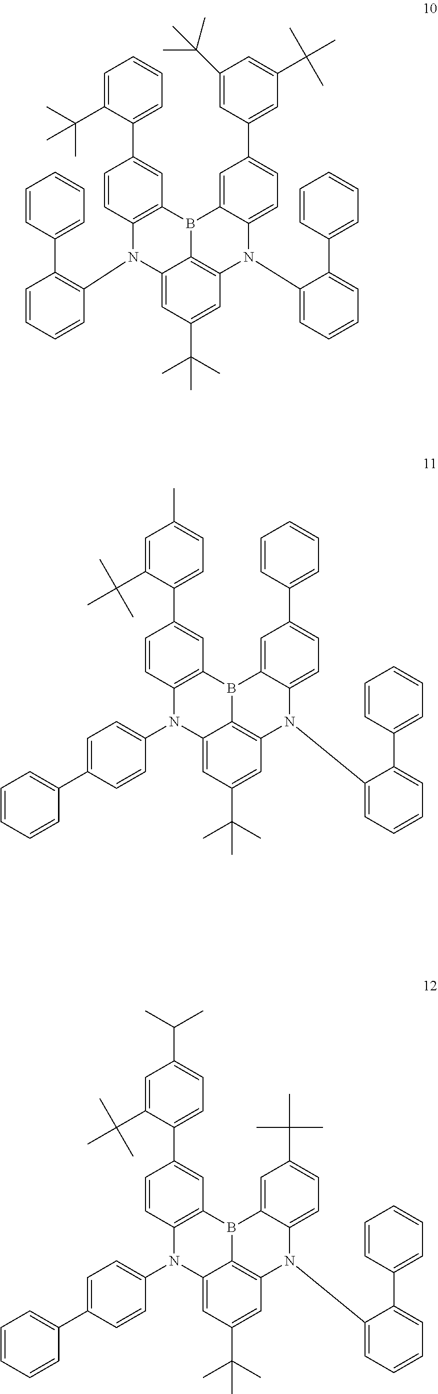 [SMILES: CC(C)(C)c1cc(-c2ccc3c(c2)B2c4cc(-c5ccccc5C(C)(C)C)ccc4N(c4ccccc4-c4ccccc4)c4cc(C(C)(C)C)cc(c42)N3c2ccccc2-c2ccccc2)cc(C(C)(C)C)c1 ; Cc1ccc(-c2ccc3c(c2)B2c4cc(-c5ccccc5)ccc4N(c4ccccc4-c4ccccc4)c4cc(C(C)(C)C)cc(c42)N3c2ccc(-c3ccccc3)cc2)c(C(C)(C)C)c1 ; CC(C)c1ccc(-c2ccc3c(c2)B2c4cc(C(C)(C)C)ccc4N(c4ccccc4-c4ccccc4)c4cc(C(C)(C)C)cc(c42)N3c2ccc(-c3ccccc3)cc2)c(C(C)(C)C)c1]

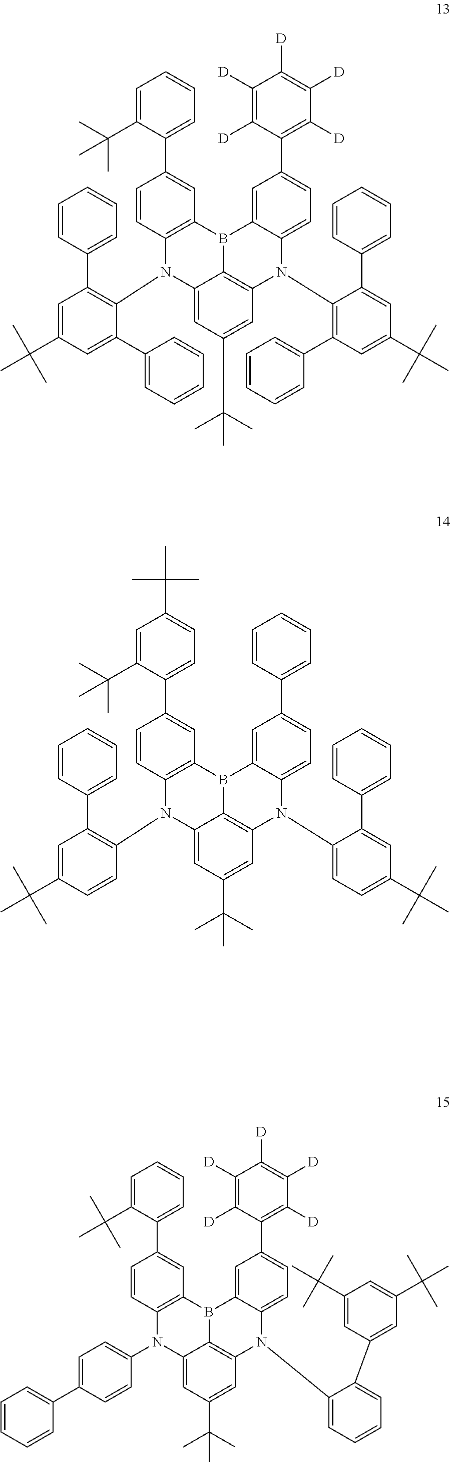

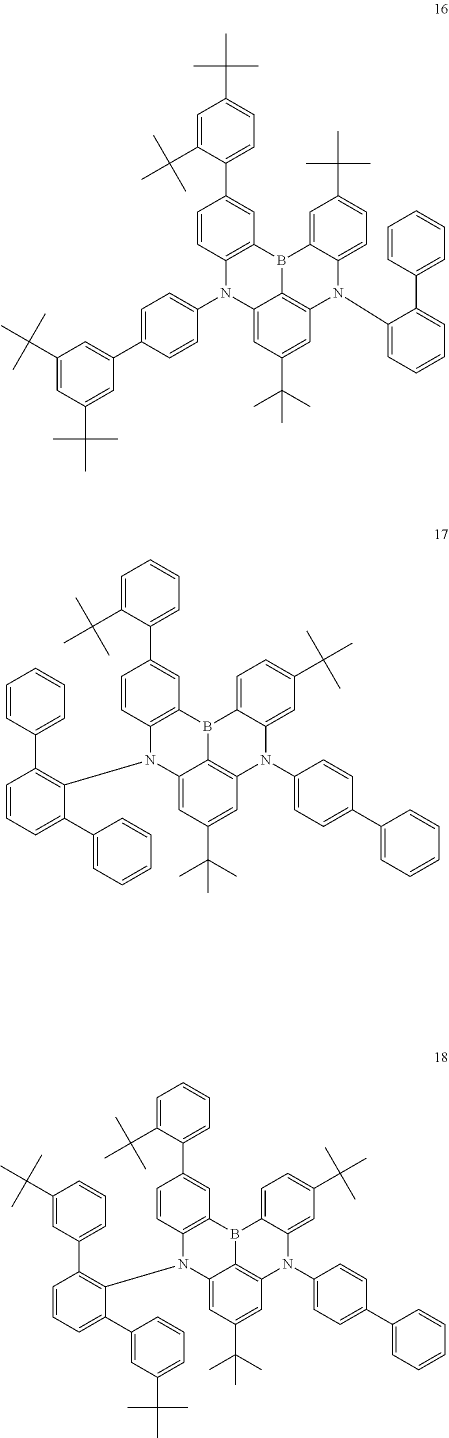 [SMILES: CC(C)(C)c1cc(-c2ccc(N3c4ccc(-c5ccc(C(C)(C)C)cc5C(C)(C)C)cc4B4c5cc(C(C)(C)C)ccc5N(c5ccccc5-c5ccccc5)c5cc(C(C)(C)C)cc3c54)cc2)cc(C(C)(C)C)c1 ; CC(C)(C)c1ccc2c(c1)N(c1ccc(-c3ccccc3)cc1)c1cc(C(C)(C)C)cc3c1B2c1cc(-c2ccccc2C(C)(C)C)ccc1N3c1c(-c2ccccc2)cccc1-c1ccccc1 ; CC(C)(C)c1cccc(-c2cccc(-c3cccc(C(C)(C)C)c3)c2N2c3ccc(-c4ccccc4C(C)(C)C)cc3B3c4ccc(C(C)(C)C)cc4N(c4ccc(-c5ccccc5)cc4)c4cc(C(C)(C)C)cc2c43)c1]

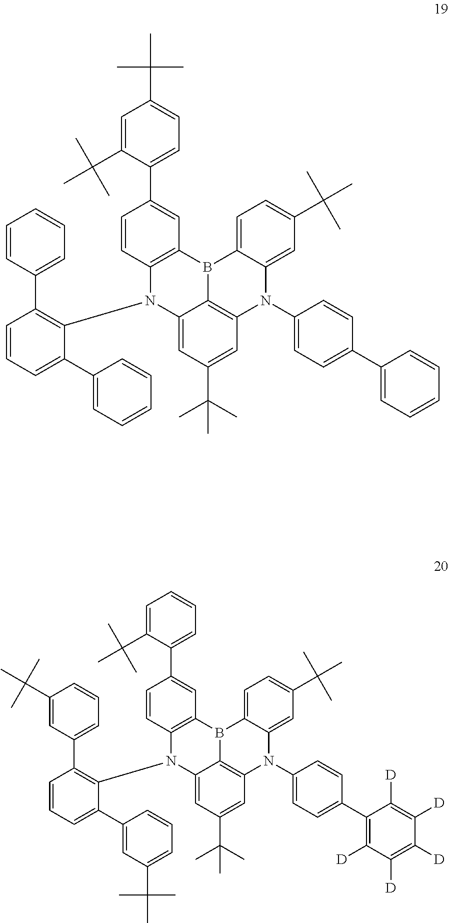 [SMILES: CC(C)(C)c1ccc2c(c1)N(c1ccc(-c3ccccc3)cc1)c1cc(C(C)(C)C)cc3c1B2c1cc(-c2ccc(C(C)(C)C)cc2C(C)(C)C)ccc1N3c1c(-c2ccccc2)cccc1-c1ccccc1 ; [2H]c1c([2H])c([2H])c(-c2ccc(N3c4cc(C(C)(C)C)ccc4B4c5cc(-c6ccccc6C(C)(C)C)ccc5N(c5c(-c6cccc(C(C)(C)C)c6)cccc5-c5cccc(C(C)(C)C)c5)c5cc(C(C)(C)C)cc3c54)cc2)c([2H])c1[2H]]

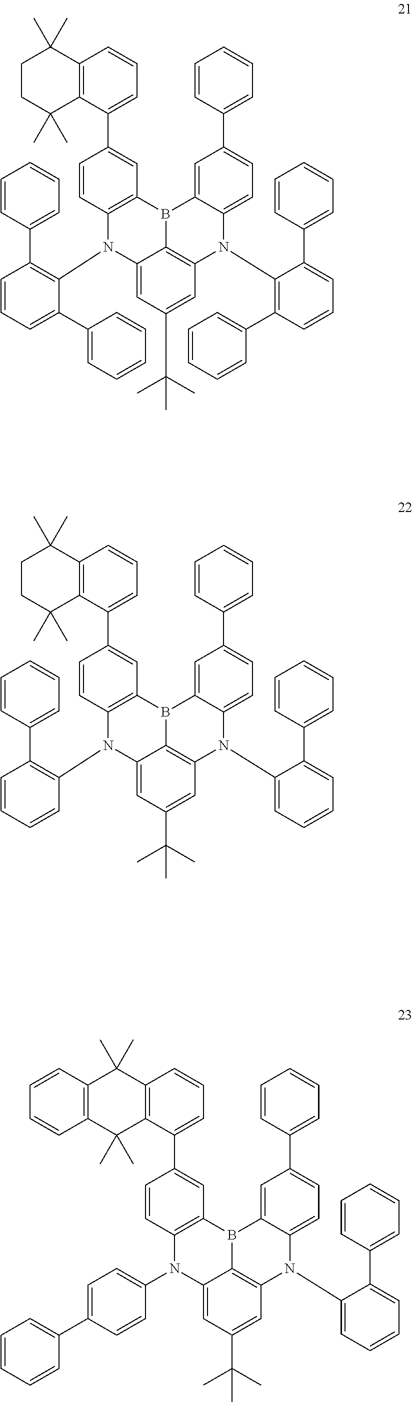 [SMILES: CC(C)(C)c1cc2c3c(c1)N(c1c(-c4ccccc4)cccc1-c1ccccc1)c1ccc(-c4cccc5c4C(C)(C)CCC5(C)C)cc1B3c1cc(-c3ccccc3)ccc1N2c1c(-c2ccccc2)cccc1-c1ccccc1 ; CC(C)(C)c1cc2c3c(c1)N(c1ccccc1-c1ccccc1)c1ccc(-c4cccc5c4C(C)(C)CCC5(C)C)cc1B3c1cc(-c3ccccc3)ccc1N2c1ccccc1-c1ccccc1 ; CC(C)(C)c1cc2c3c(c1)N(c1ccccc1-c1ccccc1)c1ccc(-c4ccccc4)cc1B3c1cc(-c3cccc4c3C(C)(C)c3ccccc3C4(C)C)ccc1N2c1ccc(-c2ccccc2)cc1]

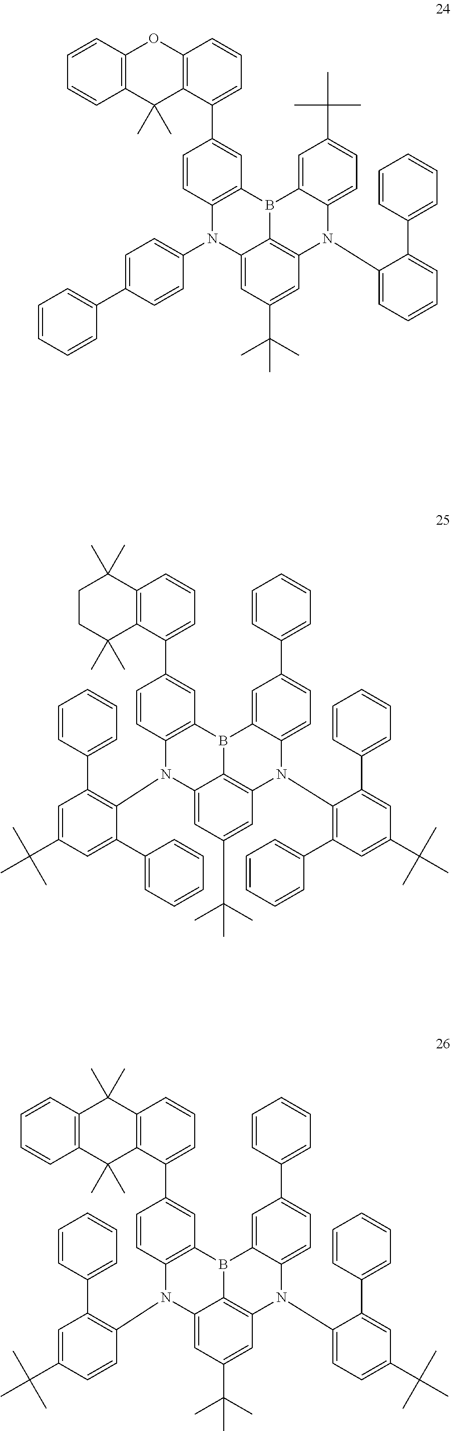

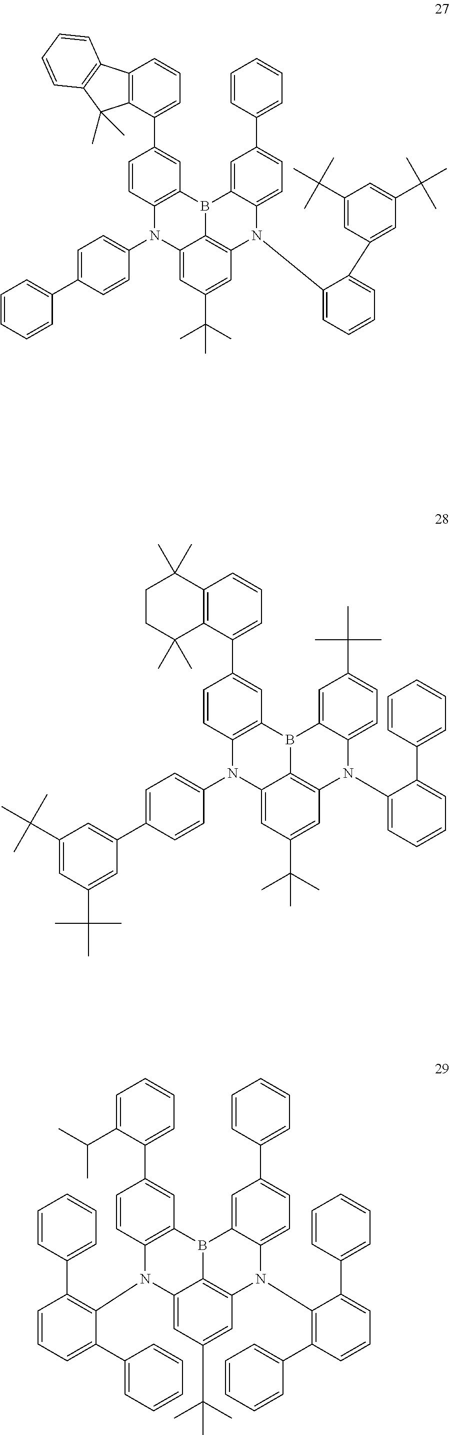

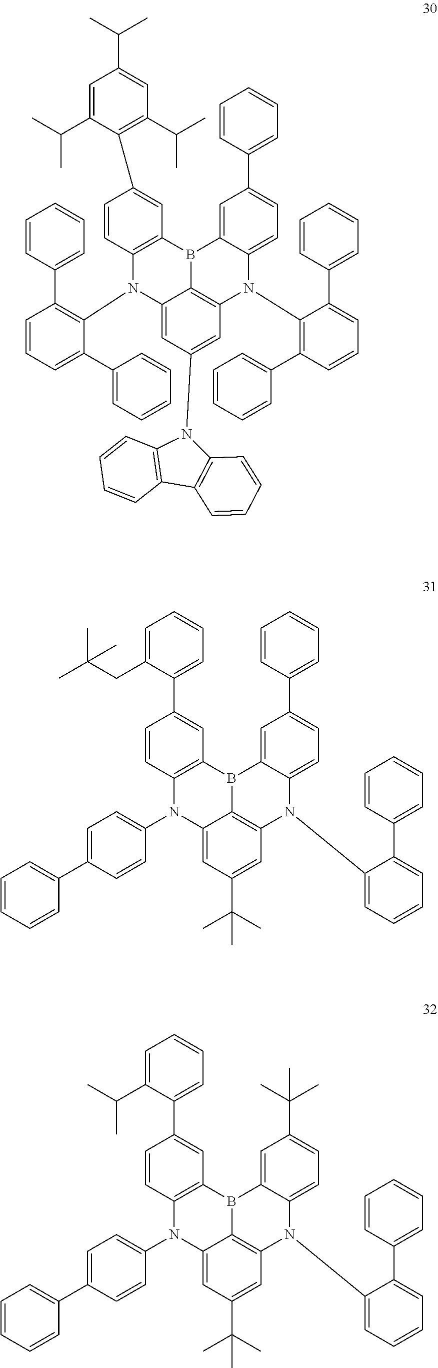 [SMILES: CC(C)c1cc(C(C)C)c(-c2ccc3c(c2)B2c4cc(-c5ccccc5)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)c(C(C)C)c1 ; CC(C)(C)Cc1ccccc1-c1ccc2c(c1)B1c3cc(-c4ccccc4)ccc3N(c3ccccc3-c3ccccc3)c3cc(C(C)(C)C)cc(c31)N2c1ccc(-c2ccccc2)cc1 ; CC(C)c1ccccc1-c1ccc2c(c1)B1c3cc(C(C)(C)C)ccc3N(c3ccccc3-c3ccccc3)c3cc(C(C)(C)C)cc(c31)N2c1ccc(-c2ccccc2)cc1]

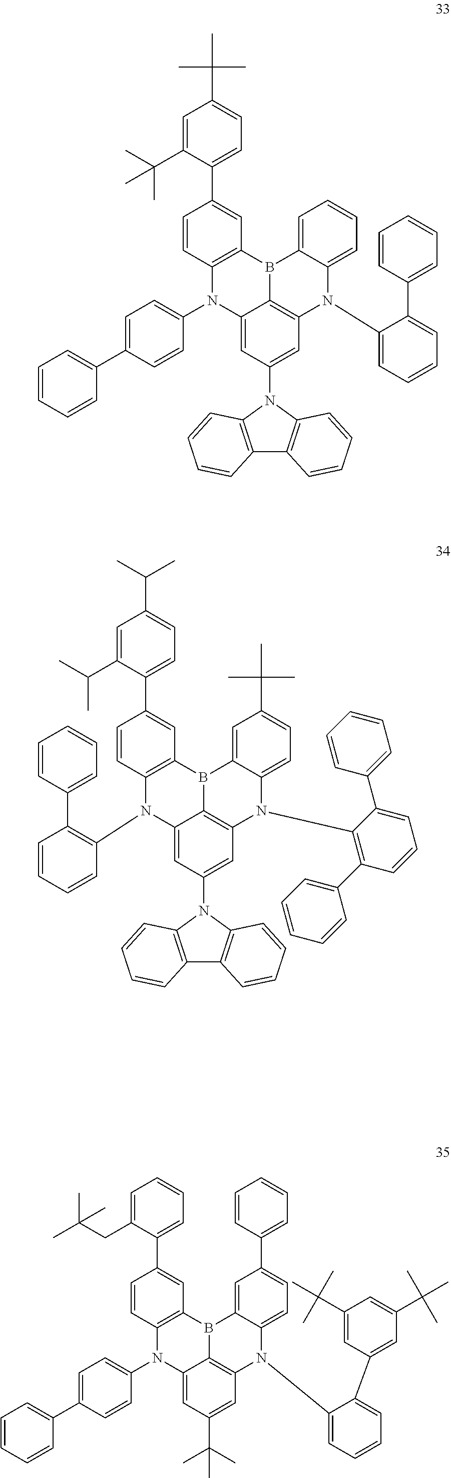 [SMILES: CC(C)(C)c1ccc(-c2ccc3c(c2)B2c4ccccc4N(c4ccccc4-c4ccccc4)c4cc(-n5c6ccccc6c6ccccc65)cc(c42)N3c2ccc(-c3ccccc3)cc2)c(C(C)(C)C)c1 ; CC(C)c1ccc(-c2ccc3c(c2)B2c4cc(C(C)(C)C)ccc4N(c4c(-c5ccccc5)cccc4-c4ccccc4)c4cc(-n5c6ccccc6c6ccccc65)cc(c42)N3c2ccccc2-c2ccccc2)c(C(C)C)c1 ; CC(C)(C)Cc1ccccc1-c1ccc2c(c1)B1c3cc(-c4ccccc4)ccc3N(c3ccccc3-c3cc(C(C)(C)C)cc(C(C)(C)C)c3)c3cc(C(C)(C)C)cc(c31)N2c1ccc(-c2ccccc2)cc1]

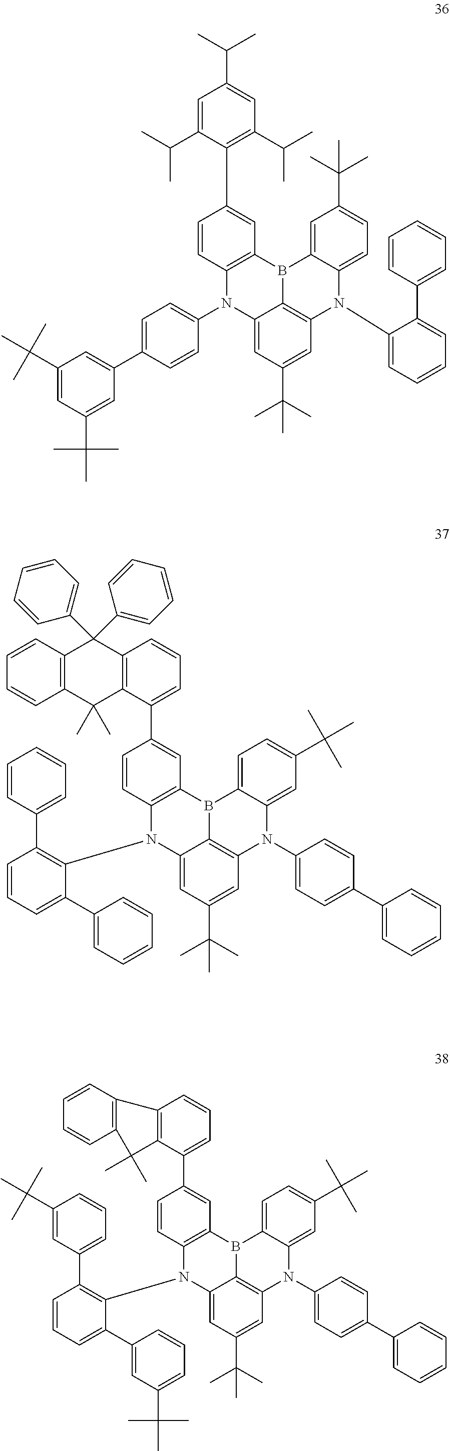 [SMILES: CC(C)c1cc(C(C)C)c(-c2ccc3c(c2)B2c4cc(C(C)(C)C)ccc4N(c4ccccc4-c4ccccc4)c4cc(C(C)(C)C)cc(c42)N3c2ccc(-c3cc(C(C)(C)C)cc(C(C)(C)C)c3)cc2)c(C(C)C)c1 ; CC(C)(C)c1ccc2c(c1)N(c1ccc(-c3ccccc3)cc1)c1cc(C(C)(C)C)cc3c1B2c1cc(-c2cccc4c2C(C)(C)c2ccccc2C4(c2ccccc2)c2ccccc2)ccc1N3c1c(-c2ccccc2)cccc1-c1ccccc1 ; CC(C)(C)c1cccc(-c2cccc(-c3cccc(C(C)(C)C)c3)c2N2c3ccc(-c4cccc5c4C(C)(C)c4ccccc4-5)cc3B3c4ccc(C(C)(C)C)cc4N(c4ccc(-c5ccccc5)cc4)c4cc(C(C)(C)C)cc2c43)c1]

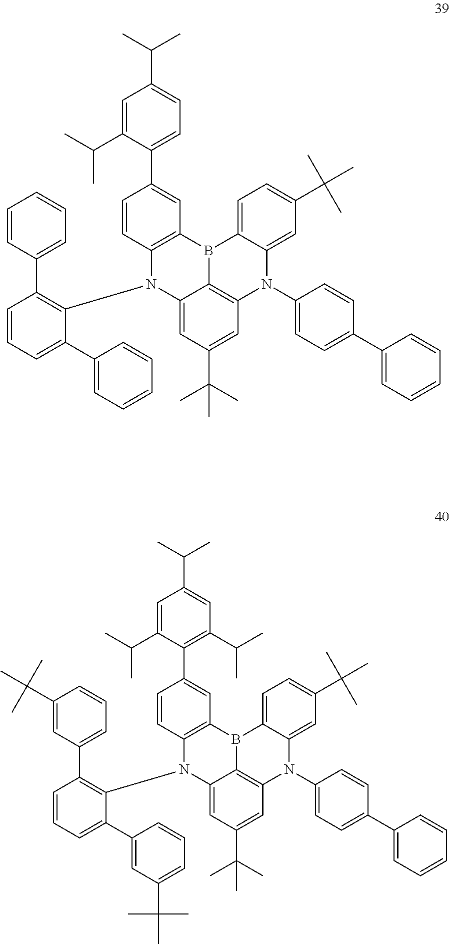 [SMILES: CC(C)c1ccc(-c2ccc3c(c2)B2c4ccc(C(C)(C)C)cc4N(c4ccc(-c5ccccc5)cc4)c4cc(C(C)(C)C)cc(c42)N3c2c(-c3ccccc3)cccc2-c2ccccc2)c(C(C)C)c1 ; CC(C)c1cc(C(C)C)c(-c2ccc3c(c2)B2c4ccc(C(C)(C)C)cc4N(c4ccc(-c5ccccc5)cc4)c4cc(C(C)(C)C)cc(c42)N3c2c(-c3cccc(C(C)(C)C)c3)cccc2-c2cccc(C(C)(C)C)c2)c(C(C)C)c1]

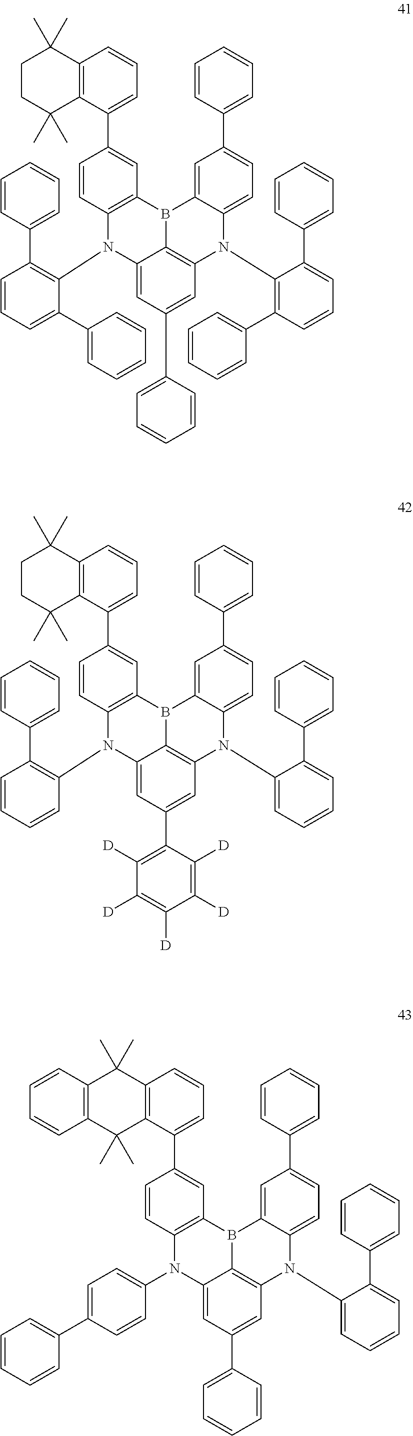 [SMILES: CC1(C)CCC(C)(C)c2c(-c3ccc4c(c3)B3c5cc(-c6ccccc6)ccc5N(c5c(-c6ccccc6)cccc5-c5ccccc5)c5cc(-c6ccccc6)cc(c53)N4c3c(-c4ccccc4)cccc3-c3ccccc3)cccc21 ; [2H]c1c([2H])c([2H])c(-c2cc3c4c(c2)N(c2ccccc2-c2ccccc2)c2ccc(-c5cccc6c5C(C)(C)CCC6(C)C)cc2B4c2cc(-c4ccccc4)ccc2N3c2ccccc2-c2ccccc2)c([2H])c1[2H] ; CC1(C)c2ccccc2C(C)(C)c2c(-c3ccc4c(c3)B3c5cc(-c6ccccc6)ccc5N(c5ccccc5-c5ccccc5)c5cc(-c6ccccc6)cc(c53)N4c3ccc(-c4ccccc4)cc3)cccc21]

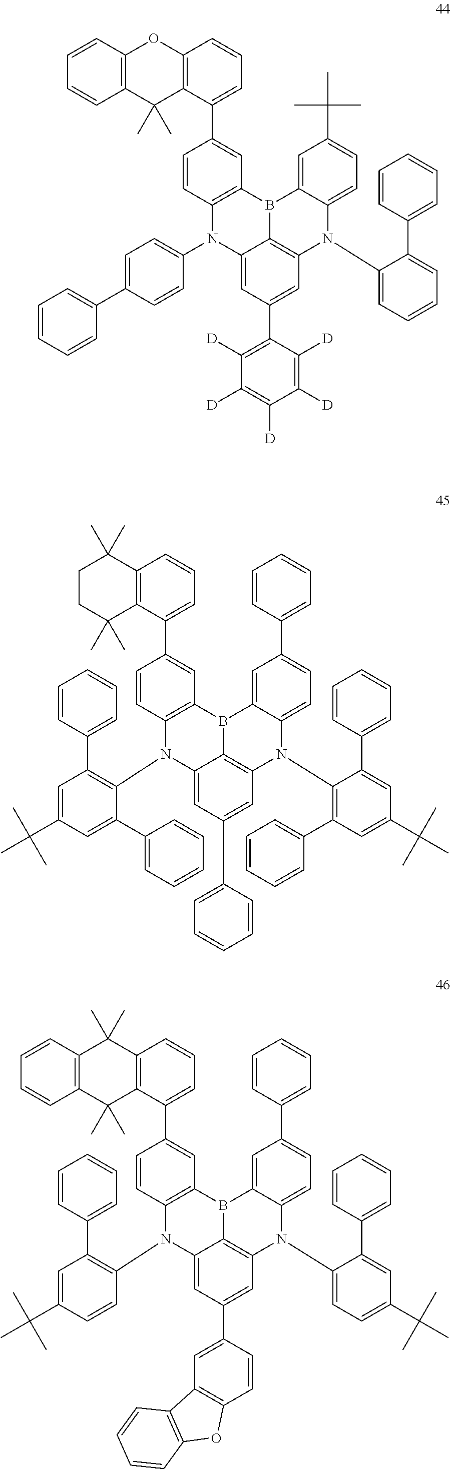

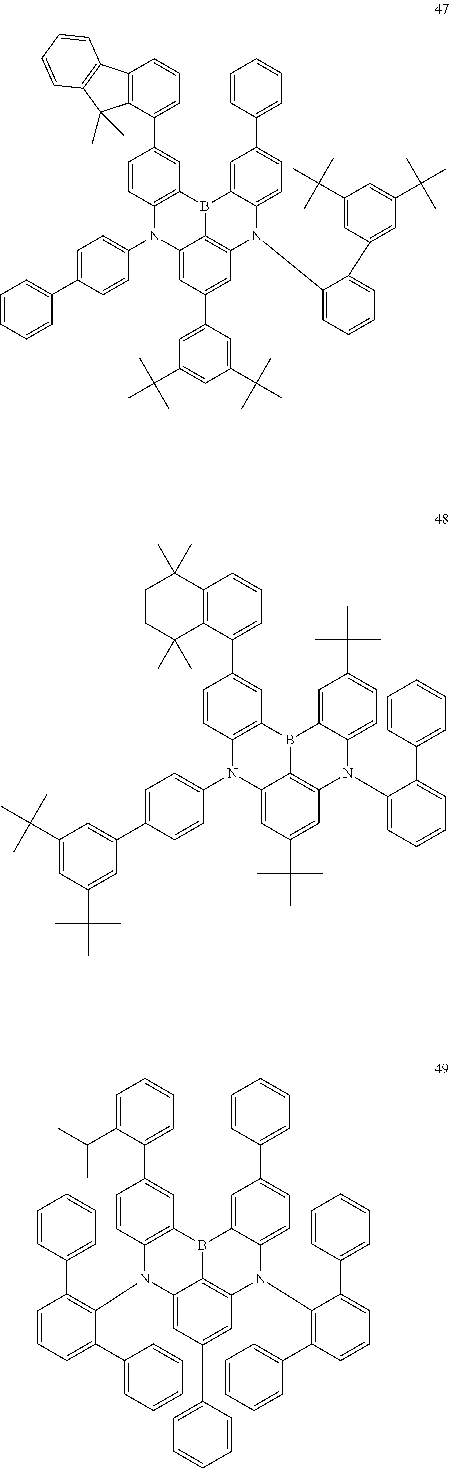

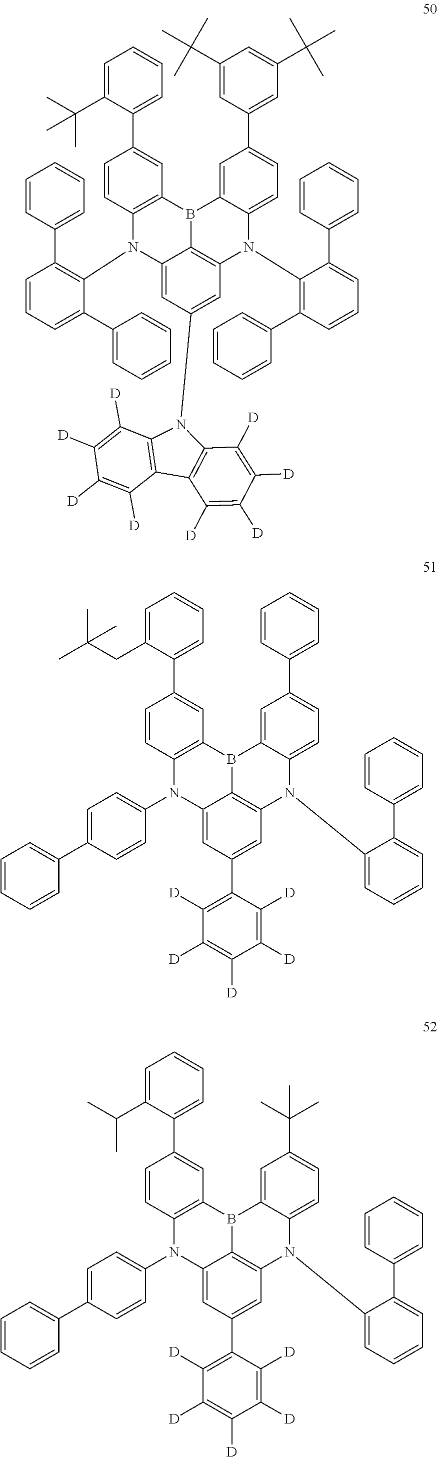 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4ccccc4C(C)(C)C)cc1B3c1cc(-c3cc(C(C)(C)C)cc(C(C)(C)C)c3)ccc1N2c1c(-c2ccccc2)cccc1-c1ccccc1 ; [2H]c1c([2H])c([2H])c(-c2cc3c4c(c2)N(c2ccccc2-c2ccccc2)c2ccc(-c5ccccc5)cc2B4c2cc(-c4ccccc4CC(C)(C)C)ccc2N3c2ccc(-c3ccccc3)cc2)c([2H])c1[2H] ; [2H]c1c([2H])c([2H])c(-c2cc3c4c(c2)N(c2ccccc2-c2ccccc2)c2ccc(C(C)(C)C)cc2B4c2cc(-c4ccccc4C(C)C)ccc2N3c2ccc(-c3ccccc3)cc2)c([2H])c1[2H]]

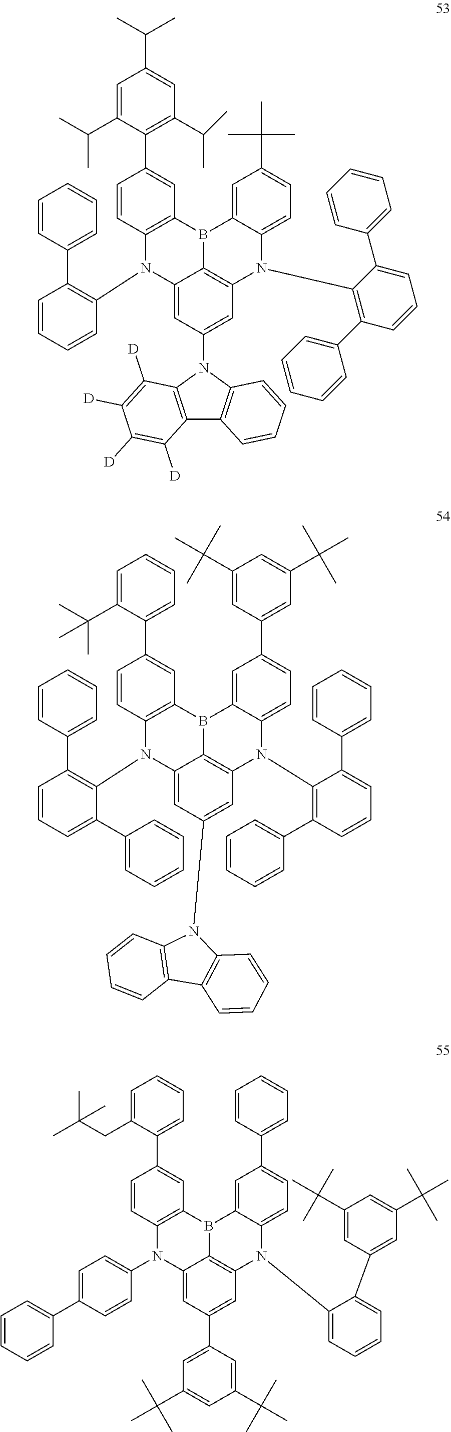 [SMILES: [2H]c1c([2H])c([2H])c2c(c1[2H])c1ccccc1n2-c1cc2c3c(c1)N(c1c(-c4ccccc4)cccc1-c1ccccc1)c1ccc(C(C)(C)C)cc1B3c1cc(-c3c(C(C)C)cc(C(C)C)cc3C(C)C)ccc1N2c1ccccc1-c1ccccc1 ; CC(C)(C)c1cc(-c2ccc3c(c2)B2c4cc(-c5ccccc5C(C)(C)C)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc(C(C)(C)C)c1 ; CC(C)(C)Cc1ccccc1-c1ccc2c(c1)B1c3cc(-c4ccccc4)ccc3N(c3ccccc3-c3cc(C(C)(C)C)cc(C(C)(C)C)c3)c3cc(-c4cc(C(C)(C)C)cc(C(C)(C)C)c4)cc(c31)N2c1ccc(-c2ccccc2)cc1]

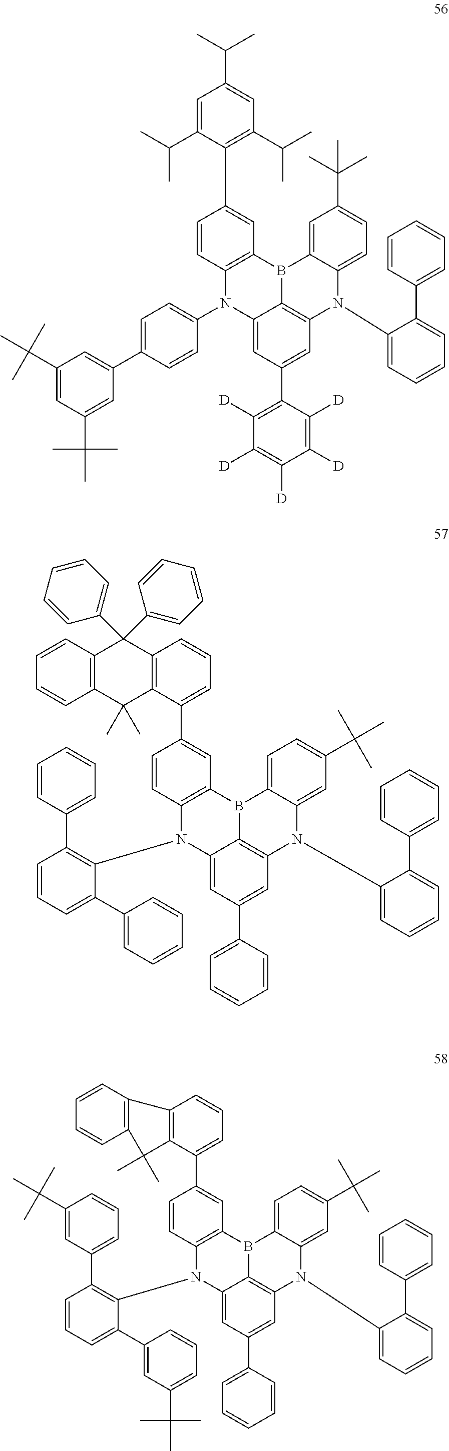 [SMILES: [2H]c1c([2H])c([2H])c(-c2cc3c4c(c2)N(c2ccccc2-c2ccccc2)c2ccc(C(C)(C)C)cc2B4c2cc(-c4c(C(C)C)cc(C(C)C)cc4C(C)C)ccc2N3c2ccc(-c3cc(C(C)(C)C)cc(C(C)(C)C)c3)cc2)c([2H])c1[2H] ; CC(C)(C)c1ccc2c(c1)N(c1ccccc1-c1ccccc1)c1cc(-c3ccccc3)cc3c1B2c1cc(-c2cccc4c2C(C)(C)c2ccccc2C4(c2ccccc2)c2ccccc2)ccc1N3c1c(-c2ccccc2)cccc1-c1ccccc1 ; CC(C)(C)c1cccc(-c2cccc(-c3cccc(C(C)(C)C)c3)c2N2c3ccc(-c4cccc5c4C(C)(C)c4ccccc4-5)cc3B3c4ccc(C(C)(C)C)cc4N(c4ccccc4-c4ccccc4)c4cc(-c5ccccc5)cc2c43)c1]

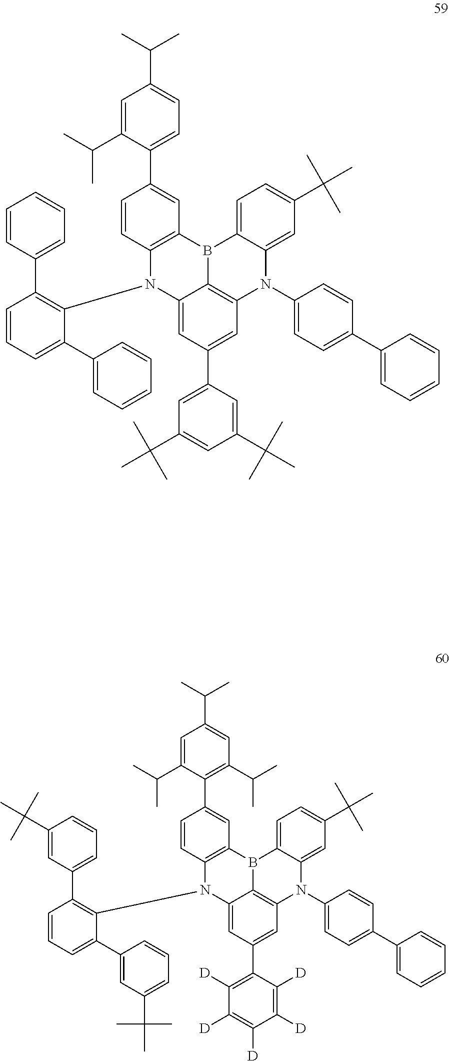 [SMILES: CC(C)c1ccc(-c2ccc3c(c2)B2c4ccc(C(C)(C)C)cc4N(c4ccc(-c5ccccc5)cc4)c4cc(-c5cc(C(C)(C)C)cc(C(C)(C)C)c5)cc(c42)N3c2c(-c3ccccc3)cccc2-c2ccccc2)c(C(C)C)c1 ; [2H]c1c([2H])c([2H])c(-c2cc3c4c(c2)N(c2c(-c5cccc(C(C)(C)C)c5)cccc2-c2cccc(C(C)(C)C)c2)c2ccc(-c5c(C(C)C)cc(C(C)C)cc5C(C)C)cc2B4c2ccc(C(C)(C)C)cc2N3c2ccc(-c3ccccc3)cc2)c([2H])c1[2H]]

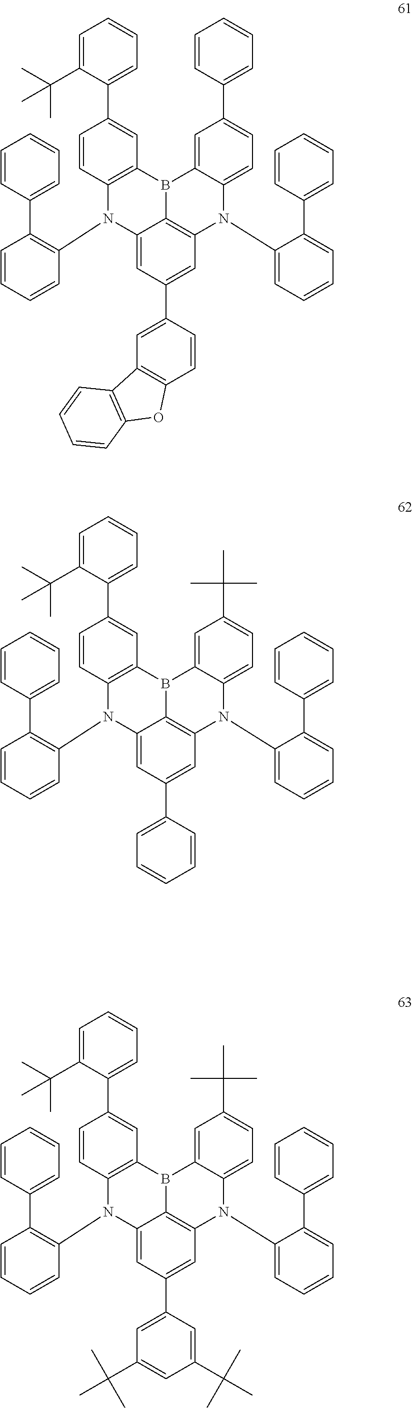 [SMILES: CC(C)(C)c1ccccc1-c1ccc2c(c1)B1c3cc(-c4ccccc4)ccc3N(c3ccccc3-c3ccccc3)c3cc(-c4ccc5oc6ccccc6c5c4)cc(c31)N2c1ccccc1-c1ccccc1 ; CC(C)(C)c1ccc2c(c1)B1c3cc(-c4ccccc4C(C)(C)C)ccc3N(c3ccccc3-c3ccccc3)c3cc(-c4ccccc4)cc(c31)N2c1ccccc1-c1ccccc1 ; CC(C)(C)c1cc(-c2cc3c4c(c2)N(c2ccccc2-c2ccccc2)c2ccc(C(C)(C)C)cc2B4c2cc(-c4ccccc4C(C)(C)C)ccc2N3c2ccccc2-c2ccccc2)cc(C(C)(C)C)c1]

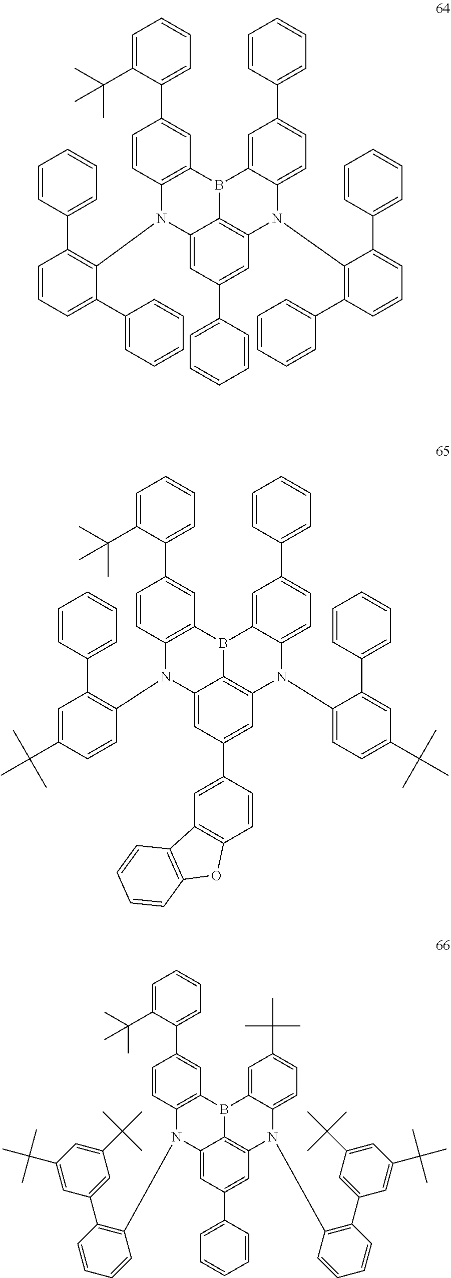

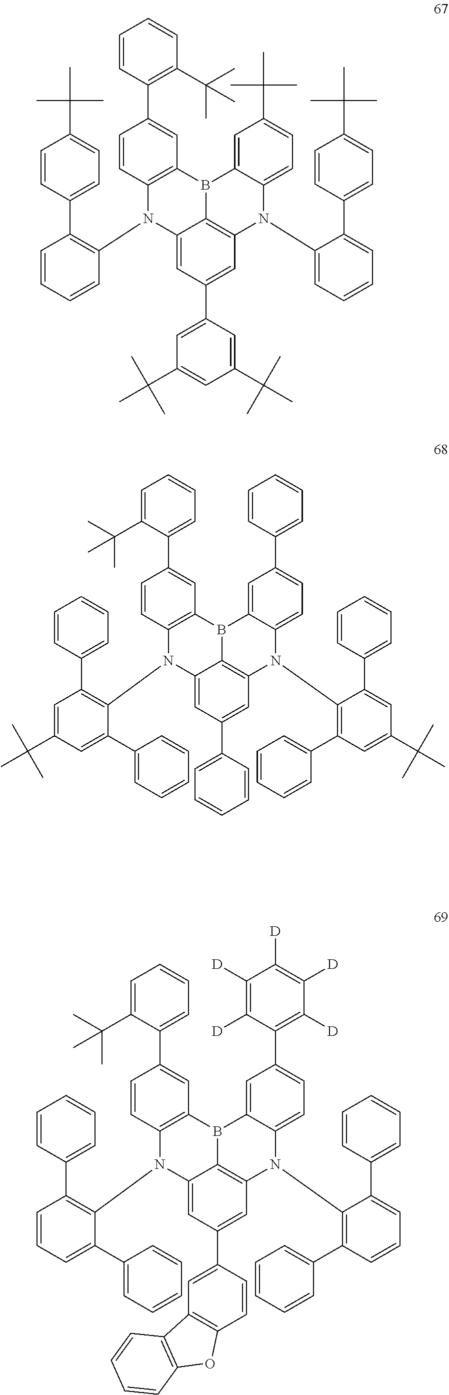

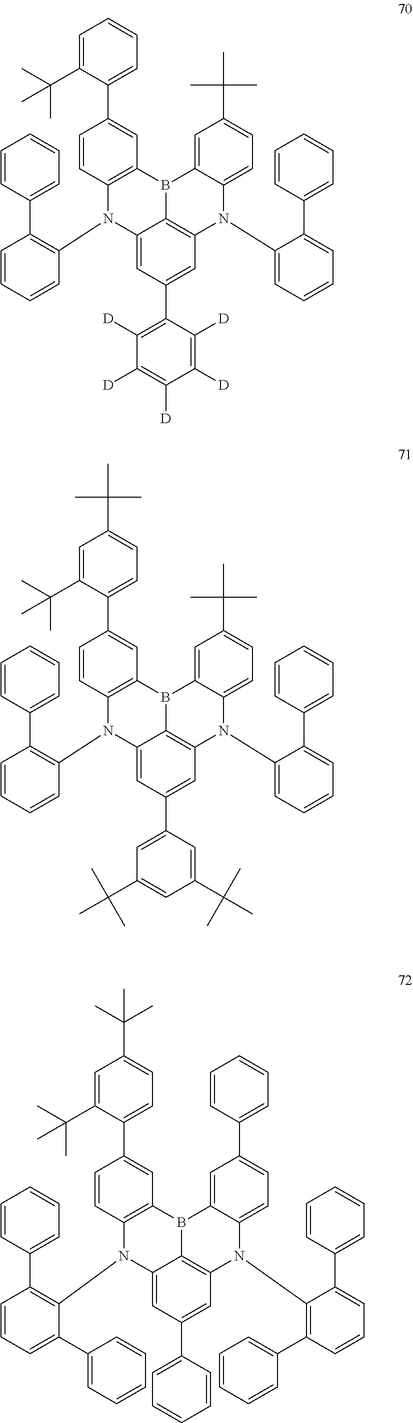 [SMILES: [2H]c1c([2H])c([2H])c(-c2cc3c4c(c2)N(c2ccccc2-c2ccccc2)c2ccc(C(C)(C)C)cc2B4c2cc(-c4ccccc4C(C)(C)C)ccc2N3c2ccccc2-c2ccccc2)c([2H])c1[2H] ; CC(C)(C)c1cc(-c2cc3c4c(c2)N(c2ccccc2-c2ccccc2)c2ccc(C(C)(C)C)cc2B4c2cc(-c4ccc(C(C)(C)C)cc4C(C)(C)C)ccc2N3c2ccccc2-c2ccccc2)cc(C(C)(C)C)c1 ; CC(C)(C)c1ccc(-c2ccc3c(c2)B2c4cc(-c5ccccc5)ccc4N(c4c(-c5ccccc5)cccc4-c4ccccc4)c4cc(-c5ccccc5)cc(c42)N3c2c(-c3ccccc3)cccc2-c2ccccc2)c(C(C)(C)C)c1]

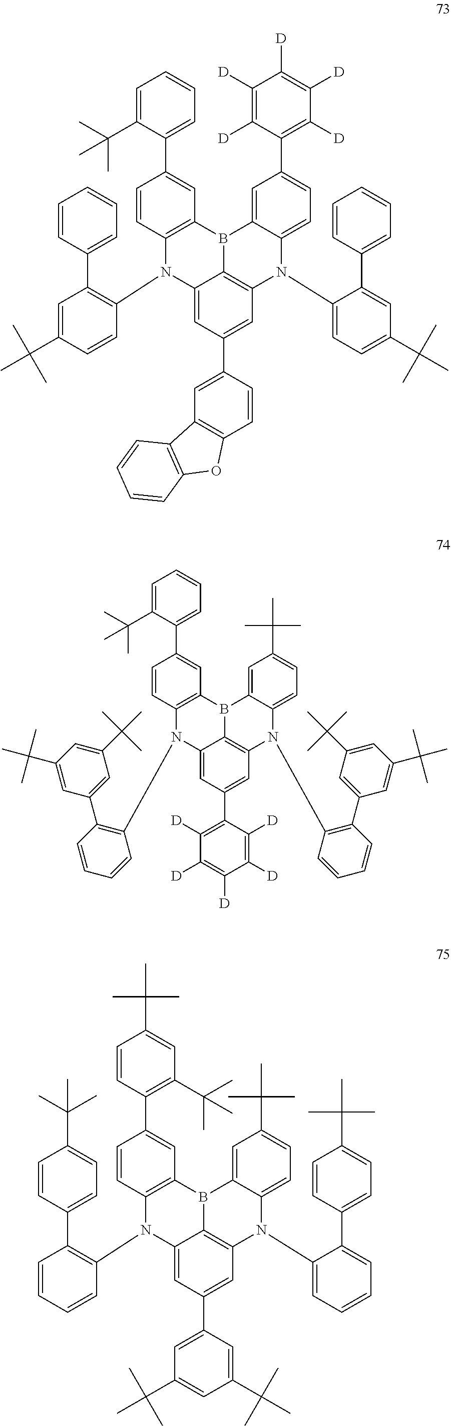

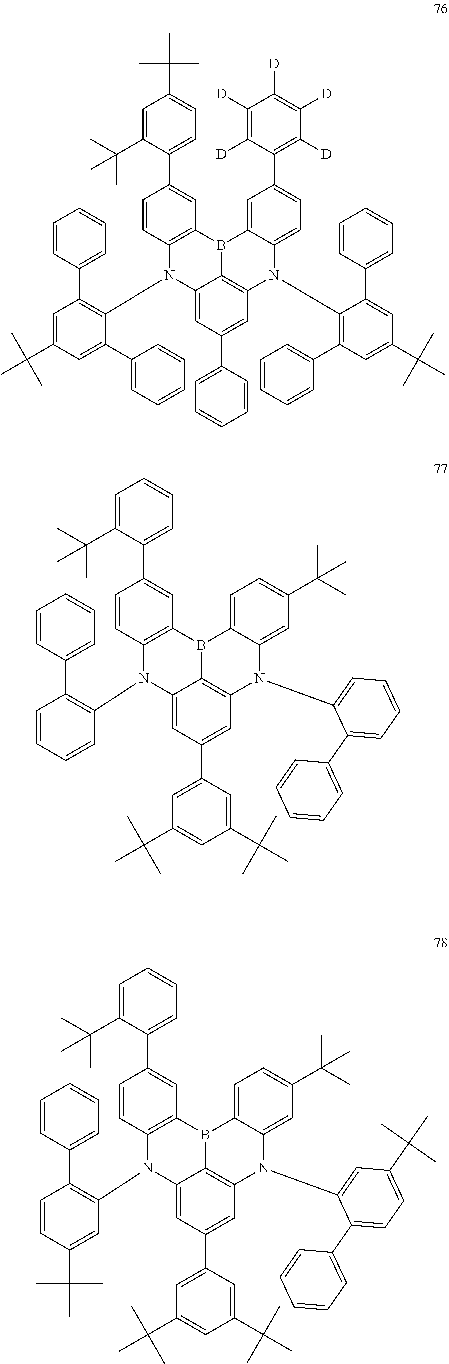

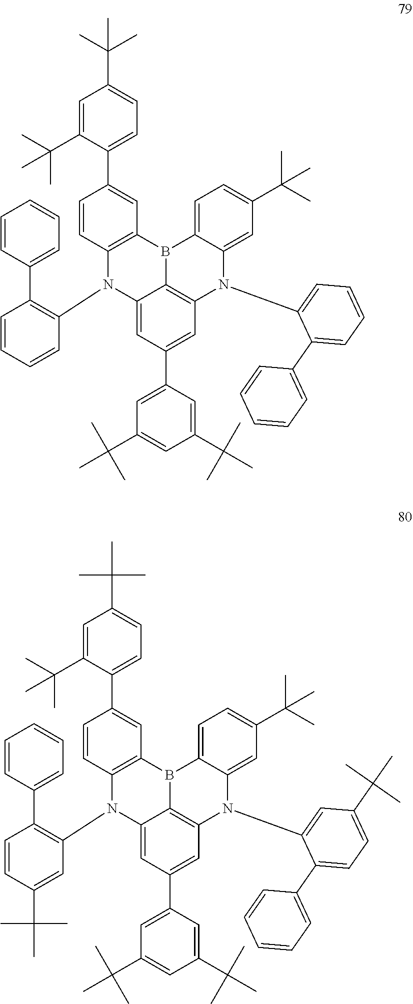 [SMILES: CC(C)(C)c1cc(-c2cc3c4c(c2)N(c2ccccc2-c2ccccc2)c2cc(C(C)(C)C)ccc2B4c2cc(-c4ccc(C(C)(C)C)cc4C(C)(C)C)ccc2N3c2ccccc2-c2ccccc2)cc(C(C)(C)C)c1 ; CC(C)(C)c1cc(-c2cc3c4c(c2)N(c2cc(C(C)(C)C)ccc2-c2ccccc2)c2cc(C(C)(C)C)ccc2B4c2cc(-c4ccc(C(C)(C)C)cc4C(C)(C)C)ccc2N3c2cc(C(C)(C)C)ccc2-c2ccccc2)cc(C(C)(C)C)c1]

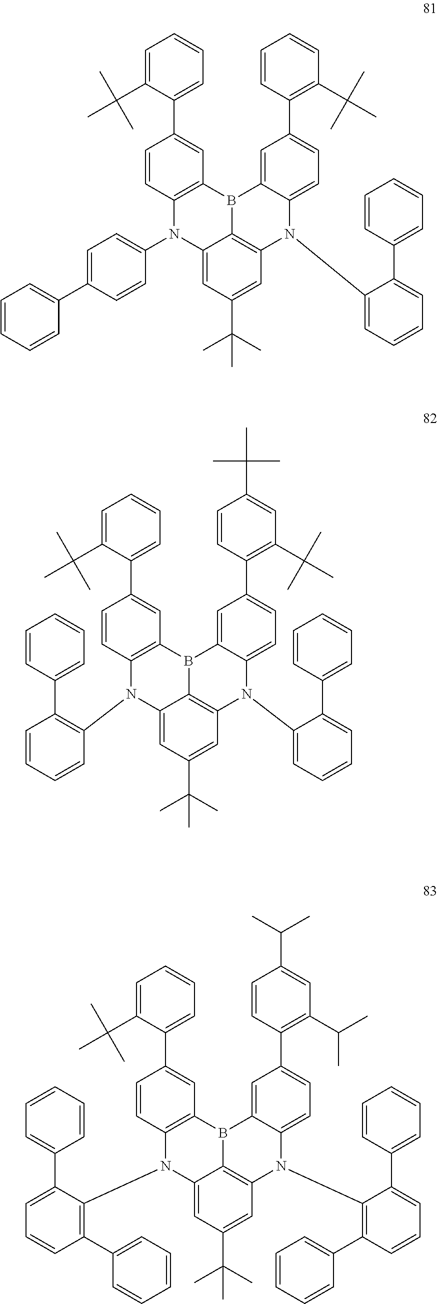

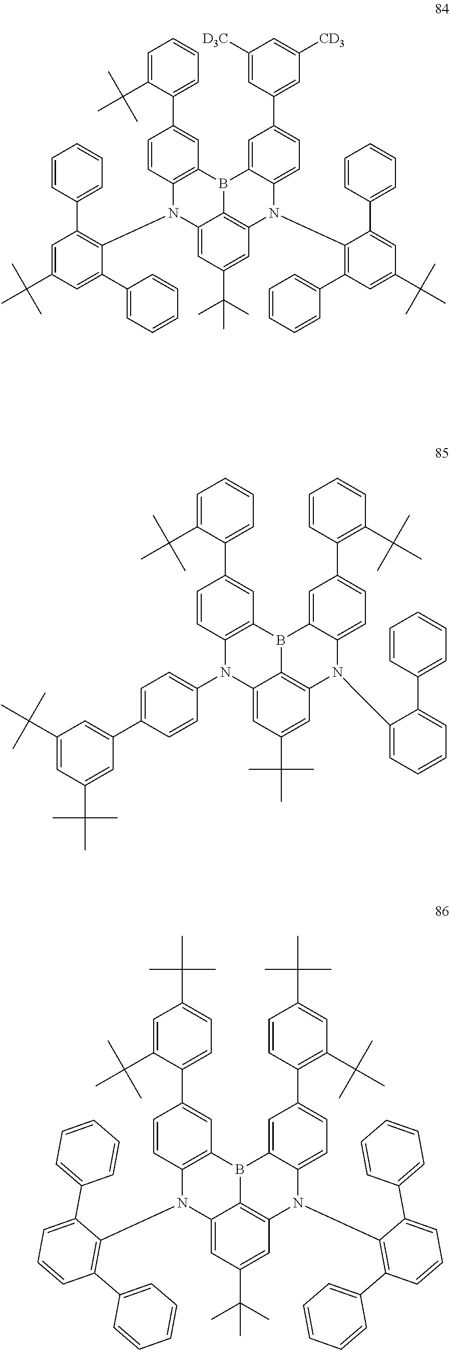

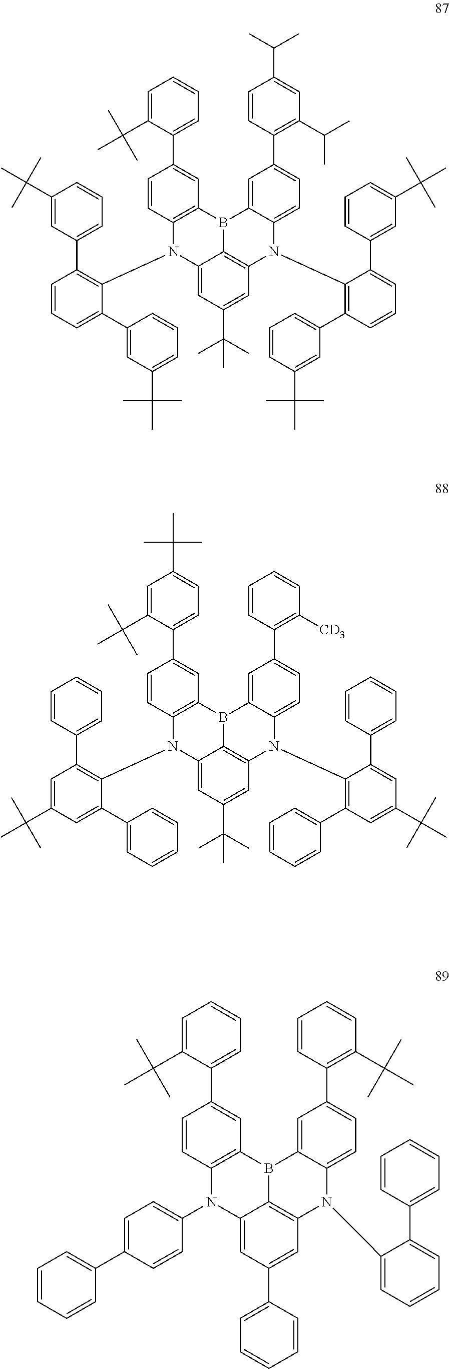

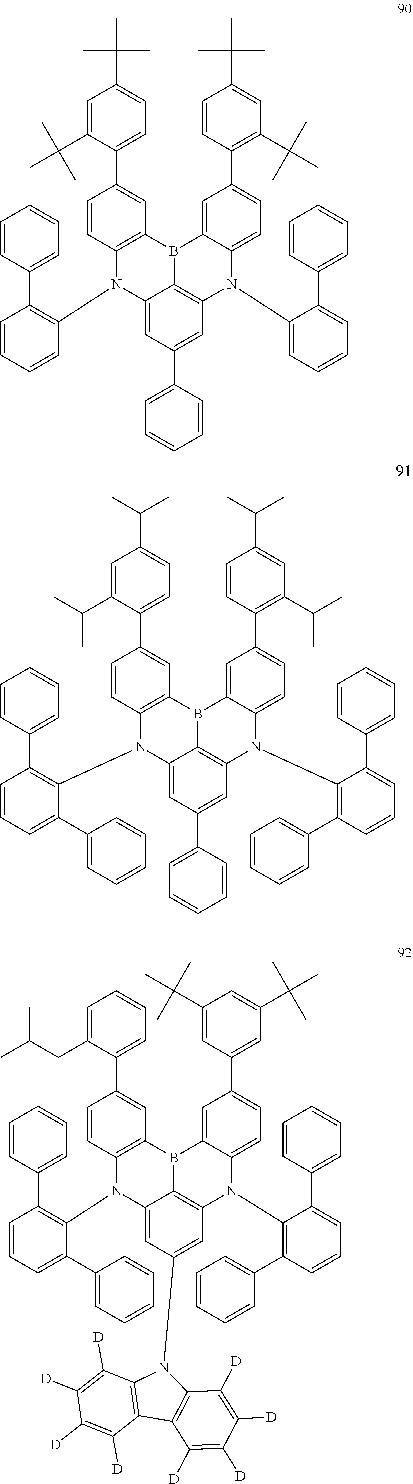

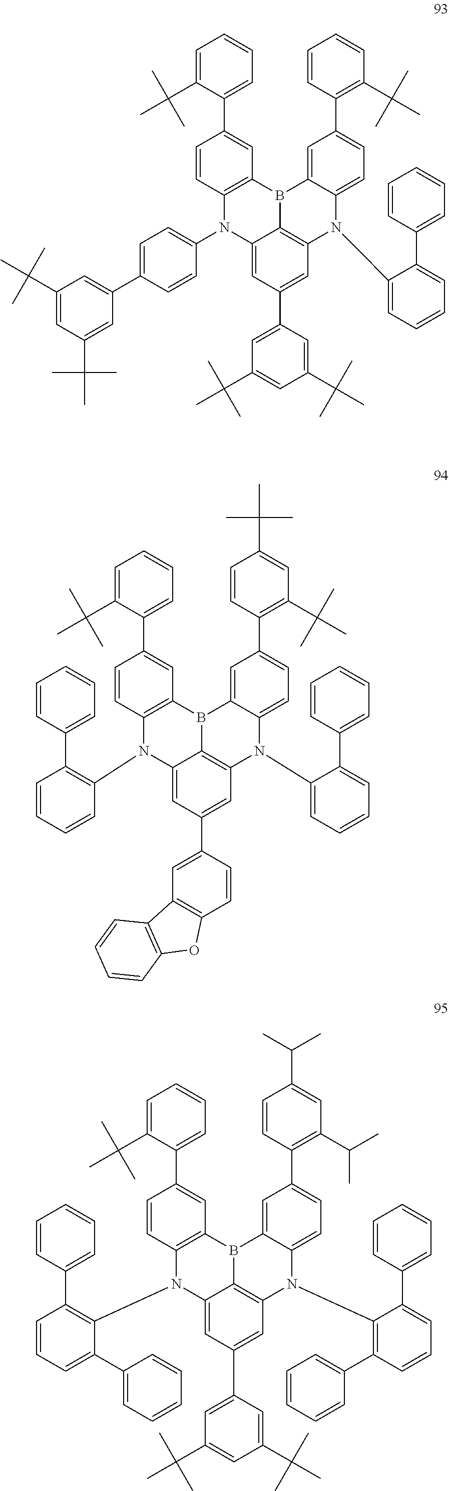

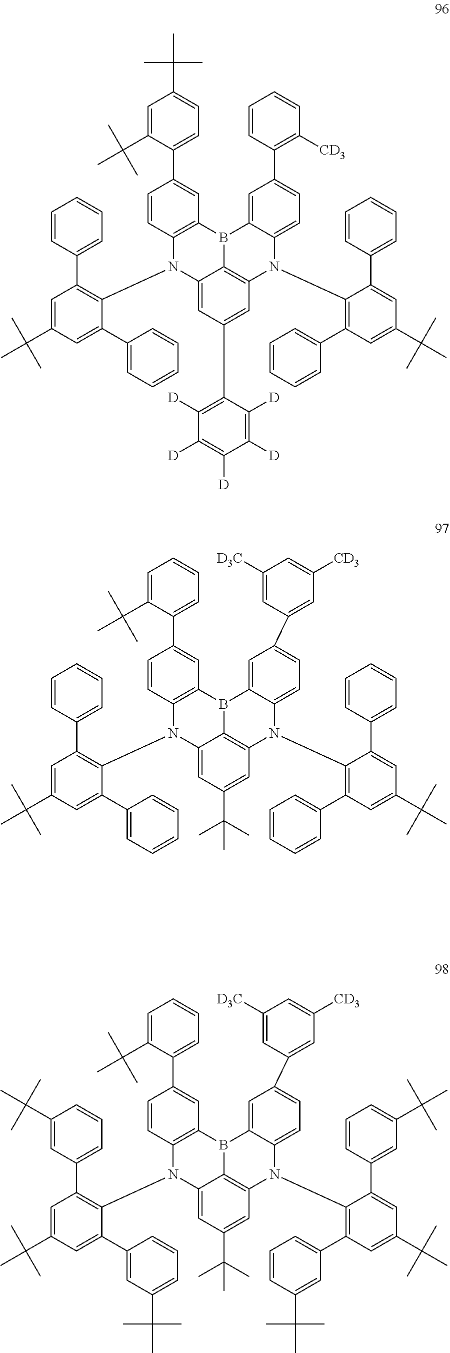

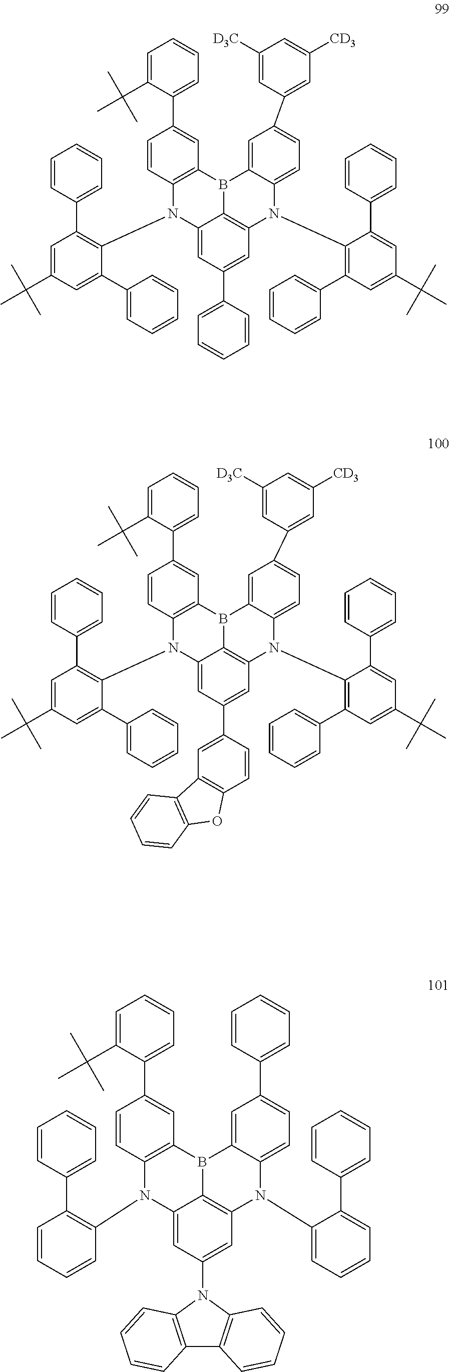

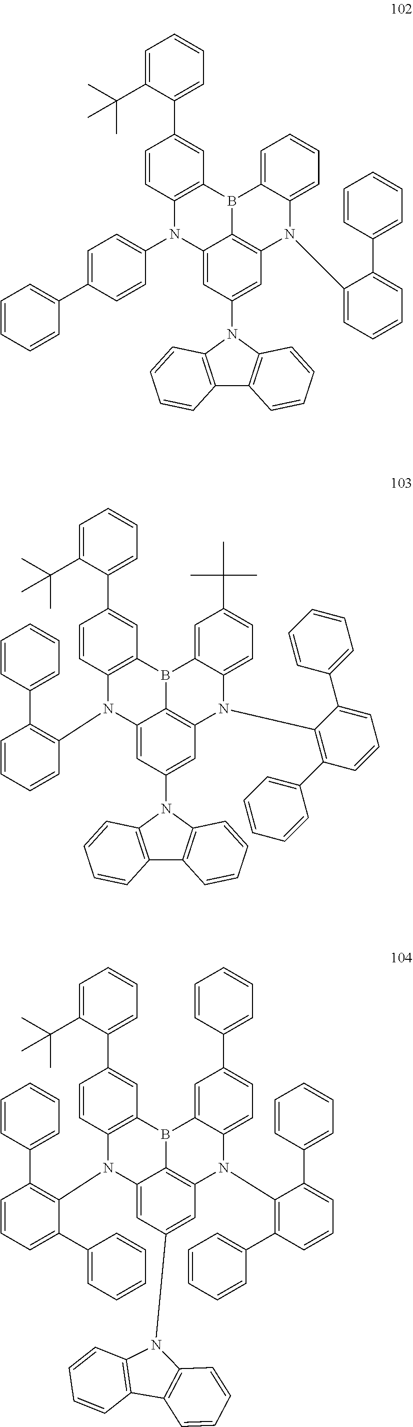 [SMILES: CC(C)(C)c1ccccc1-c1ccc2c(c1)B1c3ccccc3N(c3ccccc3-c3ccccc3)c3cc(-n4c5ccccc5c5ccccc54)cc(c31)N2c1ccc(-c2ccccc2)cc1 ; CC(C)(C)c1ccc2c(c1)B1c3cc(-c4ccccc4C(C)(C)C)ccc3N(c3ccccc3-c3ccccc3)c3cc(-n4c5ccccc5c5ccccc54)cc(c31)N2c1c(-c2ccccc2)cccc1-c1ccccc1 ; CC(C)(C)c1ccccc1-c1ccc2c(c1)B1c3cc(-c4ccccc4)ccc3N(c3c(-c4ccccc4)cccc3-c3ccccc3)c3cc(-n4c5ccccc5c5ccccc54)cc(c31)N2c1c(-c2ccccc2)cccc1-c1ccccc1]

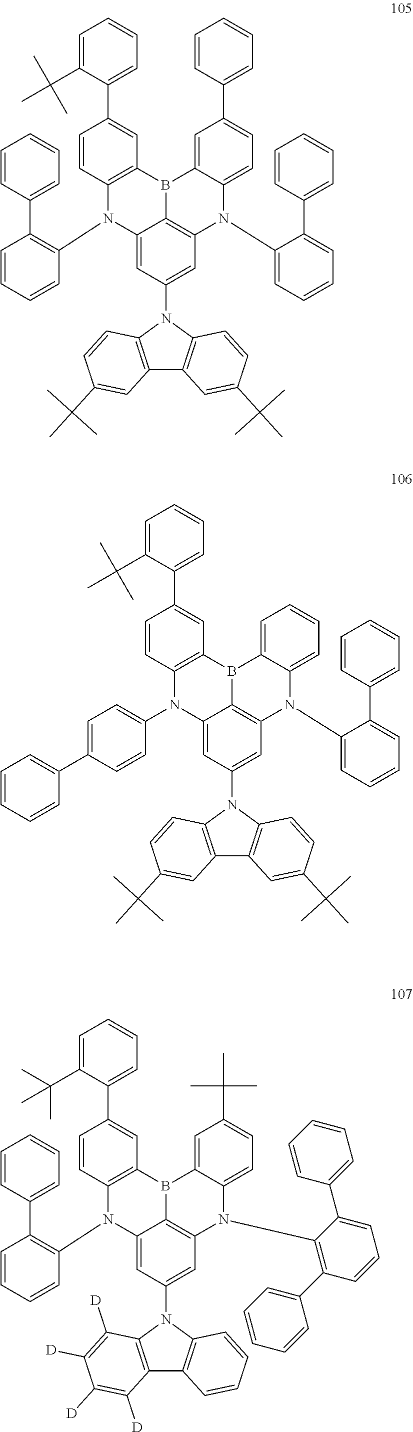 [SMILES: CC(C)(C)c1ccc2c(c1)c1cc(C(C)(C)C)ccc1n2-c1cc2c3c(c1)N(c1ccccc1-c1ccccc1)c1ccc(-c4ccccc4C(C)(C)C)cc1B3c1cc(-c3ccccc3)ccc1N2c1ccccc1-c1ccccc1 ; CC(C)(C)c1ccc2c(c1)c1cc(C(C)(C)C)ccc1n2-c1cc2c3c(c1)N(c1ccccc1-c1ccccc1)c1ccccc1B3c1cc(-c3ccccc3C(C)(C)C)ccc1N2c1ccc(-c2ccccc2)cc1 ; [2H]c1c([2H])c([2H])c2c(c1[2H])c1ccccc1n2-c1cc2c3c(c1)N(c1c(-c4ccccc4)cccc1-c1ccccc1)c1ccc(C(C)(C)C)cc1B3c1cc(-c3ccccc3C(C)(C)C)ccc1N2c1ccccc1-c1ccccc1]

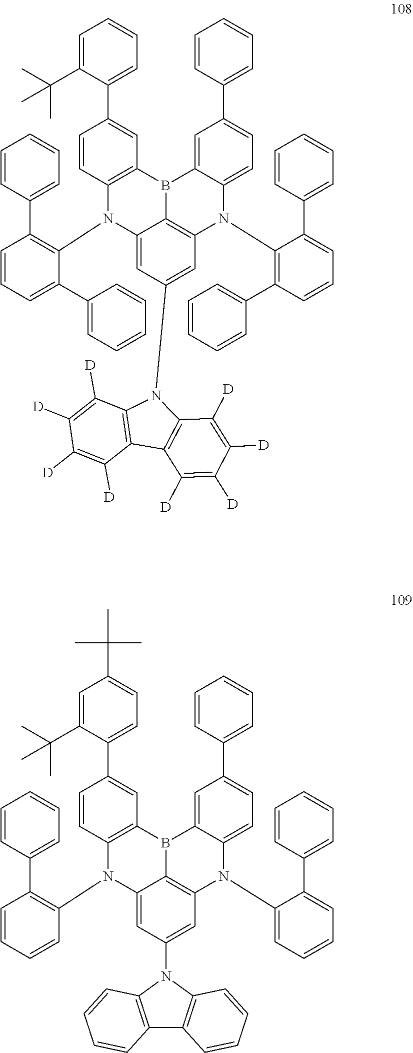 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4ccccc4C(C)(C)C)cc1B3c1cc(-c3ccccc3)ccc1N2c1c(-c2ccccc2)cccc1-c1ccccc1 ; CC(C)(C)c1ccc(-c2ccc3c(c2)B2c4cc(-c5ccccc5)ccc4N(c4ccccc4-c4ccccc4)c4cc(-n5c6ccccc6c6ccccc65)cc(c42)N3c2ccccc2-c2ccccc2)c(C(C)(C)C)c1]

The condensed cyclic compound represented by Formula 1 may include Z₁, which may be a substituted or unsubstituted C₂-C₆₀ alkyl group, a substituted or unsubstituted C₂-C₆₀ alkenyl group, or a substituted or unsubstituted C₂-C₆₀ alkynyl group, at an ortho position with respect to the core, and may have a structure in which at least one group represented by Formula 2 is linked to a nitrogen atom of the core.

Since the condensed cyclic compound represented by Formula 1 includes Z₁, which may be a substituted or unsubstituted C₂-C₆₀ alkyl group, a substituted or unsubstituted C₂-C₆₀ alkenyl group, or a substituted or unsubstituted C₂-C₆₀ alkynyl group, at an ortho position with respect to the core, chemical reactivity that may be suppressed as the condensed cyclic compound is transformed into a regular tetrahedral structure by binding to a nucleophile due to the electron deficient property of a vacant p-orbital of Y₁ atom, for example, a boron atom, in the core, multiple resonance may be further activated by the introduction of an electron donor, delocalization of electrons in the molecule may expand, polarizability may increase to further increase the f-value, and absorbance may increase.

Since the condensed cyclic compound represented by Formula 1 includes a structure in which at least one group represented by Formula 2 is linked to the nitrogen atom of the core, structural stability of the condensed cyclic compound may be improved by reducing the possibility of Dexter energy transfer as the distance between molecules increases, and color purity may also be improved by suppressing expansion of an orbital in the core.

Therefore, an electronic device, for example, a light-emitting device, including the condensed cyclic compound represented by Formula 1 may have low driving voltage, high luminance, high efficiency, high color purity, and long lifespan.

Synthesis methods of the condensed cyclic compound represented by Formula 1 may be recognizable by those of ordinary skill in the art by referring to Examples below.

At least one condensed cyclic compound represented by Formula 1 may be used in a light-emitting device (for example, an organic light-emitting device).

According to embodiments, a light-emitting device may include: a first electrode; a second electrode facing the first electrode; an interlayer between the first electrode and the second electrode and including an emission layer; and at least one condensed cyclic compound as described above.

In an embodiment, the first electrode may be an anode,
the second electrode may be a cathode,
the interlayer may further include a hole transport region between the emission layer and the first electrode and an electron transport region between the emission layer and the second electrode,
the hole transport region may include a hole injection layer, a hole transport layer, an emission auxiliary layer, an electron blocking layer, or any combination thereof, and
the electron transport region may include a buffer layer, a hole blocking layer, an electron control layer, an electron transport layer, an electron injection layer, or any combination thereof.

In an embodiment, the emission layer may include the condensed cyclic compound.

In an embodiment, the condensed cyclic compound represented by Formula 1 may emit light.

In an embodiment, the condensed cyclic compound represented by Formula 1 may emit light having a maximum emission wavelength in a range of about 400 nm to about 500 nm.

In an embodiment, an amount of the condensed cyclic compound may be greater than about 0 parts by weight and less than about 50 parts by weight based on a total of 100 parts by weight of the emission layer. For example, an amount of the condensed cyclic compound may be in a range of about 0.01 parts by weight to about 49.99 parts by weight based on 100 parts by weight of the emission layer. For another example, an amount of the condensed cyclic compound may be in a range of about 0 parts by weight to about 1 part by weight, based on 100 parts by weight of the emission layer.

In an embodiment, the emission layer may include a dopant, and

the dopant may include the condensed cyclic compound represented by Formula 1.

In an embodiment, the condensed cyclic compound represented by Formula 1 may serve as a delayed fluorescence dopant.

In an embodiment, the emission layer may further include a first compound and a second compound.

In an embodiment, the first compound may be a hole transport compound including at least one electron donating group, and

the second compound may be an electron transport compound including at least one electron withdrawing group.

The term “electron donating group” as used herein may be any moiety having a capability of providing electrons, and may be, for example, a π electron-rich C₃-C₆₀ cyclic group or an amine group, but is not limited thereto, or may refer to a cyclic group rather than a π electron-deficient nitrogen-containing C₁-C₂₀ cyclic group.

The term “electron withdrawing group” as used herein may be any moiety having a capability of withdrawing electrons, and may be, for example, —F, —CFH₂, —CF₂H, —CF₃, —CN, —NO₂, a π electron-deficient nitrogen-containing C₁-C₆₀ cyclic group, or any combination thereof, but is not limited thereto.

In an embodiment, the emission layer may further include a third compound, and the third compound may be a metal-containing compound.

In an embodiment, the emission layer may further include a host.

In an embodiment, the host may include the first compound, the second compound, or any combination thereof.

In an embodiment, the host may include the first compound and the second compound, and the first compound and the second compound may serve as exciplex hosts.

In an embodiment, the third compound may serve as a sensitizer, for example, a phosphorescent sensitizer.

In an embodiment, the third compound may not emit light.

Steps of light emission of the light-emitting device according to an embodiment may be as follows: the first compound and the second compound form an exciplex (first step), energy is transferred from the exciplex to the third compound (second step), and energy is transferred from the third compound to the condensed cyclic compound represented by Formula 1 (third step).

In an embodiment, an amount of the third compound may be in a range of about 0 parts by weight to about 50 parts by weight, based on a total of 100 parts by weight of the emission layer.

In an embodiment, the first compound may be represented by Formula 301-1A or 301-2A:

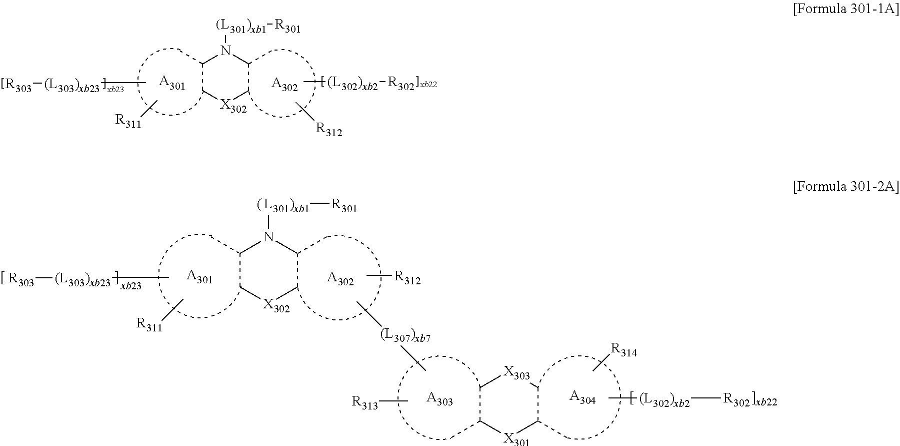

In Formulae 301-1A to 301-2A,
ring A₃₀₁ to ring A₃₀₄ may each independently be a C₃-C₆₀ carbocyclic group that is unsubstituted or substituted with at least one R₁₀ₐ or a C₁-C₂₀ heterocyclic group that is unsubstituted or substituted with at least one R₁₀ₐ,
X₃₀₁ may be 0, S, N-[(L₃₀₄)_{xb4}-R₃₀₄ₐ], C(R₃₀₄ₐ)(R_{304b}), or Si(R₃₀₄ₐ)(R_{304b}),
X₃₀₂ may be a single bond, O, S, N-[(L₃₀₅)_{xb5}-R₃₀₅ₐ], C(R₃₀₅ₐ)(R_{305b}), or Si(R₃₀₅ₐ)(R_{305b}),
X₃₀₃ may be a single bond, O, S, N-[(L₃₀₆)_{xb6}-R₃₀₆ₐ], C(R₃₀₆ₐ)(R_{306b}), or Si(R₃₀₆ₐ)(R_{306b}),
xb22 and xb23 may each independently be an integer from 0 to 10,
L₃₀₁ to L₃₀₇ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xb1 to xb7 may each independently be an integer from 0 to 5,
R₃₀₁ to R₃₀₃, R₃₀₄ₐ to R₃₀₆ₐ, R_{304b} to R_{306b}, and R₃₁₁ to R₃₁₄ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂), and
0301 to Q₃₀₃ may each independently be the same as described in connection with Q₁.

In an embodiment, the first compound may be, but is not limited to, one of Compounds HTH1 to HTH56:

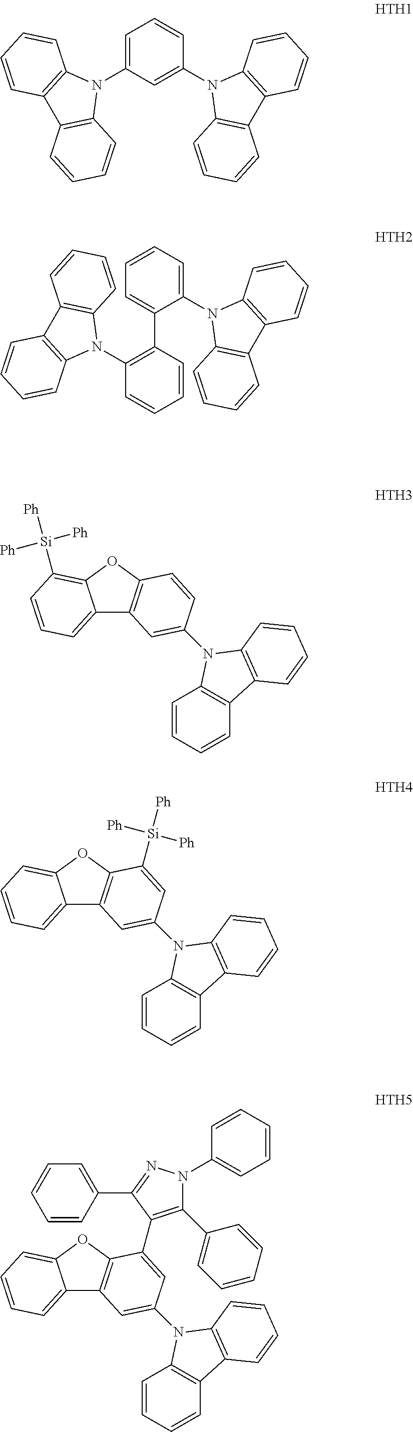 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1]

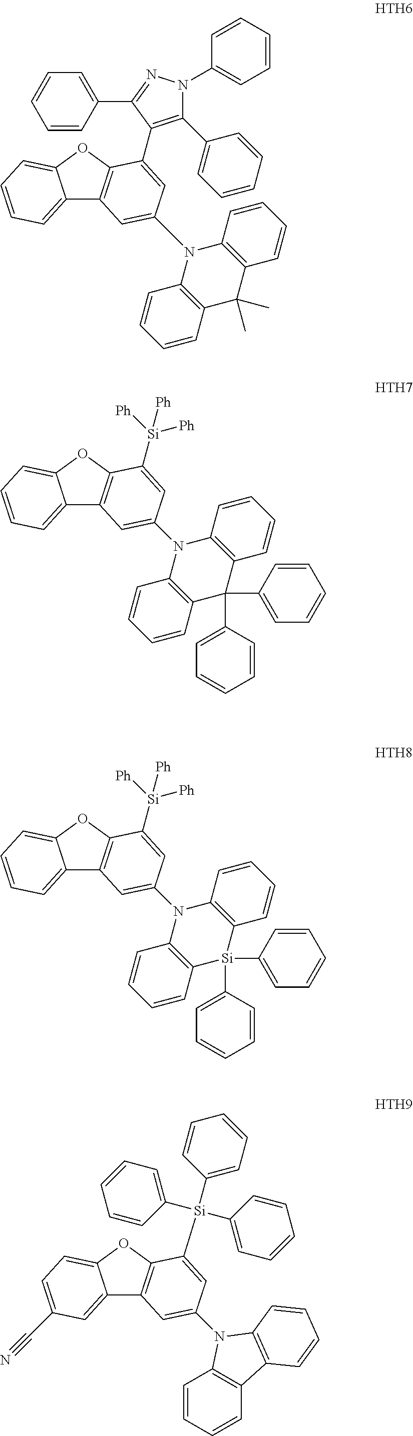 [SMILES: CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

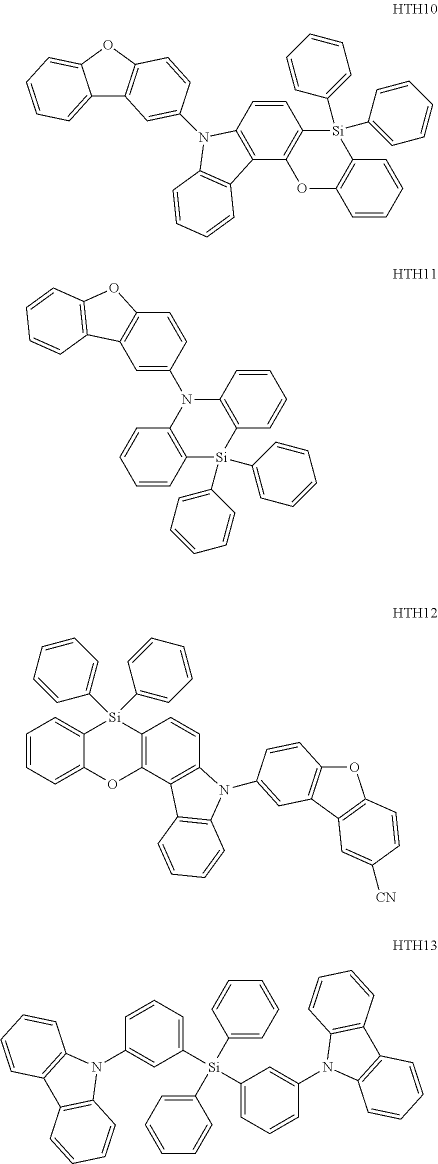 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

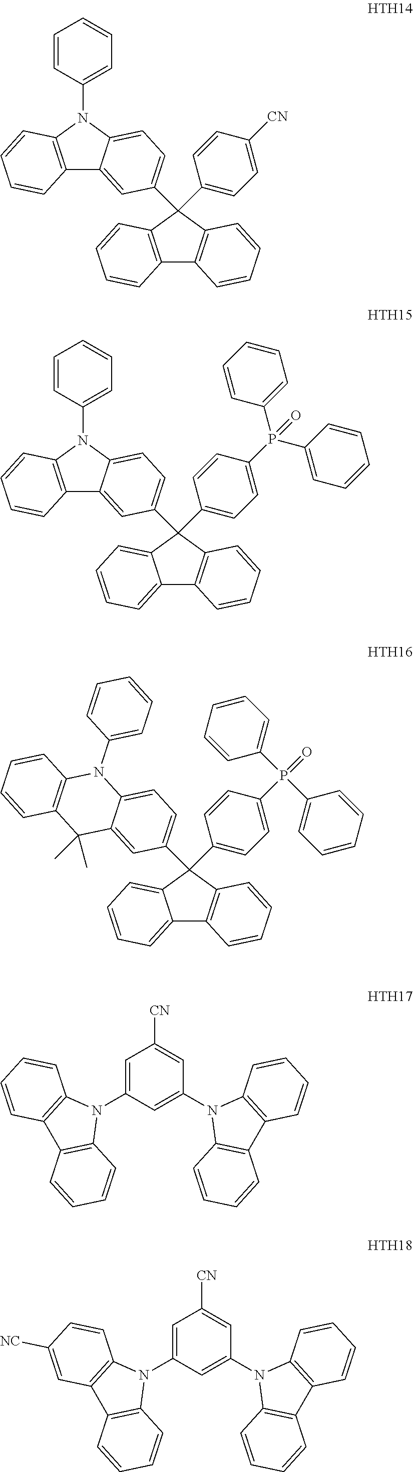 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

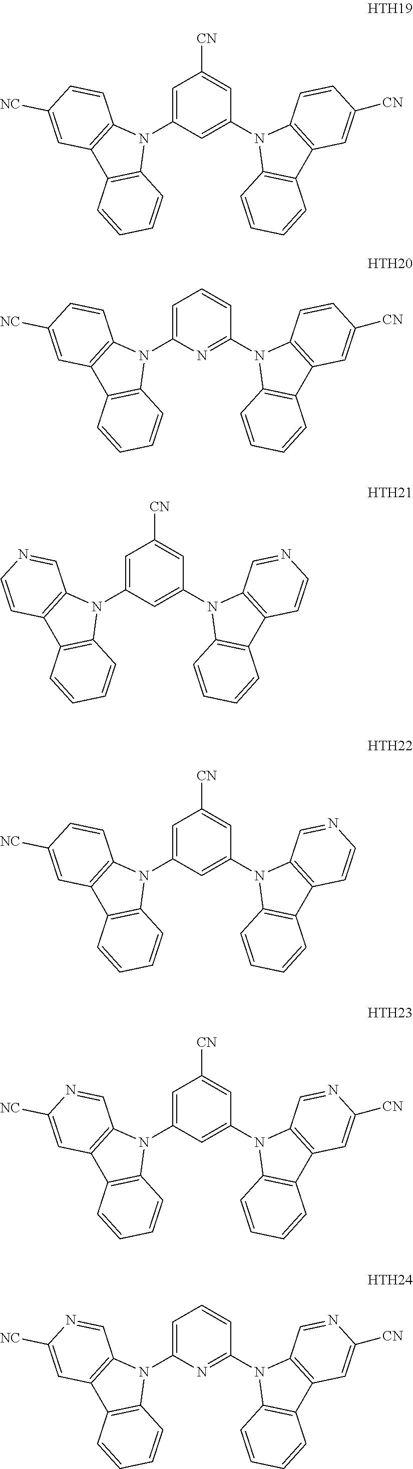 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

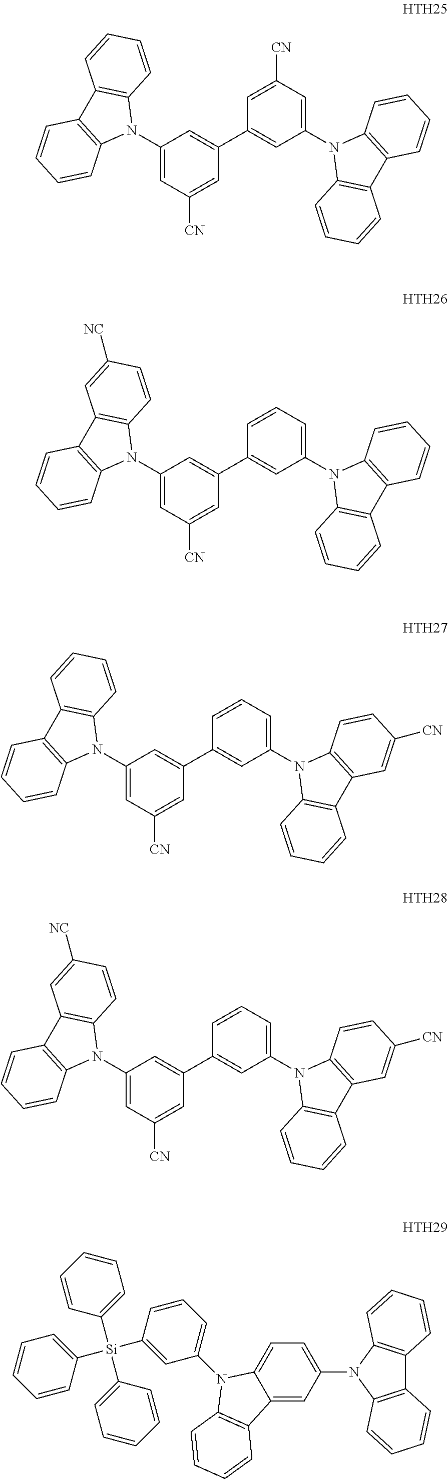 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

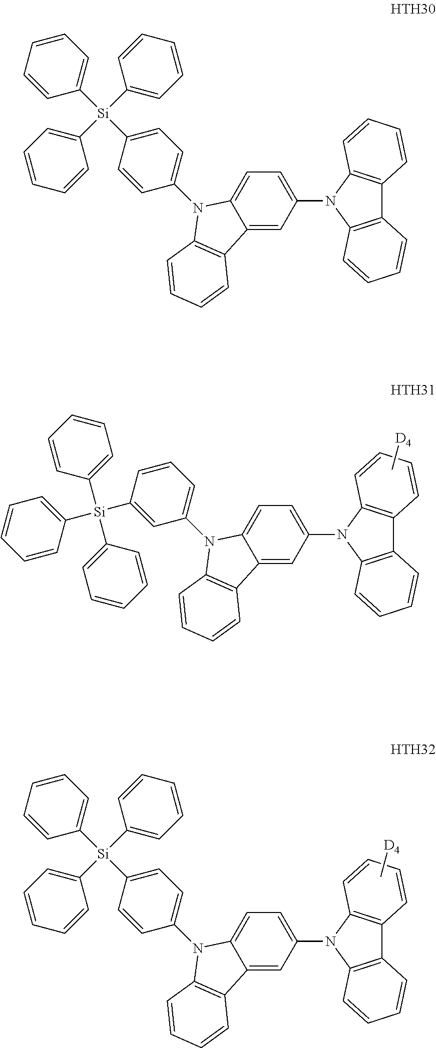

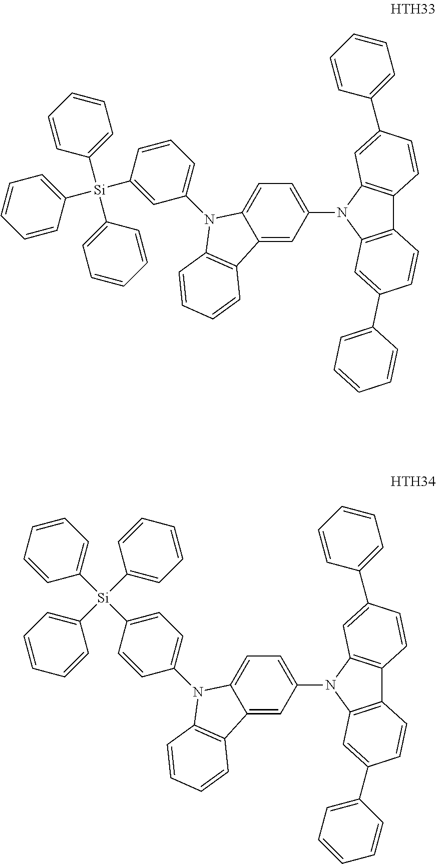 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

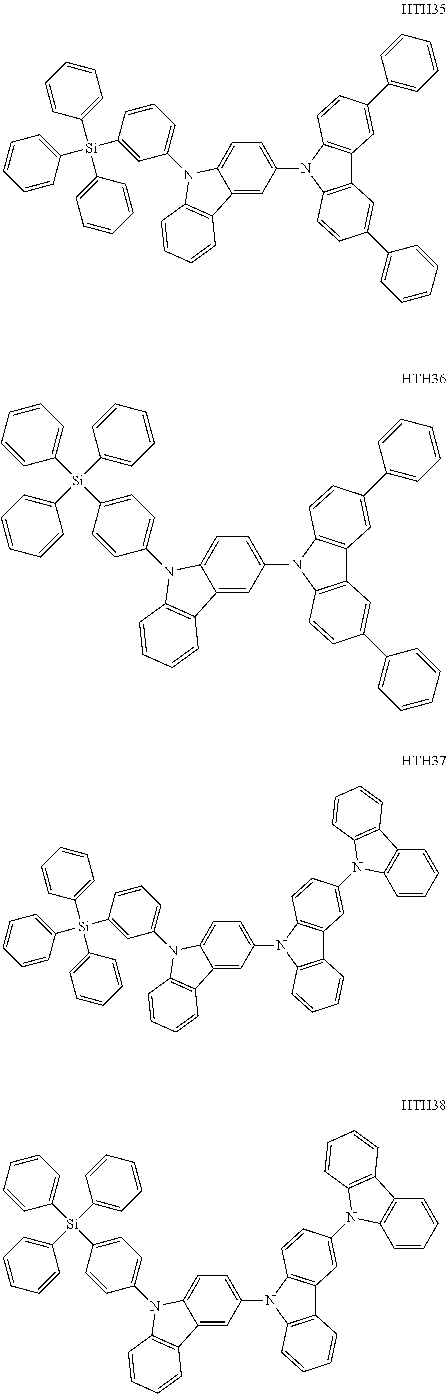 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

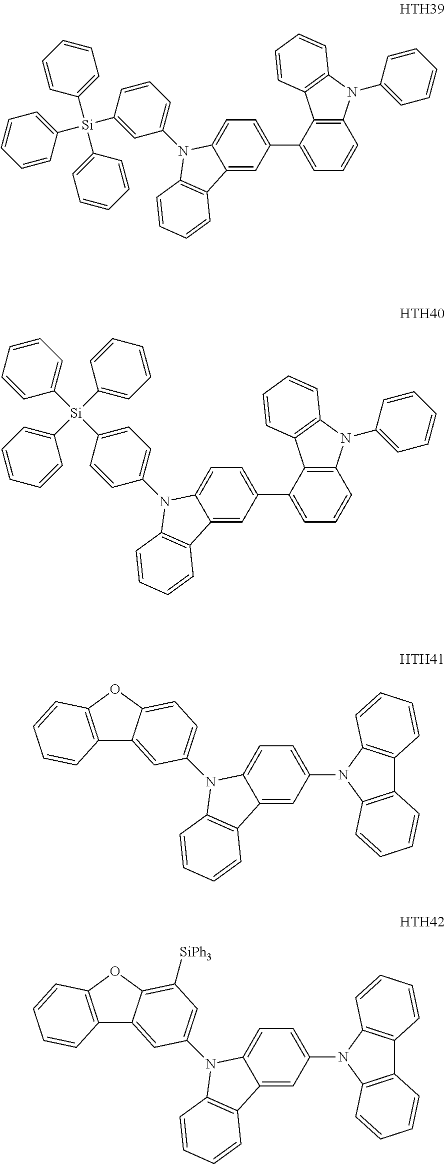

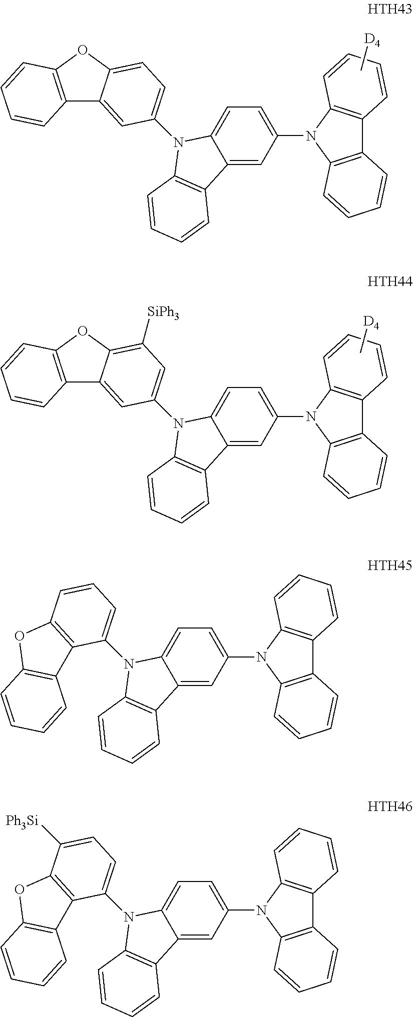

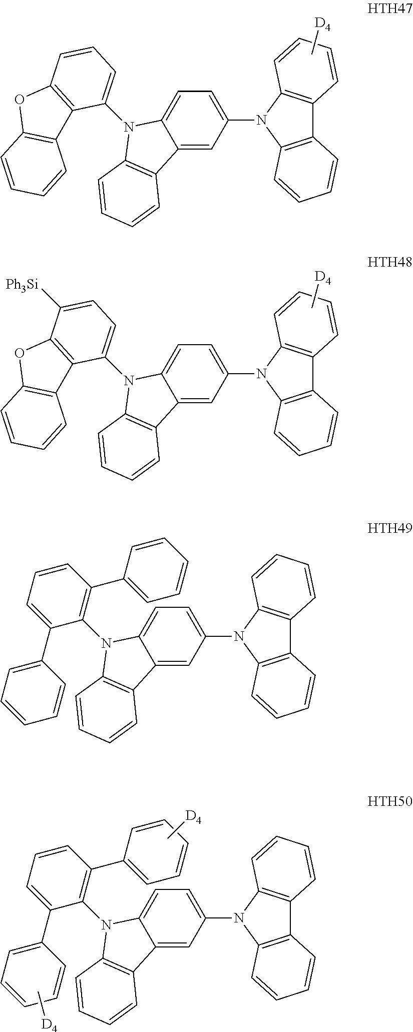

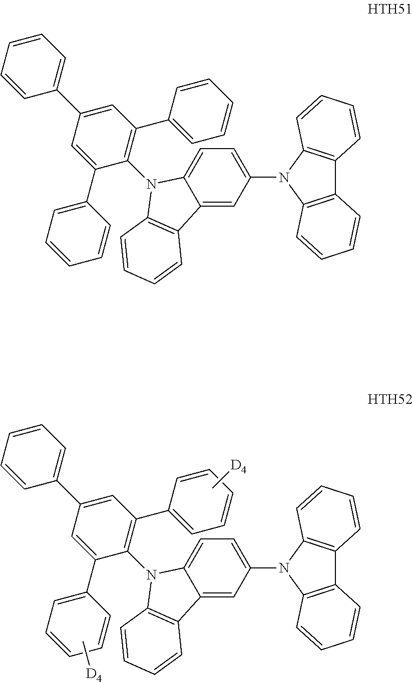

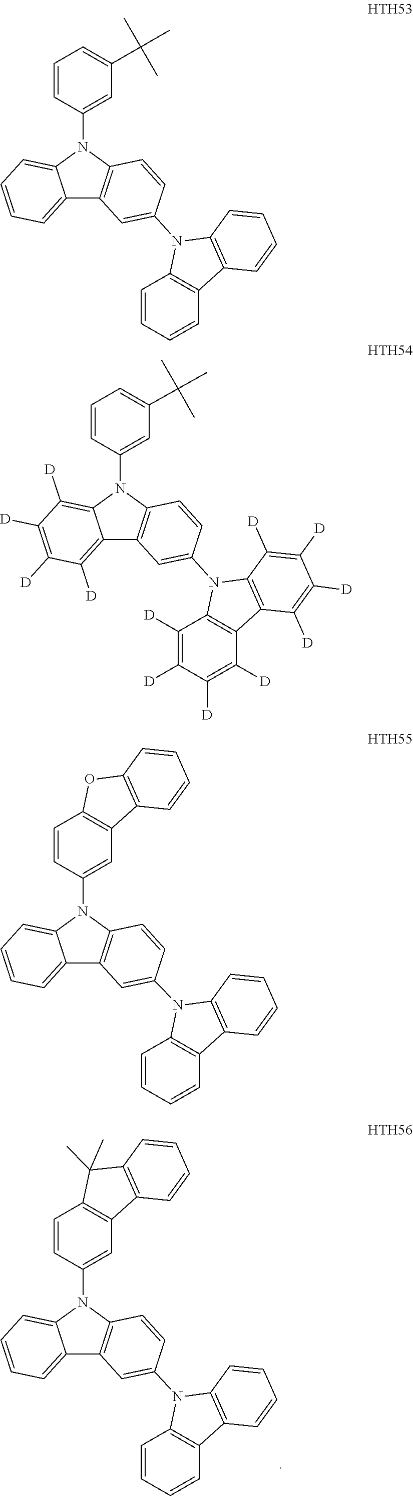

In an embodiment, the second compound may be represented by Formula 302:

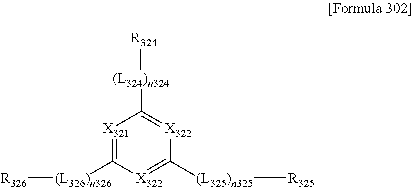

In Formula 302,
X₃₂₁ may be C(R₃₂₁) or N,
X₃₂₂ may be C(R₃₂₂) or N,
X₃₂₃ may be C(R₃₂₃) or N,
at least one of X₃₂₁ to X₃₂₃ may be N,
L₃₂₄ to L₃₂₆ may each independently be a single bond, a C₃-C₆₀ carbocyclic group that is unsubstituted or substituted with at least one R₁₀ₐ, a C₁-C₂₀ heterocyclic group that is unsubstituted or substituted with at least one R₁₀ₐ, *—C(Q₃₂₁)(Q₃₂₂)-*′, *—Si(Q₃₂₁)(Q₃₂₂)-*′, *—B(Q₃₂₁)-*′, or *—N(Q₃₂₁)-*′,
n324 to n326 may each independently be an integer from 1 to 5,
R₃₂₁ to R₃₂₆ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Bi(Q₃₂₃)(Q₃₂₄)(Q₃₂₅), —N(Q₃₂₃)(Q₃₂₄), —B(Q₃₂₃)(Q₃₂₄), —C(═O)(Q₃₂₃), —B(═O)₂(Q₃₂₃), or —P(═O)(Q₃₂₃)(Q₃₂₄),
two or more neighboring groups of Q₃₂₁ to Q₃₂₅ and R₃₂₁ to R₃₂₆ may optionally be bonded together to form a C₅-C₃₀ carbocyclic group that is unsubstituted or substituted with at least one R₁₀ₐ or a C₂-C₃₀ heterocyclic group that is unsubstituted or substituted with at least one R₁₀ₐ,
and *′ may each indicate a binding site to a neighboring atom,
R₁₀ₐ may be the same as described in the specification, and
Q₃₂₁ to Q₃₂₅ may each independently be the same as described in connection with Q₁.

In an embodiment, the second compound may be, but is not limited to, one of Compounds ETH1 to ETH86:

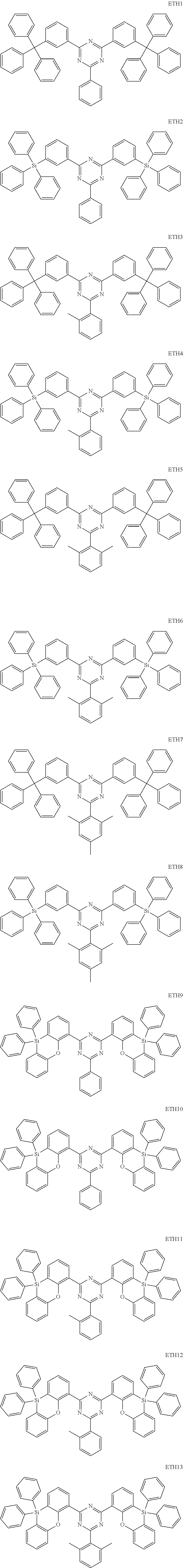

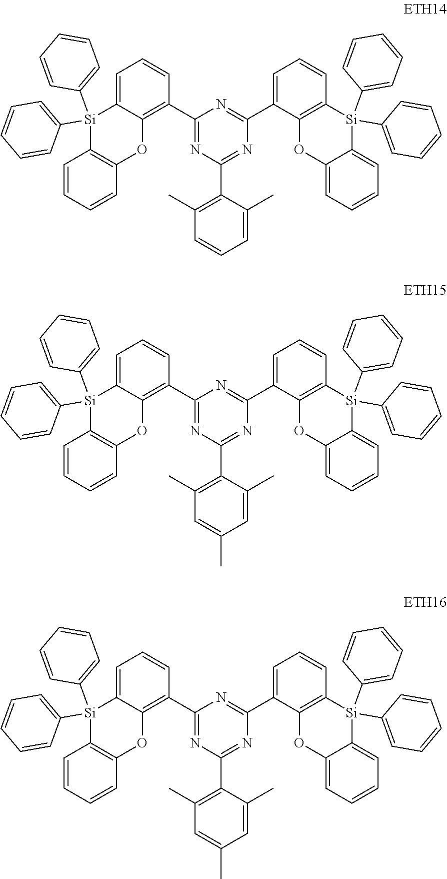 [SMILES: Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

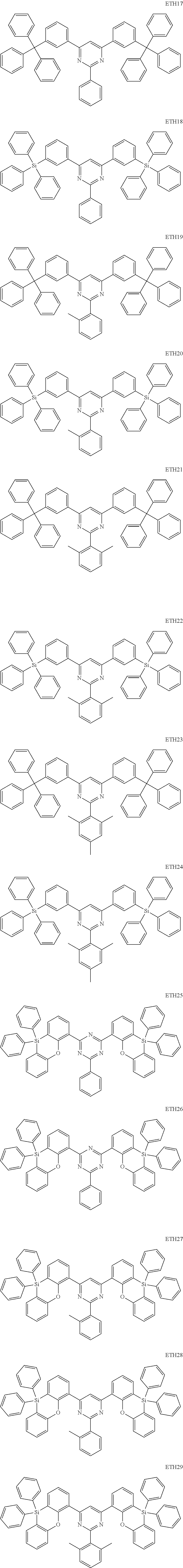

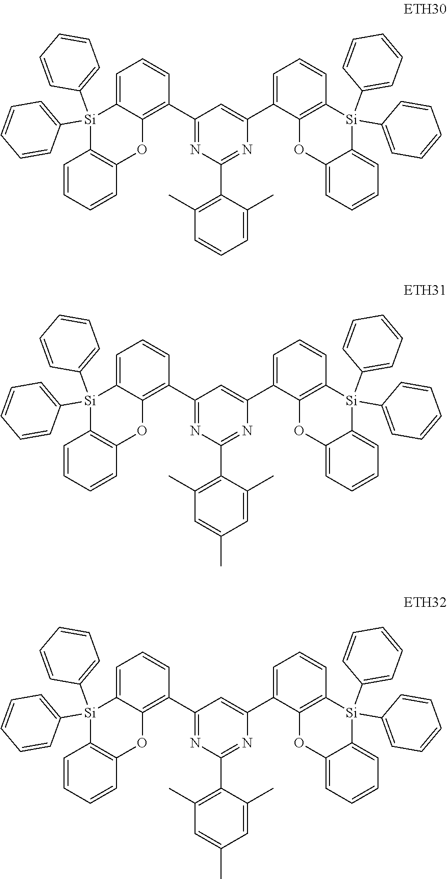 [SMILES: Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

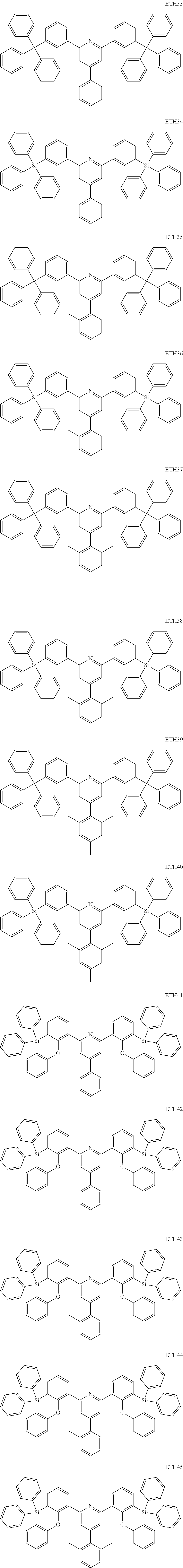

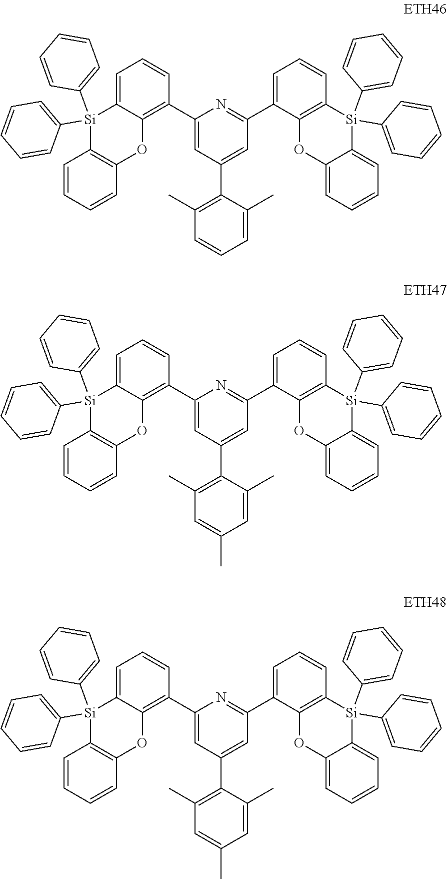 [SMILES: Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

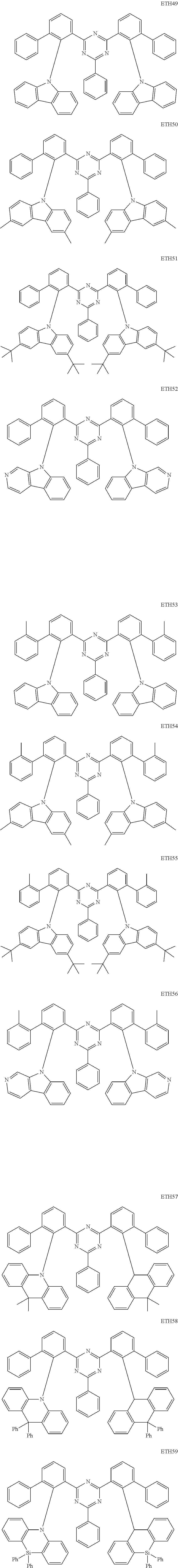

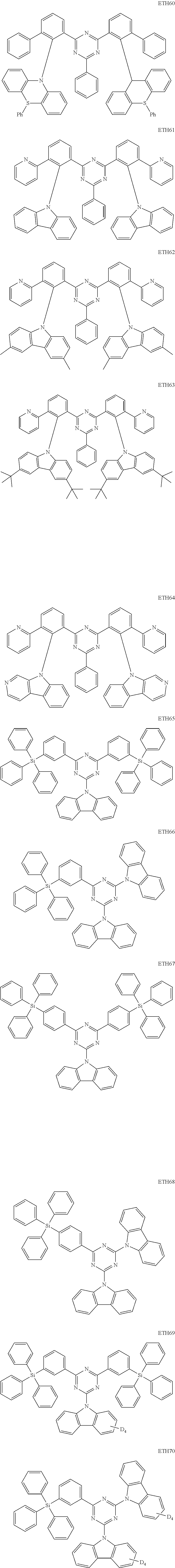

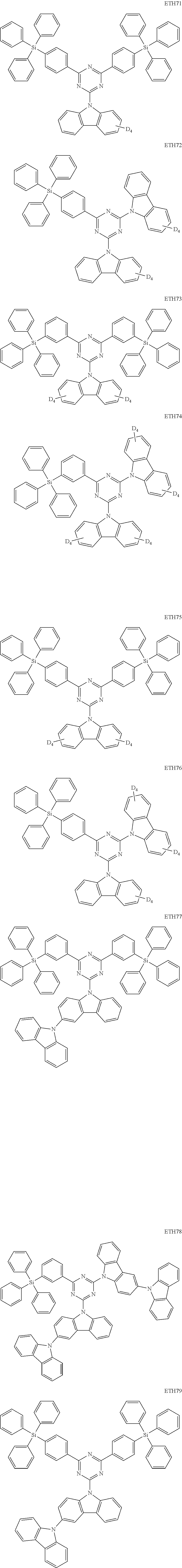

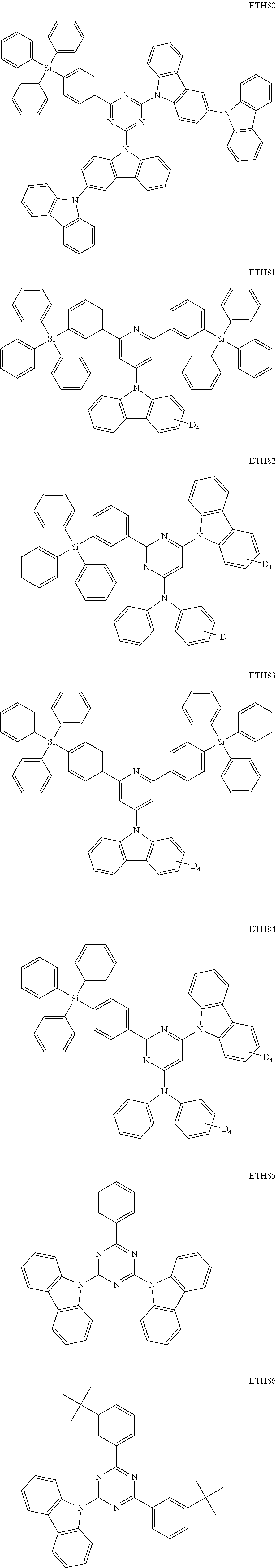

In an embodiment, the third compound may be represented by Formula 401A:

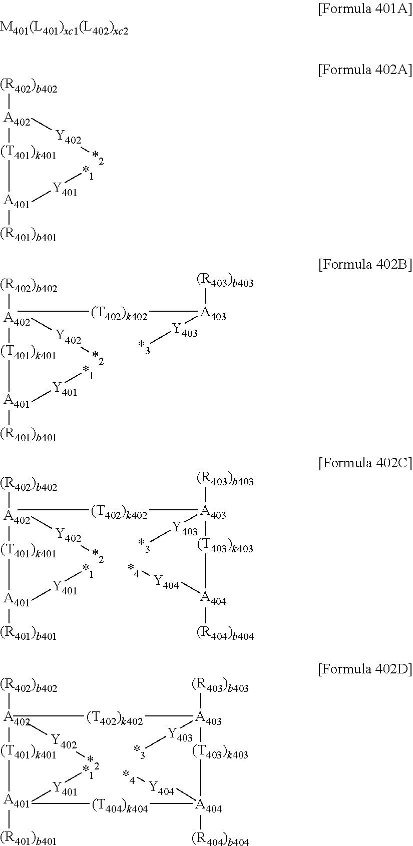

In Formulae 401A and 402A to 402D,
M₄₀₁ may be a first-row transition metal of the Periodic Table of Elements, a second-row transition metal of the Periodic Table of Elements, or a third-row transition metal of the Periodic Table of Elements,
L₄₀₁ may be a ligand represented by one of Formulae 402A to 402D,
L₄₀₂ may be a monodentate ligand, a bidentate ligand, or a tridentate ligand,
xc1 may be 1 or 2,
xc2 may be an integer from 0 to 4,
A₄₀₁ to A₄₀₄ may each independently be a C₅-C₃₀ carbocyclic group or a C₁-C₃₀ heterocyclic group,
T₄₀₁ to T₄₀₄ may each independently be a single bond, a double bond, *—O—*′, *—S—*′, *—C(═O)—*′, *—S(═O)—*′, *—C(R₄₀₆)(R₄₀₆)—*′, *—C(R₄₀₆)═C(R₄₀₆)—*′, *—C(R₄₀₆)═*′, *—Si(R₄₀₆)(R₄₀₆)—*′, *—B(R₄₀₆)—*′, *—N(R₄₀₆)—*′, or *—P(R₄₀₆)—*′,
k401 to k404 may each independently be 1, 2, or 3,
Y₄₀₁ to Y₄₀₄ may each independently be a single bond, *—O—*′, *—S—*′, *—C(R₄₀₇)(R₄₀₈)—*′, *—Si(R₄₀₇)(R₄₀₈)—*′, *—B(R₄₀₇)—*′, *—N(R₄₀₇)—*′, or *—P(R₄₀₇)—*′,
*1, *2, *3, and *4 may each indicate a binding site to M₄₀₁,
R₄₀₁ to R₄₀₈ may each independently be hydrogen, deuterium, —F, —Cl, —Br, —I, a hydroxyl group, a cyano group, a nitro group, a C₁-C₂₀ alkyl group at least one R₁₀ₐ, a C₂-C₆₀ alkenyl group at least one R₁₀ₐ, a C₂-C₆₀ alkynyl group at least one R₁₀ₐ, a C₁-C₆₀ alkoxy group at least one R₁₀ₐ, a C₃-C₆₀ carbocyclic group at least one R₁₀ₐ, a C₁-C₆₀ heterocyclic group at least one R₁₀ₐ, a C₆-C₆₀ aryloxy group at least one R₁₀ₐ, a C₆-C₆₀ arylthio group at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₄₀₁ to R₄₀₈ may optionally be bonded together to form a C₅-C₆₀ carbocyclic group at least one R₁₀ₐ or a C₁-C₆₀ heterocyclic group at least one R₁₀ₐ,
b401 to b404 may each independently be an integer from 0 to 10,
and *′ may each indicate a binding site to a neighboring atom, and
Q₁ to Q₃ and R₁₀ₐ may each be the same as described in the specification.

In an embodiment, the third compound may be, but is not limited to, one of Compounds PD40 or PD41:

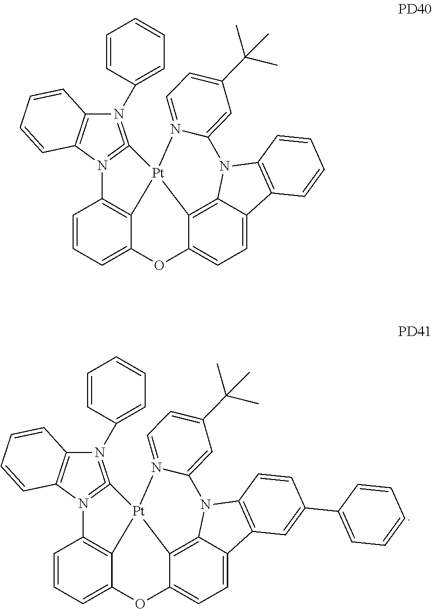

In an embodiment, R₃₀₁ to R₃₀₃, R₃₀₄ₐ to R₃₀₆ₐ, R_{304b} to R_{306b}, and R₃₁₁ to R₃₁₄ in Formulae 301-1A to 301-2A, R₃₂₁ to R₃₂₆ in Formula 302, and R₄₀₁ to R₄₀₈ in Formulae 401A and 402A to 402D may each independently be:

hydrogen, deuterium, —F, —Cl, —Br, —I, a hydroxyl group, a cyano group, a nitro group, an amidino group, a hydrazine group, a hydrazone group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbomenyl group, a cyclopentenyl group, a cyclohexenyl group, a cycloheptenyl group, a phenyl group, a biphenyl group, a C₁-C₁₀ alkylphenyl group, a naphthyl group, a tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a thiadiazolyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a thiadiazolyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, —Si(Q₃₁)(Q₃₂)(Q₃₃), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be the same as described in the specification.

In an embodiment, R₃₀₁ to R₃₀₃, R₃₀₄ₐ to R₃₀₆ₐ, R_{304b} to R_{306b}, and R₃₁₁ to R₃₁₄ in Formulae 301-1A to 301-2A, R₃₂₁ to R₃₂₆ in Formula 302, and R₄₀₁ to R₄₀₈ in Formulae 401A and 402A to 402D may each independently be:
hydrogen, deuterium, —F, —Cl, —Br, —I, —CD₃, —CD₂H, —CDH₂, —CF₃, —CF₂H, —CFH₂, a cyano group, a nitro group, a C₁-C₆₀ alkyl group, a C₂-C₆₀ alkenyl group, a C₂-C₆₀ alkynyl group, or a C₁-C₆₀ alkoxy group;
a group represented by one of Formulae 9-1 to 9-61 or a group represented by one of Formulae 10-1 to 10-348; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂):

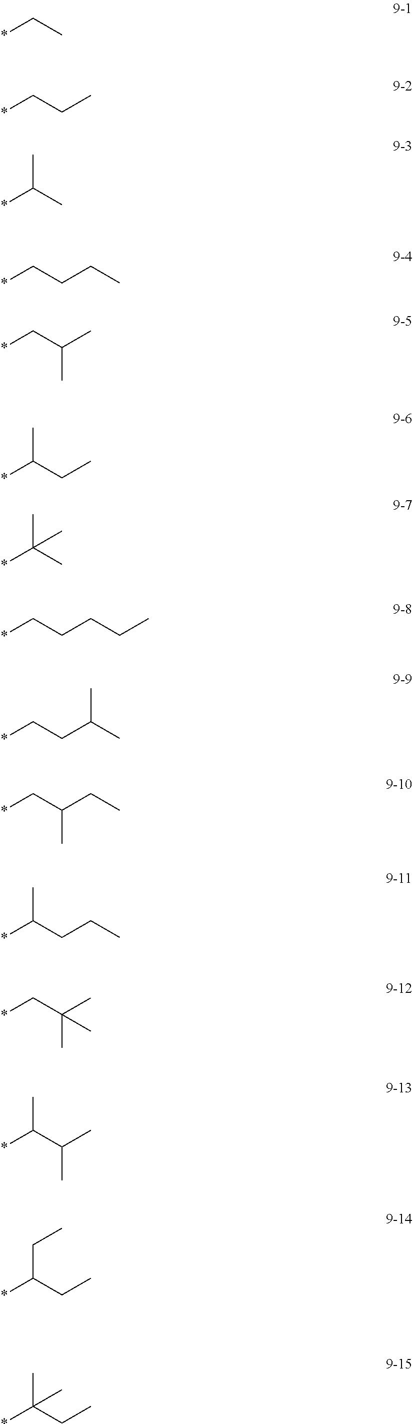

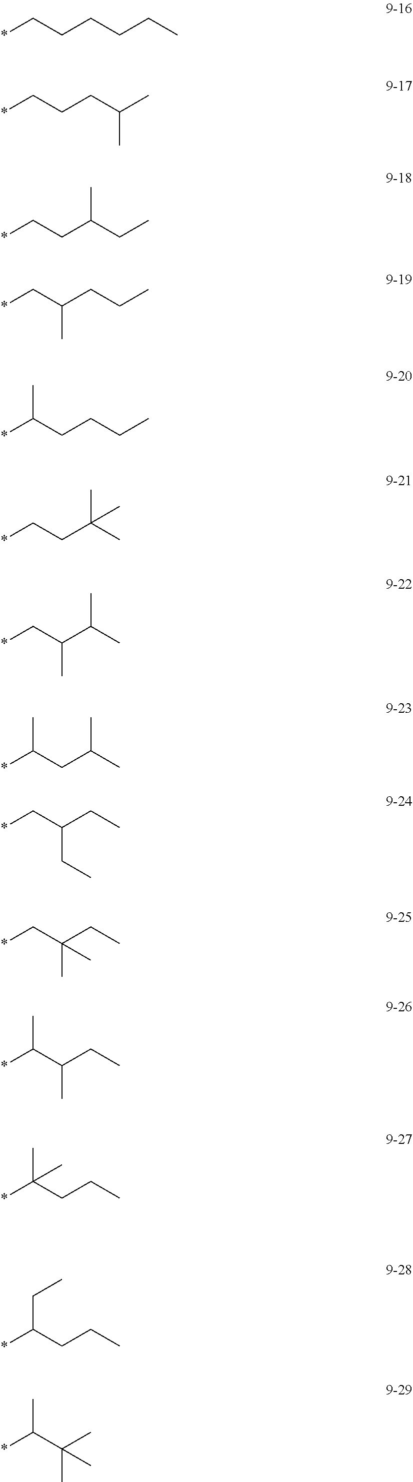

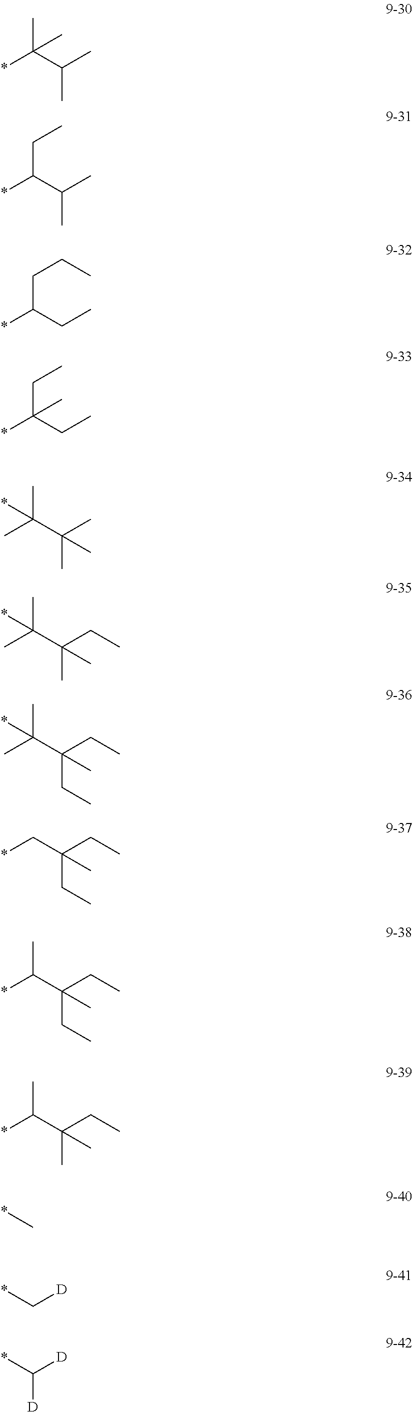

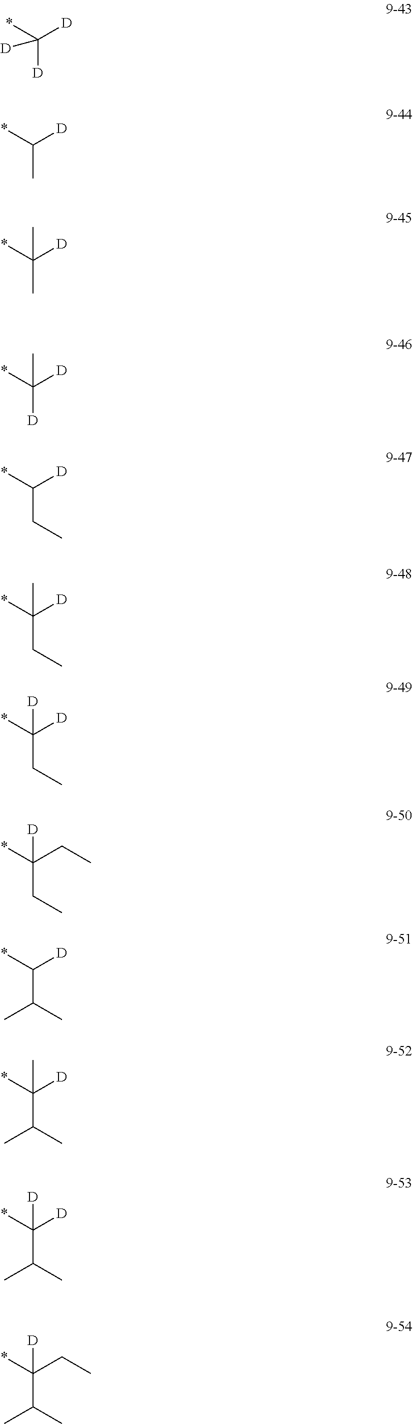

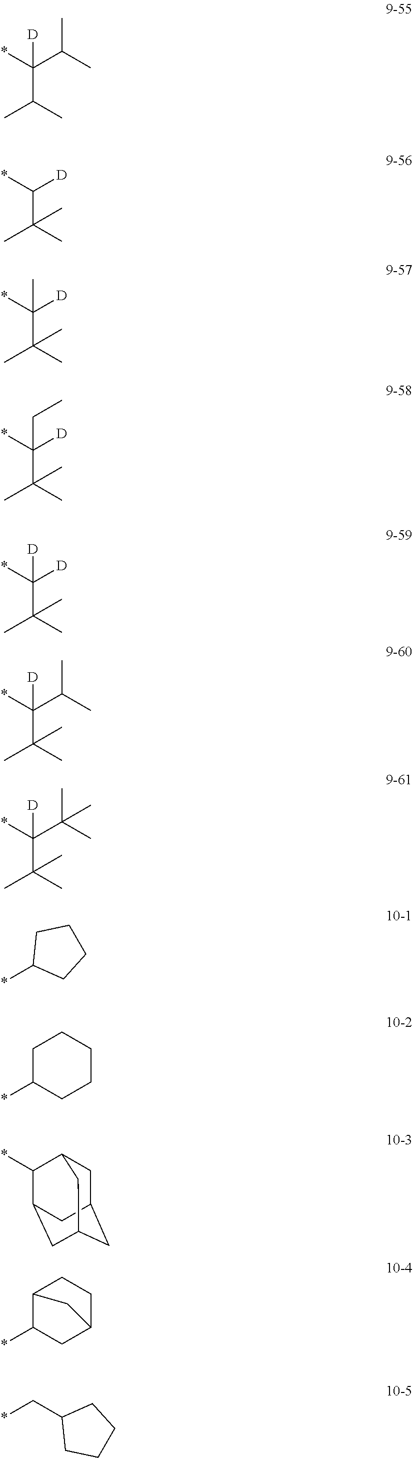

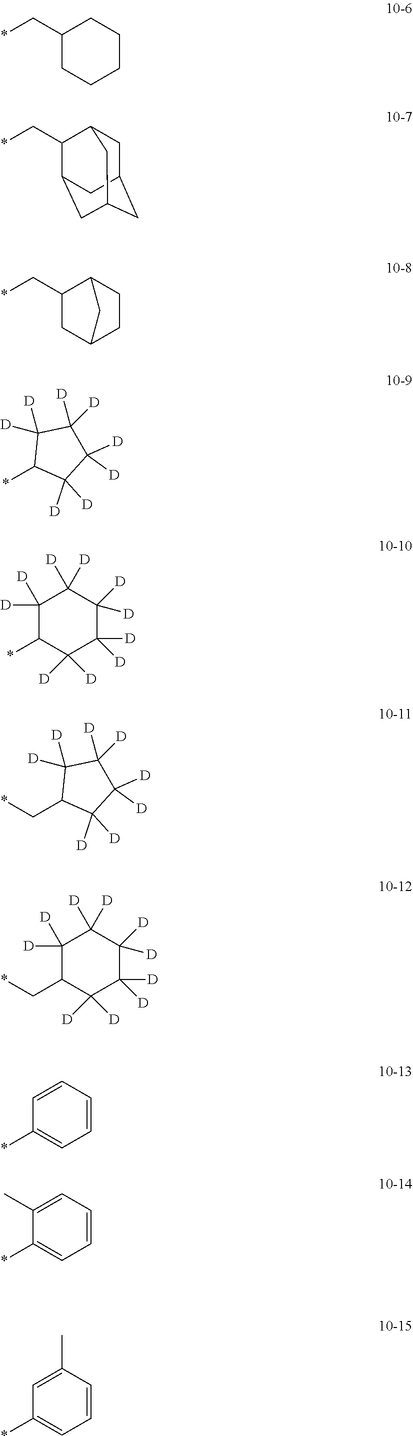

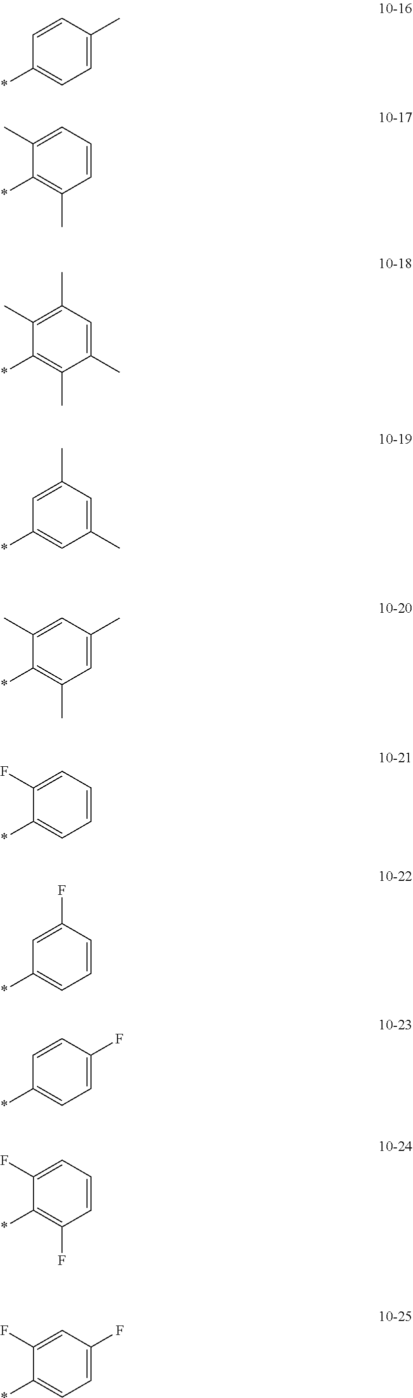

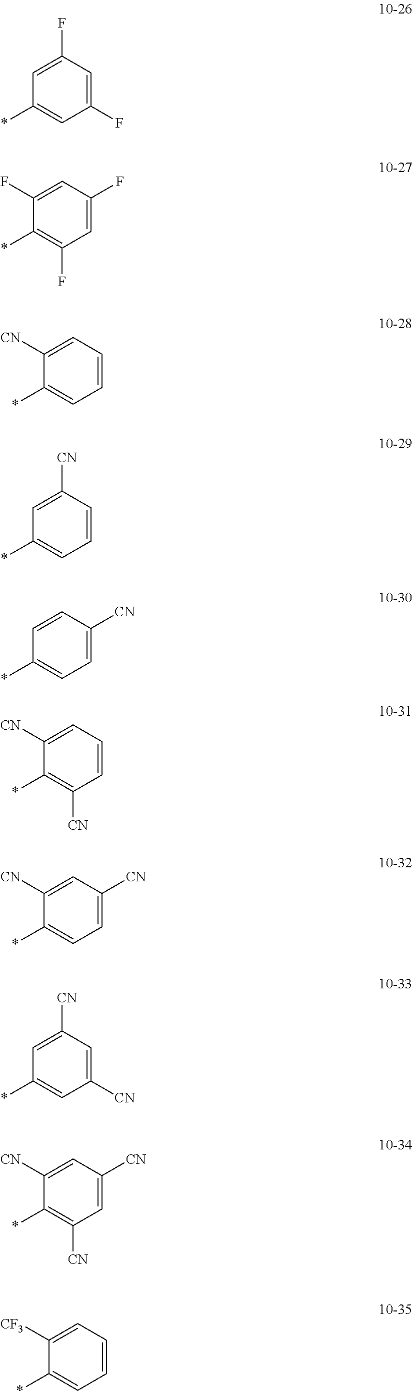

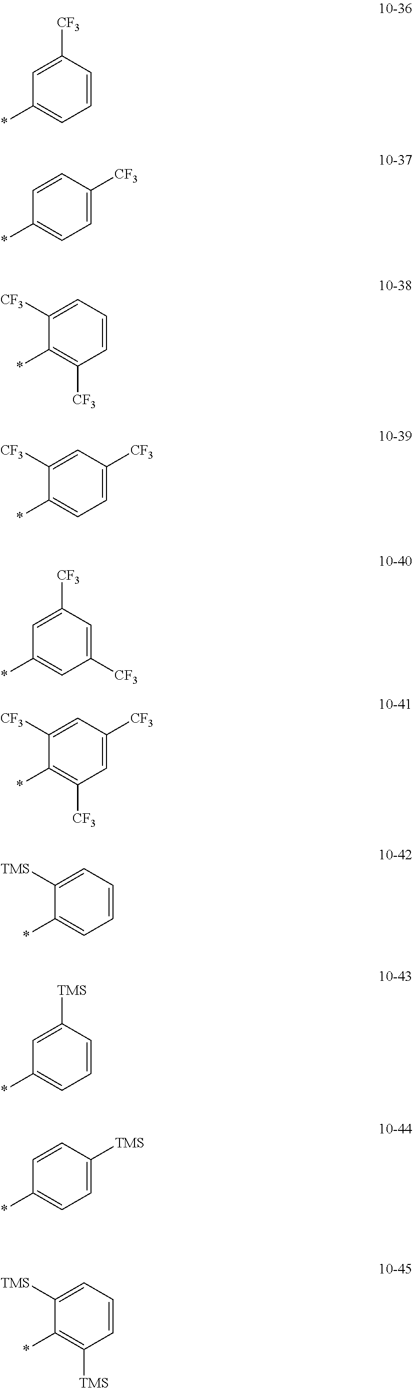

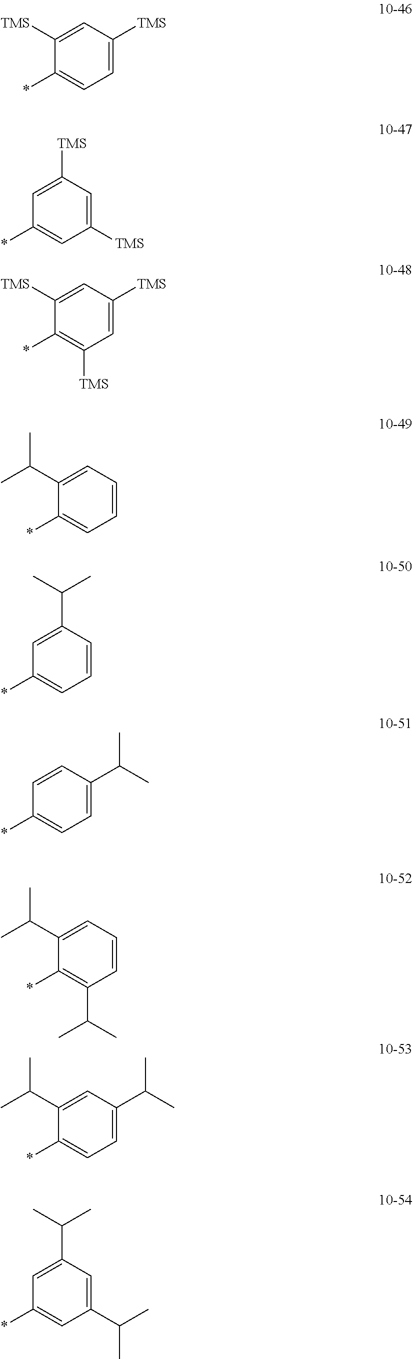

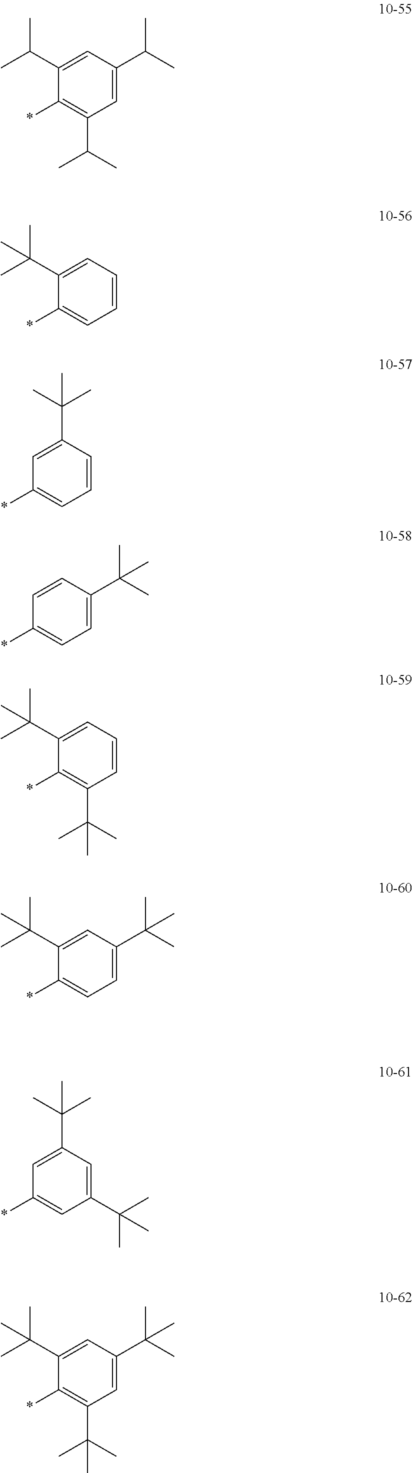

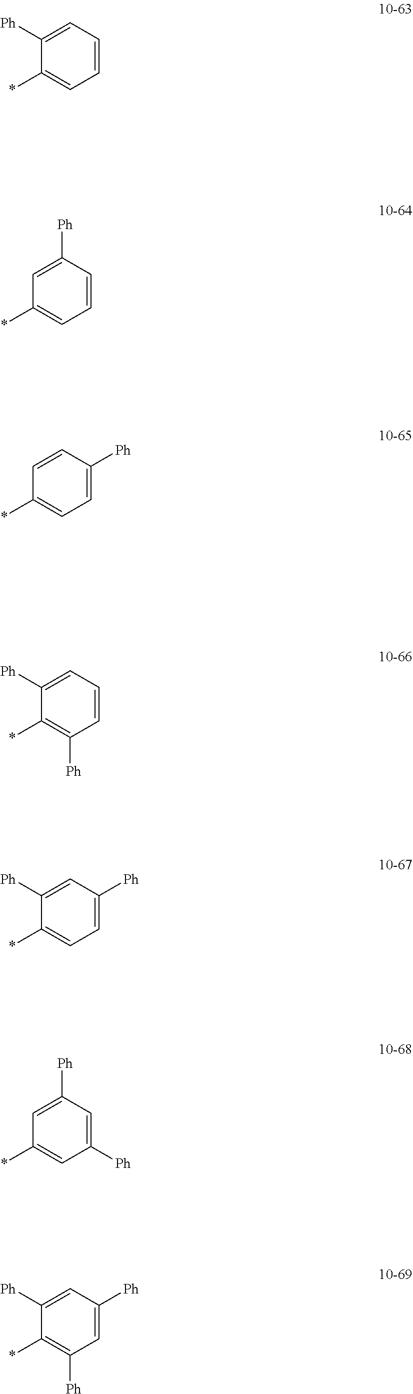

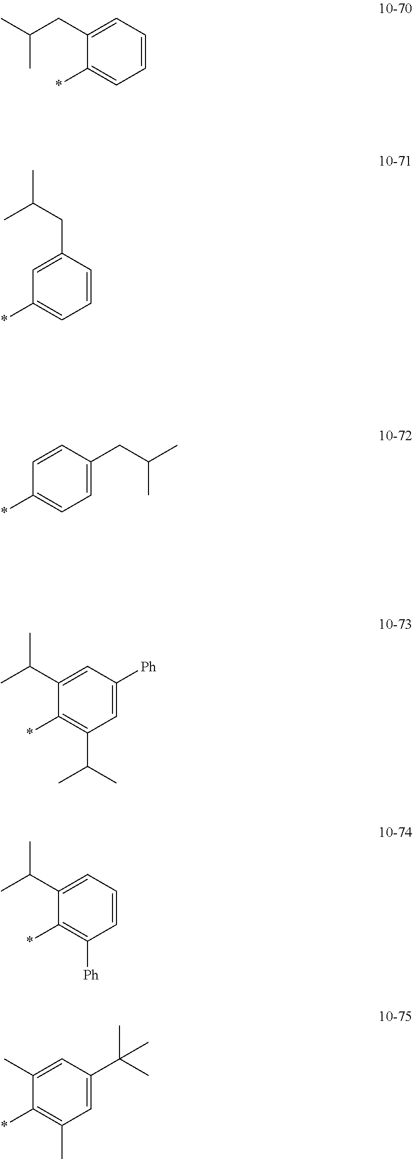

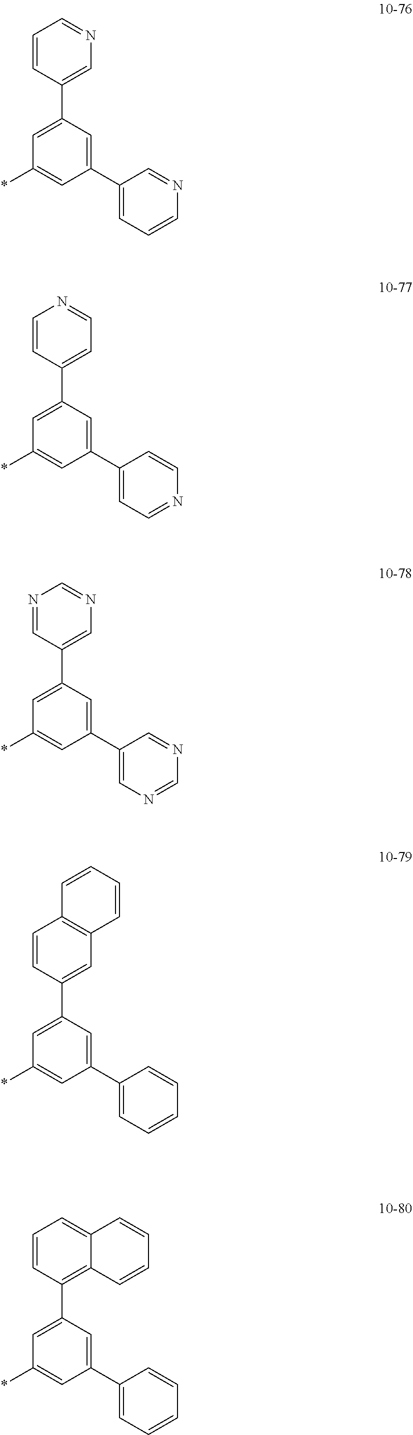 [SMILES: *c1cc(-c2cccnc2)cc(-c2cccnc2)c1 ; *c1cc(-c2ccncc2)cc(-c2ccncc2)c1 ; *c1cc(-c2cncnc2)cc(-c2cncnc2)c1 ; *c1cc(-c2ccccc2)cc(-c2ccc3ccccc3c2)c1 ; *c1cc(-c2ccccc2)cc(-c2cccc3ccccc23)c1]

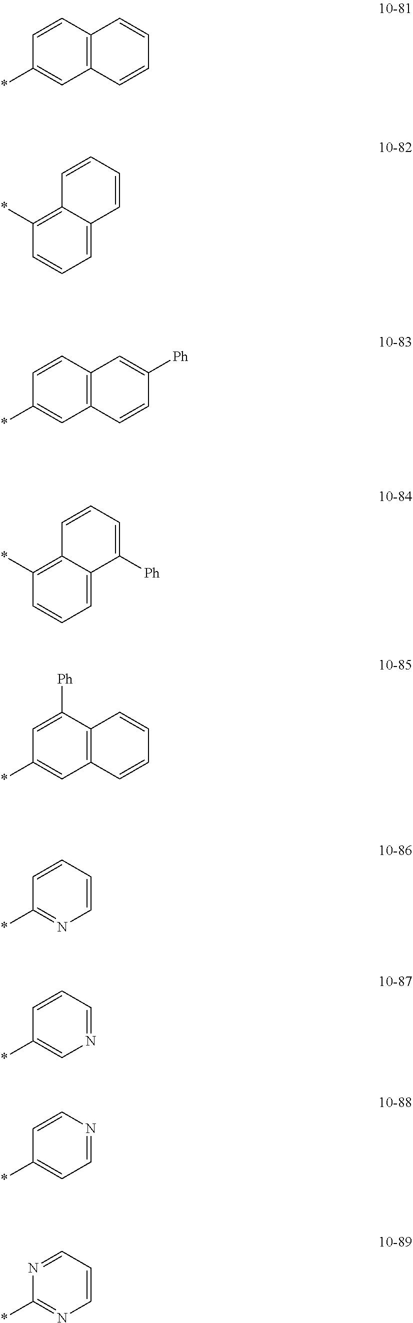

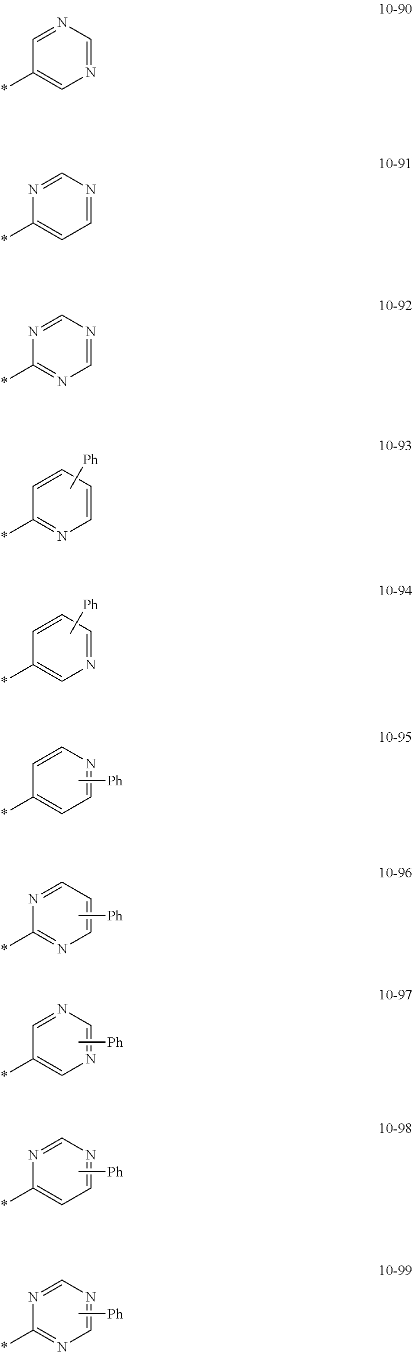

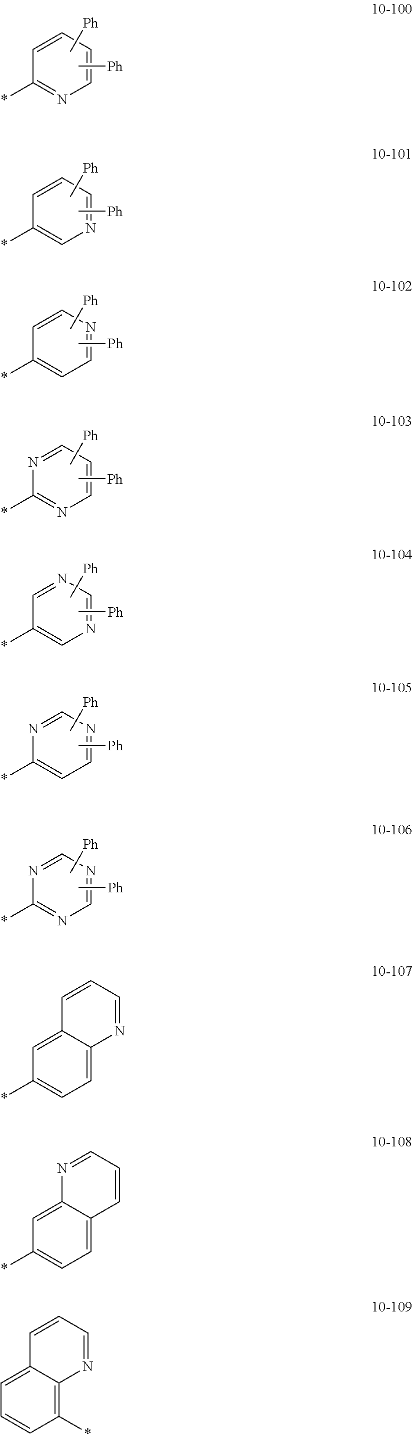

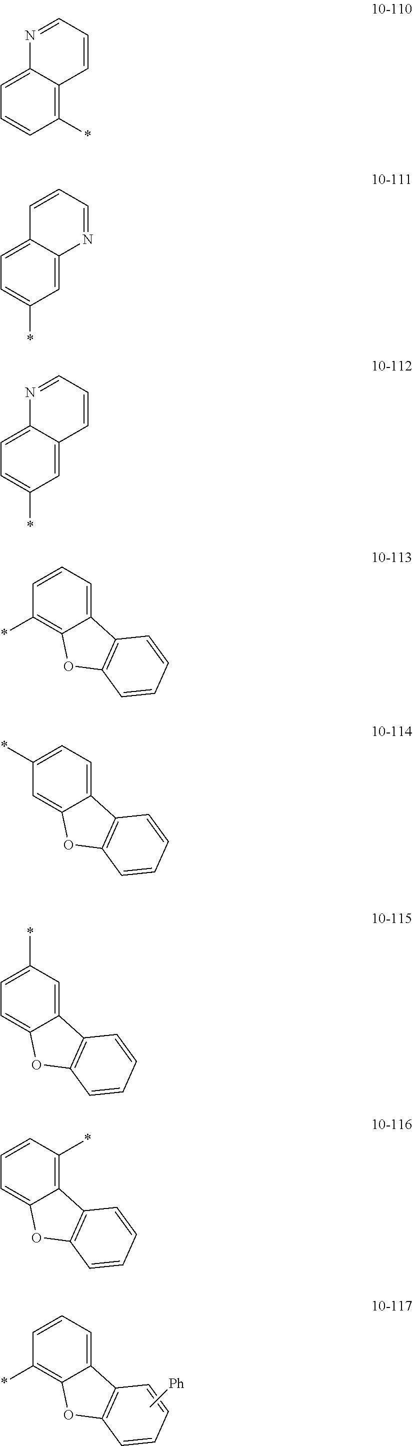

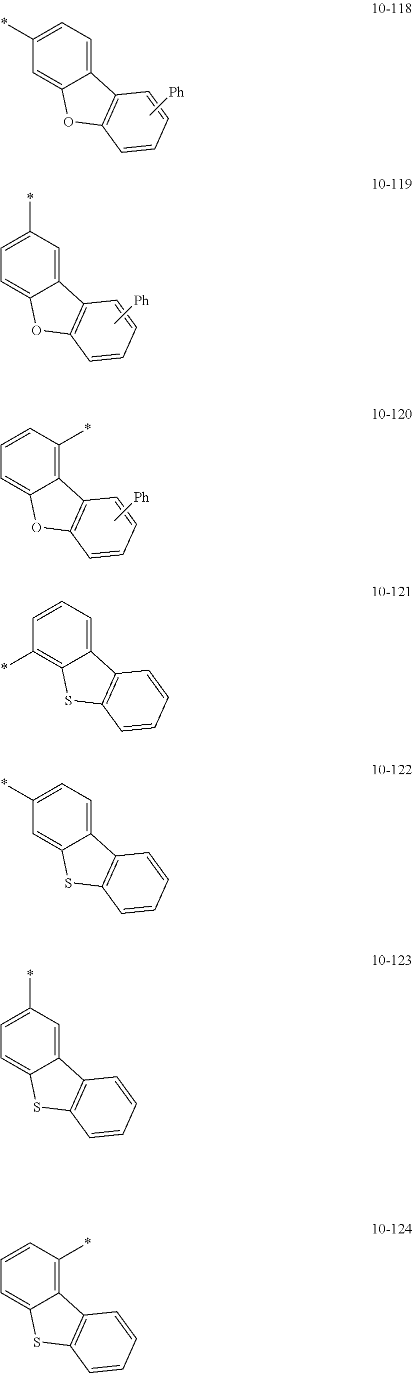

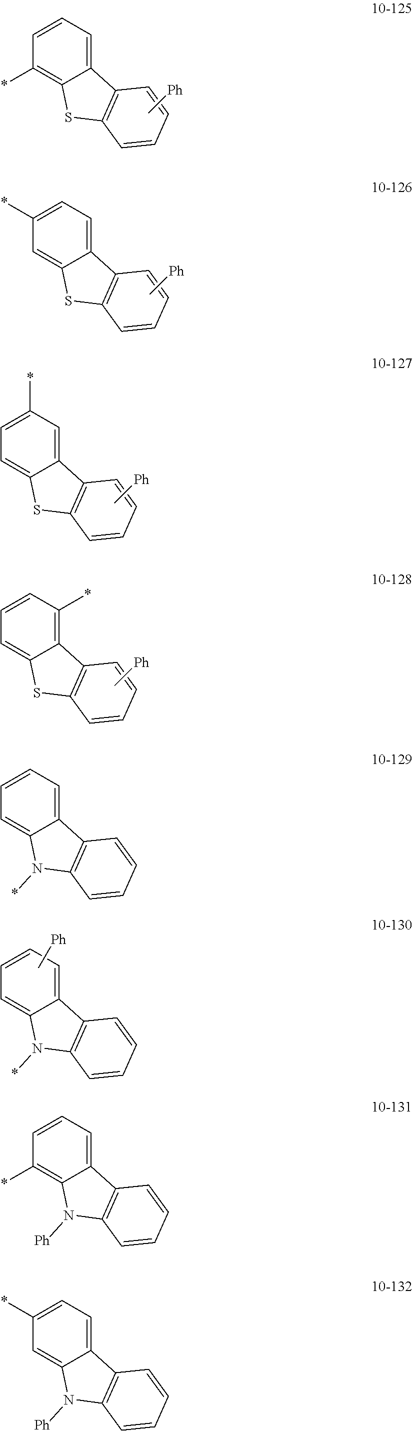

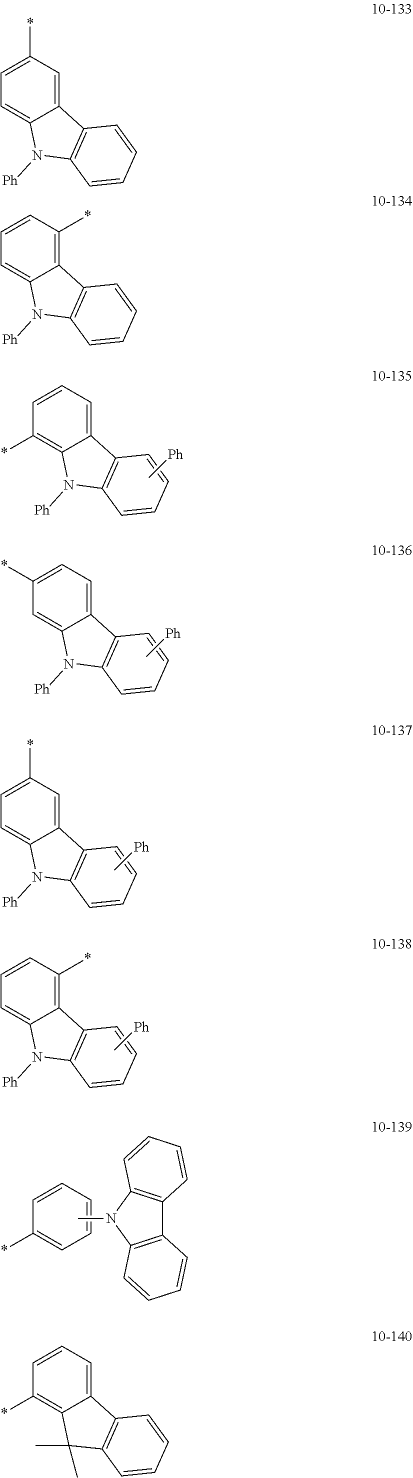

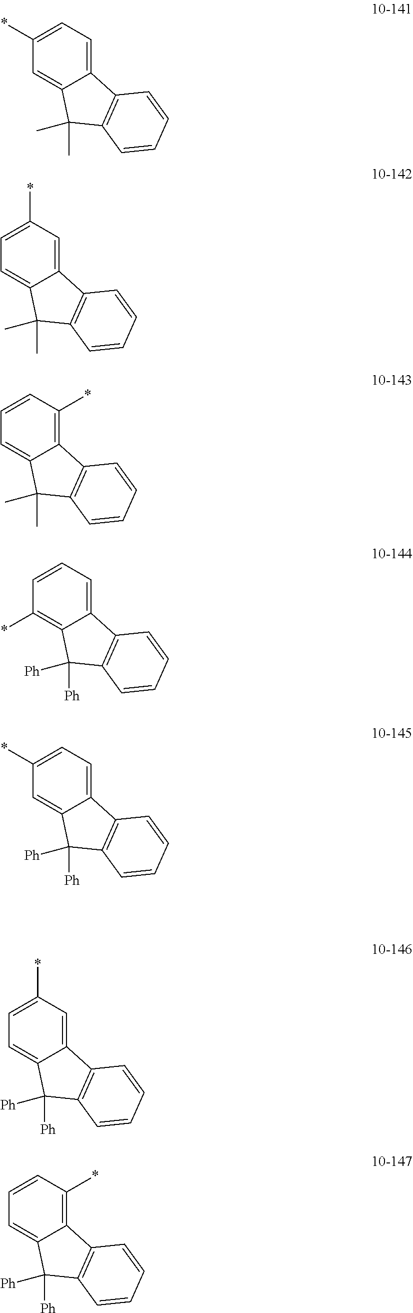

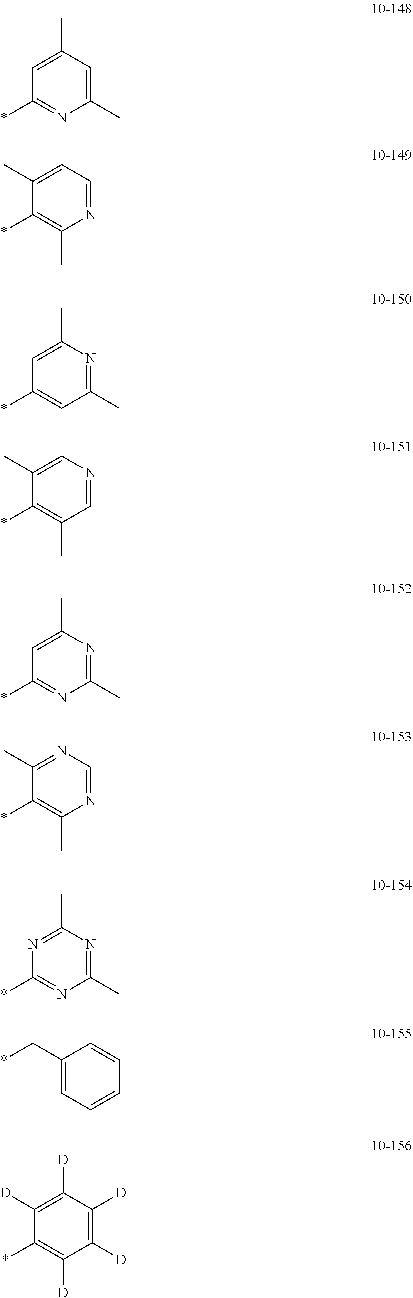

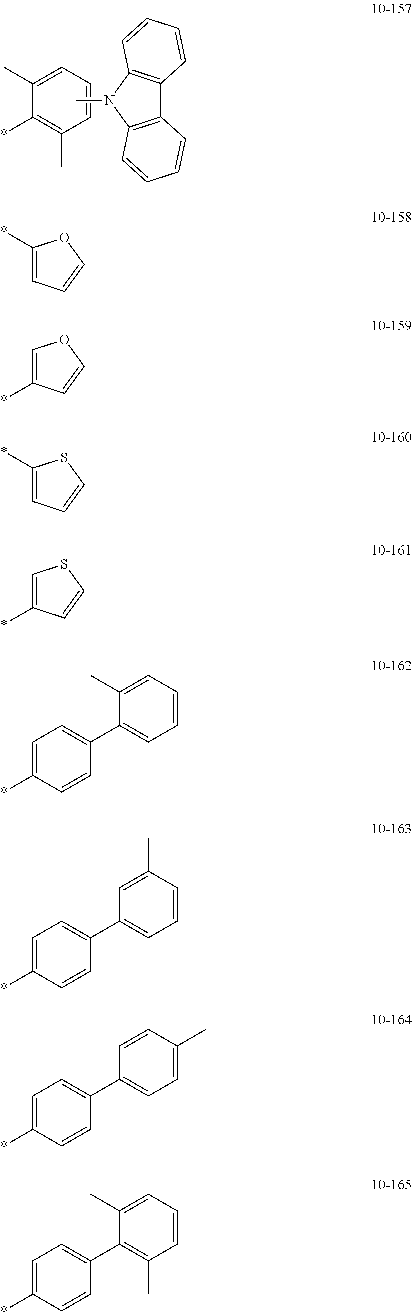

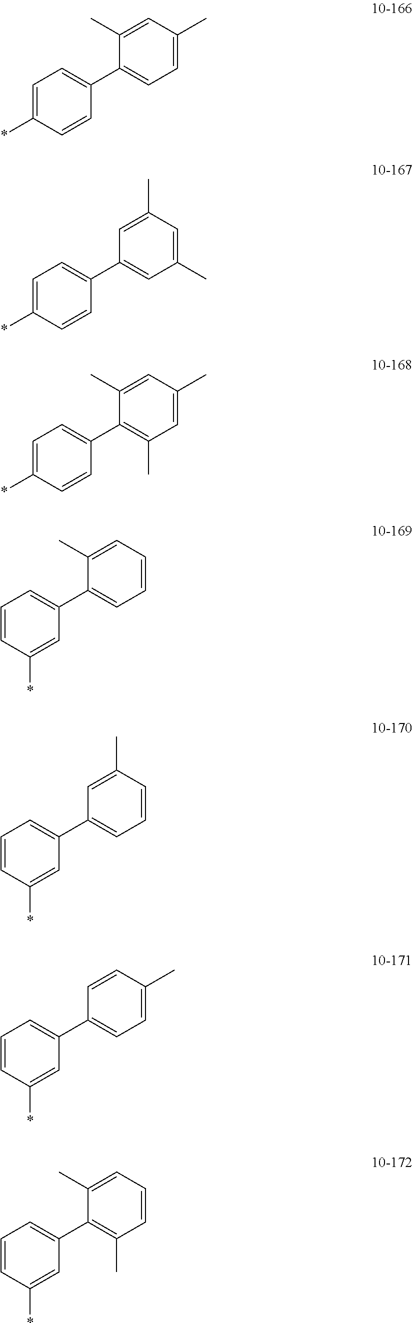

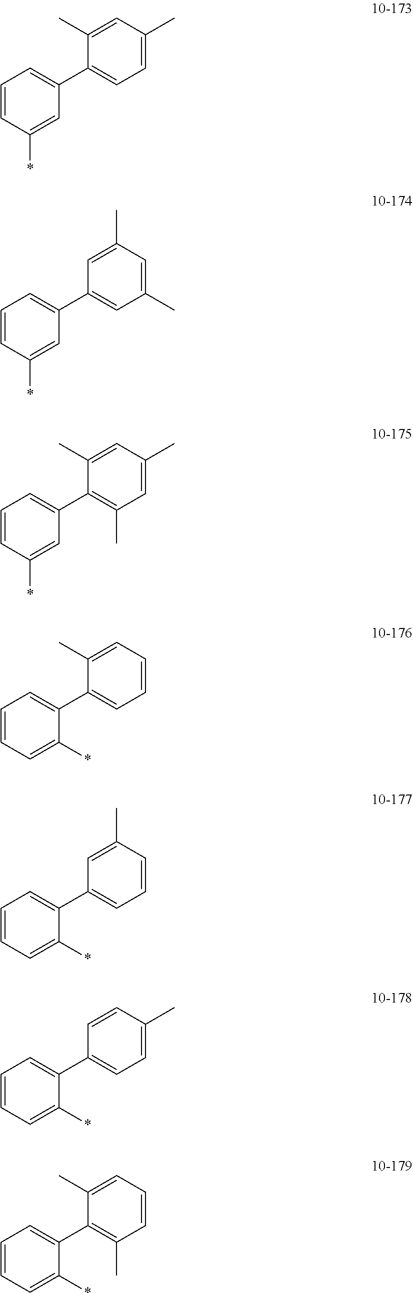

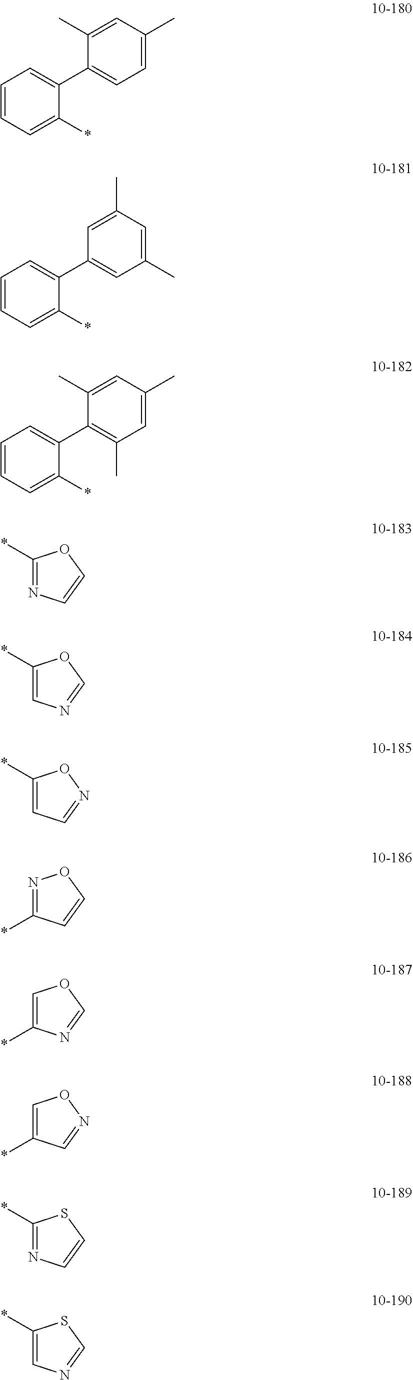

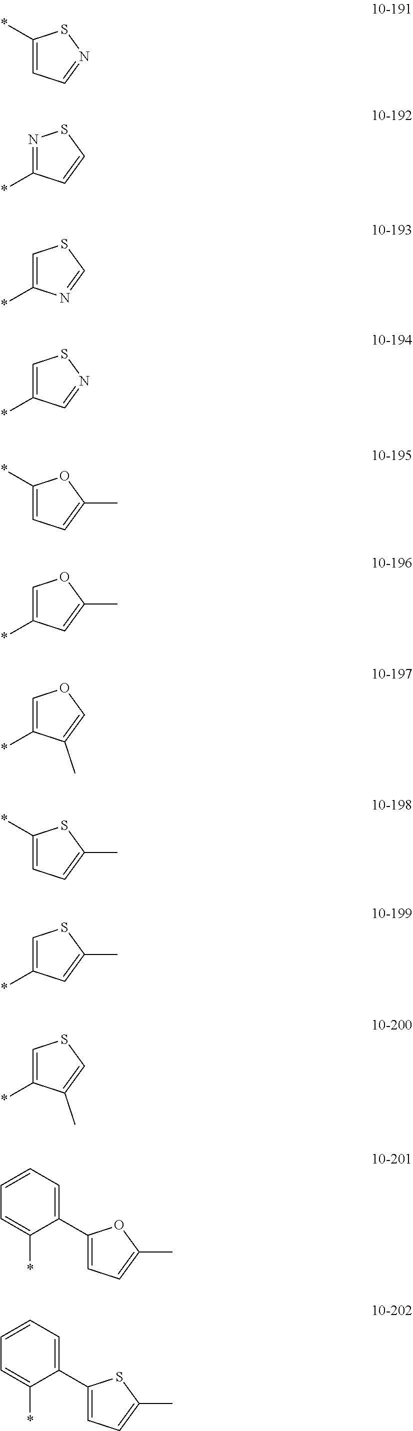

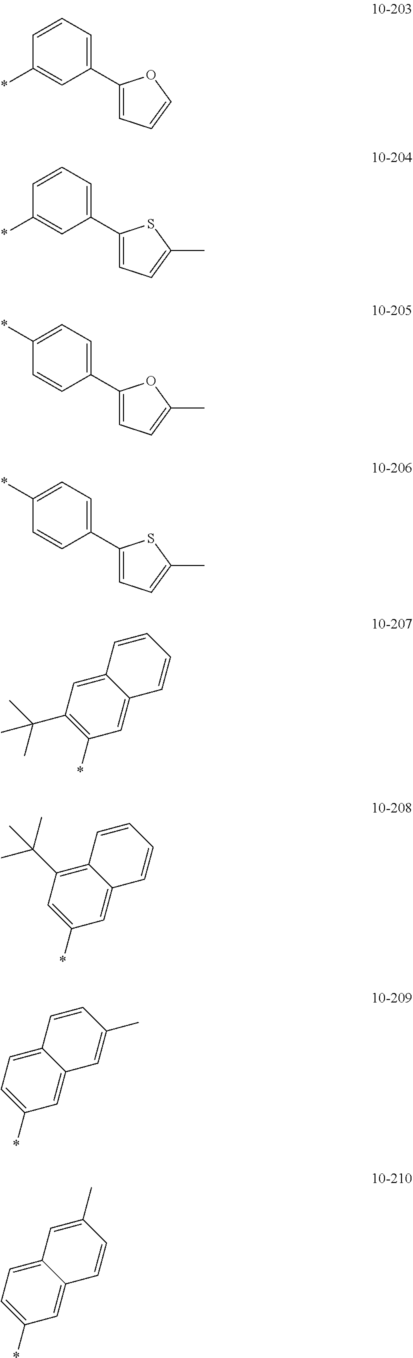

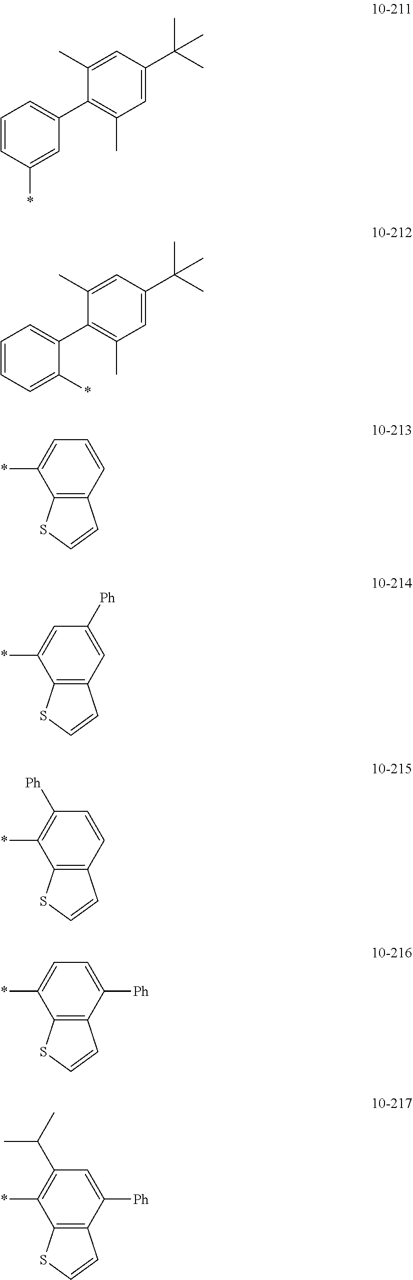

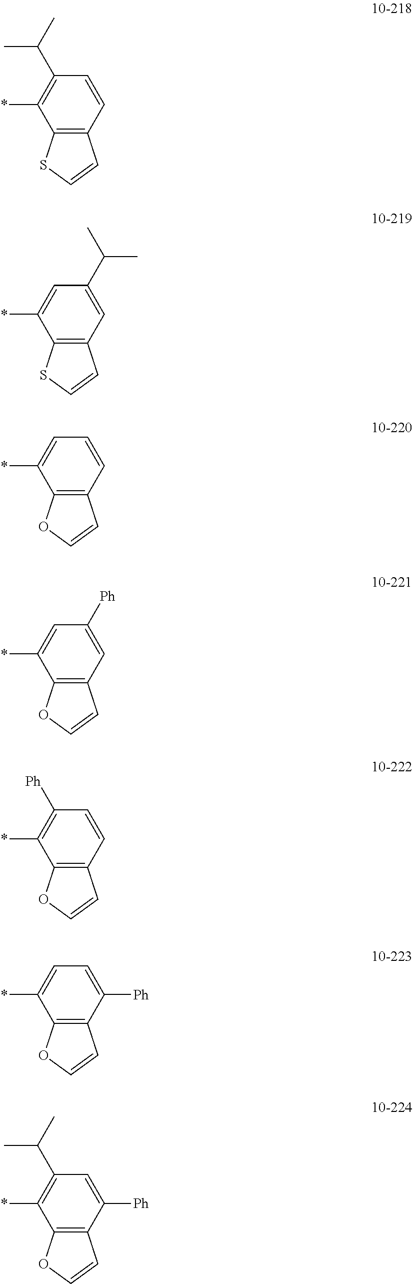

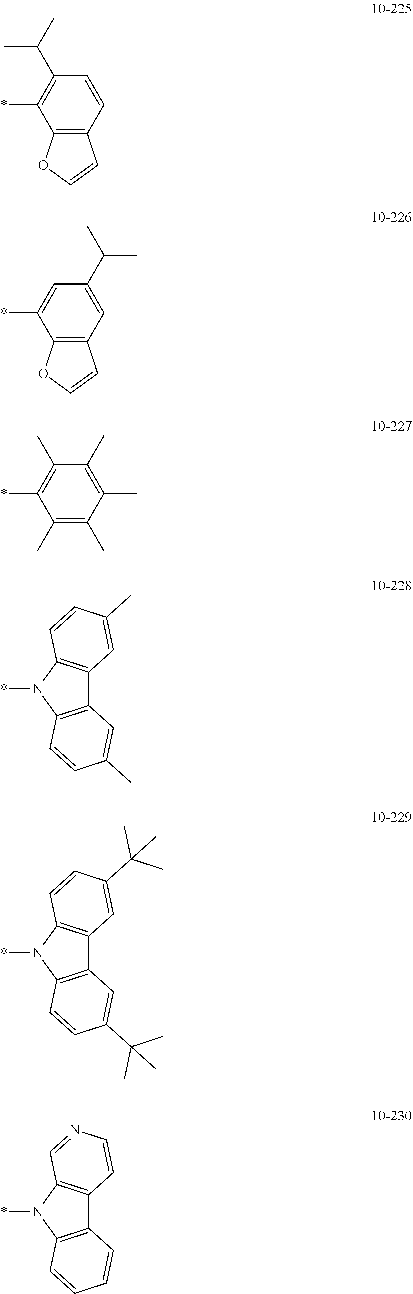

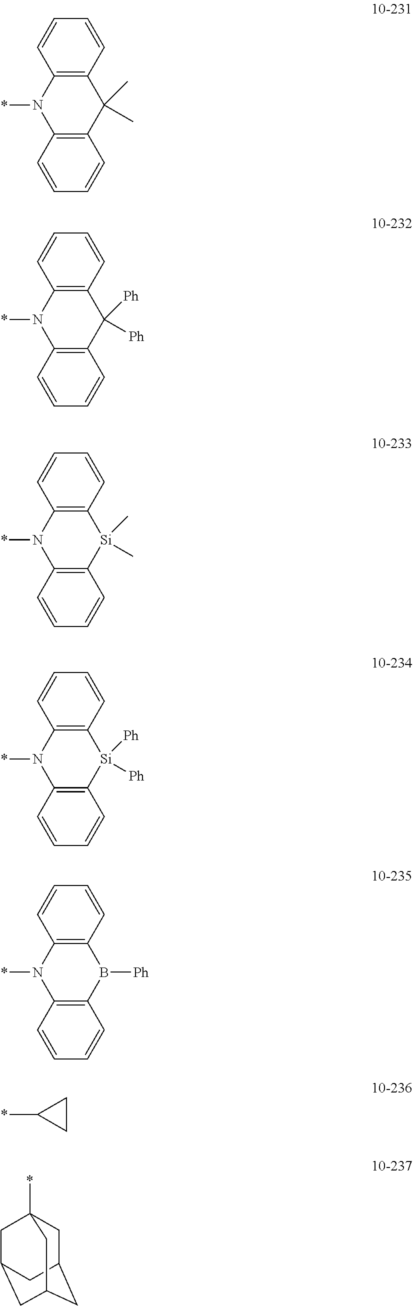

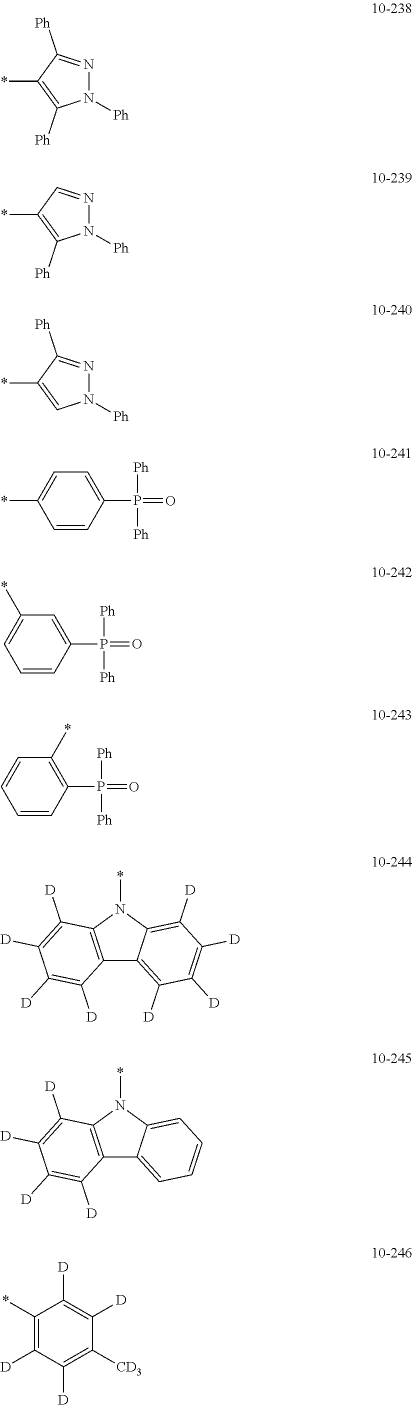

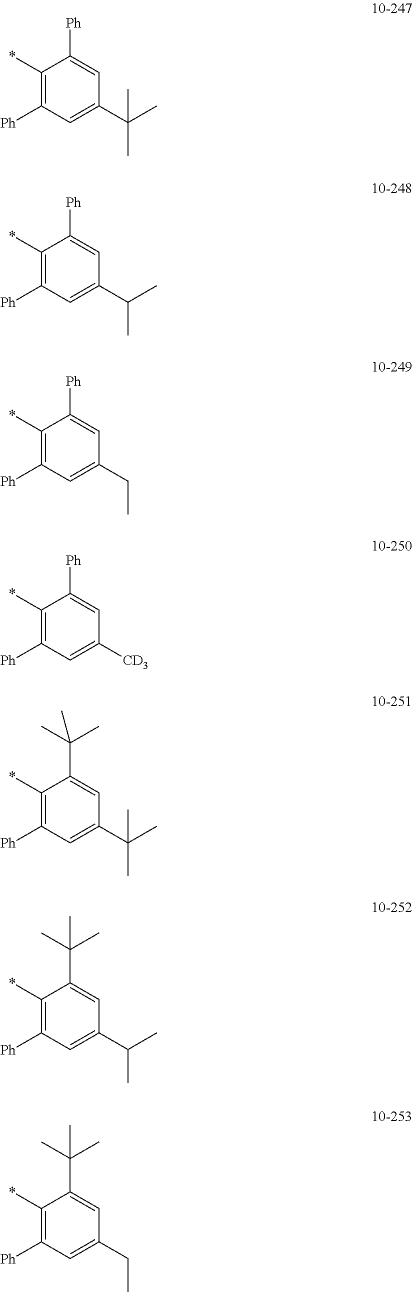

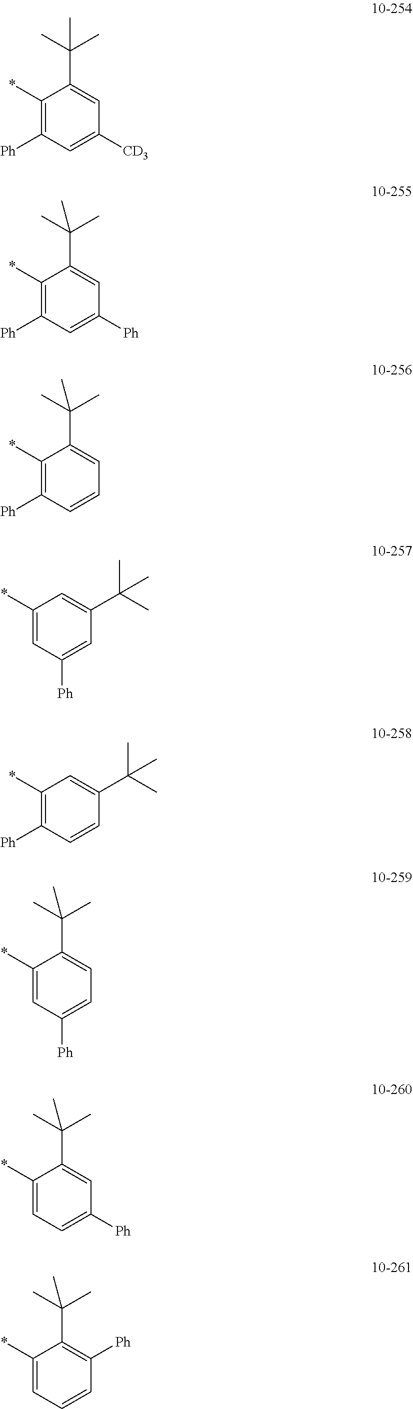

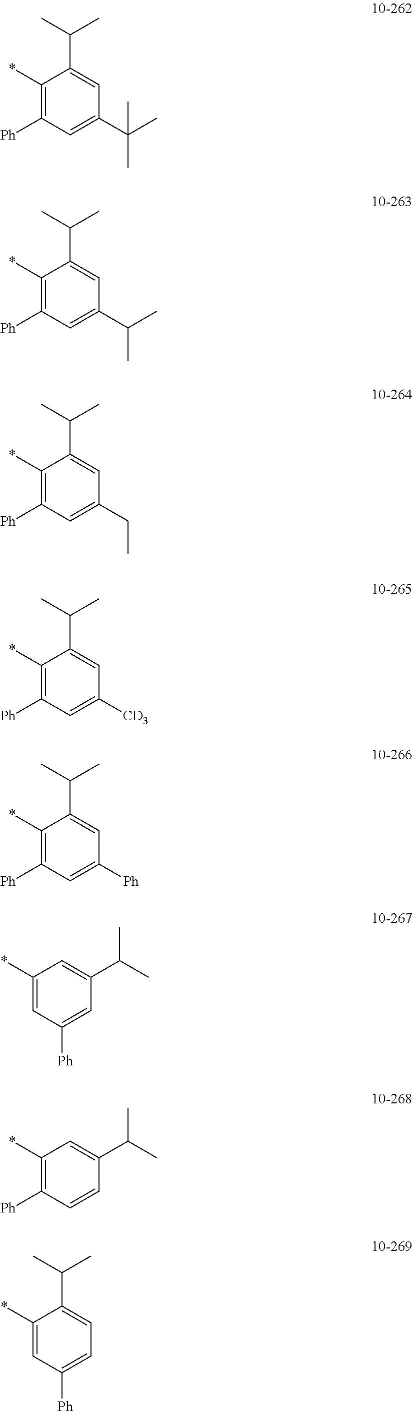

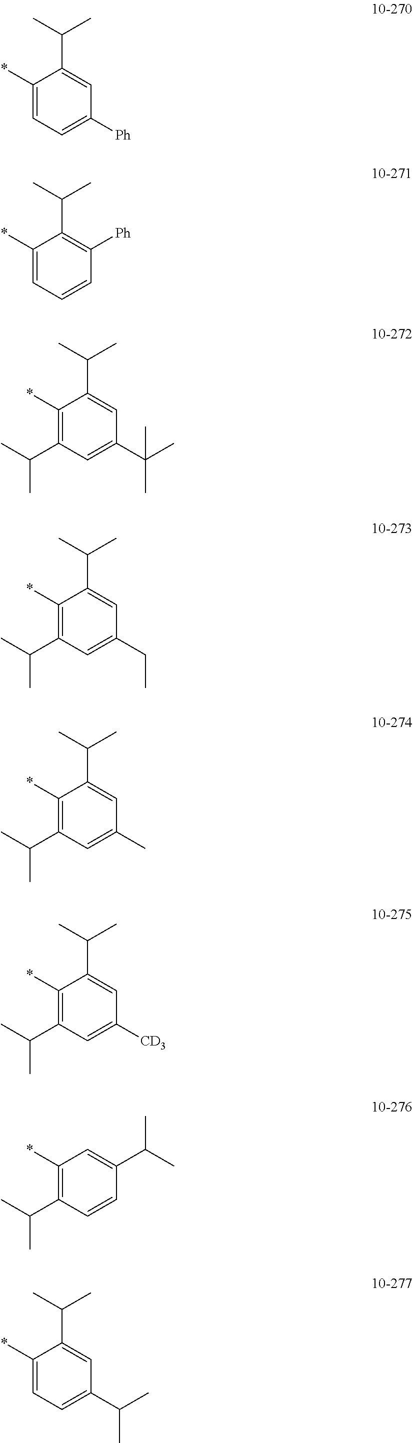

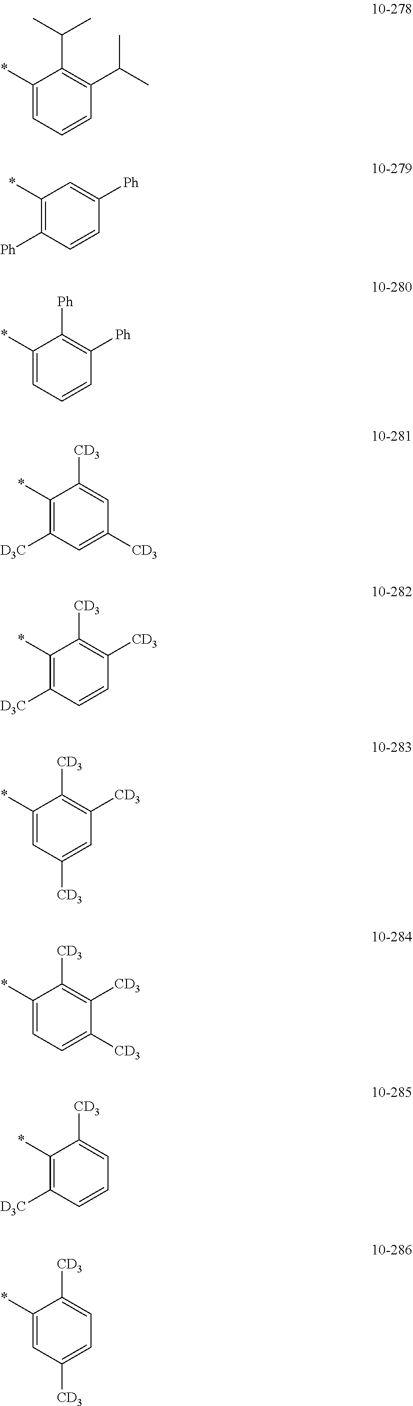

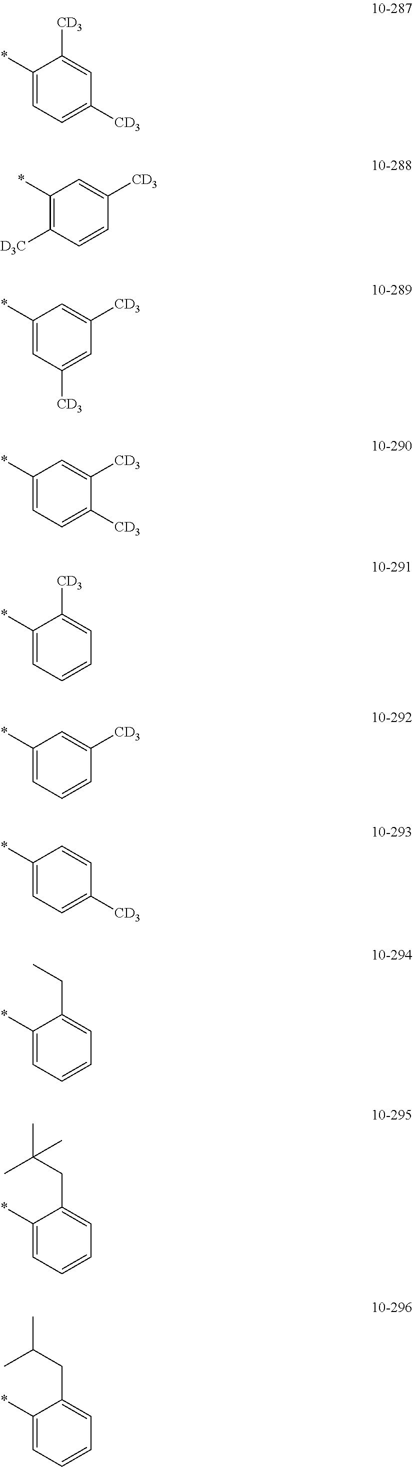

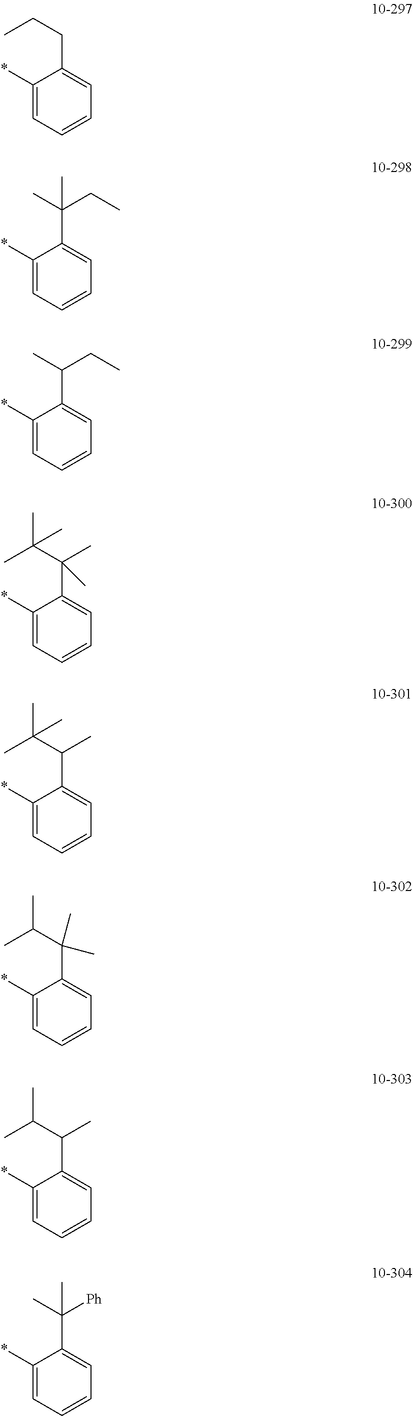

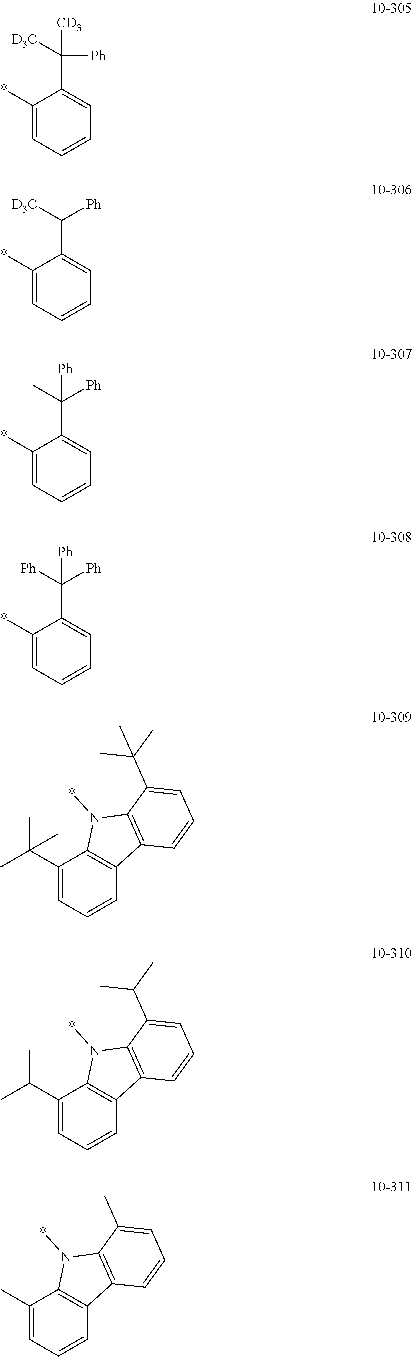

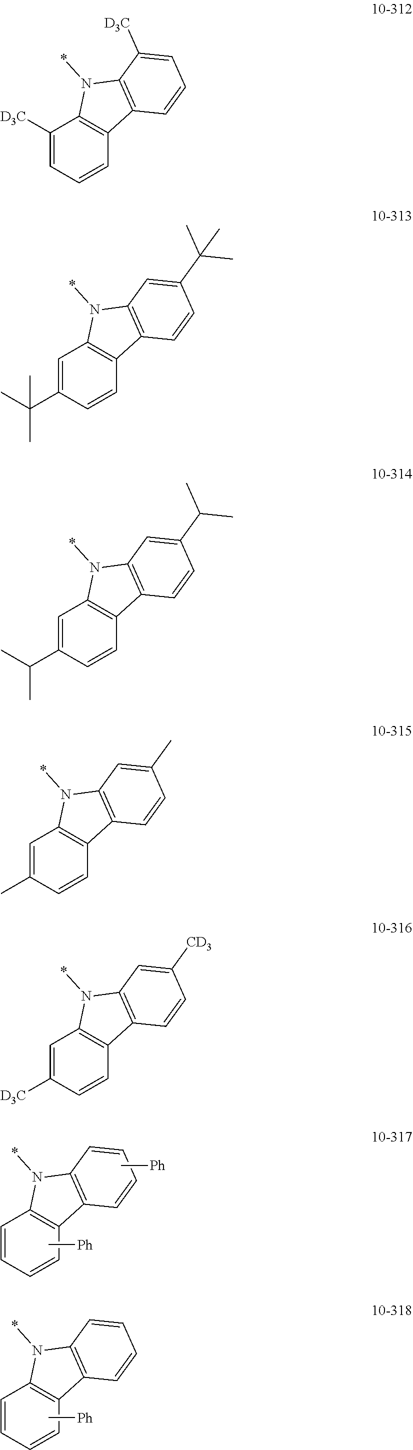

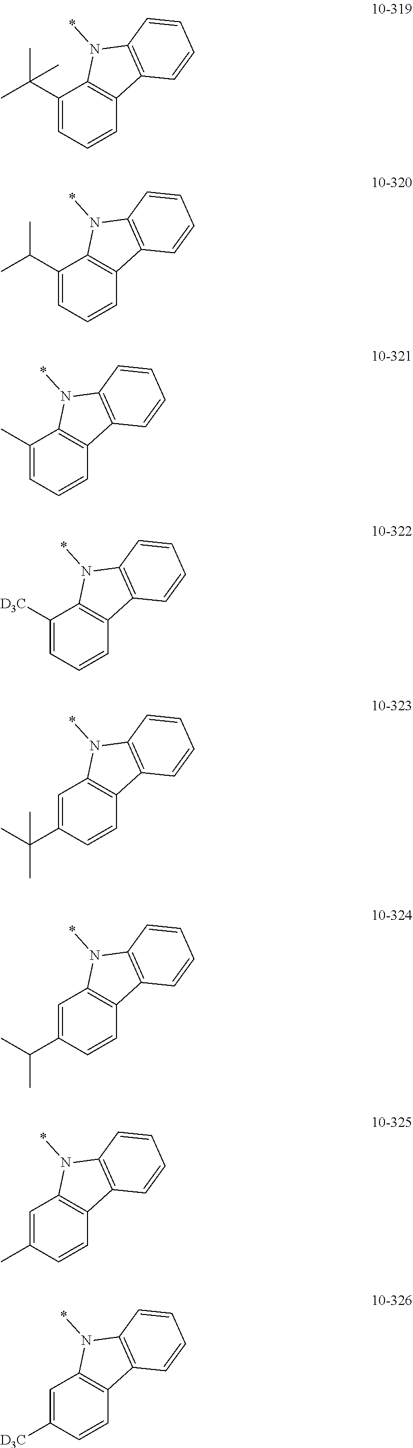

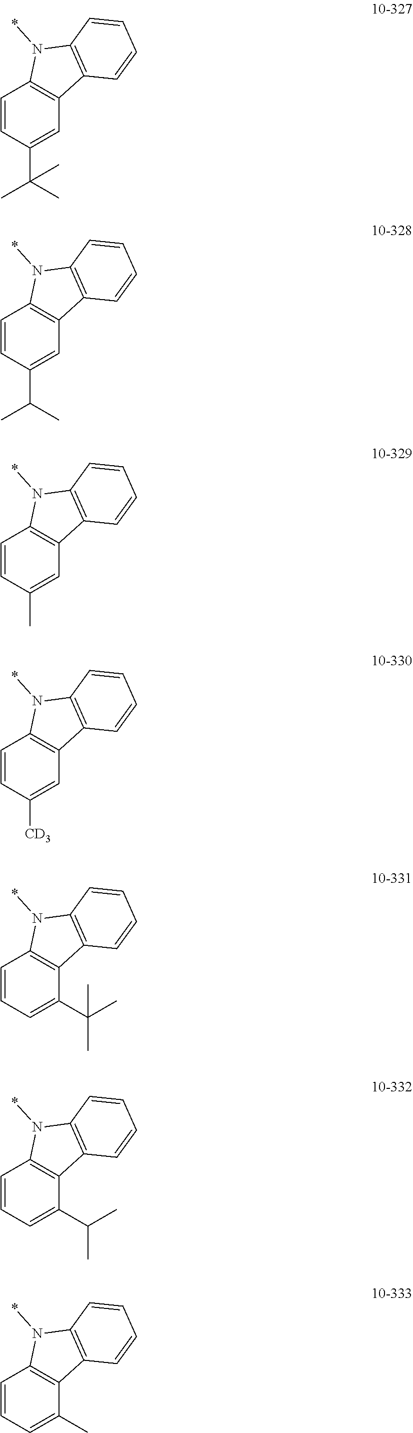

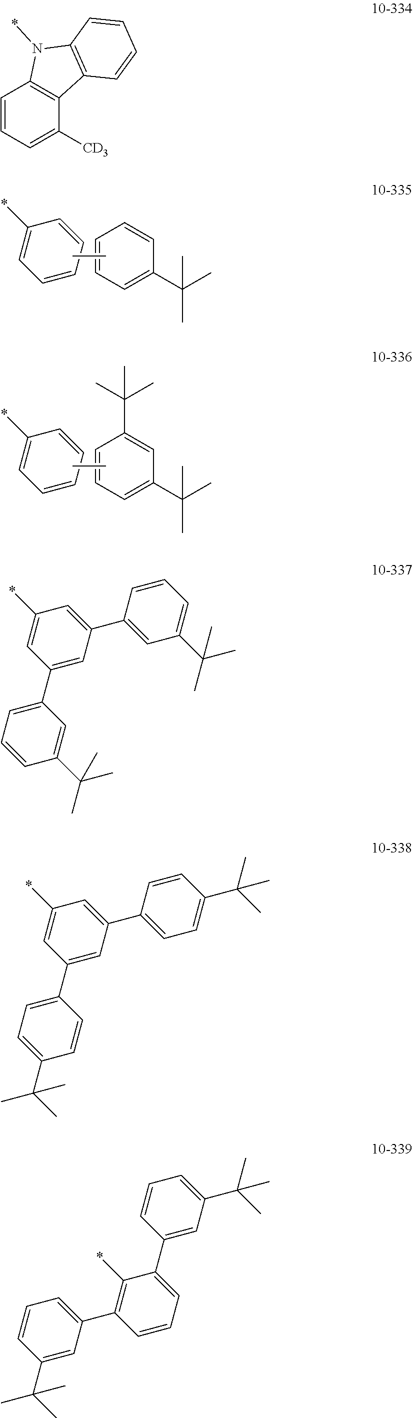

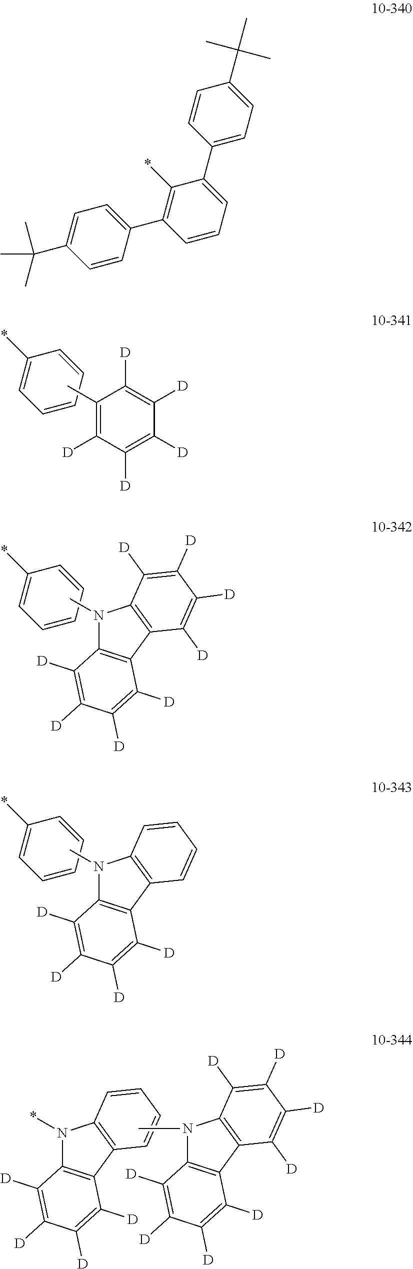

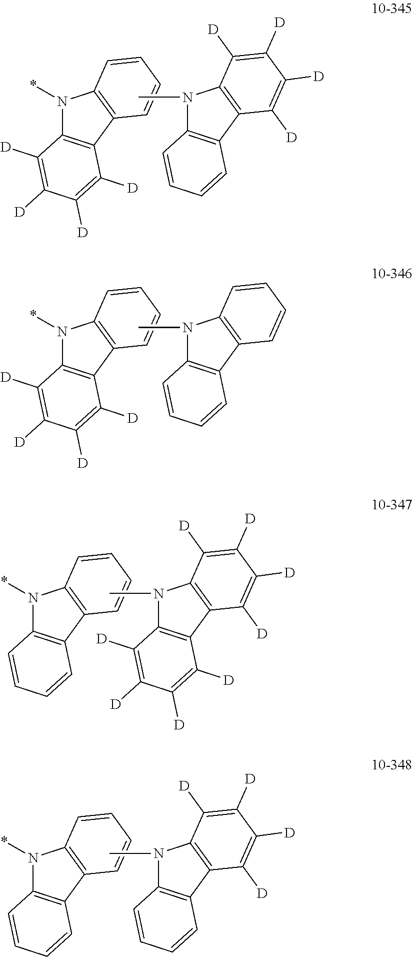

In Formulae 9-1 to 9-61 and 10-1 to 10-348, * indicates a binding site to a neighboring atom, Ph is a phenyl group, TMS is a trimethylsilyl group, D is a deuterium atom, and

Q₁ to Q₃ may each be the same as described in the specification.

The expression “(interlayer) includes a condensed cyclic compound” as used herein may be interpreted such that the (interlayer) may include one kind of condensed cyclic compound represented by Formula 1 or two or more different kinds of condensed cyclic compounds, each independently represented by Formula 1.

For example, the interlayer may include, as the condensed cyclic compound, only Compound 1. In this regard, Compound 1 may be present in the emission layer of the light-emitting device. In an embodiment, the interlayer may include, as the condensed cyclic compound, Compound 1 and Compound 2. In this regard, Compound 1 and Compound 2 may be present in the same layer (for example, both Compound 1 and Compound 2 may be present in the emission layer), or may be present in different layers (for example, Compound 1 may be present in the emission layer, and Compound 2 may be present in the electron transport region).

The term “interlayer” as used herein refers to a single layer and/or all layers between the first electrode and the second electrode of the light-emitting device.

According to embodiments, an electronic apparatus may include the light-emitting device as described above. The electronic apparatus may further include a thin-film transistor. For example, the electronic apparatus may further include a thin-film transistor including a source electrode and a drain electrode, and the first electrode of the light-emitting device may be electrically connected to the source electrode or the drain electrode. In an embodiment, the electronic apparatus may further include a color filter, a color conversion layer, a touch screen layer, a polarizing layer, or any combination thereof. Details for the electronic apparatus are the same as described in the specification.

According to embodiments, an electronic device may include the light-emitting device as described above.

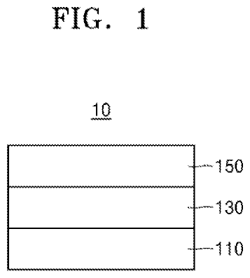

For example, the electronic device may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

[Description of FIG. 1]

FIG. 1 is a schematic cross-sectional view of a light-emitting device 10 according to an embodiment. The light-emitting device 10 includes a first electrode 110, an interlayer 130, and a second electrode 150.

Hereinafter, a structure of the light-emitting device 10 according to an embodiment and a method of manufacturing the light-emitting device 10 will be described in connection with FIG. 1.

[First Electrode 110]

In FIG. 1, a substrate may be further included under the first electrode 110 or above the second electrode 150. The substrate may be a glass substrate or a plastic substrate but is not limited thereto. In an embodiment, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high work function material to facilitate injection of holes.

The first electrode 110 may be a reflective electrode, a semi-transmissive electrode, or a transmissive electrode. When the first electrode 110 is a transmissive electrode, the material for forming the first electrode 110 may include indium tin oxide (ITO), indium zinc oxide (IZO), tin oxide (SnO₂), zinc oxide (ZnO), or any combination thereof. In an embodiment, when the first electrode 110 is a semi-transmissive electrode or a reflective electrode, the material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a structure consisting of a single layer, or a structure including multiple layers. For example, the first electrode 110 may have a three-layered structure of ITO/Ag/ITO.

[Interlayer 130]

The interlayer 130 may be disposed above the first electrode 110. The interlayer 130 may include an emission layer.

The interlayer 130 may further include a hole transport region between the first electrode 110 and the emission layer, and an electron transport region between the emission layer and the second electrode 150.

The interlayer 130 may further include a metal-containing compound such as an organometallic compound, an inorganic material such as a quantum dot, or the like, in addition to various organic materials.

In an embodiment, the interlayer 130 may include, two or more emitting units stacked between the first electrode 110 and the second electrode 150, and at least one charge generation layer between the two or more emitting units. When the interlayer 130 includes the two or more emitting units and the at least one charge generation layer as described above, the light-emitting device 10 may be a tandem light-emitting device.

[Hole Transport Region in Interlayer 130]

The hole transport region may have a structure consisting of a layer consisting of a single material; a structure consisting of a layer including different materials; or a structure including multiple layers including different materials.

The hole transport region may include a hole injection layer, a hole transport layer, an emission auxiliary layer, an electron blocking layer, or any combination thereof.

In an embodiment, the hole transport region may have a multilayer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the layers of each structure may be stacked from the first electrode 110 in its respective stated order, but the structure of the hole transport region is not limited thereto.

The hole transport region may include a compound represented by Formula 201, a compound represented by Formula 202, or any combination thereof:

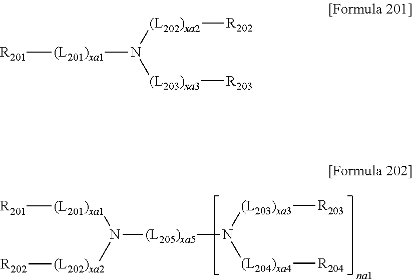

In Formulae 201 and 202,
L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
L₂₀₅ may be *—O—*′, *—S—*′, *—N(Q₂₀₁)-*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xa1 to xa4 may each independently be an integer from 0 to 5,
xa5 may be an integer from 1 to 10,
R₂₀₁ to R₂₀₄ and 0201 may each independently be a C₃-C₆₀ carbocyclic group that is unsubstituted or substituted with at least one R₁₀ₐ or a C₁-C₂₀ heterocyclic group that is unsubstituted or substituted with at least one R₁₀ₐ,
R₂₀₁ and R₂₀₂ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₅-C₆₀ polycyclic group (for example, a carbazole group) that is unsubstituted or substituted with at least one R₁₀ₐ (for example, see Compound HT16),
R₂₀₃ and R₂₀₄ may optionally be linked together via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group that is unsubstituted or substituted with at least one R₁₀ₐ, and
na1 may be an integer from 1 to 4.

In an embodiment, Formulae 201 and 202 may each include at least one of groups represented by Formulae CY201 to CY217:

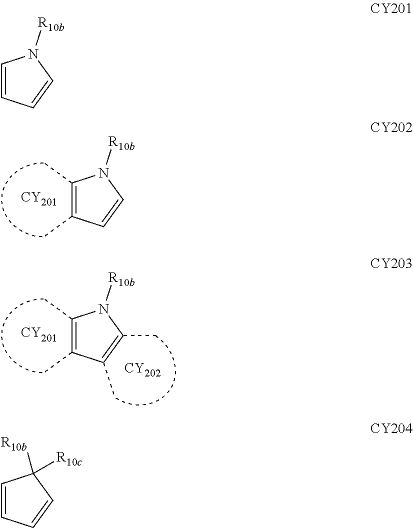

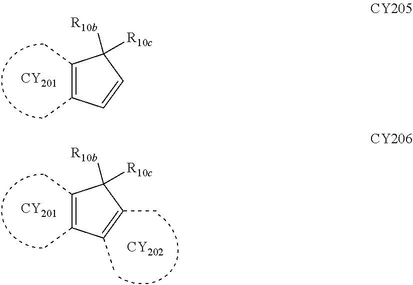

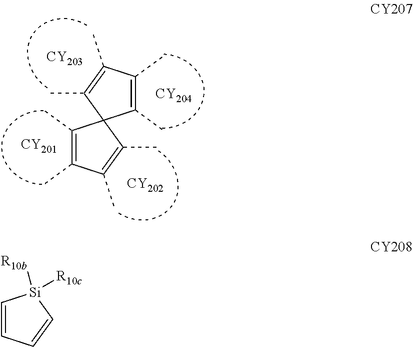

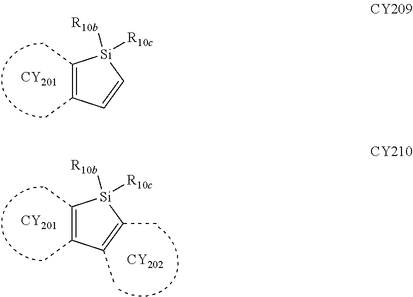

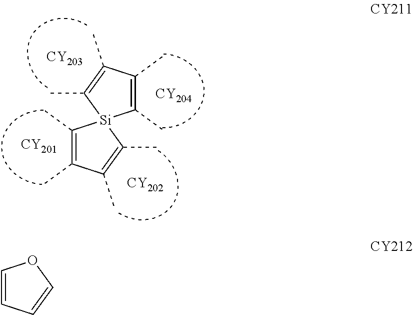

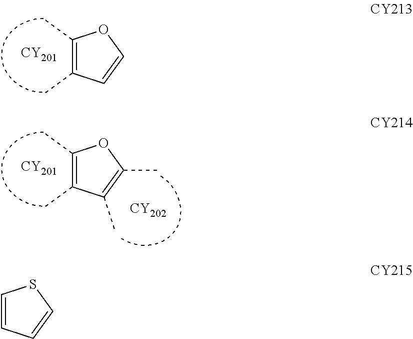

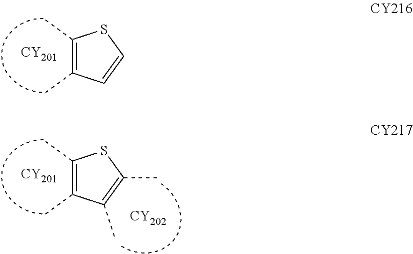

In Formulae CY201 to CY217, R_{10b} and R_{10c} may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described herein.

In an embodiment, ring CY₂₀₁ to ring CY₂₀₄ in Formulae CY201 to CY217 may each independently be a benzene group, a naphthalene group, a phenanthrene group, or an anthracene group.

In an embodiment, the compound represented by Formula 201 and the compound represented by Formula 202 may each independently include at least one of groups represented by Formulae CY201 to CY203.

In an embodiment, the compound represented by Formula 201 may include at least one of groups represented by Formulae CY201 to CY203 and at least one of groups represented by Formulae CY204 to CY217.

In an embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

In an embodiment, the compound represented by Formula 201 and the compound represented by Formula 202 may each not include groups represented by Formulae CY201 to CY203.

In an embodiment, the compound represented by Formula 201 and the compound represented by Formula 202 may each not include groups represented by Formulae CY201 to CY203, and may each independently include at least one of groups represented by Formulae CY204 to CY217.

In an embodiment, the compound represented by Formula 201 and the compound represented by Formula 202 may each not include groups represented by Formulae CY201 to CY217.

In an embodiment, the hole transport region may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANT/CSA), polyaniline/poly(4-styrene sulfonate) (PANT/PSS), or any combination thereof:

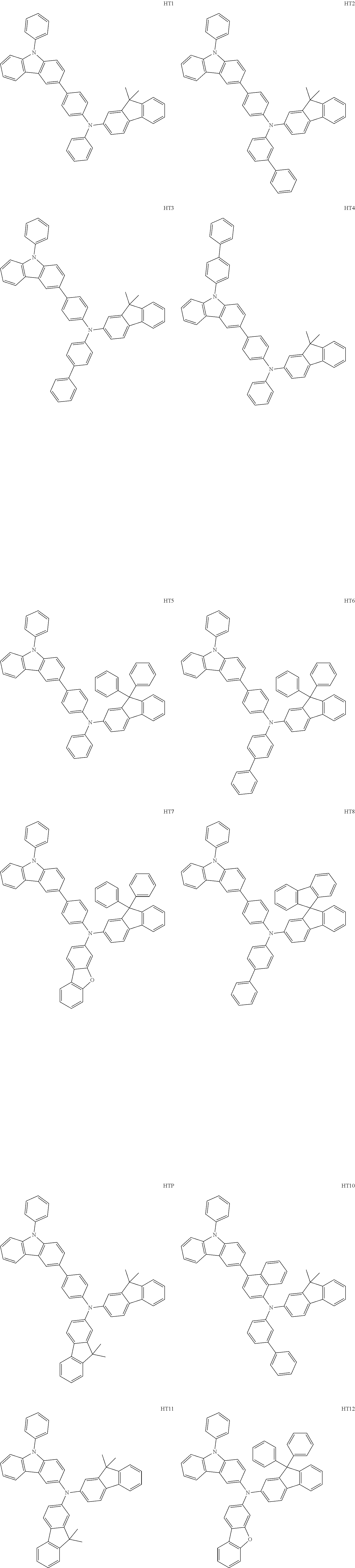

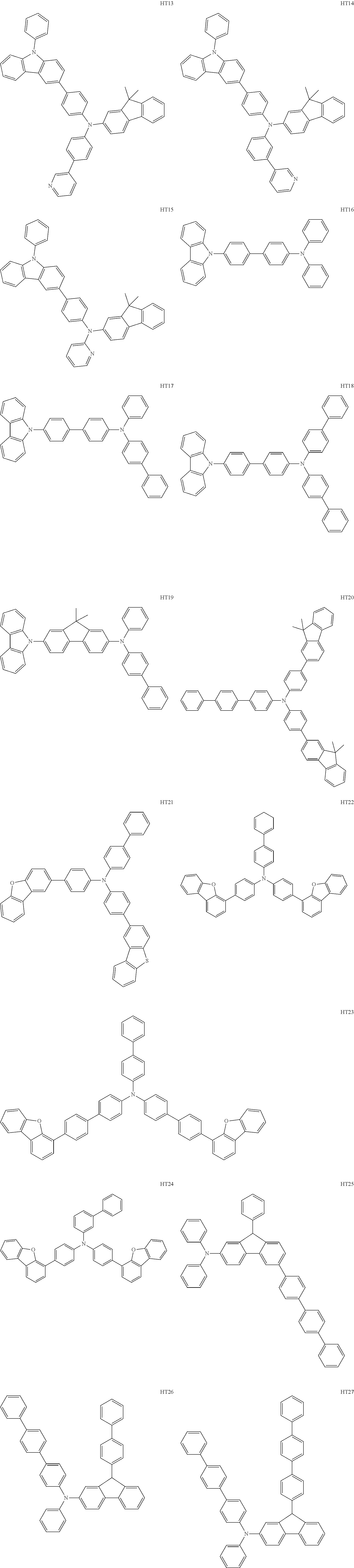

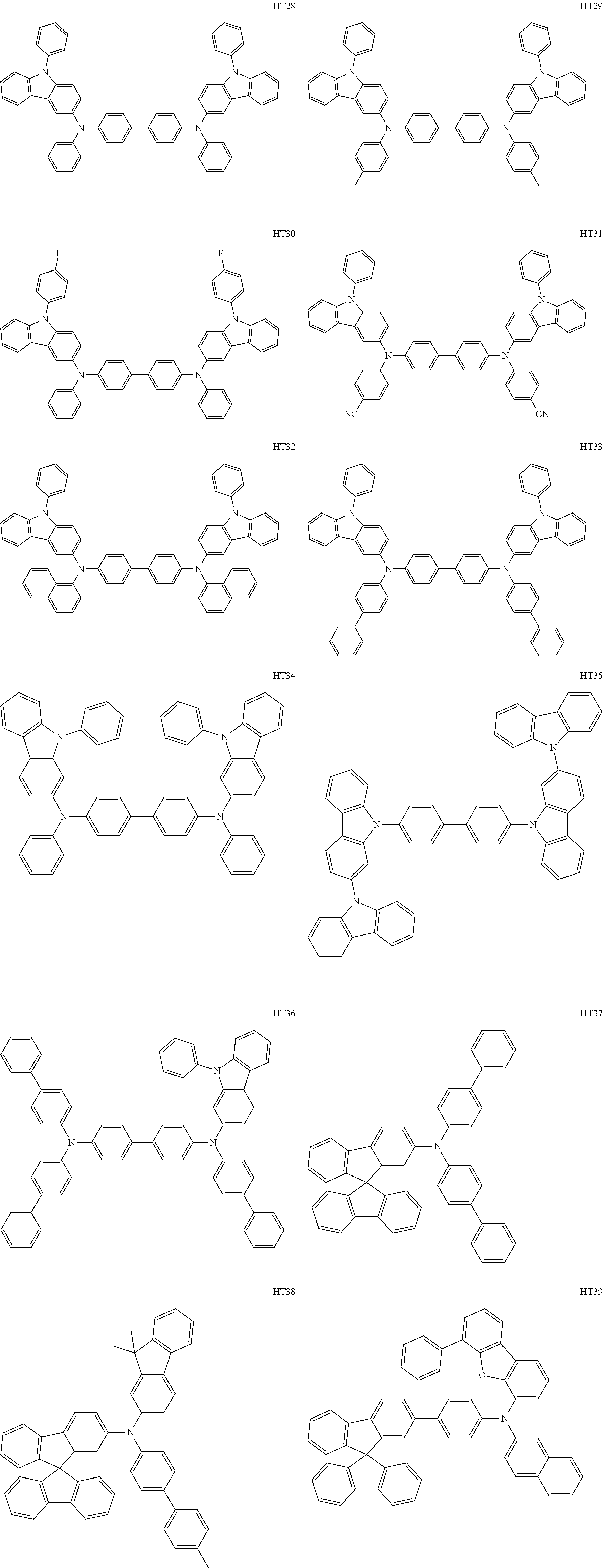

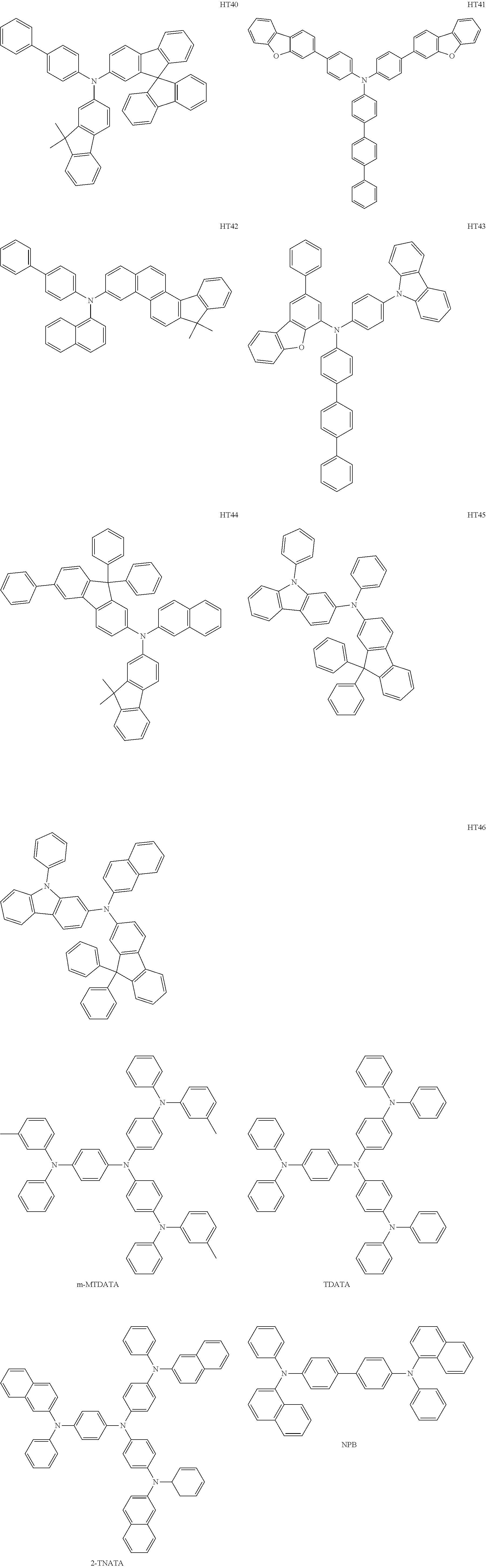

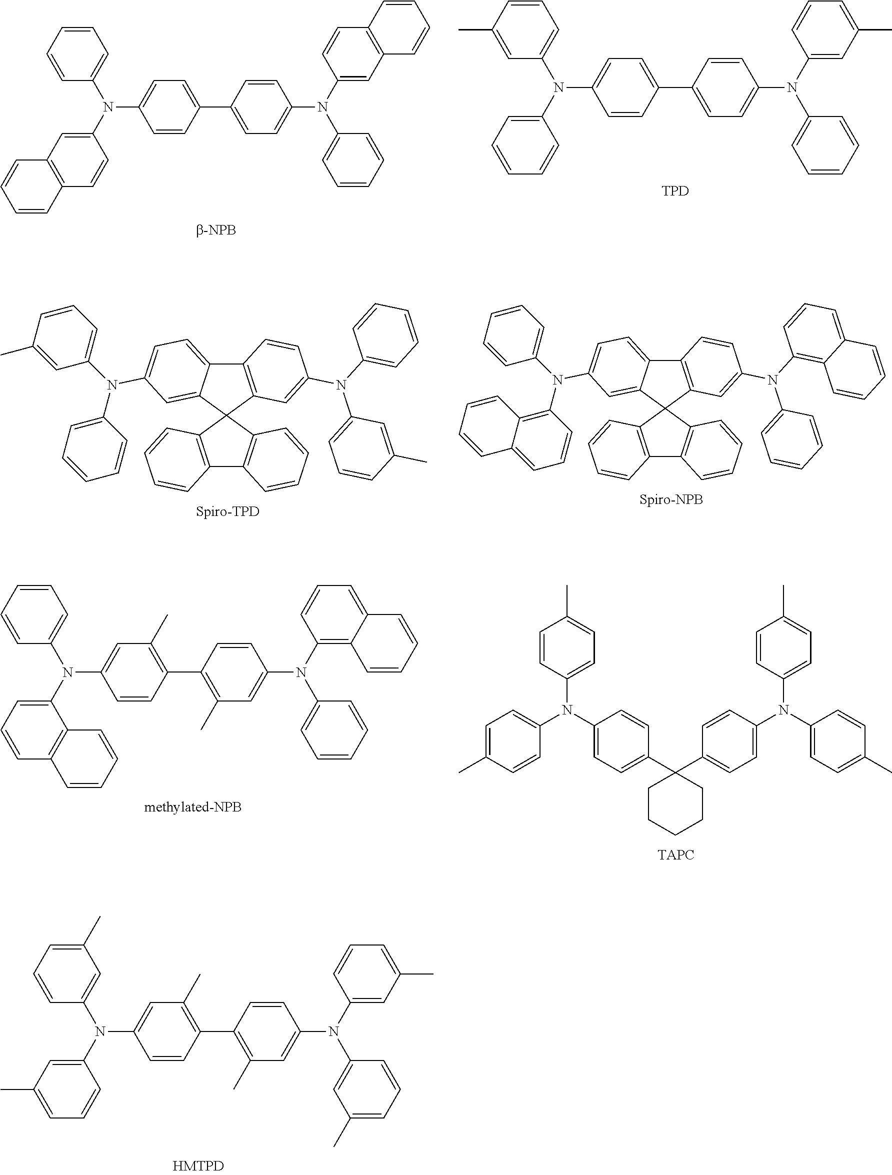

A thickness of the hole transport region may be in a range of about 50 Å to about 10,000 Å. For example, the thickness of the hole transport region may be in a range of about 100 Å to about 4,000 Å. When the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection region may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer are within these ranges, satisfactory hole-transporting characteristics may be obtained without a substantial increase in driving voltage.

The emission auxiliary layer may increase light-emission efficiency by compensating for an optical resonance distance according to a wavelength of light emitted by an emission layer, and the electron blocking layer may block the leakage of electrons from an emission layer to a hole transport region. Materials that may be included in the hole transport region may be included in the emission auxiliary layer and the electron blocking layer.

[p-Dopant]

The hole transport region may further include, in addition to these materials, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

In an embodiment, a lowest unoccupied molecular orbital (LUMO) energy level of the p-dopant may be equal to or less than about −3.5 eV.

In an embodiment, the p-dopant may include a quinone derivative, a cyano group-containing compound, a compound including an element EL1 and an element EL2, or any combination thereof.

Examples of a quinone derivative may include TCNQ, F4-TCNQ, and the like.

Examples of a cyano group-containing compound may include HAT-CN, a compound represented by Formula 221, and the like.

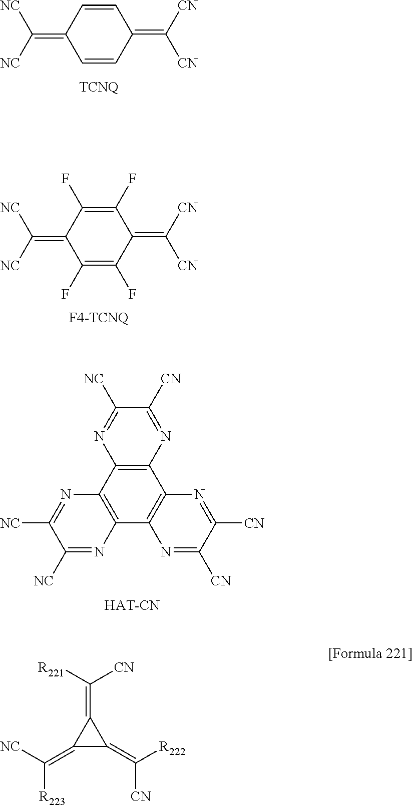

In Formula 221,

R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and

at least one of R₂₂₁ to R₂₂₃ may each independently be: a C₃-C₆₀ carbocyclic group or a C₁-C₆₀ heterocyclic group, each substituted with: a cyano group; —F; —Cl; —Br; —I; a C₁-C₂₀ alkyl group that is substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of a metalloid may include silicon (Si), antimony (Sb), and tellurium (Te).

Examples of a non-metal may include oxygen (O) and a halogen (for example, F, Cl, Br, I, etc.).

In an embodiment, examples of the compound including element EL1 and element EL2 may include a metal oxide, a metal halide (for example, a metal fluoride, a metal chloride, a metal bromide, or a metal iodide), a metalloid halide (for example, a metalloid fluoride, a metalloid chloride, a metalloid bromide, or a metalloid iodide), a metal telluride, or any combination thereof.

Examples of a metal oxide may include a tungsten oxide (for example, WO, W₂O₃, WO₂, WO₃, W₂O₅, etc.), a vanadium oxide (for example, VO, V₂O₃, VO₂, V₂O₅, etc.), a molybdenum oxide (MoO, Mo₂O₃, MoO₂, MoO₃, Mo₂O₅, etc.), and a rhenium oxide (for example, ReO₃, etc.).

Examples of a metal halide may include an alkali metal halide, an alkaline earth metal halide, a transition metal halide, a post-transition metal halide, and a lanthanide metal halide.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and CsI.

Examples of an alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, Mgl₂, Cal₂, Srl₂, and Bale.

Examples of a transition metal halide may include a titanium halide (for example, TiF₄, TiCl₄, TiBr₄, Til₄, etc.), a zirconium halide (for example, ZrF₄, ZrCl₄, ZrBr₄, Zrl₄, etc.), a hafnium halide (for example, HfF₄, HfCl₄, HfBr₄, Hfl₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrCl₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, Tcl₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, RuI₂, etc.), an osmium halide (for example, OsF₂, OsCl₂, OsBr₂, OsI₂, etc.), a cobalt halide (for example, CoF₂, CoCl₂, CoBr₂, CoI₂, etc.), a rhodium halide (for example, RhF₂, RhCl₂, RhBr₂, RhI₂, etc.), an iridium halide (for example, IrF₂, IrCl₂, IrBr₂, IrI₂, etc.), a nickel halide (for example, NiF₂, NiCl₂, NiBr₂, NiI₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), and a gold halide (for example, AuF, AuCl, AuBr, AuI, etc.).

Examples of a post-transition metal halide may include a zinc halide (for example, ZnF₂, ZnCl₂, ZnBr₂, ZnI₂, etc.), an indium halide (for example, InI₃, etc.), and a tin halide (for example, SnI₂, etc.).

Examples of a lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, and SmI₃.

Examples of a metalloid halide may include an antimony halide (for example, SbCl₅, etc.).

Examples of a metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), and a lanthanide metal telluride (for example, LaTe, CeTe, PrTe, NdTe, PmTe, EuTe, GdTe, TbTe, DyTe, HoTe, ErTe, TmTe, YbTe, LuTe, etc.).

[Emission Layer in Interlayer 130]

When the light-emitting device 10 is a full-color light-emitting device, the emission layer may be patterned into a red emission layer, a green emission layer, and/or a blue emission layer, according to a subpixel. In an embodiment, the emission layer may have a stacked structure of two or more layers of a red emission layer, a green emission layer, and a blue emission layer, in which the two or more layers may contact each other or may be separated from each other. In an embodiment, the emission layer may include two or more materials of a red light-emitting material, a green light-emitting material, and a blue light-emitting material, in which the two or more materials may be mixed with each other in a single layer to emit white light.

The emission layer may include a host and a dopant. The dopant may include a phosphorescent dopant, a fluorescent dopant, or any combination thereof.

An amount of the dopant in the emission layer may be in a range of about 0.01 parts by weight to about 15 parts by weight, based on 100 parts by weight of the host.

In an embodiment, the emission layer may include a quantum dot.

In an embodiment, the emission layer may include a delayed fluorescence material. The delayed fluorescence material may serve as a host or as a dopant in the emission layer.

A thickness of the emission layer may be in a range of about 100 Å to about 1,000 Å. For example, the thickness of the emission layer may be in a range of about 200 Å to about 600 Å. When the thickness of the emission layer is within these ranges, excellent light-emission characteristics may be obtained without a substantial increase in driving voltage.

[Host]

The host may include a compound represented by Formula 301:

[Ar₃₀₁]_{xb11}-[(L₃₀₁)_{xb1}-R₃₀₁]_{xb21} [Formula 301]

In Formula 301,
Ar₃₀₁ and L₃₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₂₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described in connection with Q₁.

In an embodiment, in Formula 301, when xb11 is 2 or more, two or more Ar₃₀₁ (s) may be linked together via a single bond.

In an embodiment, the host may include a first compound represented by Formula 301-1A or 301-2A, a second compound represented by Formula 302, or any combination thereof.

For another example, the host may include a compound represented by Formula 301-1, a compound represented by Formula 301-2, or any combination thereof:

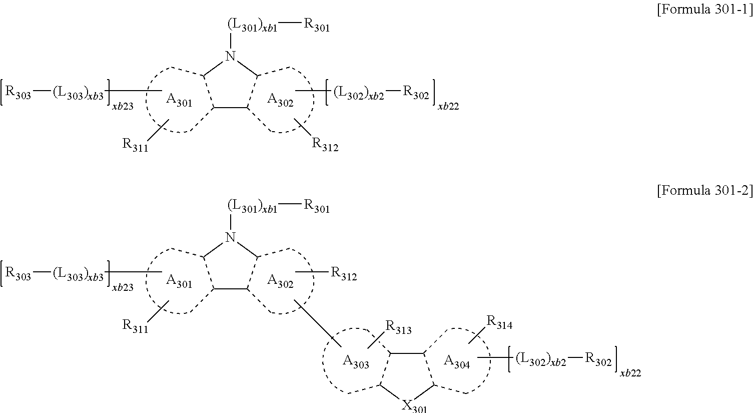

In Formulae 301-1 and 301-2,
ring A₃₀₁ to ring A₃₀₄ may each independently be a C₃-C₆₀ carbocyclic group that is unsubstituted or substituted with at least one R₁₀ₐ or a C₁-C₂₀ heterocyclic group that is unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each independently be the same as described in the specification,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In an embodiment, the host may include an alkali earth metal complex, a post-transition metal complex, or any combination thereof. For example, the host may include a Be complex (for example, Compound H55), an Mg complex, a Zn complex, or any combination thereof.

In an embodiment, the host may include one of Compounds H1 to H124, one of Compounds HTH1 to HTH56, one of Compounds ETH1 to ETH86, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyI)-1,1′-biphenyl (CBP), 1,3-di-9-carbazolylbenzene (mCP), 1,3,5-tri(carbazol-9-yl)benzene (TCP), or any combination thereof:

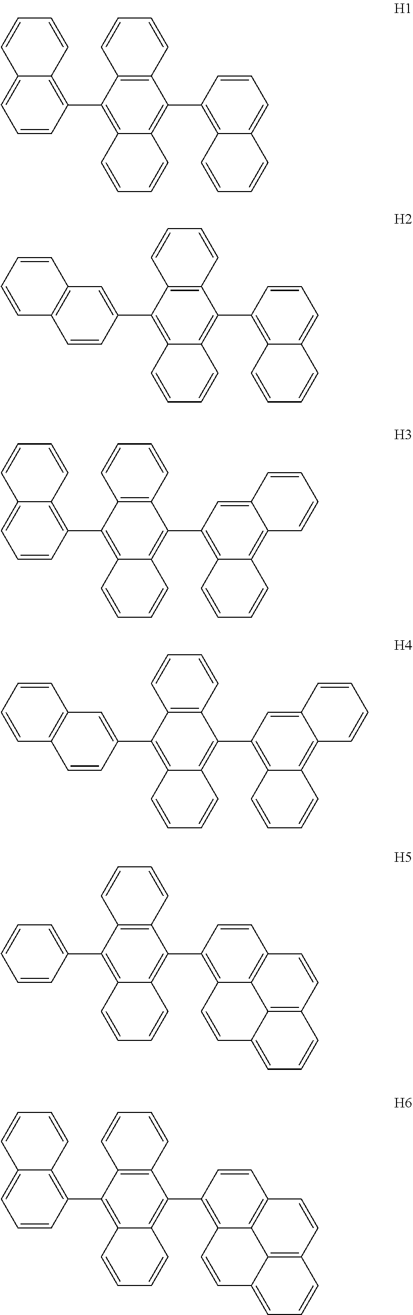

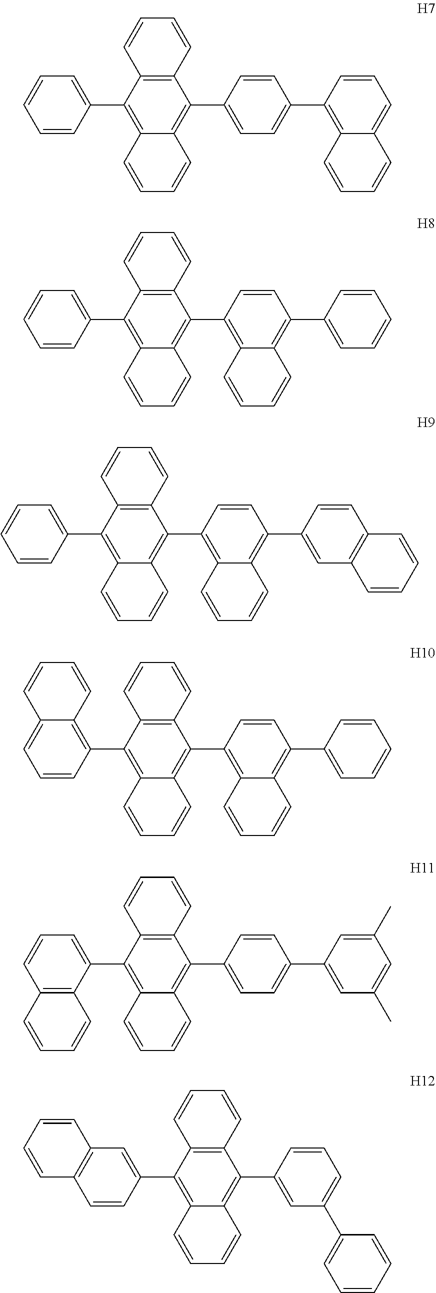

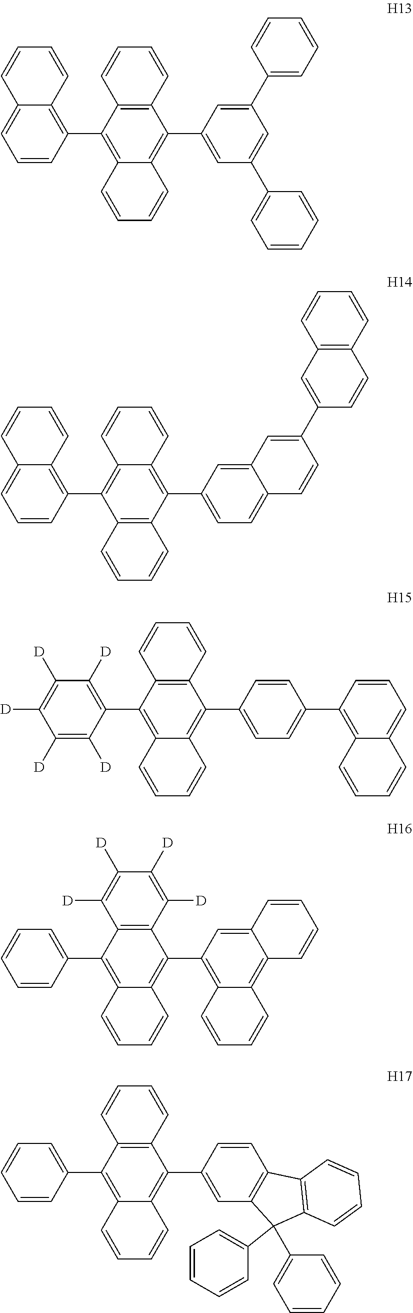

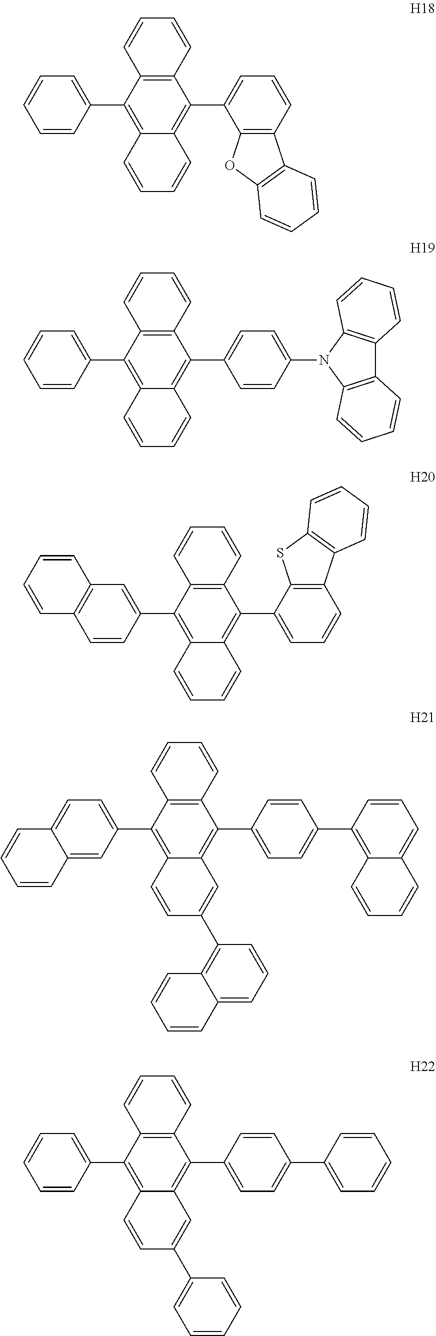

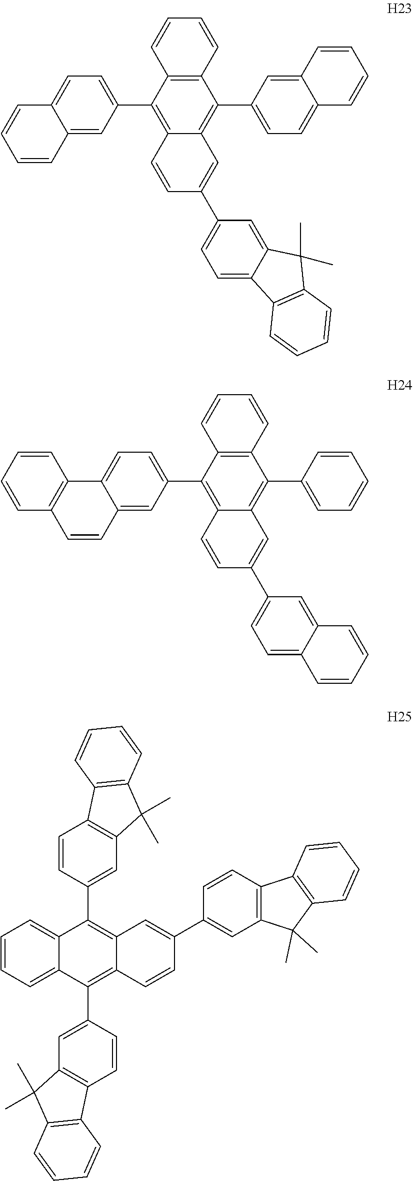

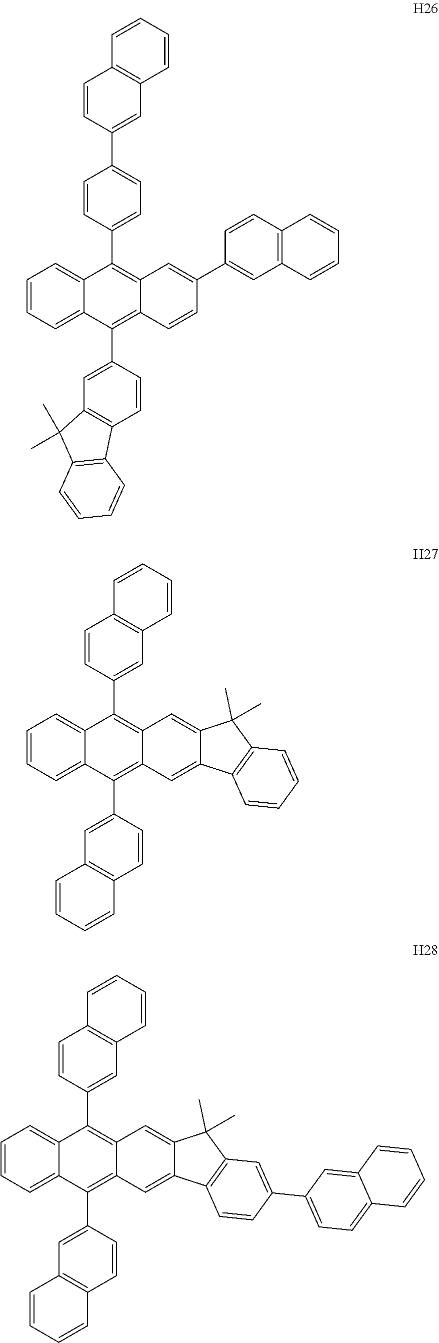

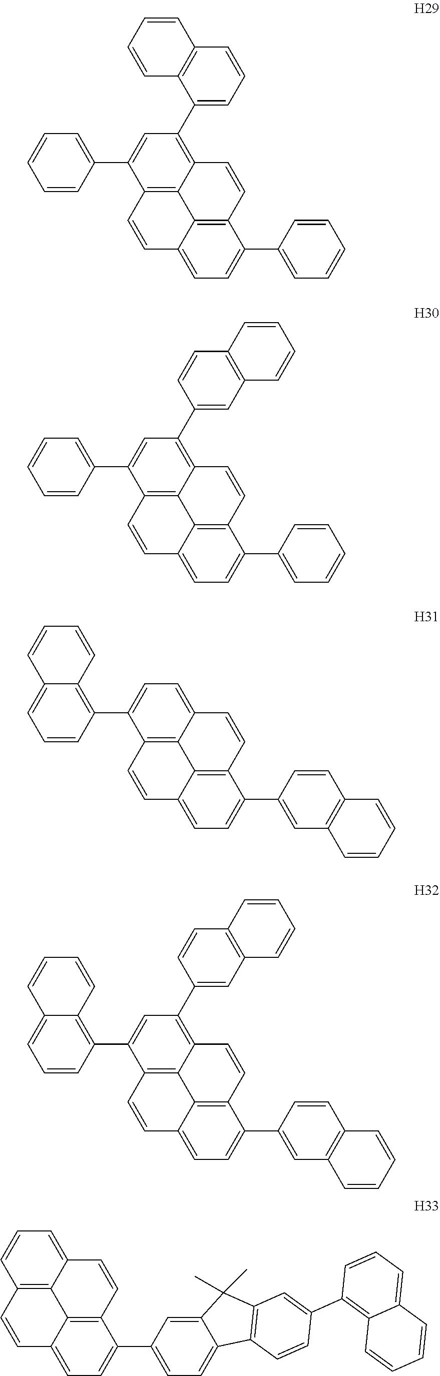

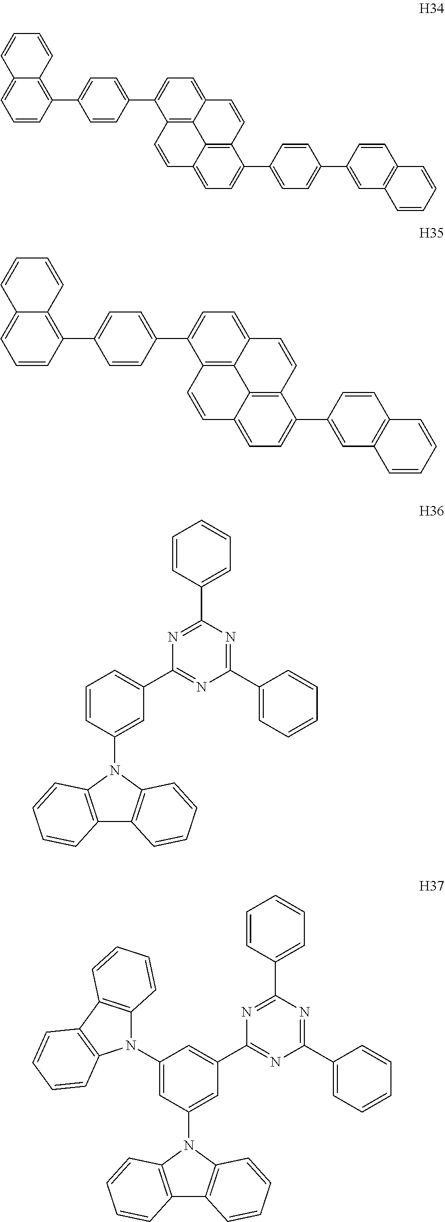

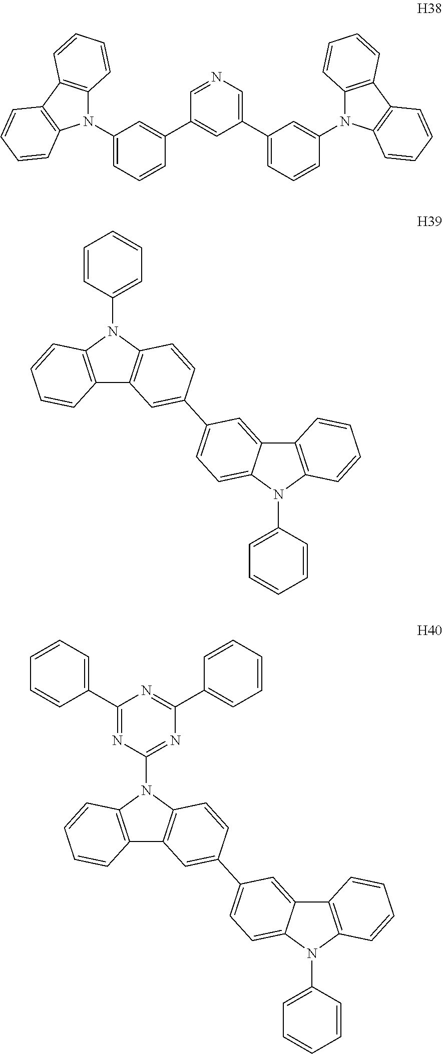 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

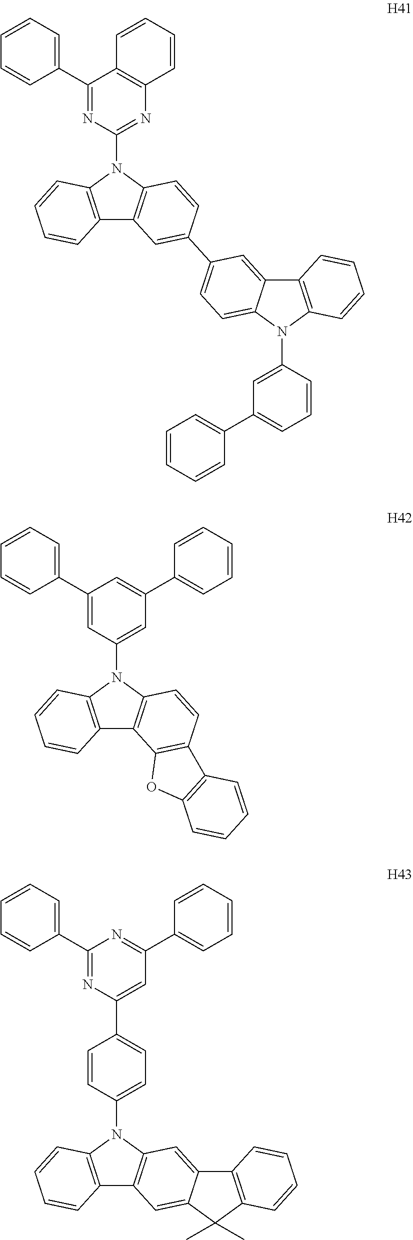 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

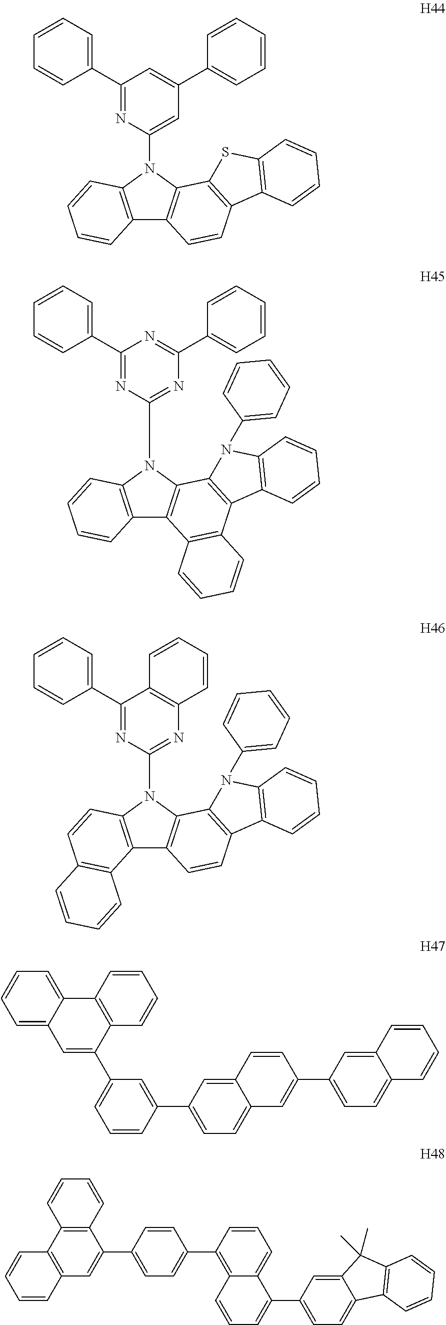

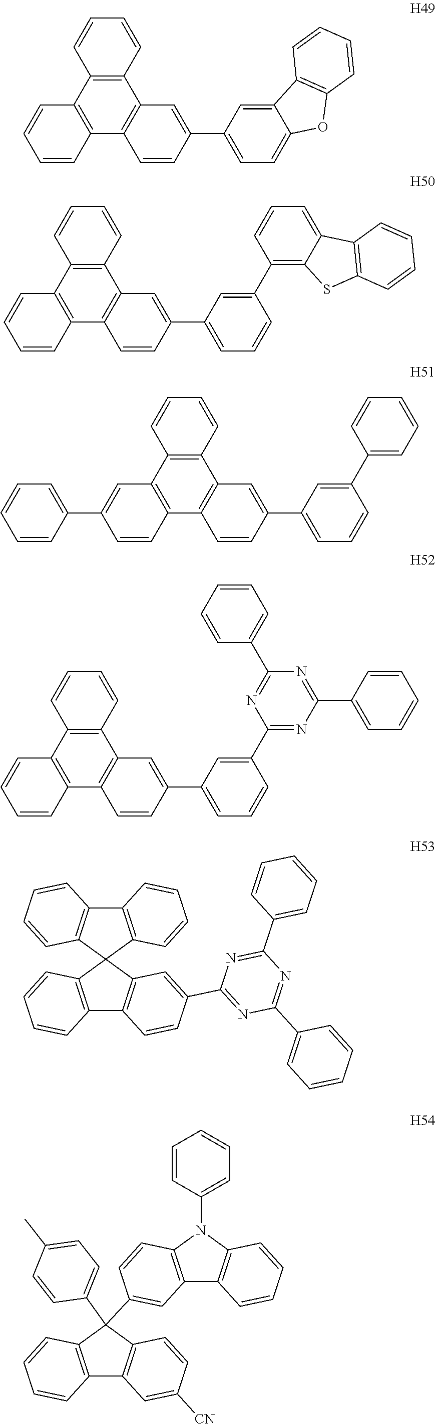

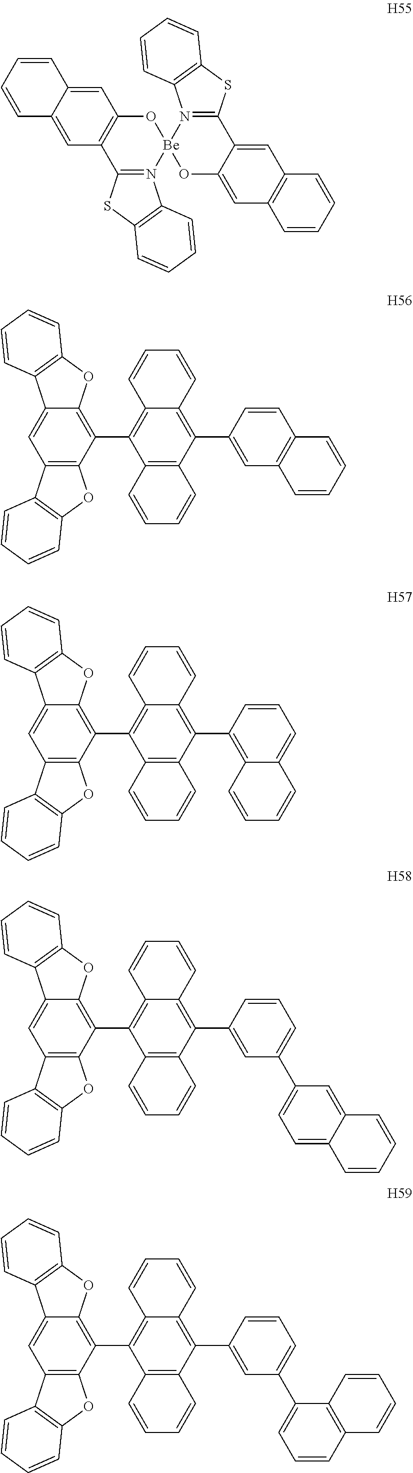

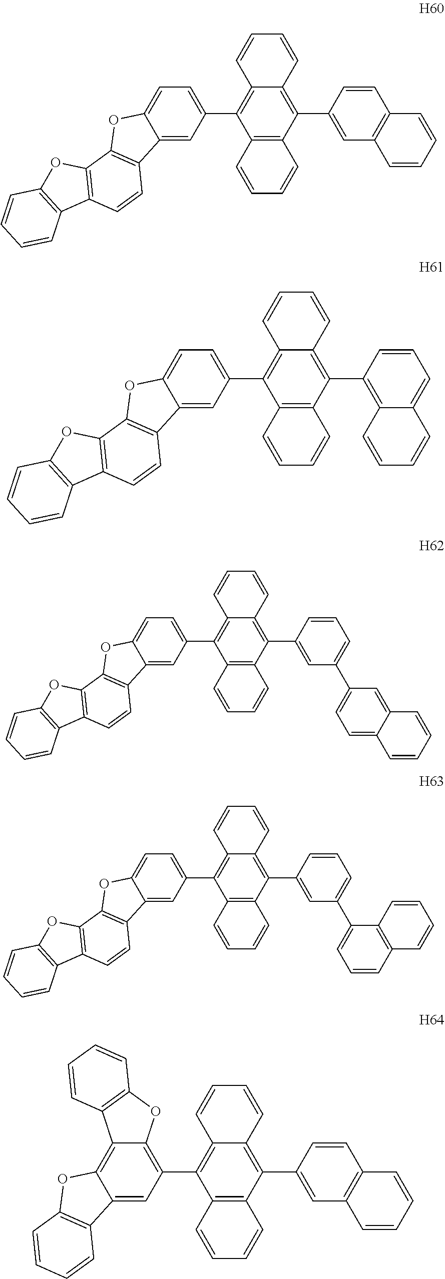 [SMILES: c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

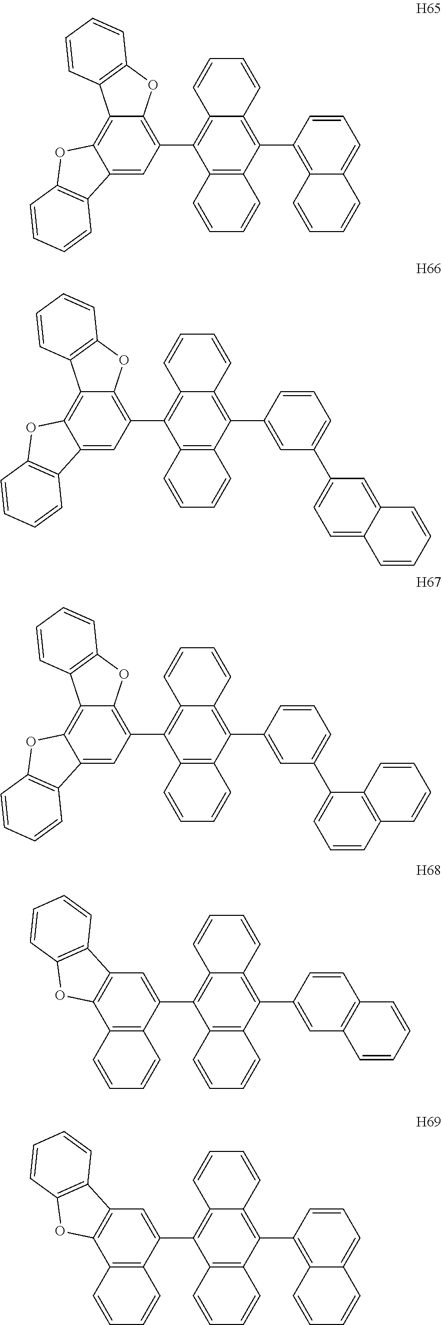

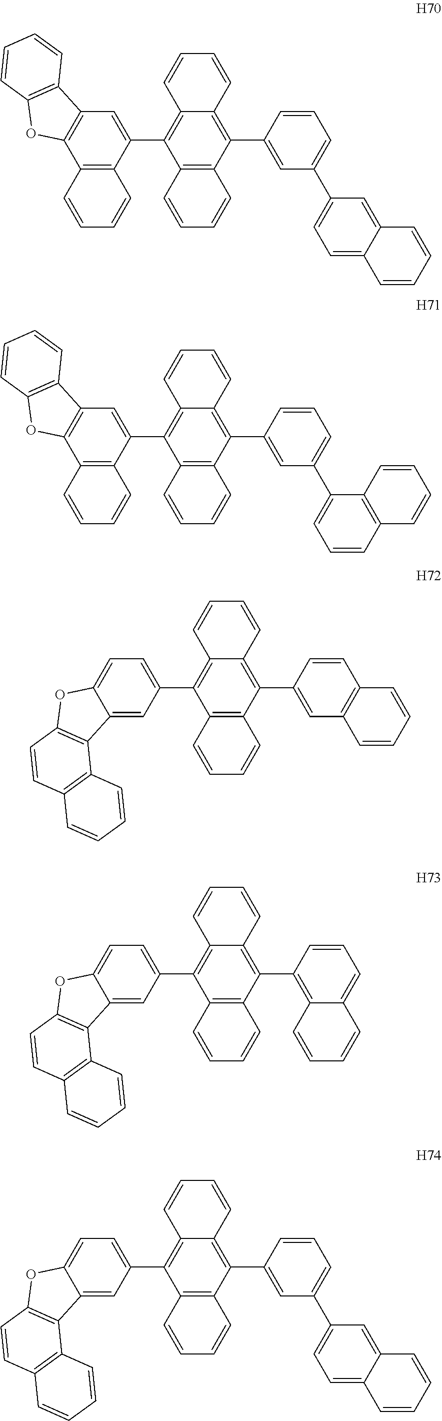 [SMILES: c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1]

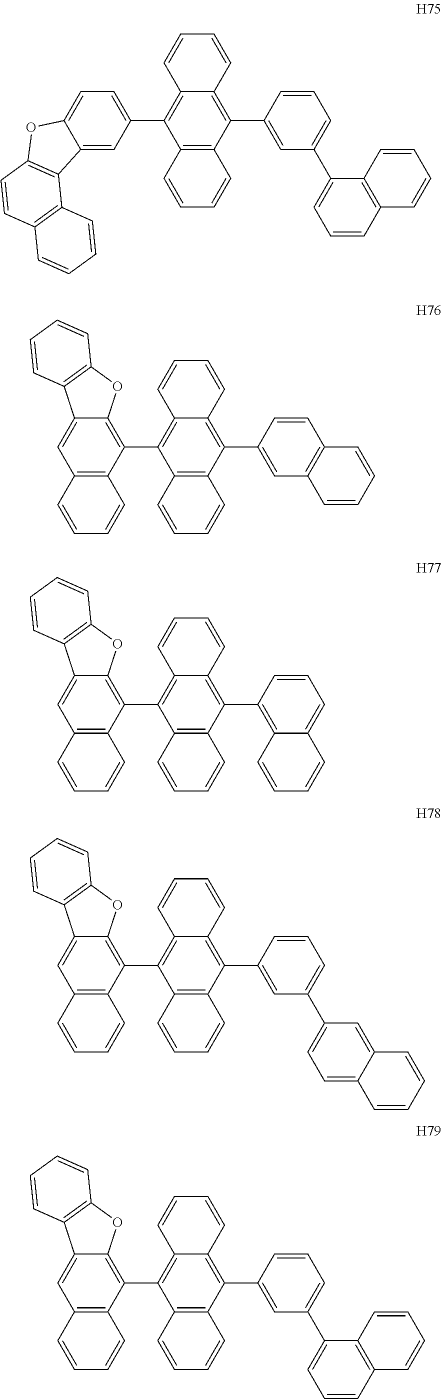 [SMILES: c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

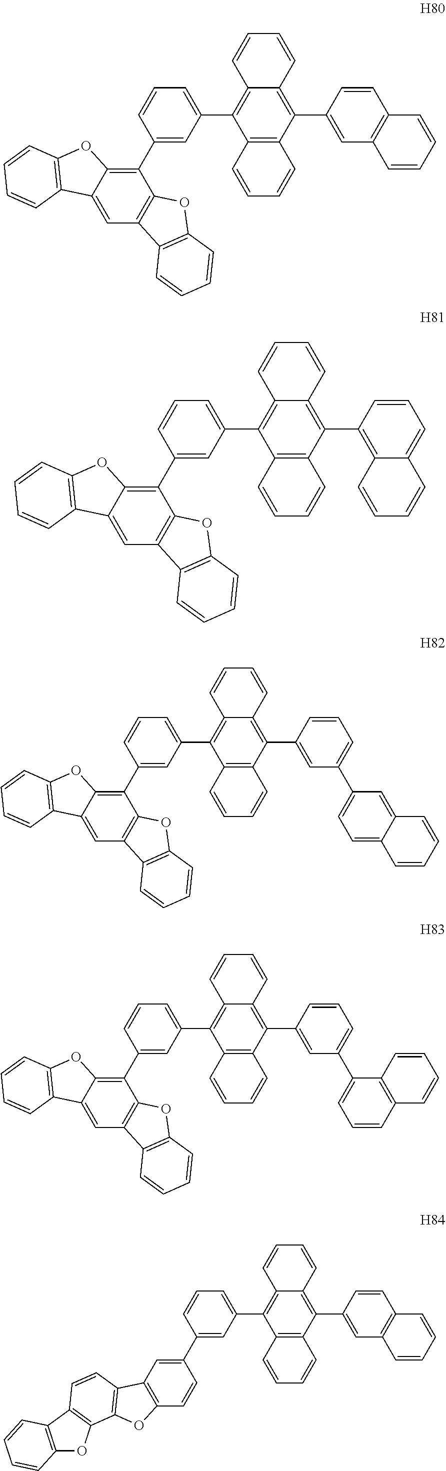 [SMILES: c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1]

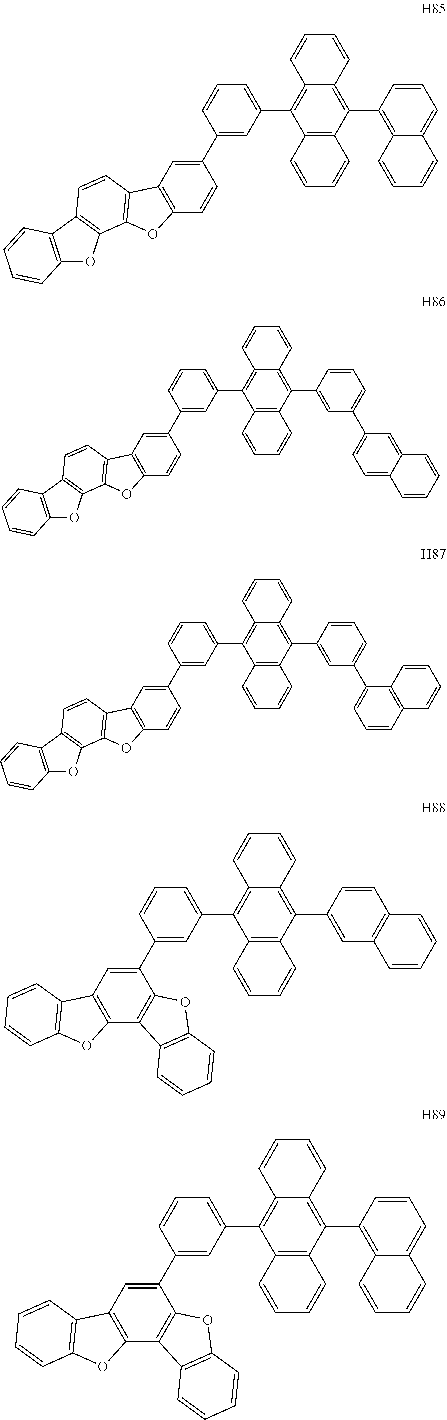 [SMILES: c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1]

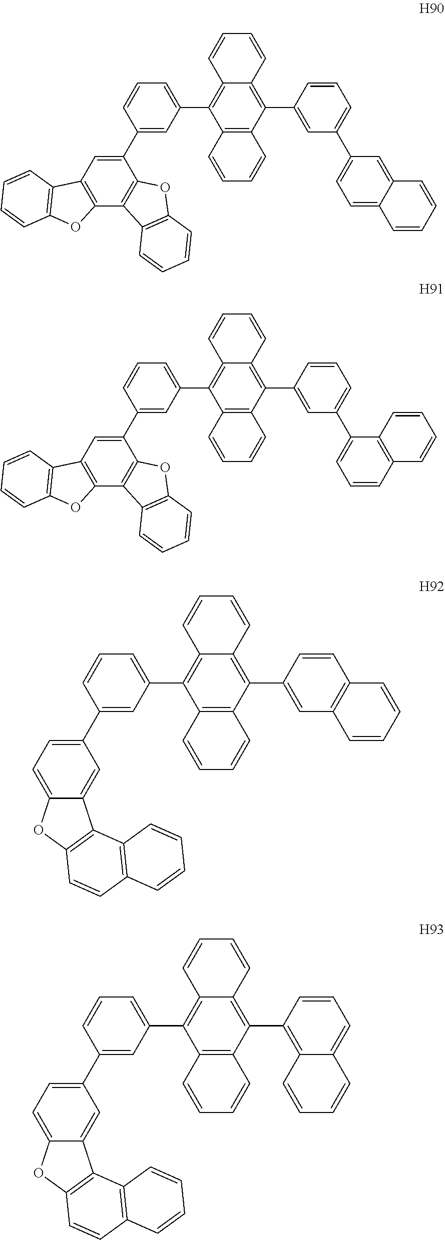 [SMILES: c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1]

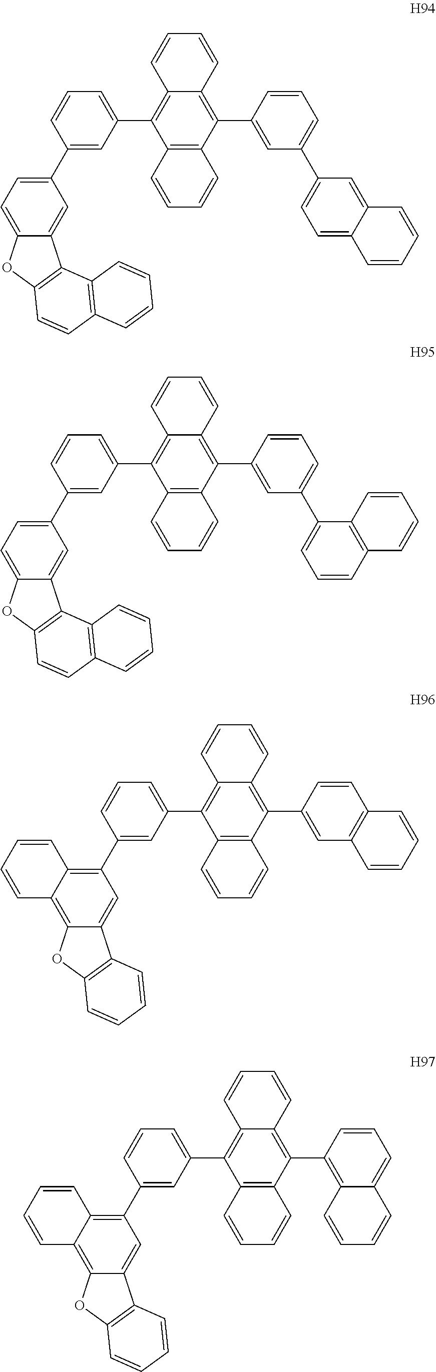 [SMILES: c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1]

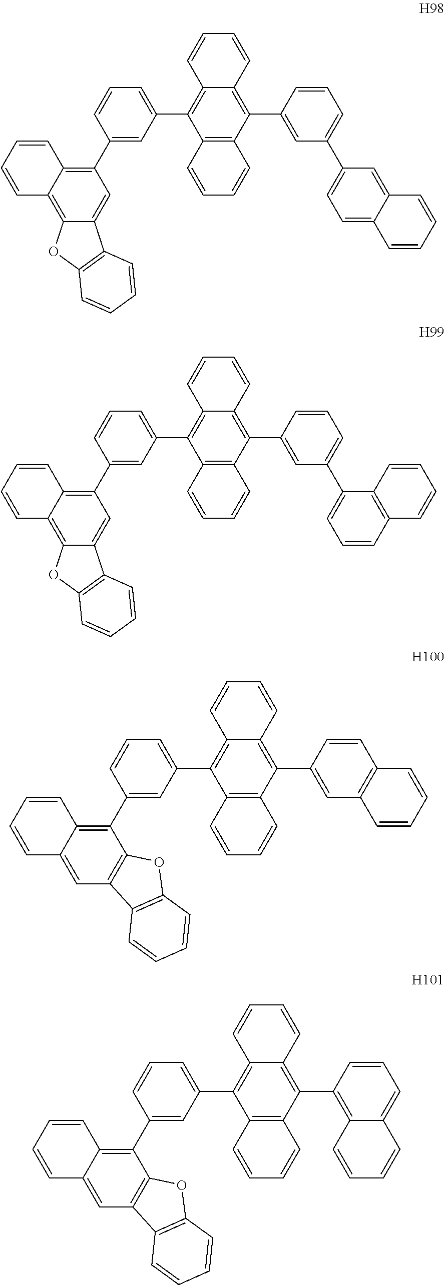 [SMILES: c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1]

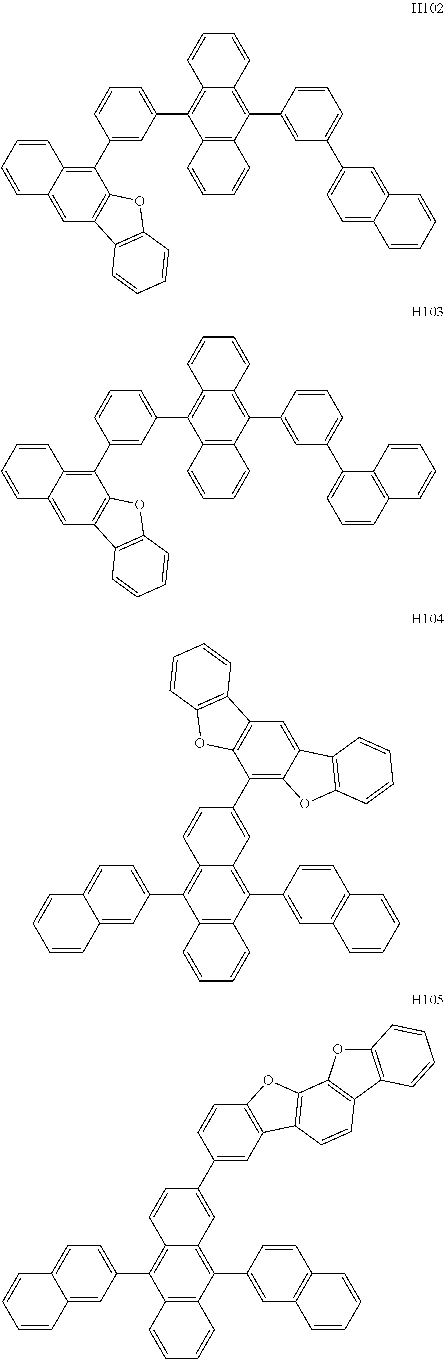 [SMILES: c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1]

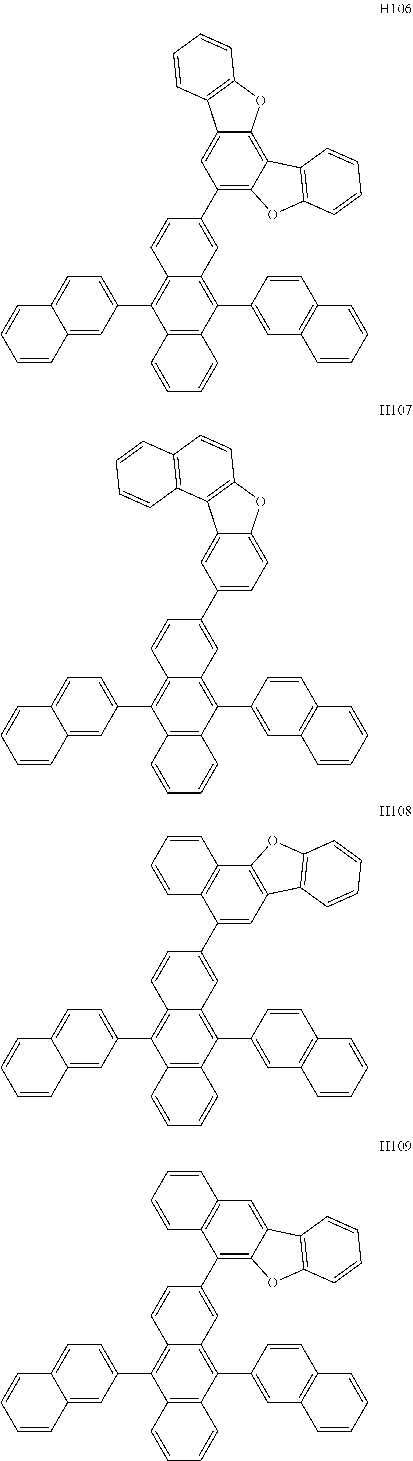

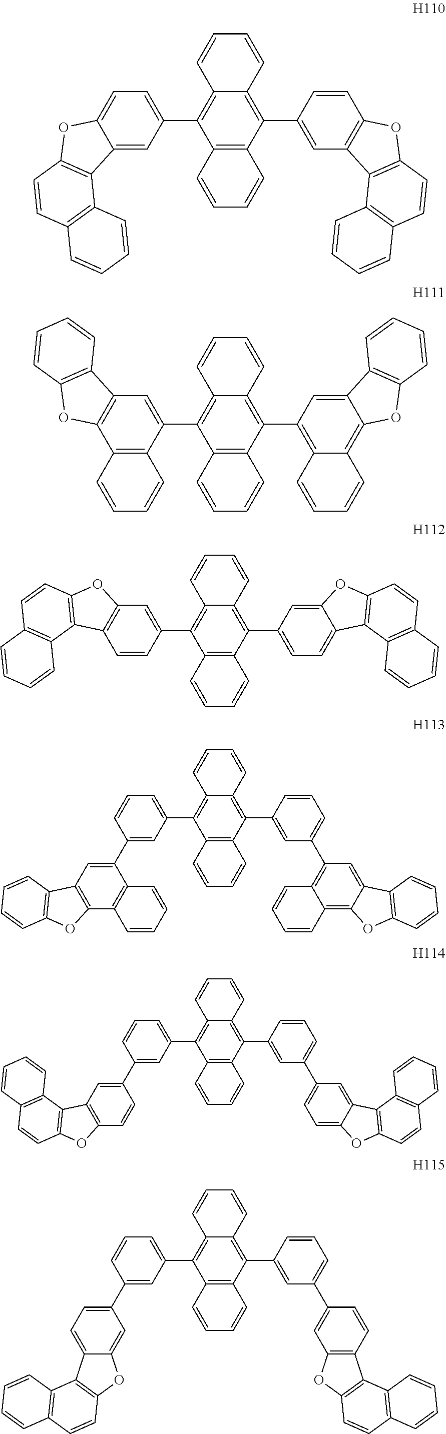

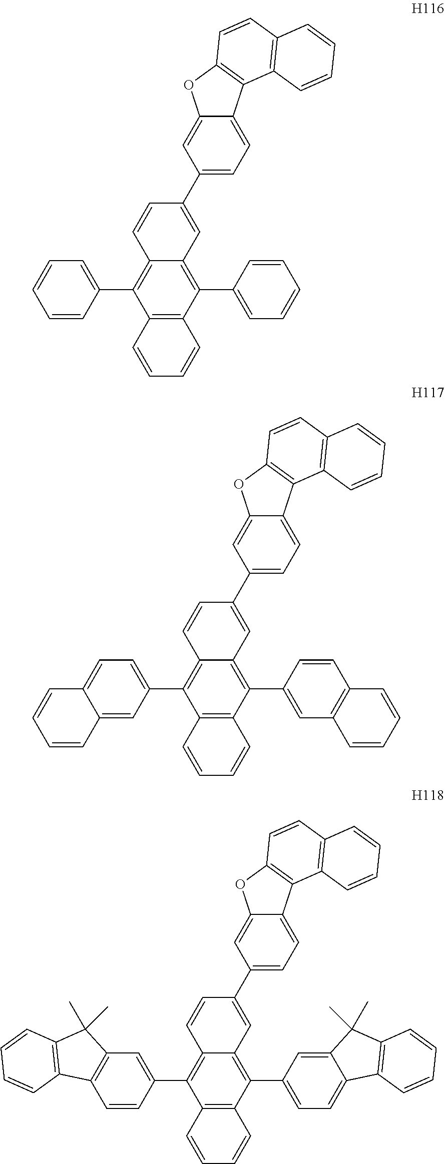 [SMILES: c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

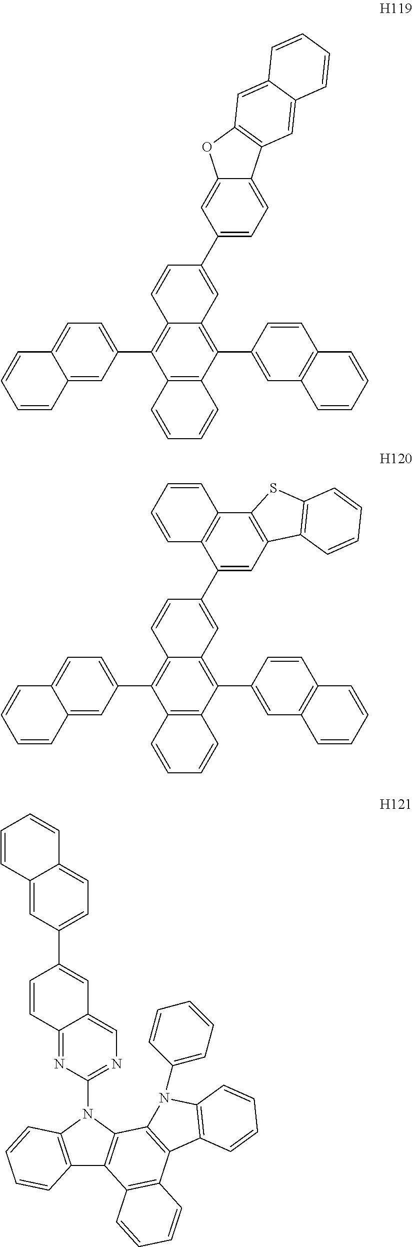

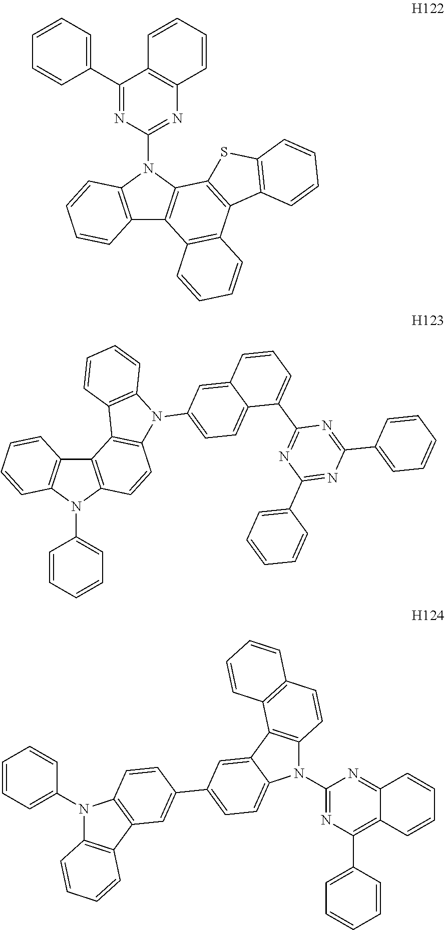 [SMILES: c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

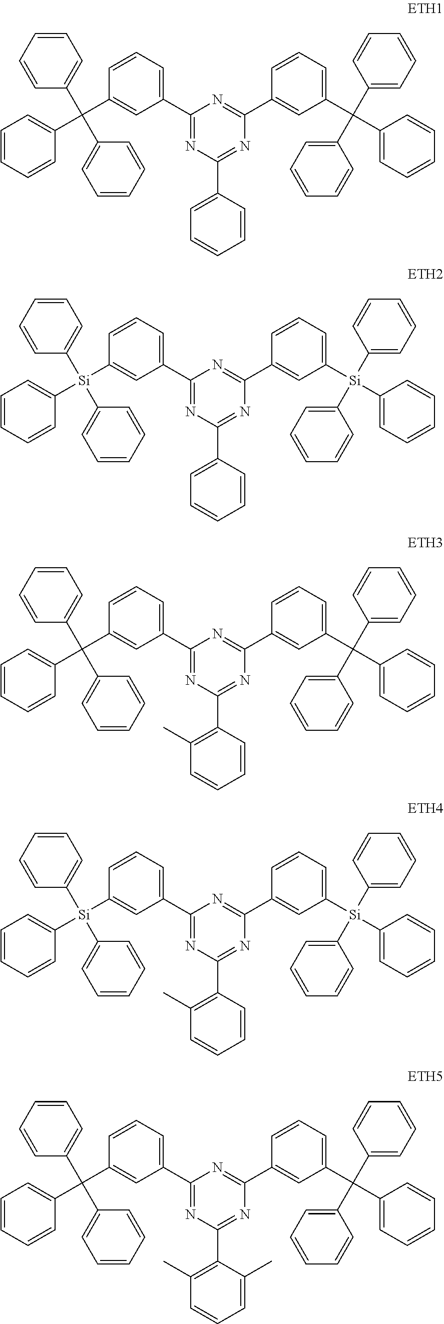

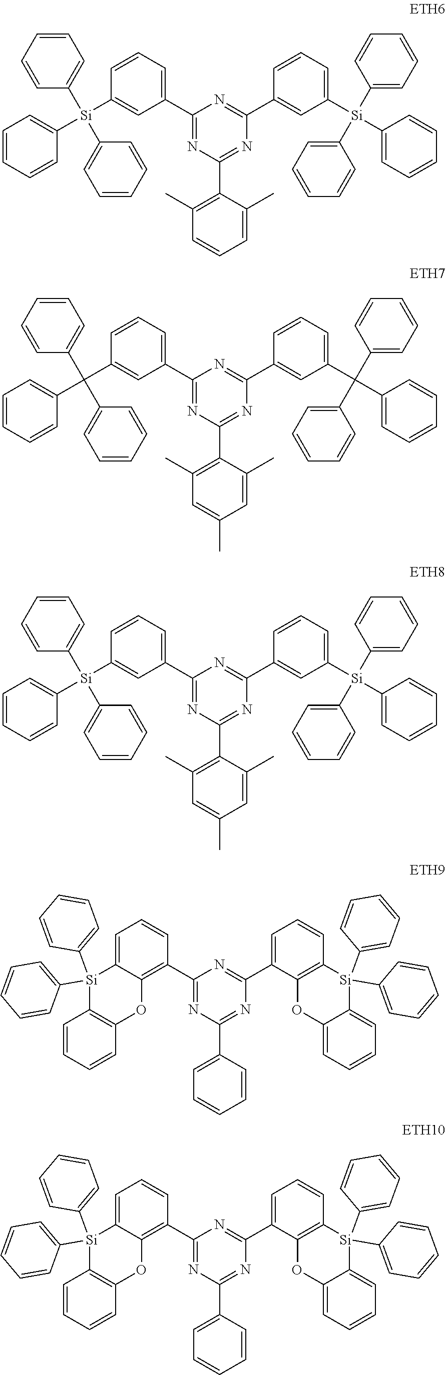

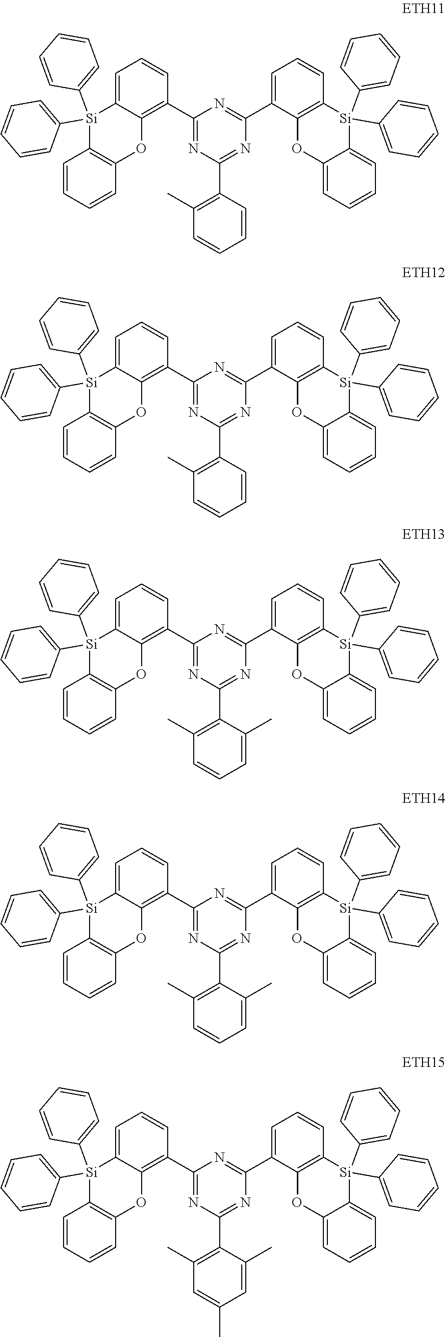

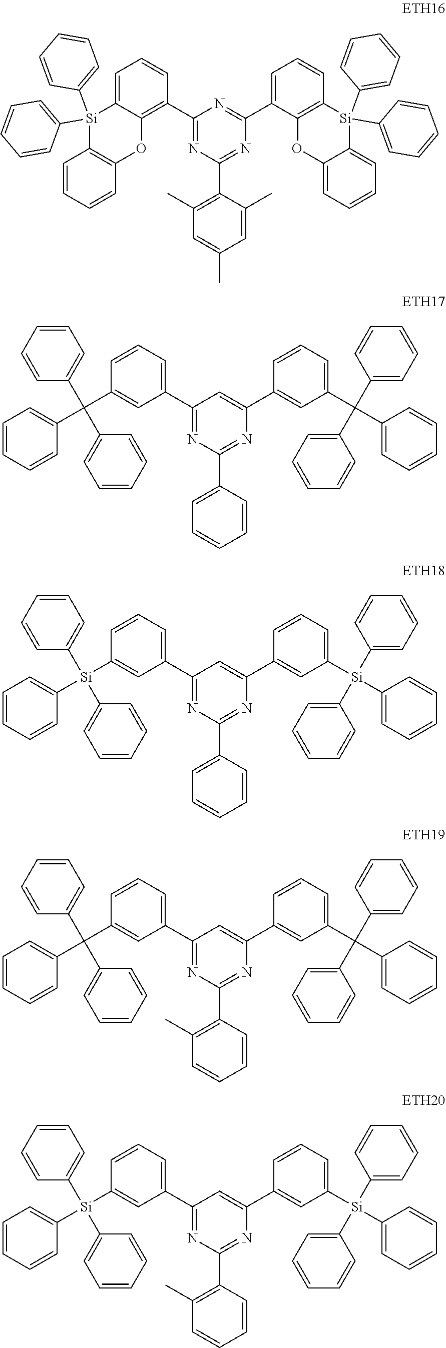

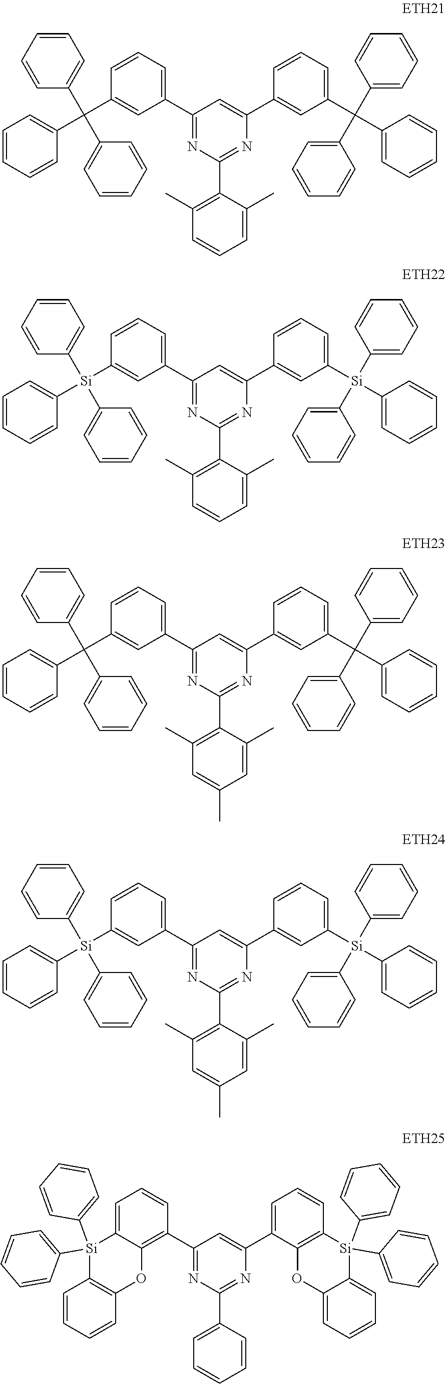

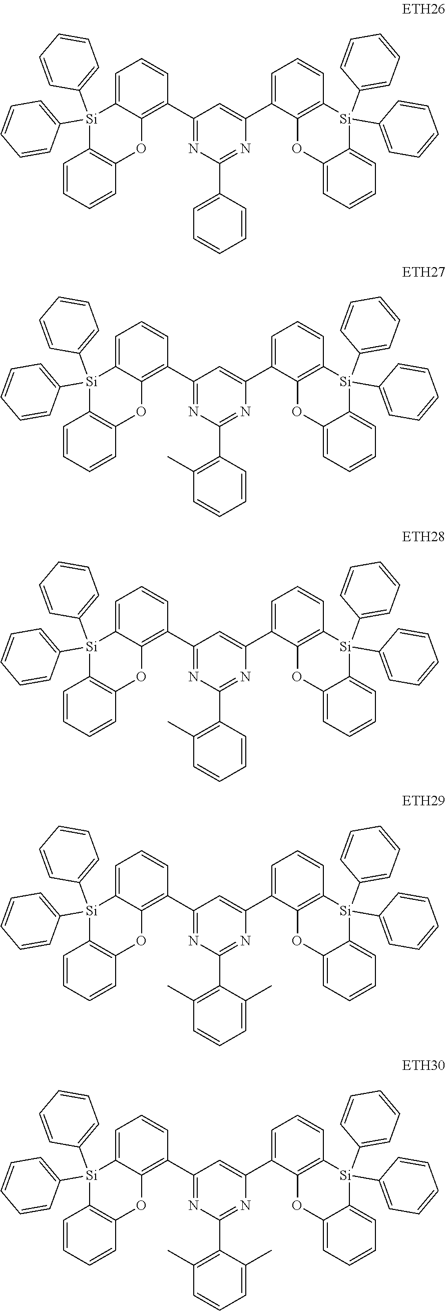

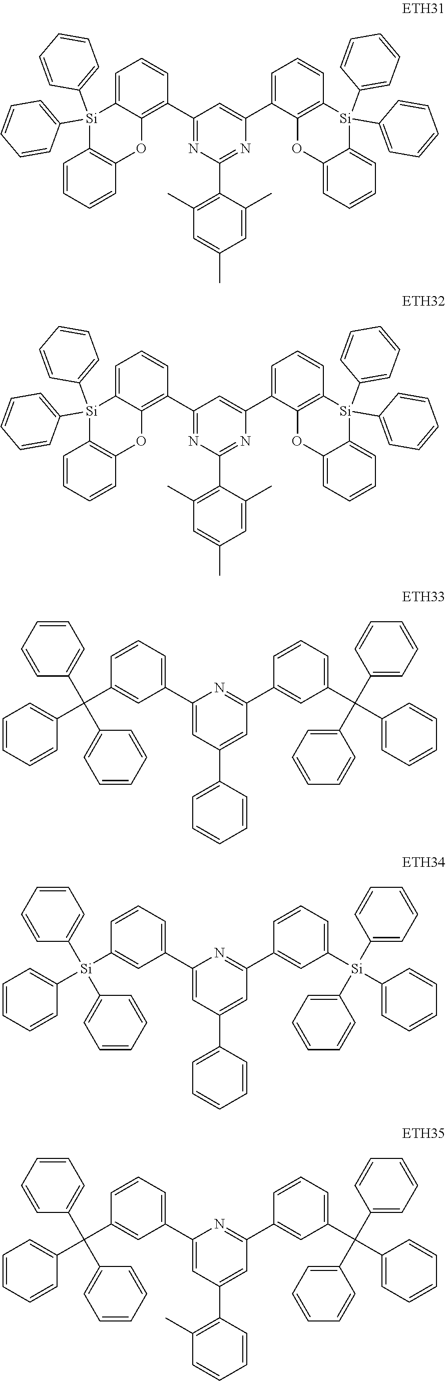

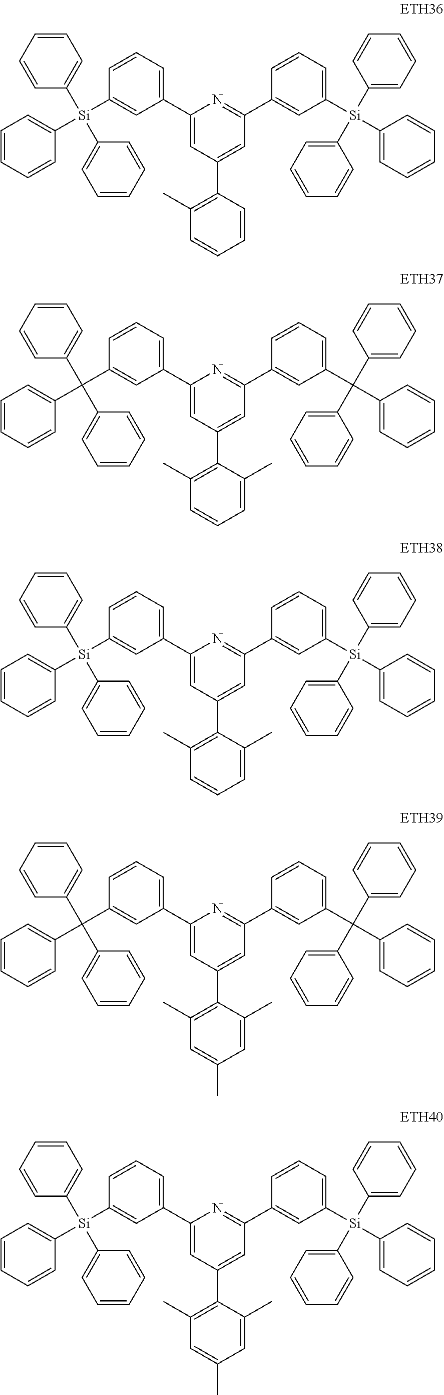

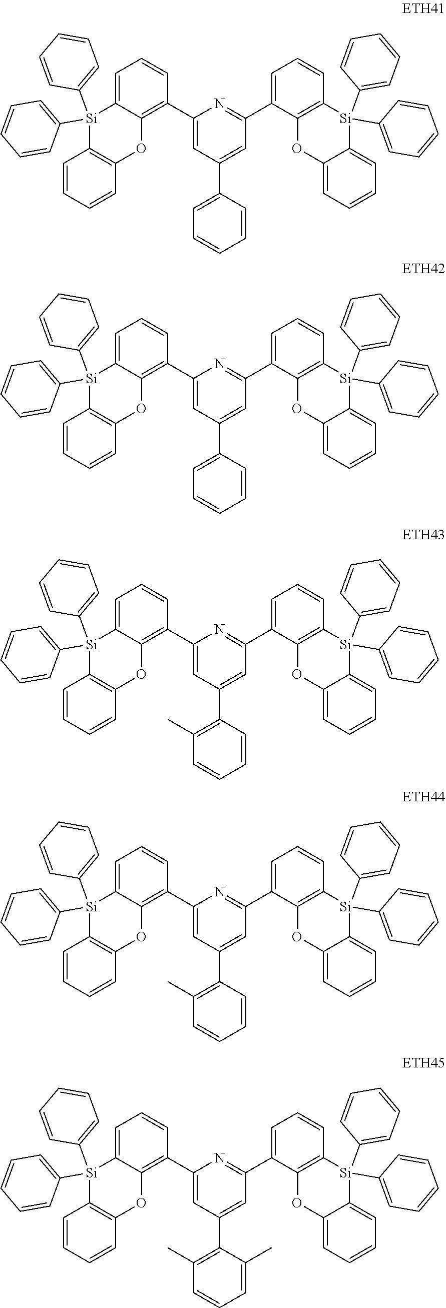

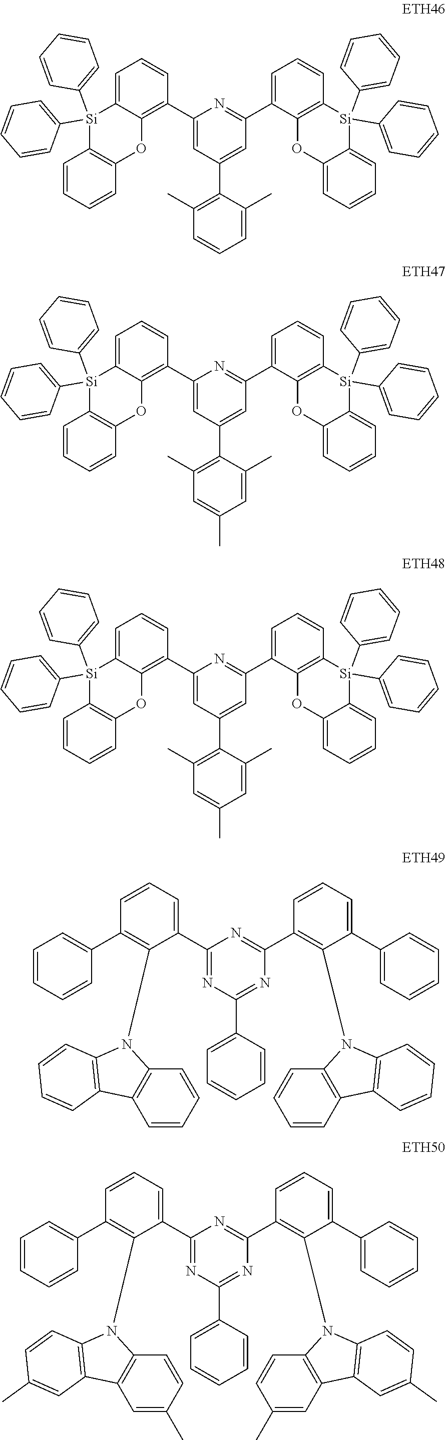

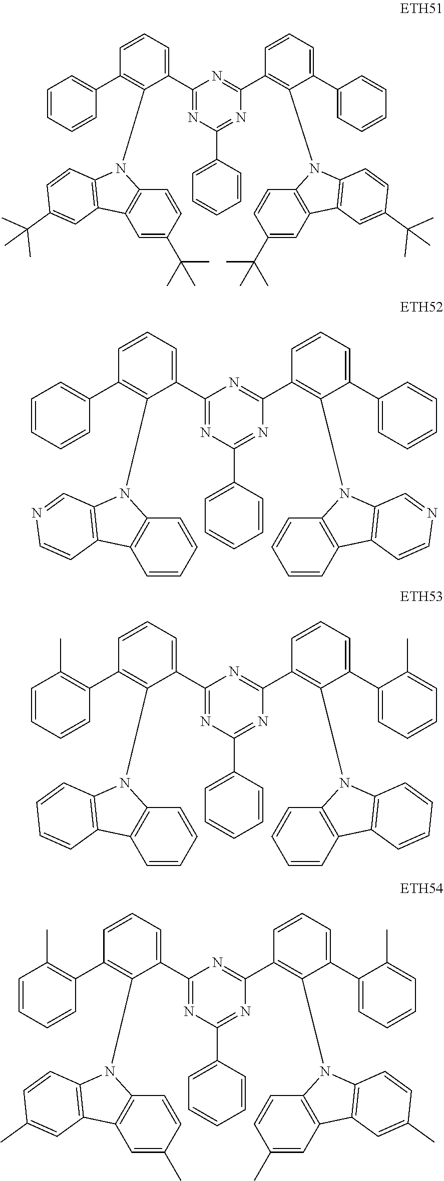

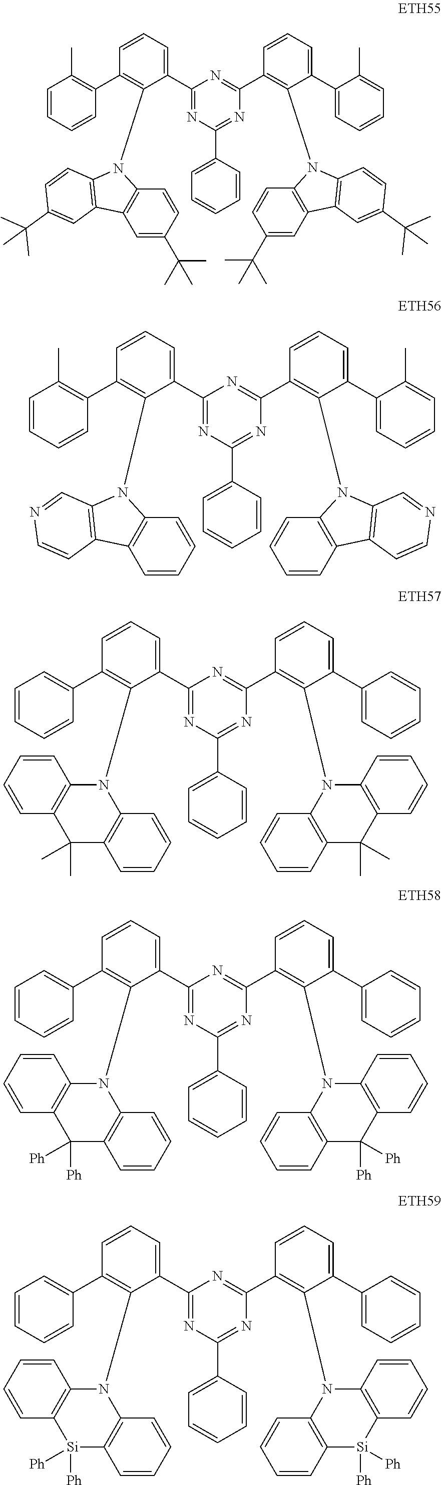

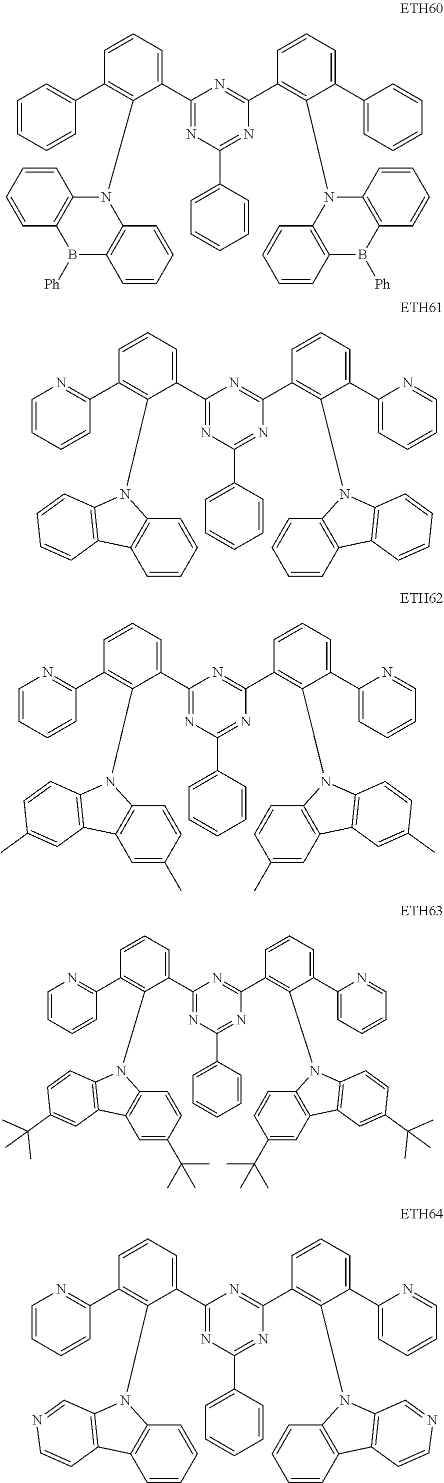

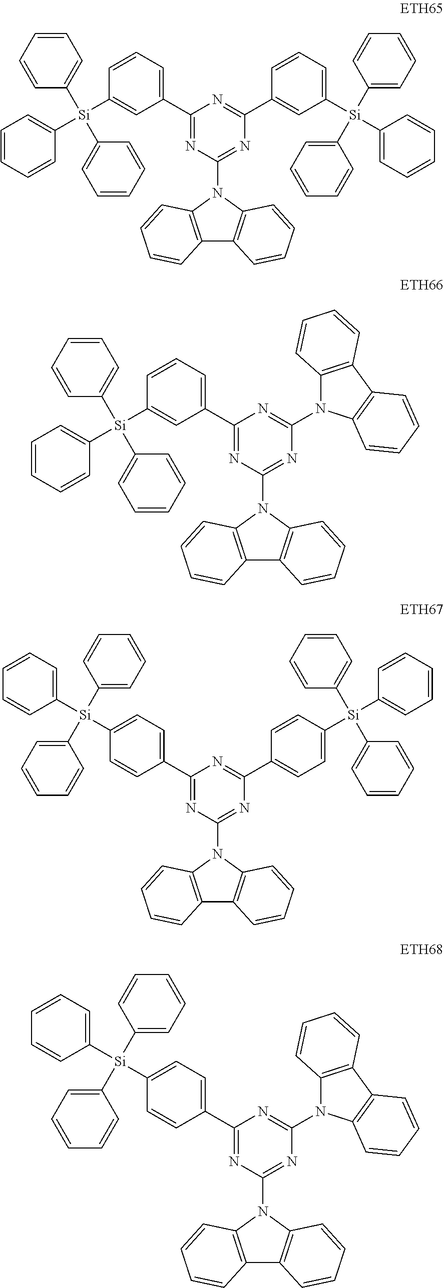 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

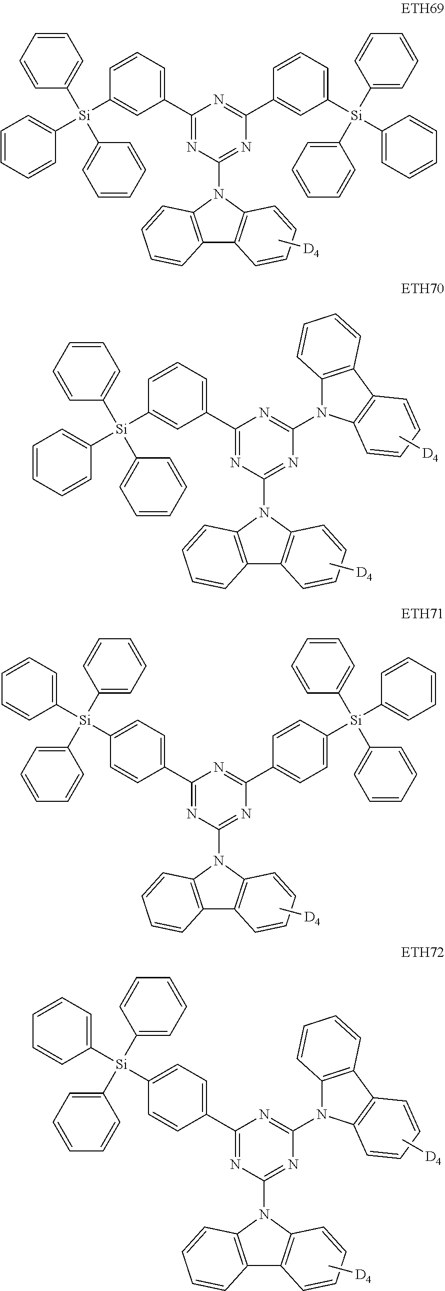

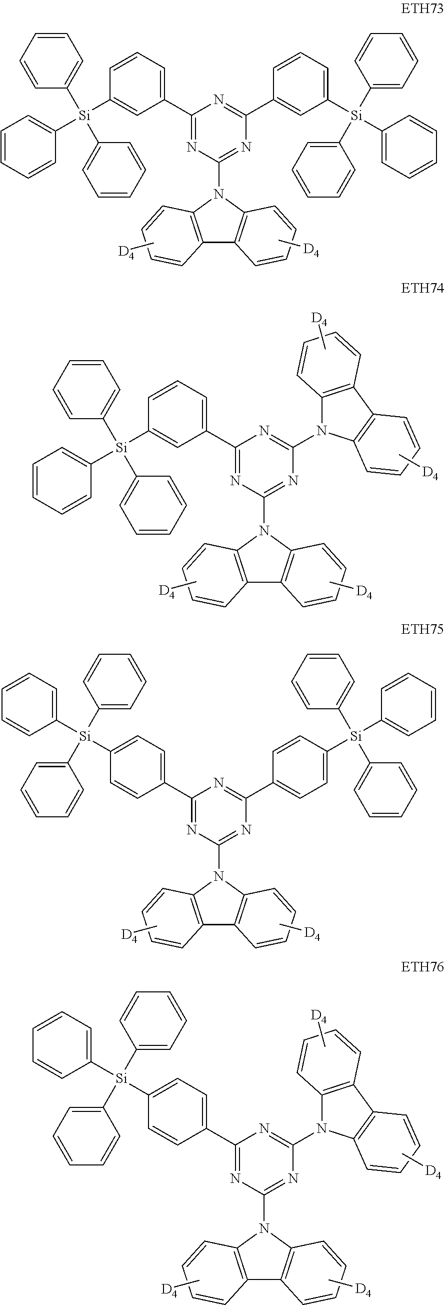

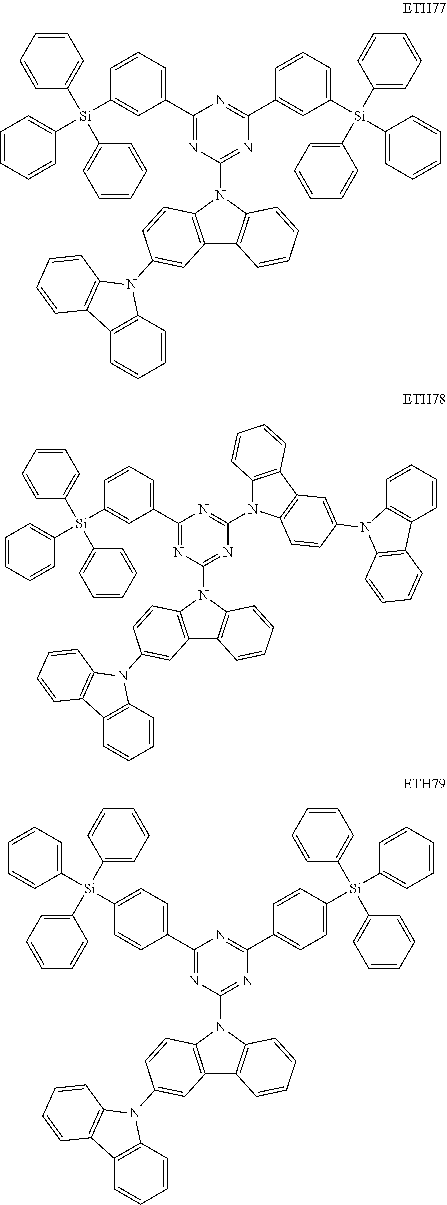 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

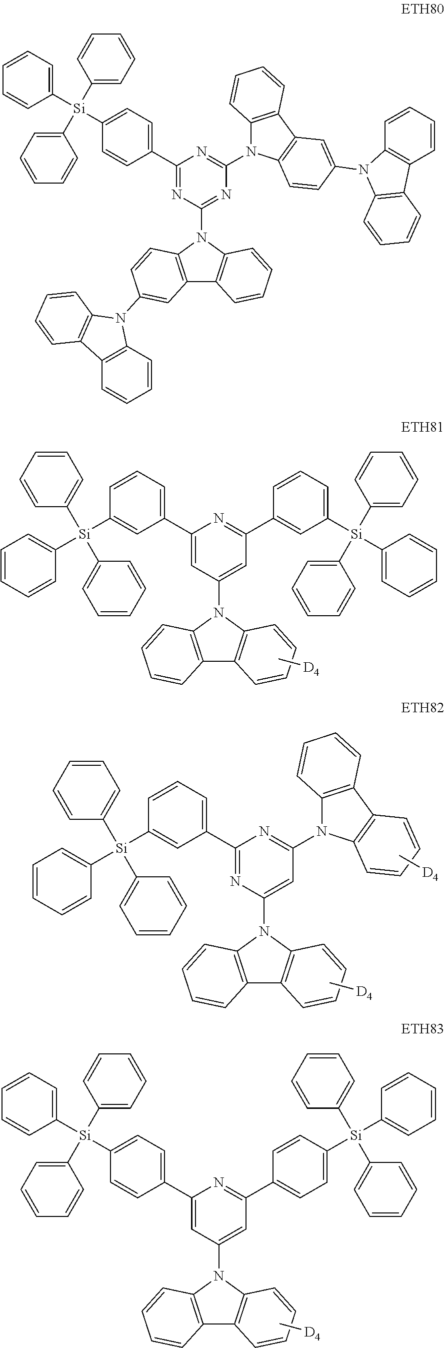

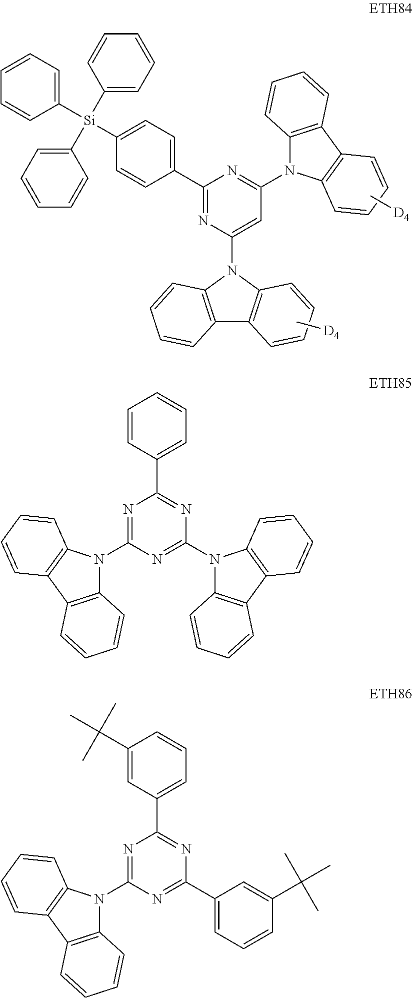

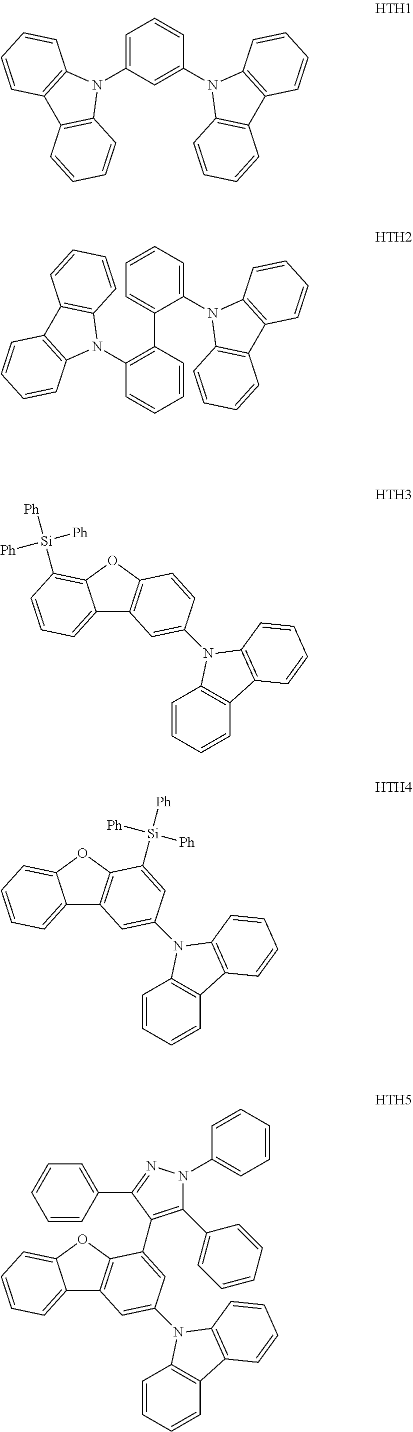 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1]

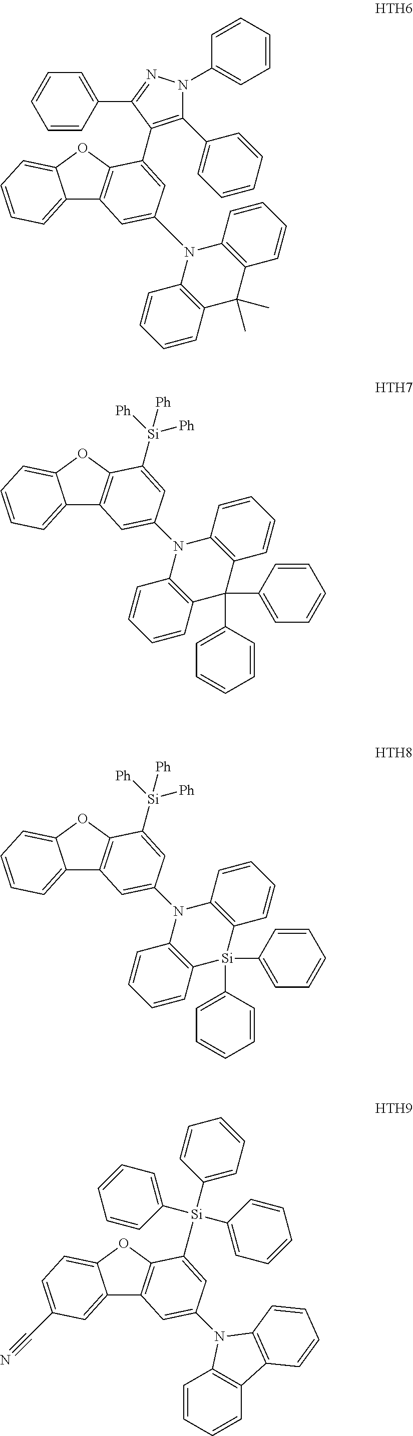 [SMILES: CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

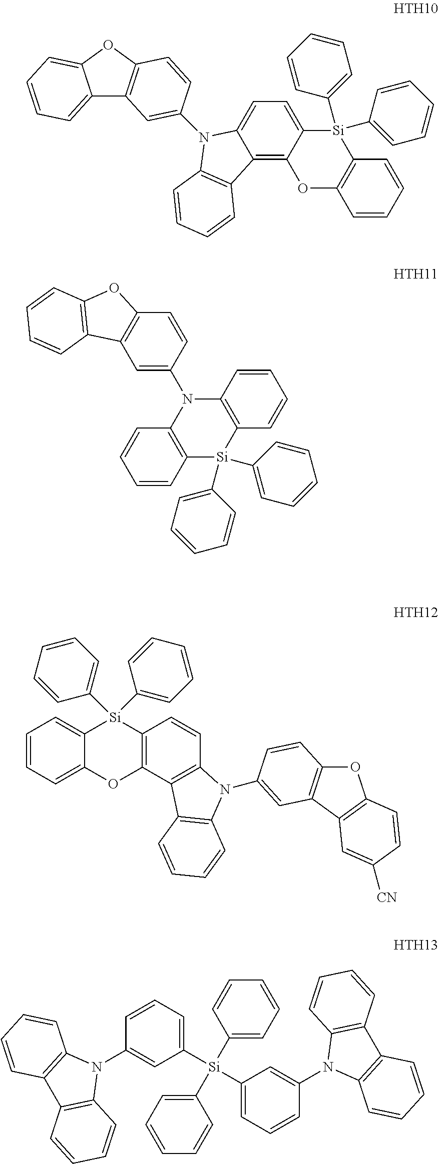 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

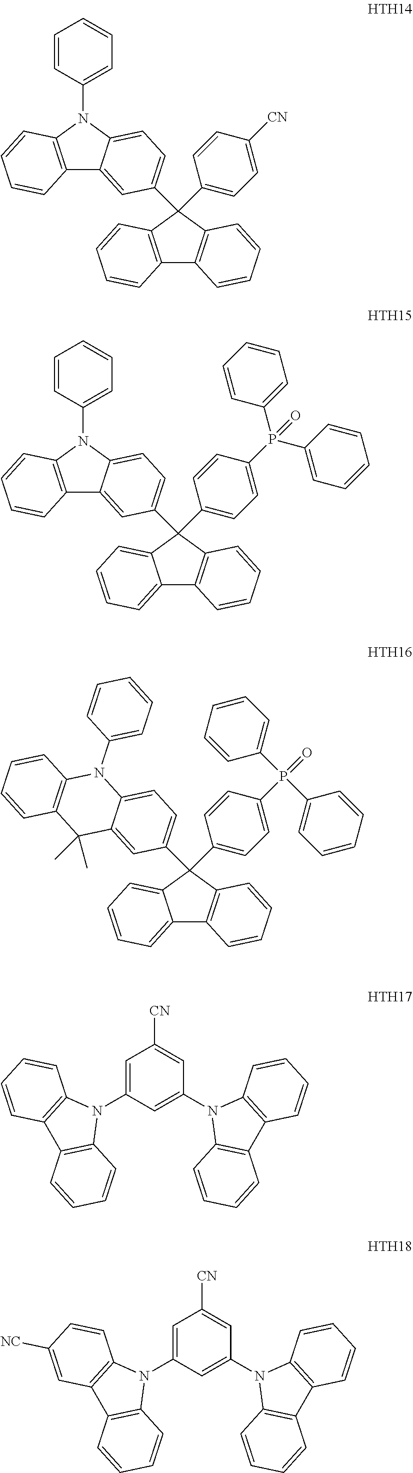 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

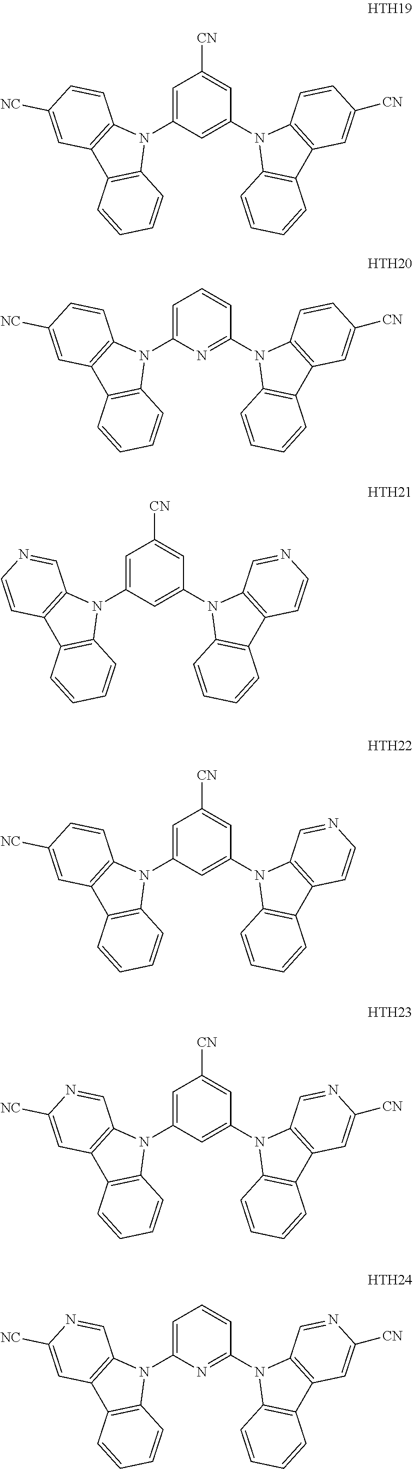 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

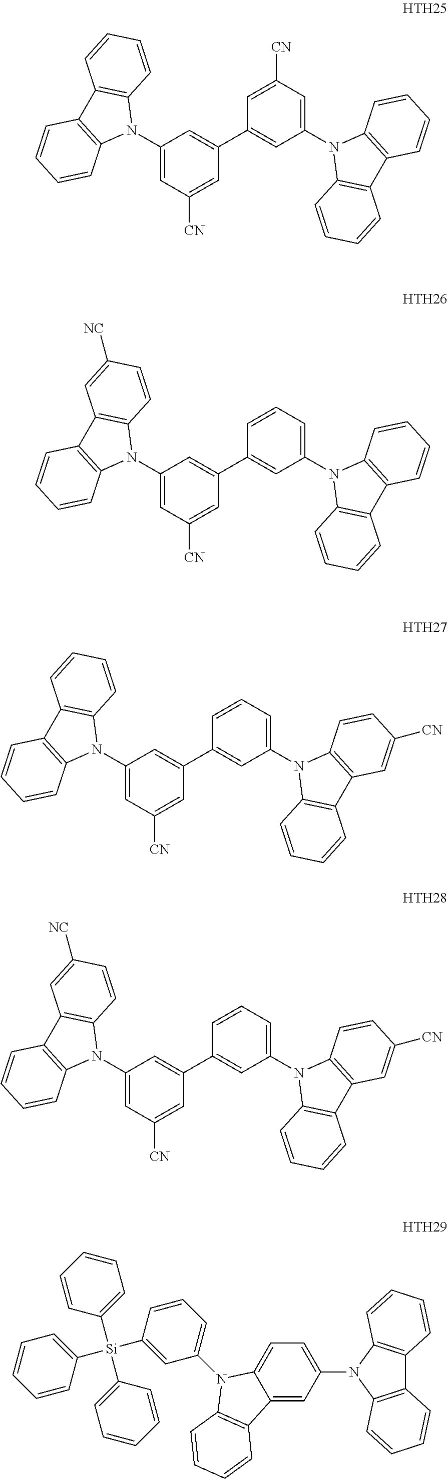 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

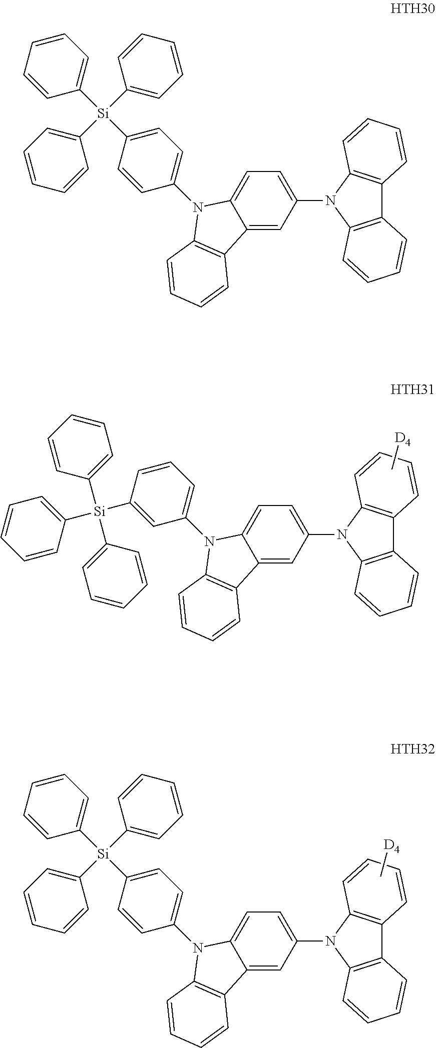

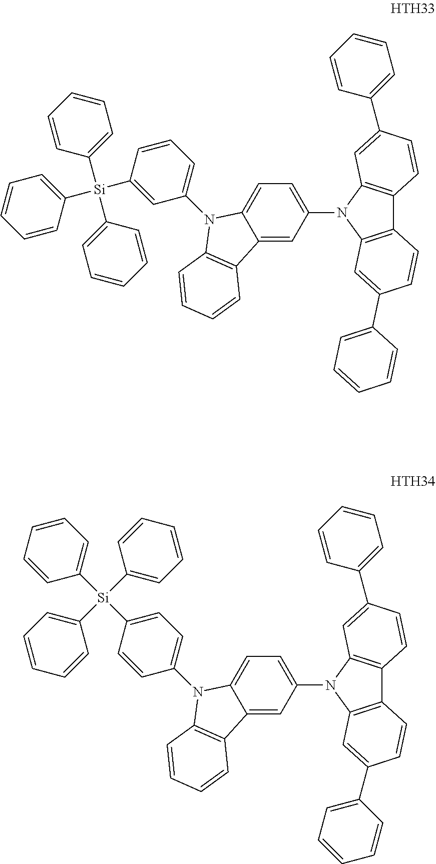 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

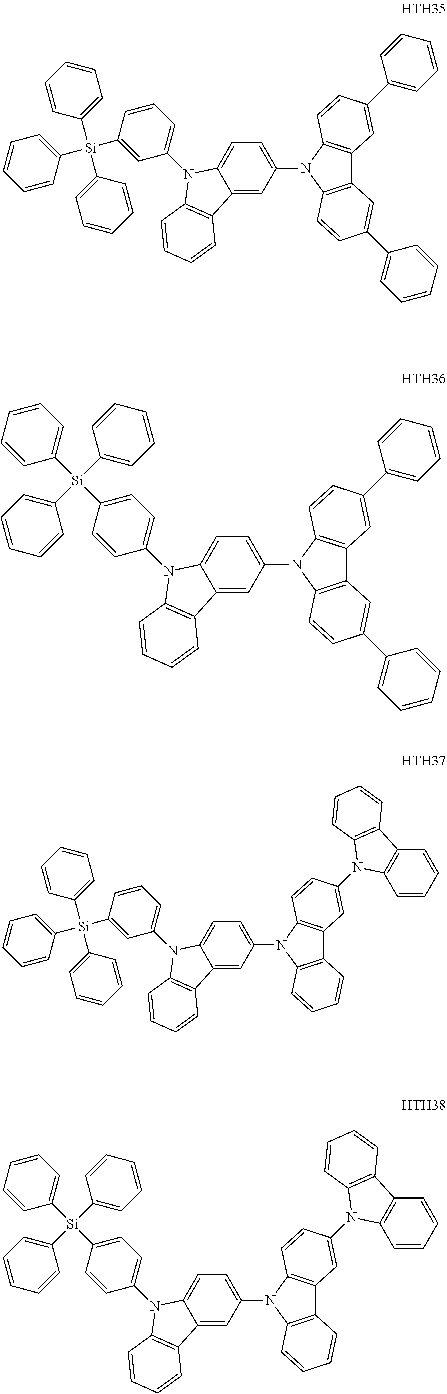 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

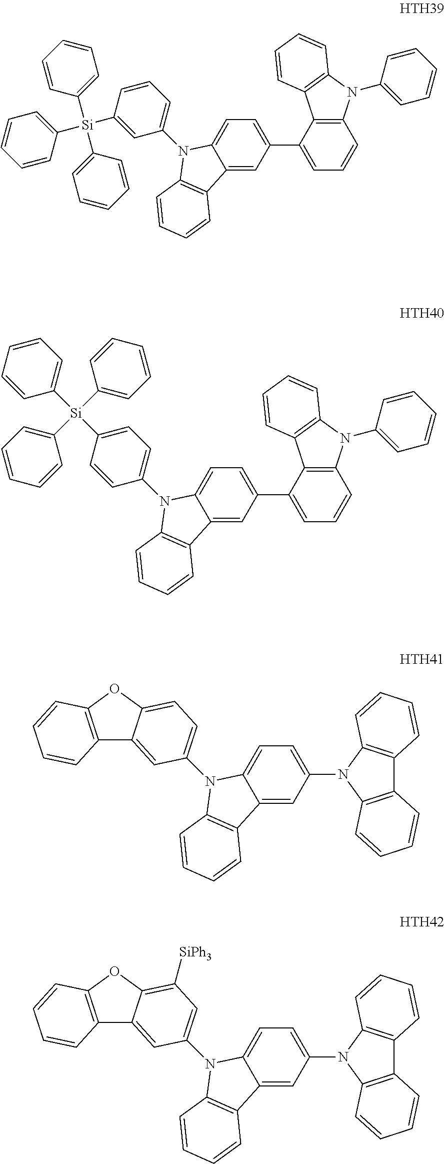

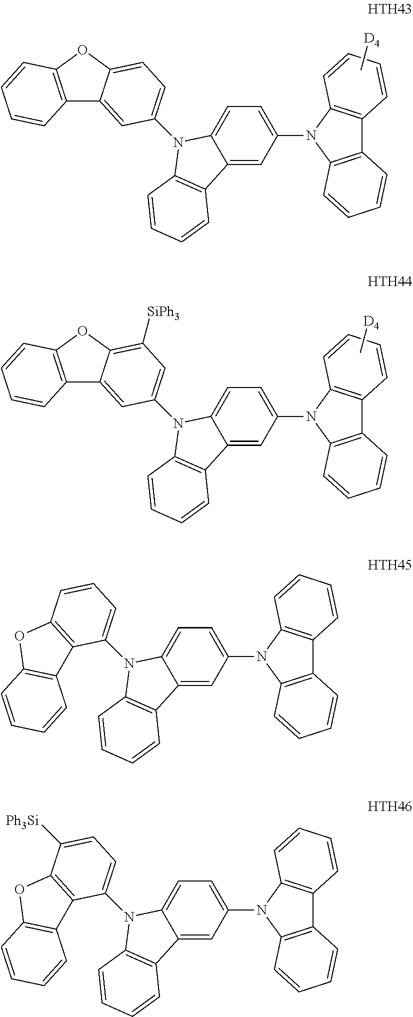

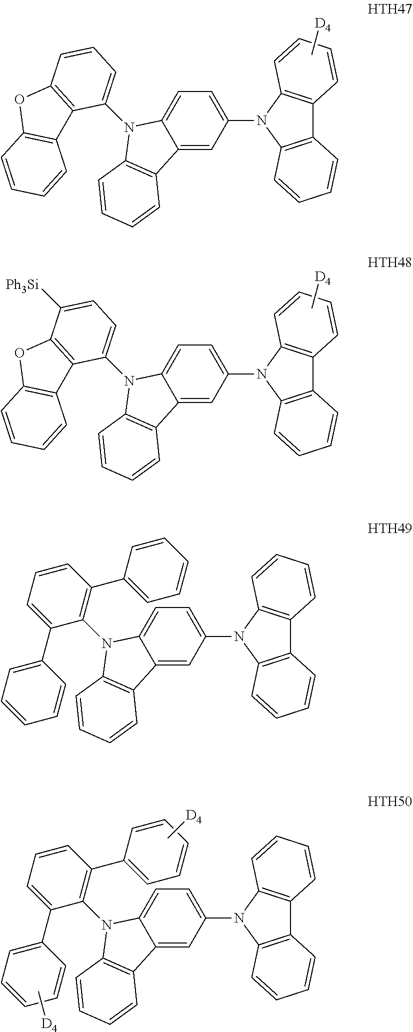

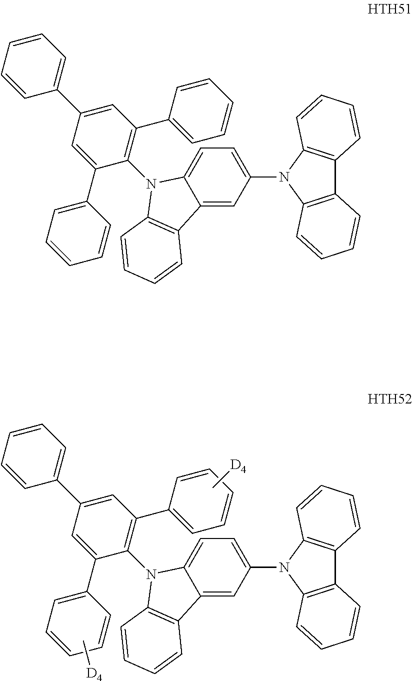

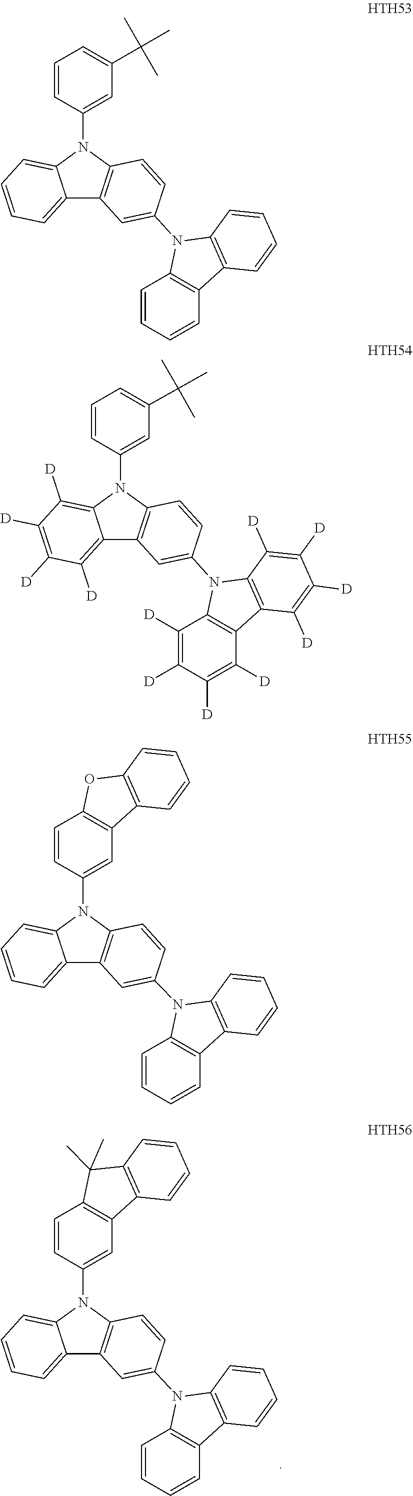

[Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include a fourth compound represented by Formula 401A.

In an embodiment, the phosphorescent dopant may include an organometallic compound represented by Formula 401:

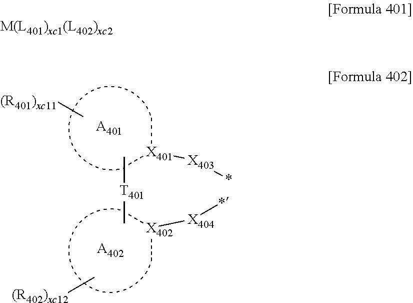

In Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is two or more, two or more L₄₀₁(5) may be identical to or different from each other,
L₄₀₂ may be an organic ligand, and xc2 may be 0, 1, 2, 3, or 4, wherein when xc2 is 2 or more, two or more L₄₀₂(5) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *=C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group that is unsubstituted or substituted with at least one R₁₀ₐ, a C₁-C₂₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described in connection with Q₁,
xc11 and xc12 may each independently be an integer from 0 to 10, and
* and *′ in Formula 402 may each indicate a binding site to M in Formula 401.

In an embodiment, in Formula 402, X₄₀₁ may be nitrogen and X₄₀₂ may be carbon, or X₄₀₁ and X₄₀₂ may each be nitrogen.

In an embodiment, in Formula 401, when xc1 is 2 or more, two ring A₄₀₁(5) among two or more L₄₀₁(5) may optionally be linked to each other via T₄₀₂, which is a linking group, and two ring A₄₀₂(5) among two or more L₄₀₁(5) may optionally be linked to each other via T₄₀₃, which is a linking group (see Compounds PD1 to PD4 and PD7). T₄₀₂ and T₄₀₃ may each independently be the same as described in connection with T₄₀₁.

In Formula 401, L₄₀₂ may be an organic ligand. For example, L₄₀₂ may include a halogen group, a diketone group (for example, an acetylacetonate group), a carboxylic acid group (for example, a picolinate group), —C(═O), an isonitrile group, —CN group, a phosphorus group (for example, a phosphine group or a phosphite group), or any combination thereof.

The phosphorescent dopant may include, for example, one of Compounds PD1 to PD41, or any combination thereof:

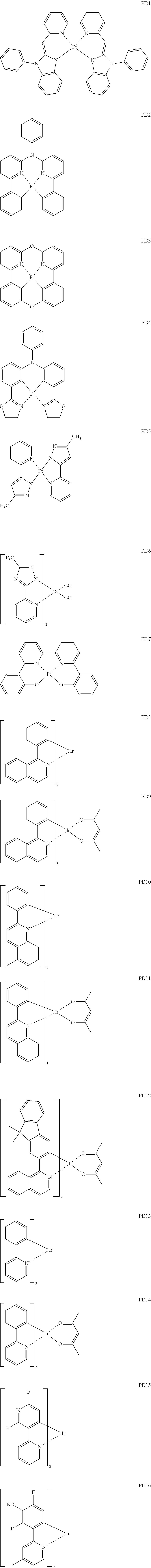

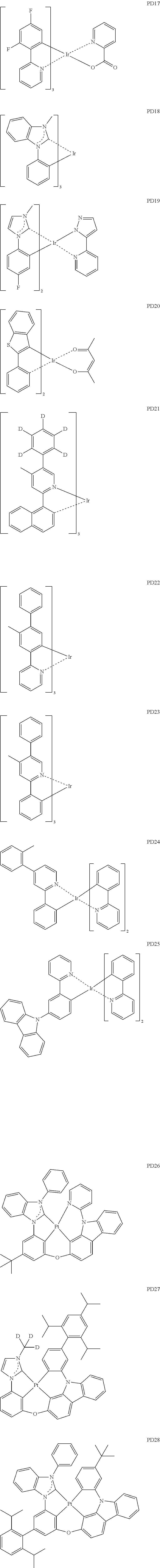

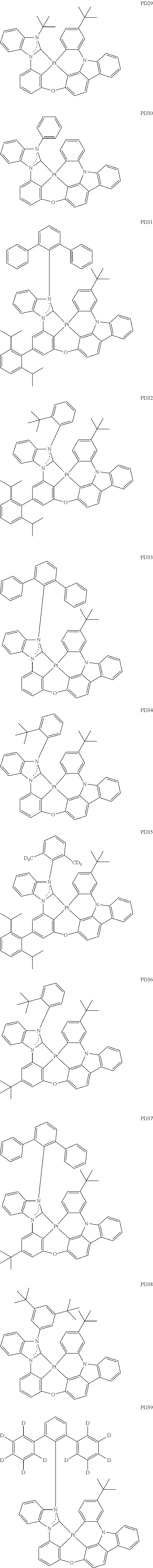

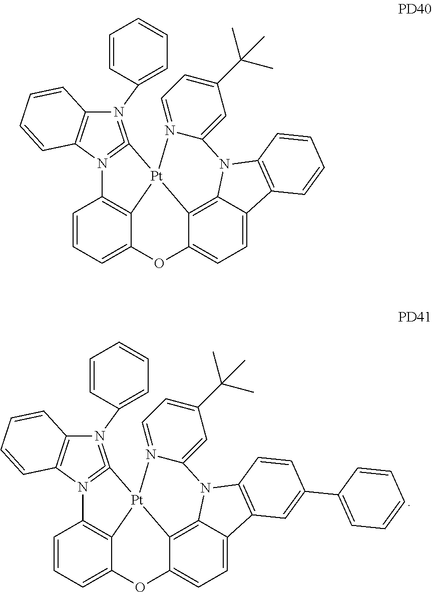

[Fluorescent Dopant]

The fluorescent dopant may include an amine group-containing compound, a styryl group-containing compound, or any combination thereof.

For example, the fluorescent dopant may include a compound represented by Formula 501:

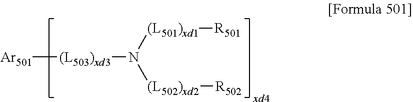

In Formula 501,
Ar₅₀₁, L₅₀₁ to L₅₀₃, R₅₀₁, and R₅₀₂ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xd1 to xd3 may each independently be an integer from 0, 1, 2, or 3, and
xd4 may be 1, 2, 3, 4, 5, or 6.

In an embodiment, in Formula 501, Ar₆₀₁ may be a condensed cyclic group (for example, an anthracene group, a chrysene group, or a pyrene group) in which three or more monocyclic groups are condensed with each other.

In an embodiment, in Formula 501, xd4 may be 2.

In an embodiment, the fluorescent dopant may include one of Compounds FD1 to FD36, DPVBi, DPAVBi, or any combination thereof:

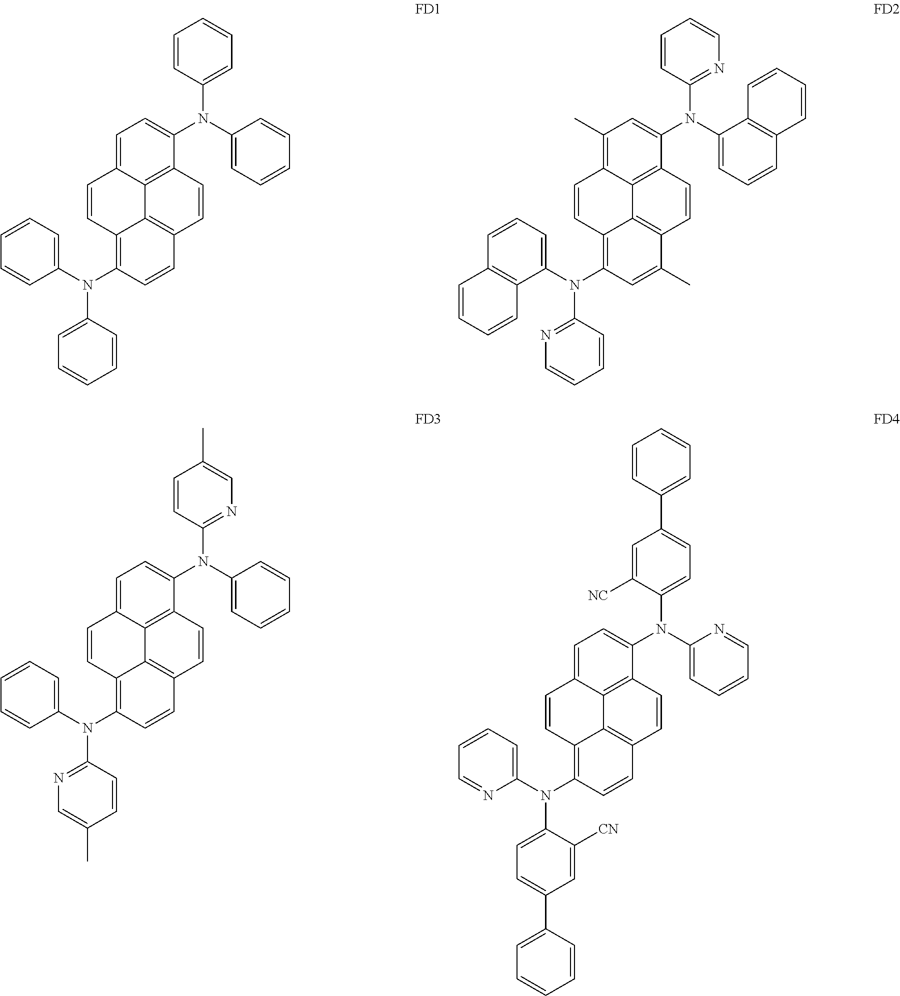 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1 ; N#Cc1cc(-c2ccccc2)ccc1N(c1ccccn1)c1ccc2ccc3c(N(c4ccccn4)c4ccc(-c5ccccc5)cc4C#N)ccc4ccc1c2c43]

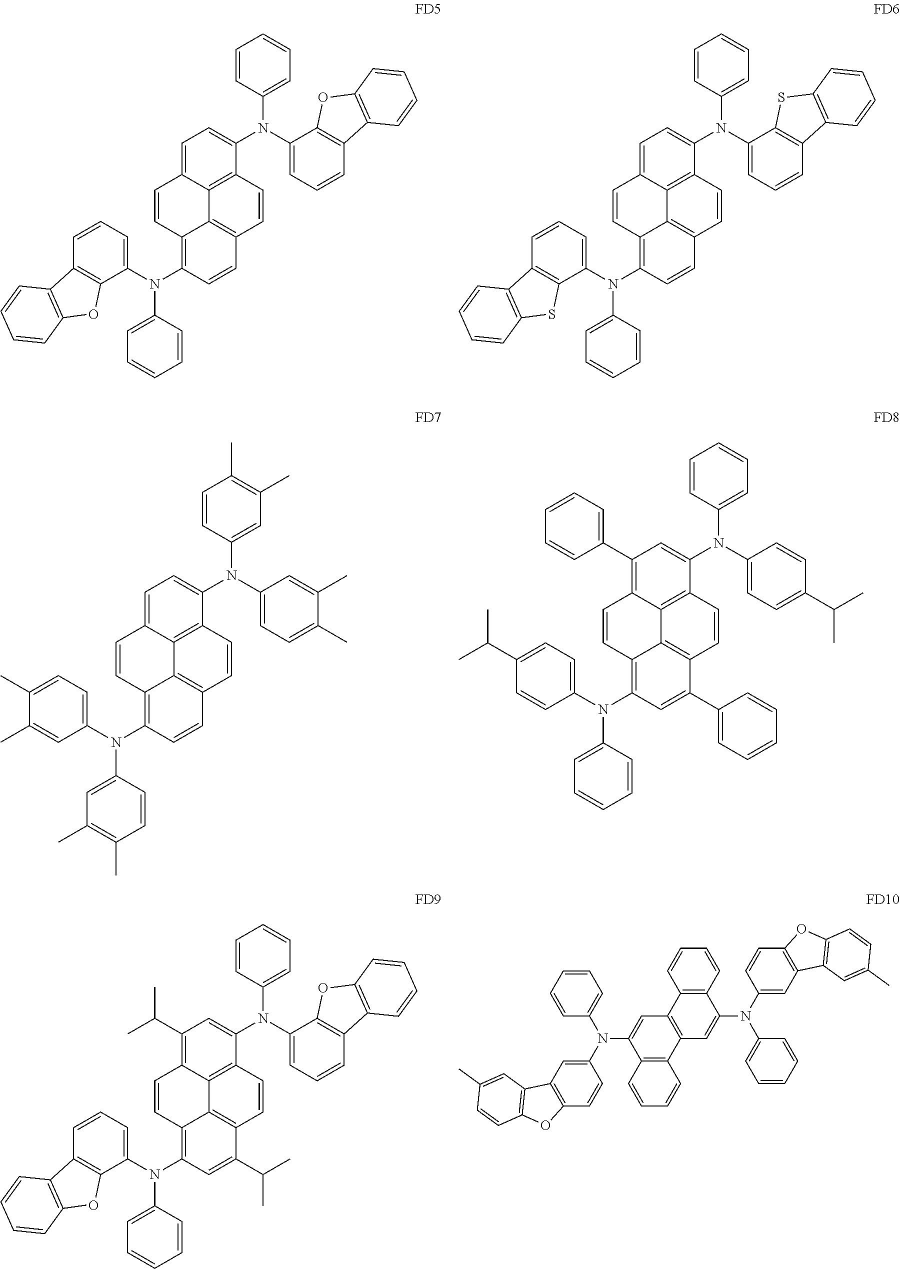

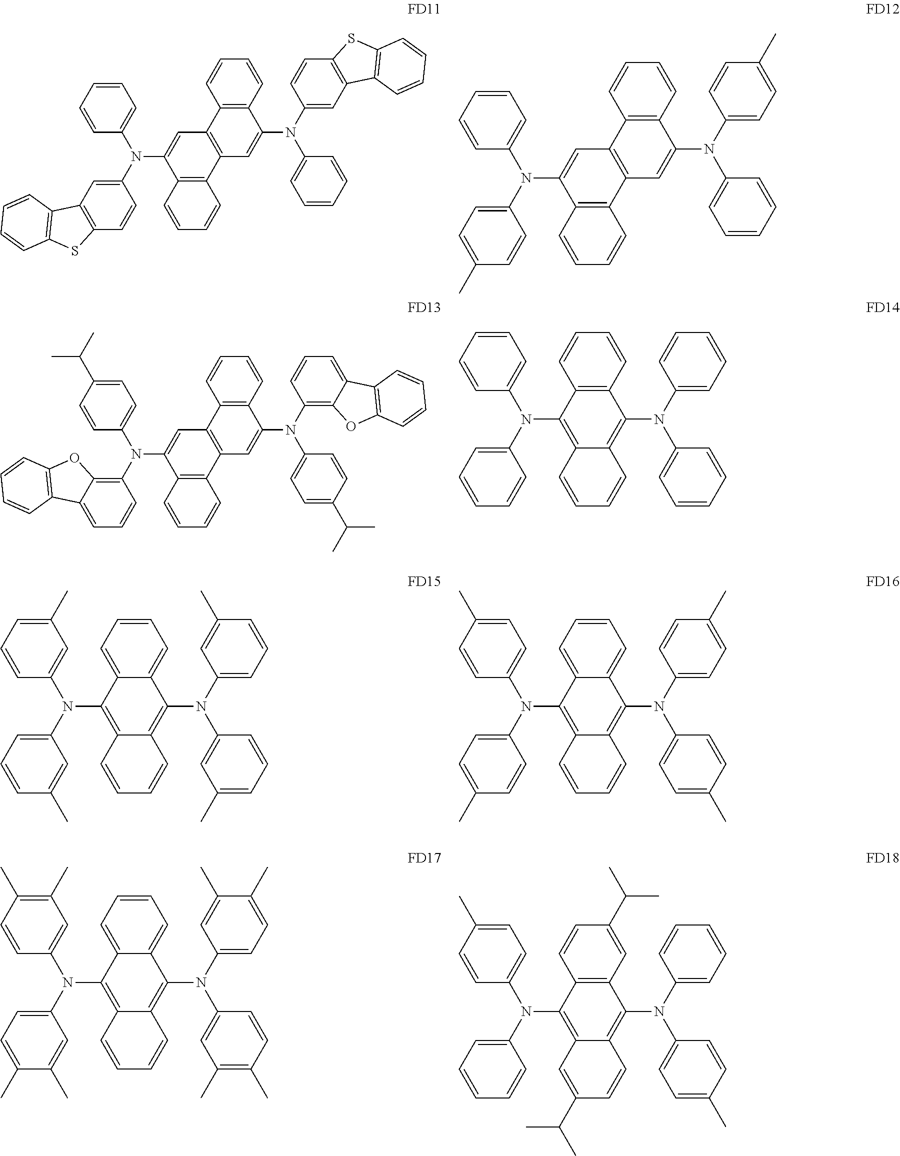

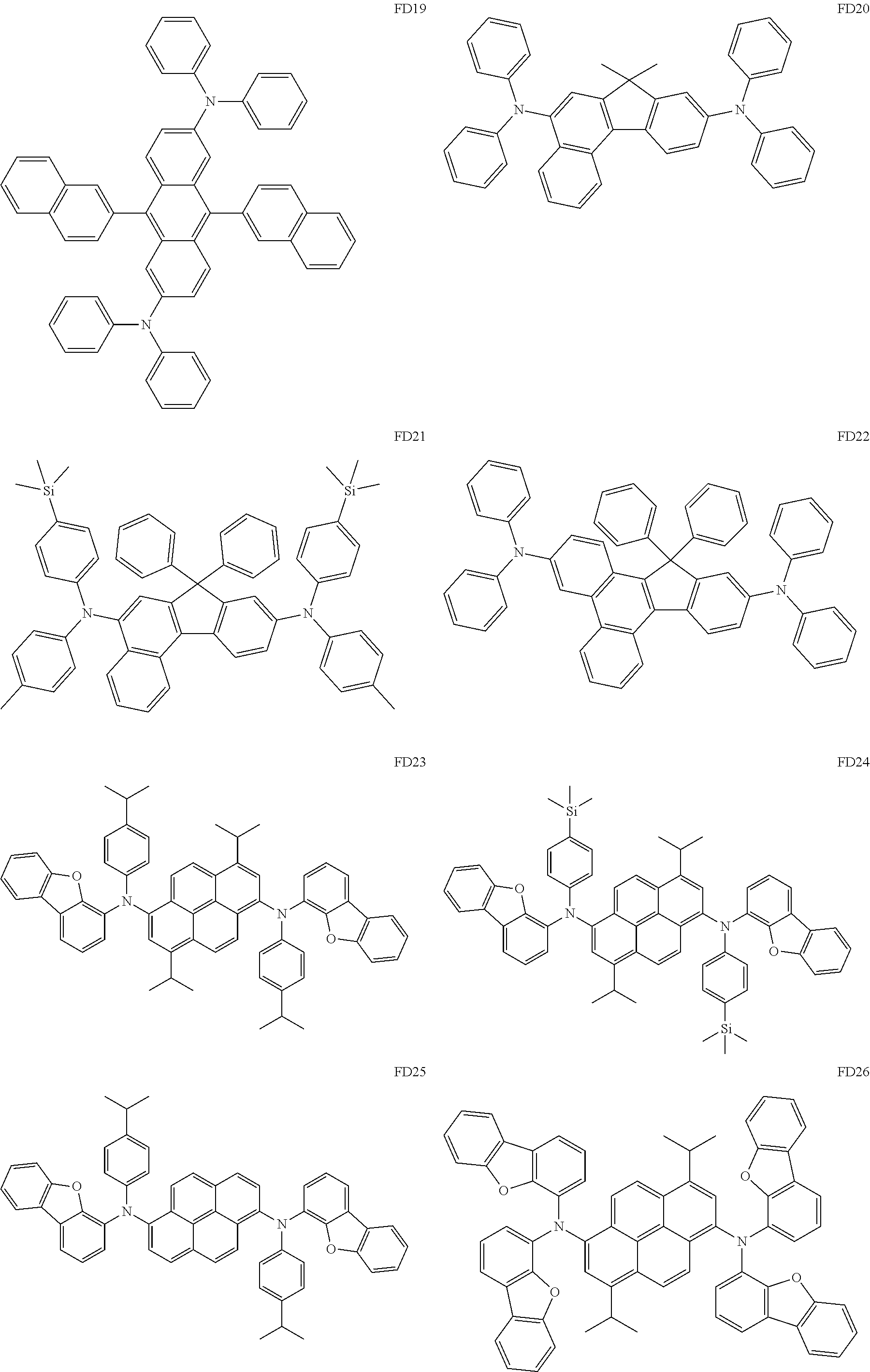

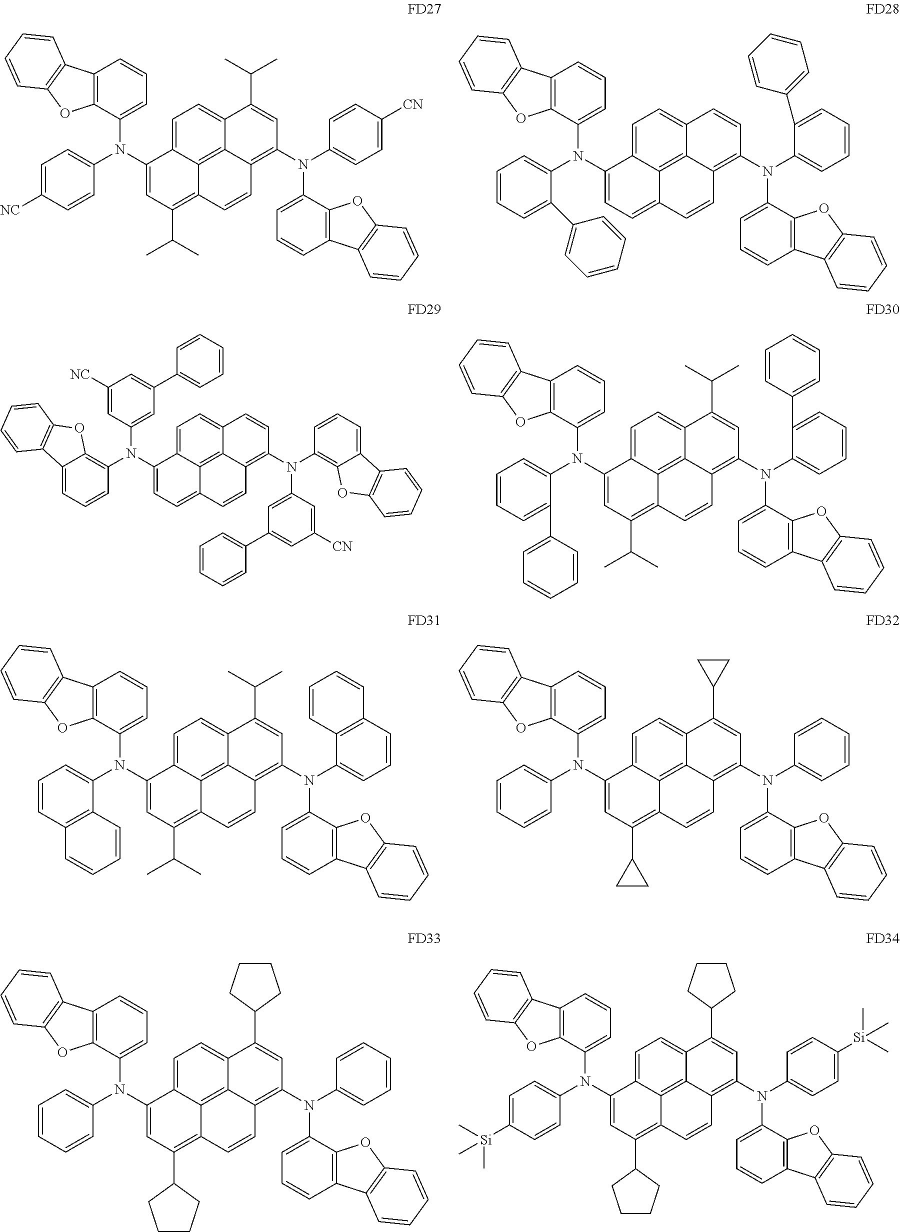

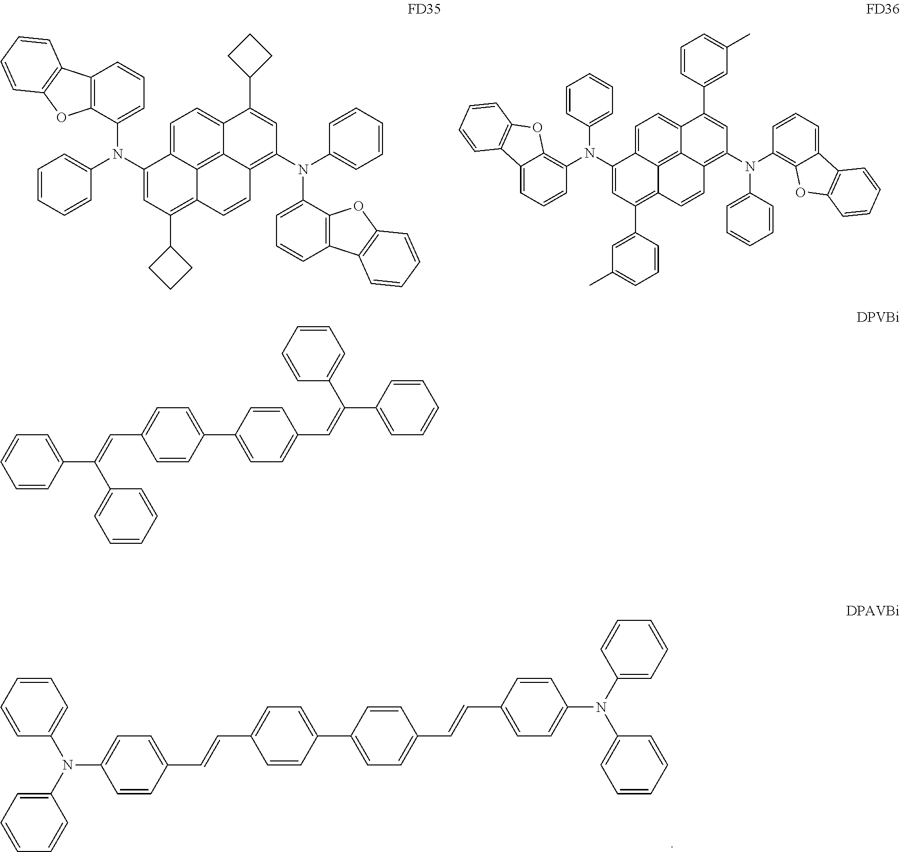

[Delayed Fluorescence Material]

The emission layer may include a delayed fluorescence material.

In the specification, the delayed fluorescence material may be selected from compounds capable of emitting delayed fluorescence based on a delayed fluorescence emission mechanism.

The delayed fluorescence material included in the emission layer may serve as a host or as a dopant, depending on the types of other materials included in the emission layer.

In an embodiment, the delayed fluorescence material may be the condensed cyclic compound represented by Formula 1.

In an embodiment, a difference between a triplet energy level (eV) of the delayed fluorescence material and a singlet energy level (eV) of the delayed fluorescence material may be greater than or equal to about 0 eV and less than or equal to about 0.5 eV. When the difference between the triplet energy level (eV) of the delayed fluorescence material and the singlet energy level (eV) of the delayed fluorescence material satisfies the above-described range, up-conversion from the triplet state to the singlet state of the delayed fluorescence materials may effectively occur, and thus, the luminescence efficiency of the light-emitting device 10 may be increased.

In an embodiment, the delayed fluorescence material may include: a material including at least one electron donor (for example, a π electron-rich C₃-C₆₀ cyclic group such as a carbazole group) and at least one electron acceptor (for example, a sulfoxide group, a cyano group, and a π electron-deficient nitrogen-containing C₁-C₆₀ cyclic group); a material including a C₈-C₆₀ polycyclic group in which two or more cyclic groups are condensed while sharing boron (B); or the like.

Examples of a delayed fluorescence material may include at least one of Compounds DF1 to DF9:

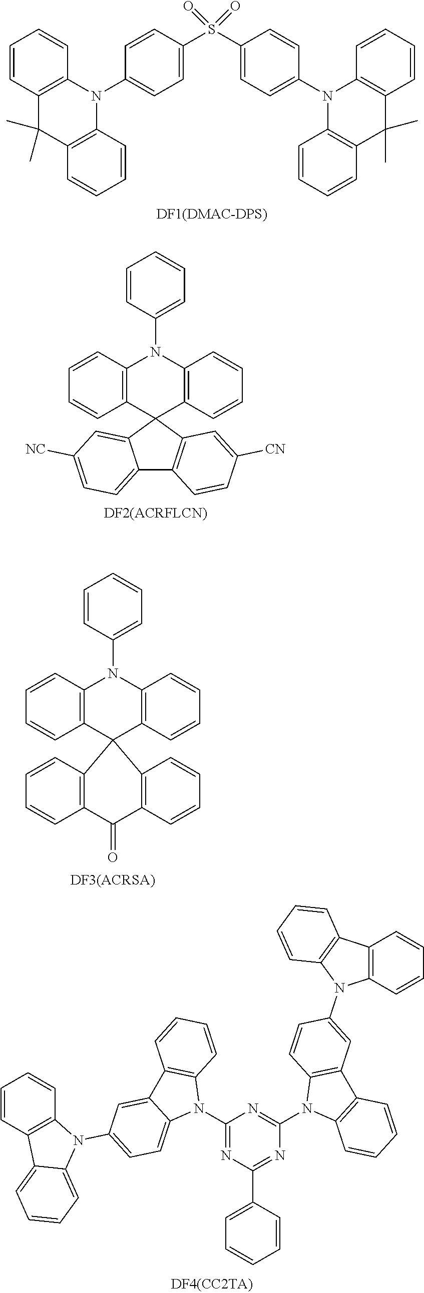

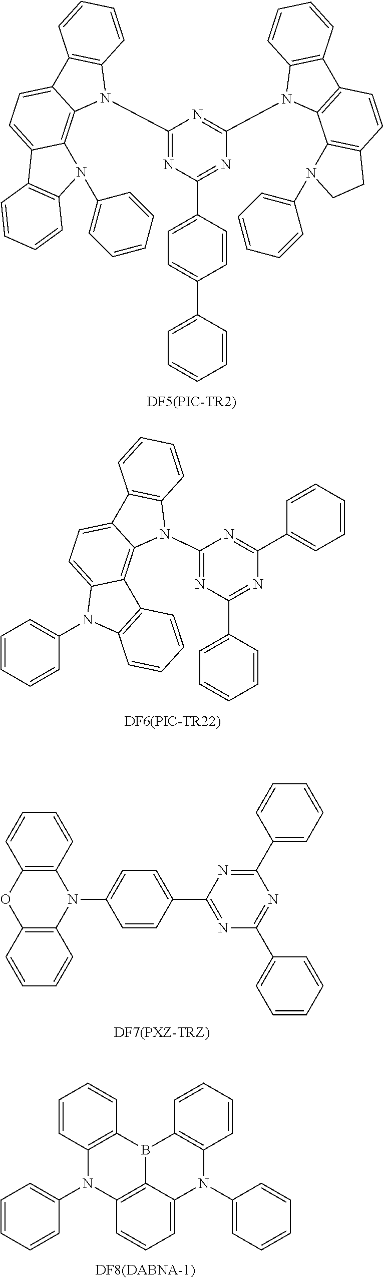 [SMILES: c1ccc(-c2ccc(-c3nc(-n4c5ccccc5c5ccc6c(c54)N(c4ccccc4)CC6)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1 ; c1ccc(N2c3ccccc3B3c4ccccc4N(c4ccccc4)c4cccc2c43)cc1]

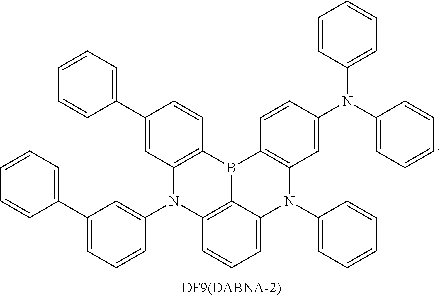 [SMILES: c1ccc(-c2cccc(N3c4cc(-c5ccccc5)ccc4B4c5ccc(N(c6ccccc6)c6ccccc6)cc5N(c5ccccc5)c5cccc3c54)c2)cc1]

[Quantum Dot]

The emission layer may include a quantum dot.

In the specification, a quantum dot may be a crystal of a semiconductor compound, and may include any material capable of emitting light of various emission wavelengths according to a size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method that includes mixing a precursor material with an organic solvent and growing quantum dot particle crystals. When the crystal grows, the organic solvent naturally acts as a dispersant coordinated on the surface of the quantum dot crystal and controls the growth of the crystal so that the growth of quantum dot particles may be controlled through a process which costs less, and may be more readily performed than vapor deposition methods, such as metal organic chemical vapor deposition (MOCVD) or molecular beam epitaxy (MBE).

The quantum dot may include a Group II-VI semiconductor compound, a Group III-V semiconductor compound, a Group III-VI semiconductor compound, a Group I—III-VI semiconductor compound, a Group IV-VI semiconductor compound, a Group IV element or compound, or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CdZnSeS, CdZnSeTe, CdZnSTe, CdHgSeS, CdHgSeTe, CdHgSTe, HgZnSeS, HgZnSeTe, or HgZnSTe; or any combination thereof.

Examples of a Group III-V semiconductor compound may include: a binary compound, such as GaN, GaP, GaAs, GaSb, AlN, AlP, AIAs, AlSb, InN, InP, InAs, or InSb; a ternary compound, such as GaNP, GaNAs, GaNSb, GaPAs, GaPSb, AINP, AINAs, AINSb, AIPAs, AIPSb, InGaP, InNP, InAlP, InNAs, InNSb, InPAs, or InPSb; a quaternary compound, such as GaAINP, GaAINAs, GaAINSb, GaAIPAs, GaAIPSb, GaInNP, GaInNAs, GaInNSb, GaInPAs, GaInPSb, InAINP, InAINAs, InAINSb, InAIPAs, or InAIPSb; or any combination thereof. In an embodiment, the Group III-V semiconductor compound may further include a Group II element. Examples of the Group III-V semiconductor compound further including a Group II element may include InZnP, InGaZnP, InAlZnP, and the like.

Examples of a Group III-VI semiconductor compound may include: a binary compound, such GaS, GaSe, Ga₂Se₃, GaTe, InS, InSe, In₂S₃, In₂Se₃, or InTe; a ternary compound, such as InGaS₃, or InGaSe₃; or any combination thereof.

Examples of a Group I-III-VI semiconductor compound may include: a ternary compound, such as AgInS, AgInS₂, CuInS, CuInS₂, CuGaO₂, AgGaO₂, or AgAlO₂; or any combination thereof.

Examples of a Group IV-VI semiconductor compound may include: a binary compound, such as SnS, SnSe, SnTe, PbS, PbSe, PbTe, or the like; a ternary compound, such as SnSeS, SnSeTe, SnSTe, PbSeS, PbSeTe, PbSTe, SnPbS, SnPbSe, SnPbTe, or the like; a quaternary compound, such as SnPbSSe, SnPbSeTe, SnPbSTe, or the like; or any combination thereof.

Examples of a Group IV element or compound may include: a single element material, such as Si or Ge; a binary compound, such as SiC or SiGe; or any combination thereof.

Each element included in a multi-element compound such as a binary compound, a ternary compound, and a quaternary compound, may exist in a particle at a uniform concentration or at a non-uniform concentration.

In an embodiment, the quantum dot may have a single structure or a core-shell structure. When the quantum dot has a single structure, the concentration of each element included in a quantum dot may be uniform. When the quantum dot has a core-shell structure, a material included in the core and a material included in the shell may be different from each other.

The shell of the quantum dot may serve as a protective layer that prevents chemical degeneration of the core to maintain semiconductor characteristics and/or may serve as a charging layer that imparts electrophoretic characteristics to the quantum dot. The shell may be a single layer or a multi-layer. An interface between the core and the shell of the quantum dot may have a concentration gradient in which the concentration of a material that is present in the shell decreases toward the core.

Examples of a material forming the shell of the quantum dot may include a metal oxide, a metalloid oxide, a non-metal oxide, a semiconductor compound, or any combination thereof. Examples of the metal oxide, the metalloid oxide, or the non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound, such as MgAl₂O₄, CoFe₂O₄, NiFe₂O₄, or CoMn₂O₄; or any combination thereof. Examples of the semiconductor compound may include, as described herein, a Group II-VI semiconductor compound, a Group III-V semiconductor compound, a Group III-VI semiconductor compound, a Group I-III-VI semiconductor compound, a Group IV-VI semiconductor compound, or any combination thereof. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of an emission wavelength spectrum of the quantum dot may be equal to or less than about 45 nm. For example, a FWHM of an emission wavelength spectrum of the quantum dot may be equal to or less than about 40 nm. For example, a FWHM of an emission wavelength spectrum of the quantum dot may be equal to or less than about 30 nm. Within these ranges, color purity or color reproducibility may be increased. Light emitted through the quantum dot may be emitted in all directions, so that a wide viewing angle may be improved.

The quantum dot may be a spherical nanoparticle, a pyramidal nanoparticle, a multi-arm nanoparticle, a cubic nanoparticle, a nanotube, a nanowire, a nanofiber, or a nanoplate particle.

Because the energy band gap may be adjusted by controlling the size of the quantum dot, light having various wavelength bands may be obtained from a quantum dot emission layer. Therefore, by using quantum dots of different sizes, a light-emitting device that emits light of various wavelengths may be implemented. In an embodiment, the size of the quantum dot may be selected to emit red, green, and/or blue light. The size of the quantum dot may be configured to emit white light by combining light of various colors.

[Electron Transport Region in Interlayer 130]

The electron transport region may have a structure consisting of a layer consisting of a single material, a structure consisting of a layer including different materials, or a structure including multiple layers including different materials.

The electron transport region may include a buffer layer, a hole blocking layer, an electron control layer, an electron transport layer, an electron injection layer, or any combination thereof.

In an embodiment, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers of each structure may be stacked from an emission layer in its respective stated order, but the structure of the electron transport region is not limited thereto.

The electron transport region (for example, a buffer layer, a hole blocking layer, an electron control layer, or an electron transport layer in the electron transport region) may include a metal-free compound including at least one π electron-deficient nitrogen-containing C₁-C₆₀ cyclic group.

In an embodiment, the electron transport region may include a compound represented by Formula 601:

[Ar₆₀₁]ₓₑ₁₁-[(L₆₀₁)ₓₑ₁-R₆₀₁]ₓₑ₂₁ [Formula 601]

In Formula 601,
Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₂₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be air electron-deficient nitrogen-containing C₁-C₆₀ cyclic group that is unsubstituted or substituted with at least one R₁₀ₐ.

In an embodiment, in Formula 601, when xe11 is 2 or more, two or more Ar₆₀₁(s) may be linked to each other via a single bond.

In an embodiment, in Formula 601, Ar₆₀₁ may be a substituted or unsubstituted anthracene group.

In an embodiment, the electron transport region may include a compound represented by Formula 601-1:

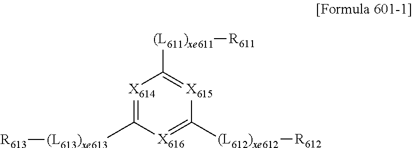

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀carbocyclic group that is unsubstituted or substituted with at least one R₁₀ₐ, or a C₁-C₆₀ heterocyclic group that is unsubstituted or substituted with at least one R₁₀ₐ.

In an embodiment, in Formulae 601 and 601-1, xe1 and xe611 to xe613 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

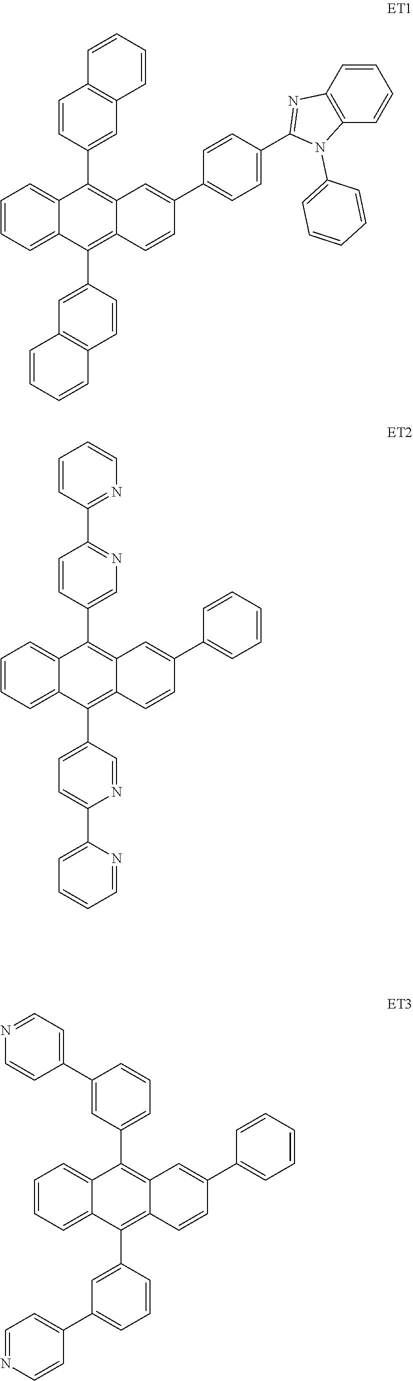 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

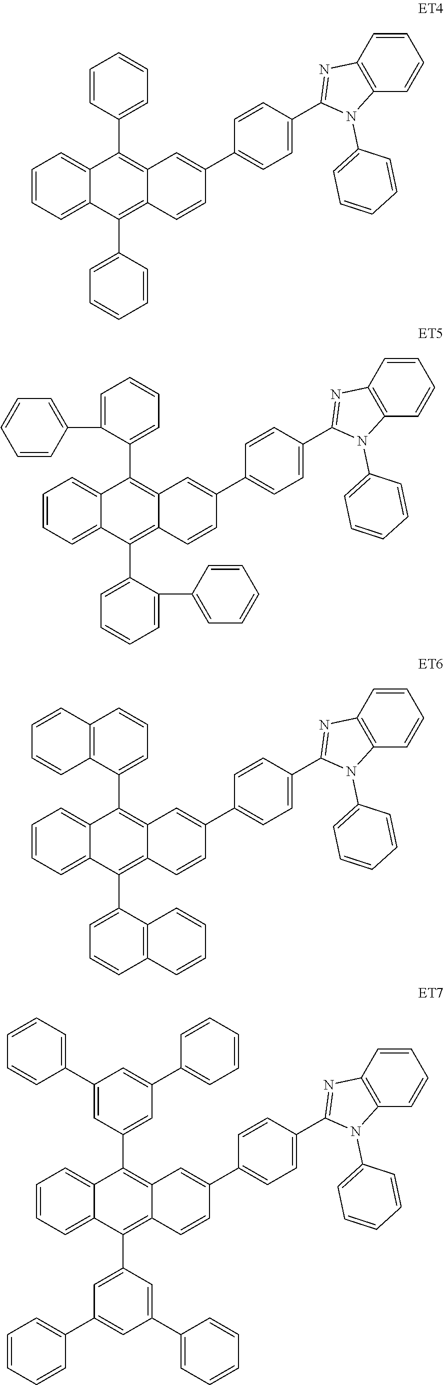 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

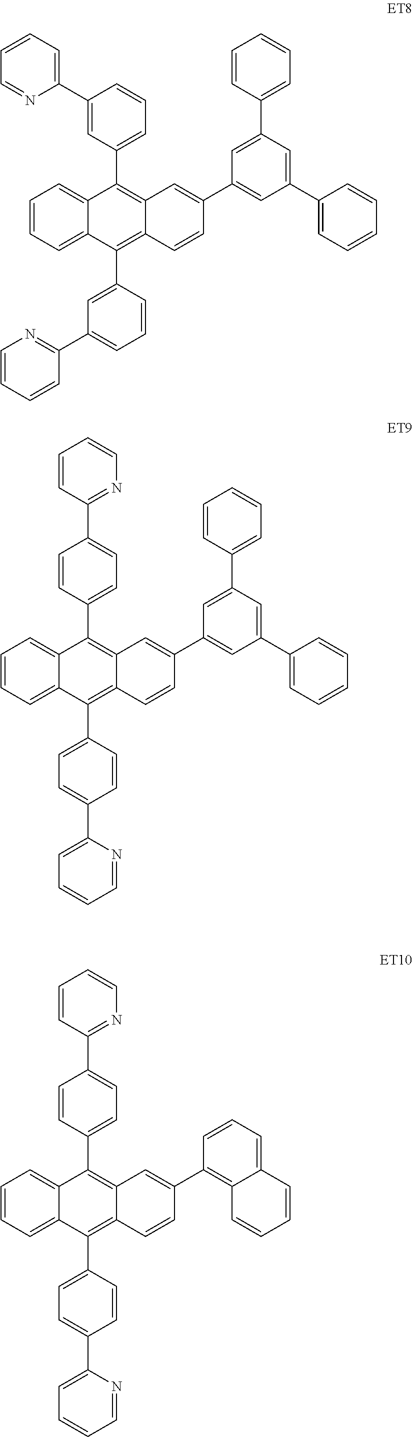 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

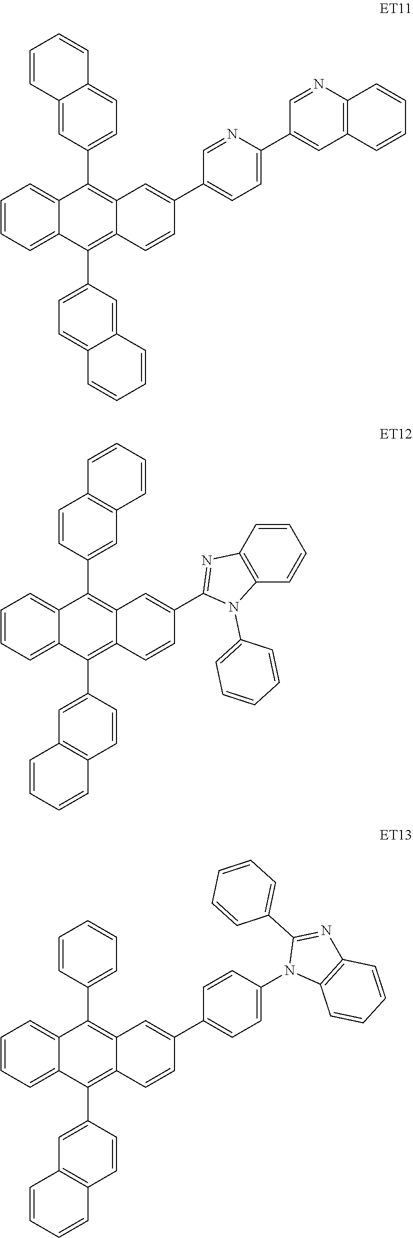

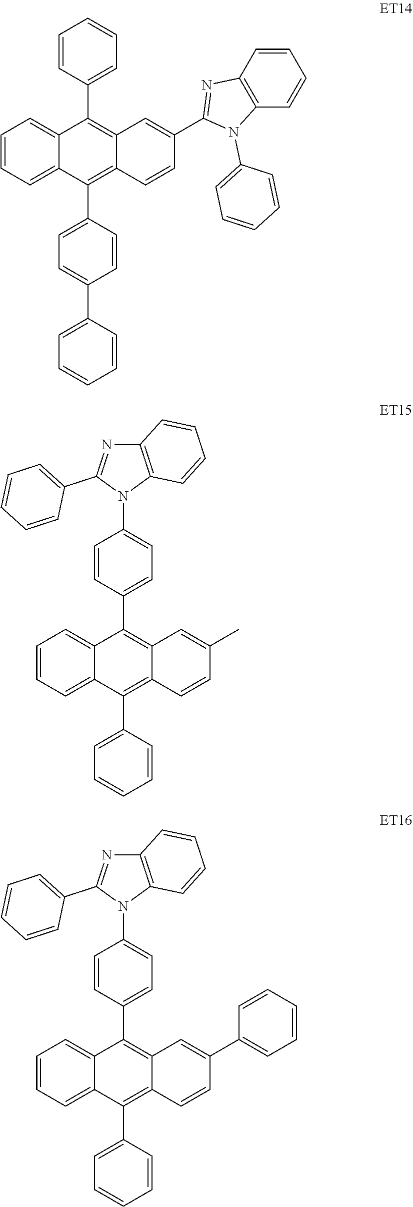 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

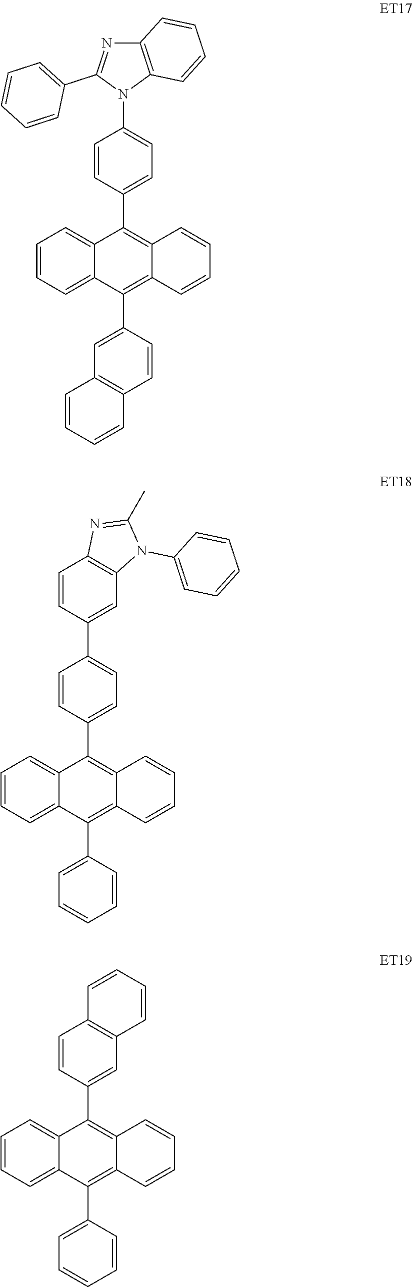

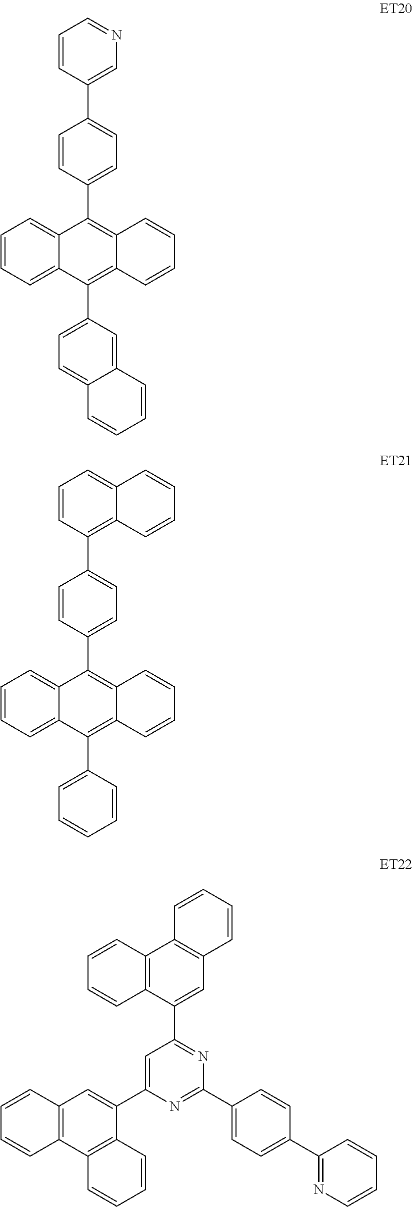

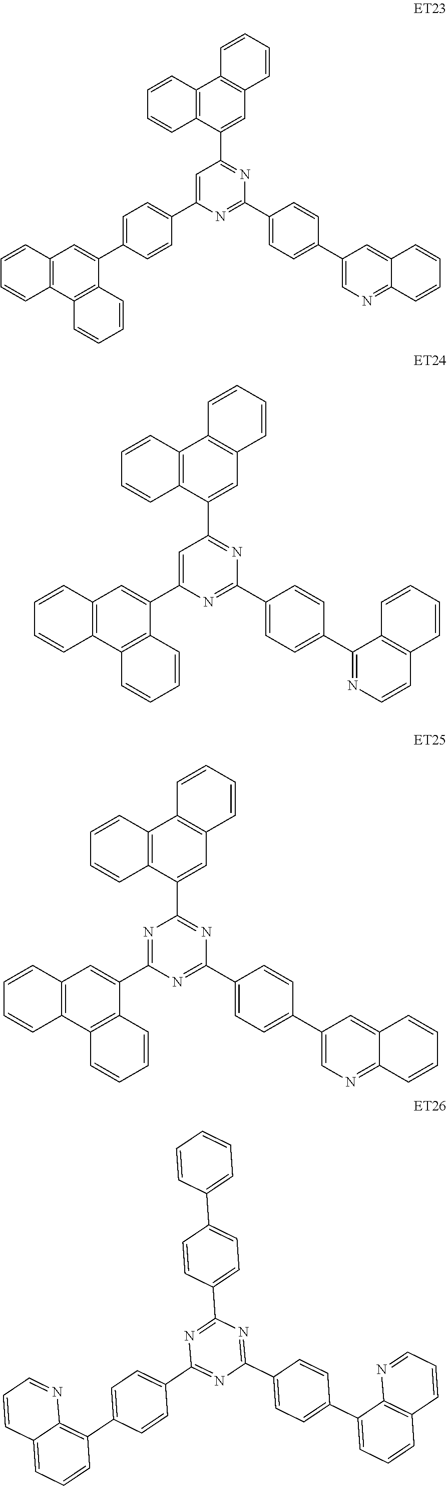 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

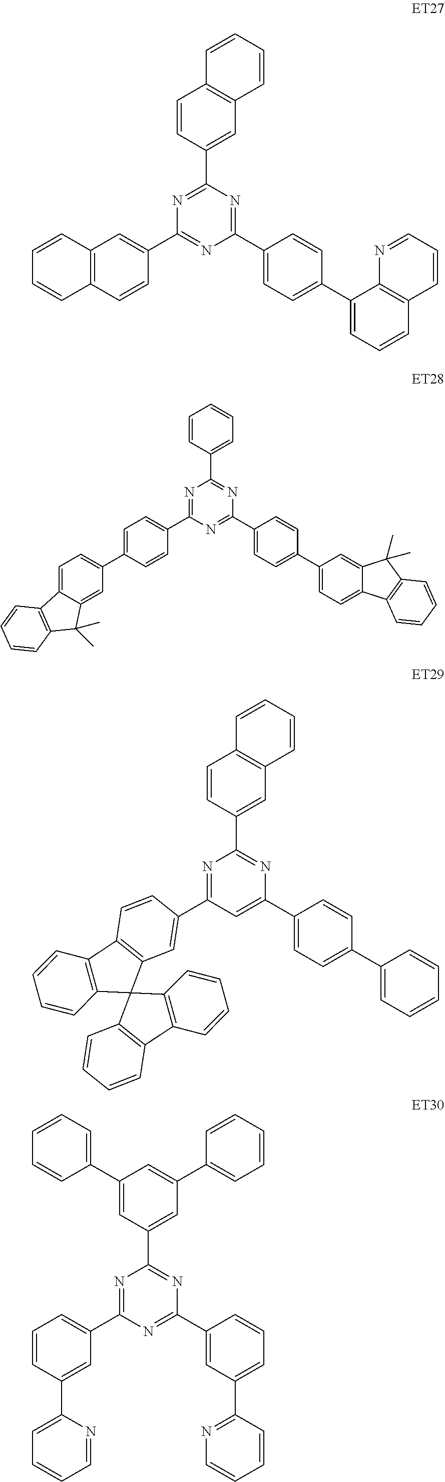

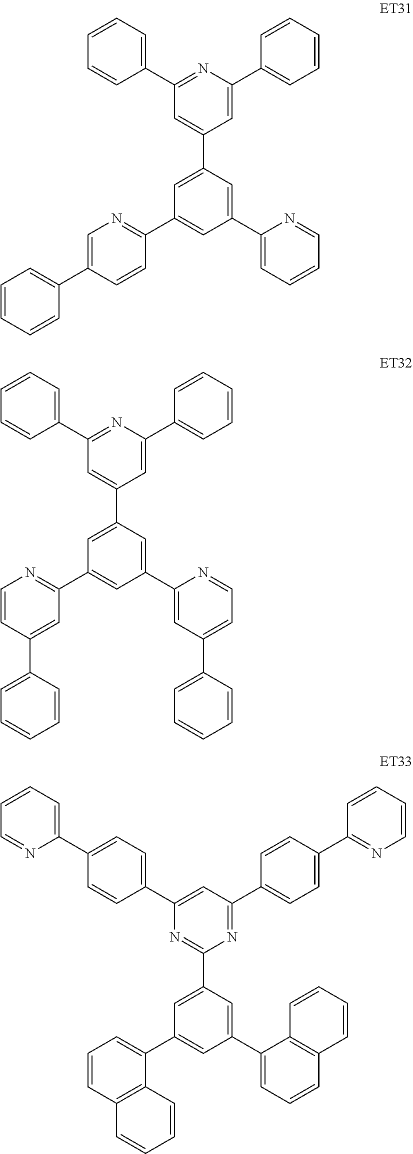

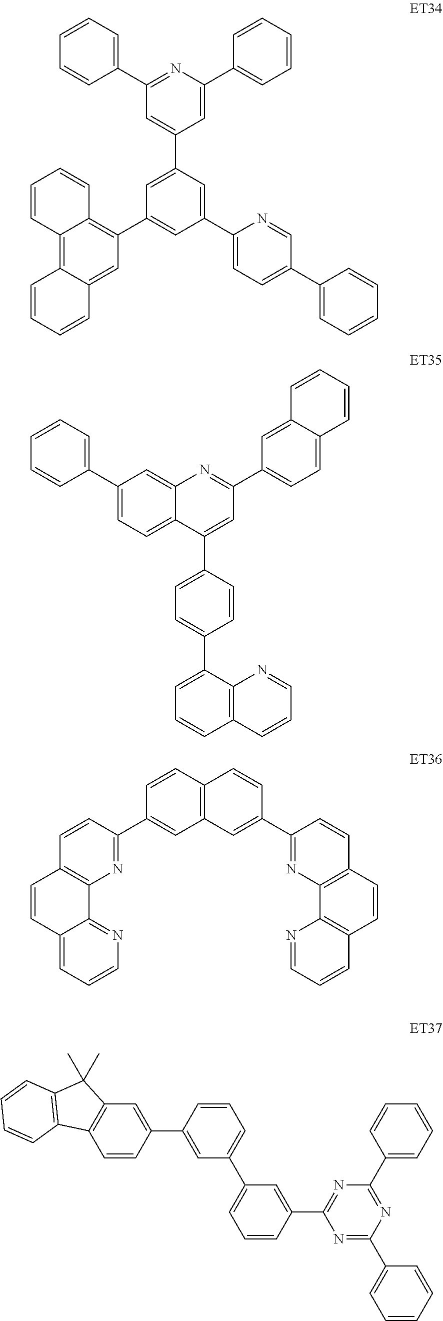

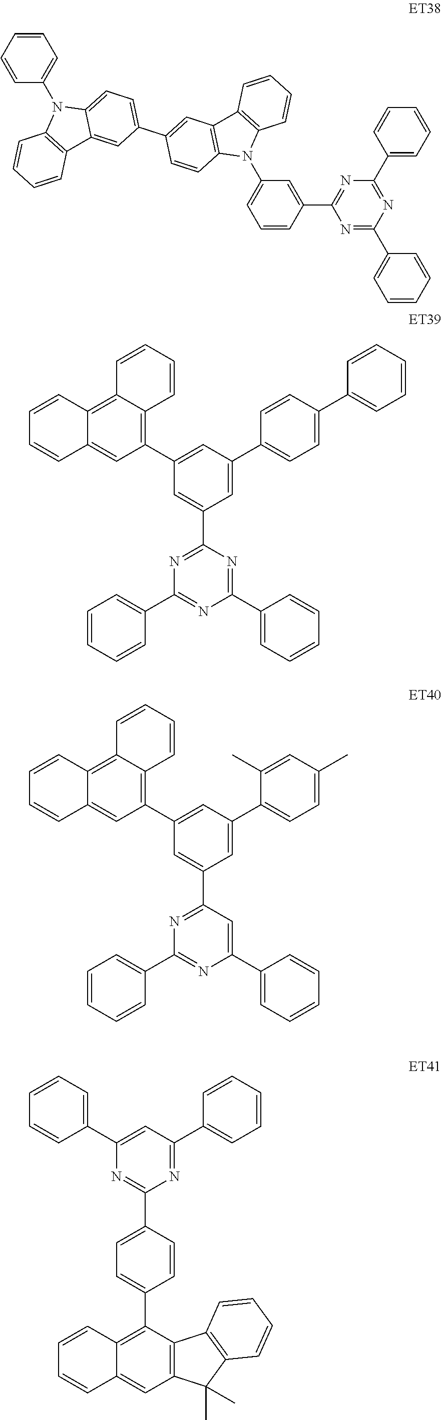

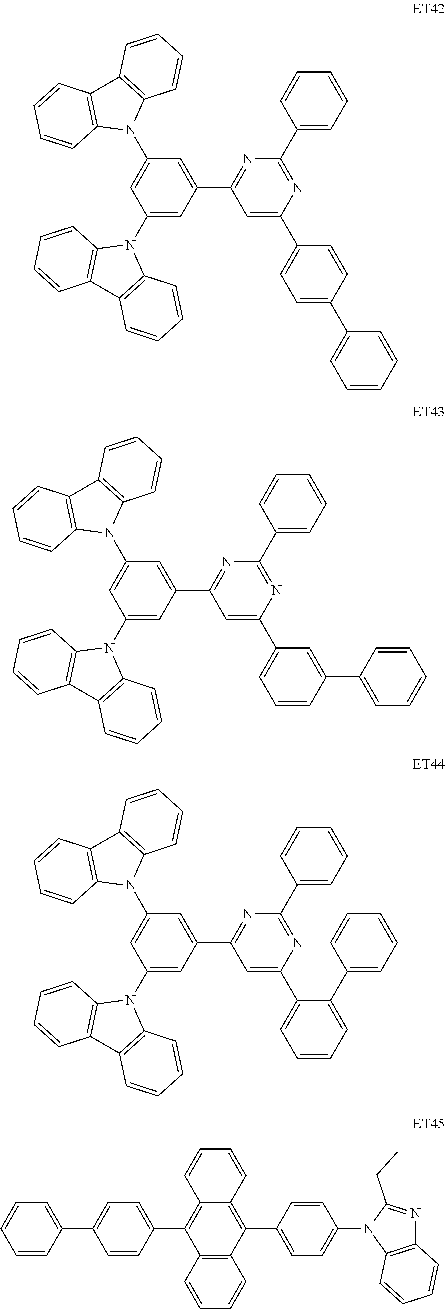 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

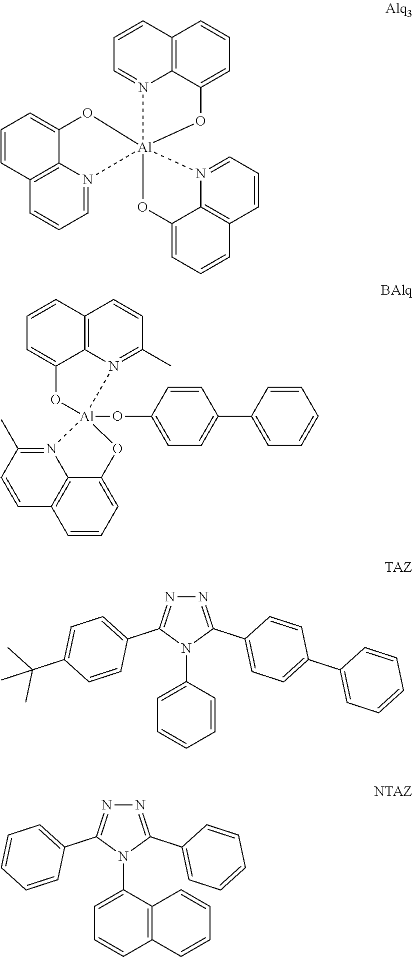

A thickness of the electron transport region may be in a range of about 100 Å to about 5,000 Å. For example, the thickness of the electron transport region may be in a range of about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may each independently be in a range of about 20 Å to about 1,000 Å, and a thickness of the electron transport layer may be in a range of about 100 Å to about 1,000 Å. For example, the thickness of the buffer layer, the hole blocking layer, or the electron control layer may each independently be in a range of about 30 Å to about 300 Å. For example, the thickness of the electron transport layer may be in a range of about 150 Å to about 500 Å. When the thicknesses of the buffer layer, the hole blocking layer, the electron control layer, the electron transport layer, and/or the electron transport region are within these ranges, satisfactory electron transporting characteristics may be obtained without a substantial increase in driving voltage.

The electron transport region (for example, an electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion.

A ligand coordinated with the metal ion of the alkali metal complex or with the metal ion of the alkaline earth-metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

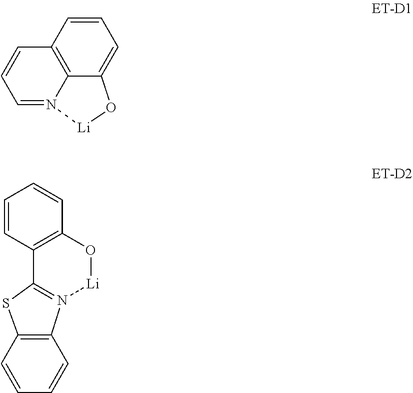

The electron transport region may include an electron injection layer to facilitate the injection of electrons from the second electrode 150. The electron injection layer may directly contact the second electrode 150.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, or any combination thereof.

The alkali metal-containing compound may include: alkali metal oxides, such as Li₂O, Cs₂O, or K₂O; alkali metal halides, such as LiF, NaF, CsF, KF, L₁₁, NaI, CsI, or KI; or any combination thereof. The alkaline earth metal-containing compound may include an alkaline earth metal compound, such as BaO, SrO, CaO, BaₓSr₁₋ₓO (x is a real number satisfying the condition of 0<x<1), BaₓCa₁₋ₓO (x is a real number satisfying the condition of 0<x<1), or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include: an alkali metal ion, an alkaline earth metal ion, or a rare earth metal ion; and a ligand bonded to the metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof).

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (for example, a compound represented by Formula 601).

In an embodiment, the electron injection layer may consist of an alkali metal-containing compound (for example, an alkali metal halide); or the electron injection layer may consist of an alkali metal-containing compound (for example, an alkali metal halide), and an alkali metal, an alkaline earth metal, a rare earth metal, or any combination thereof. For example, the electron injection layer may be a KI:Yb co-deposited layer, a RbI:Yb co-deposited layer, a LiF:Yb co-deposited layer, or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be homogeneously or non-homogeneously dispersed in a matrix including the organic material.

A thickness of the electron injection layer may be in a range of about 1 Å to about 100 Å. For example, the thickness of the electron injection layer may about 3 Å to about 90 Å. When the thickness of the electron injection layer is within the above-describe range, satisfactory electron injection characteristics may be obtained without a substantial increase in driving voltage.

[Second Electrode 150]

The second electrode 150 is disposed on the interlayer 130. The second electrode 150 may be a cathode, which is an electron injection electrode. The second electrode 150 may include a material having a low-work function, for example, a metal, an alloy, an electrically conductive compound, or any combination thereof.

In an embodiment, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multilayered structure.

[Capping Layer]

The light-emitting device 10 may include a first capping layer outside the first electrode 110, and/or a second capping layer outside the second electrode 150. For example, the light-emitting device 10 may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

Light generated in an emission layer of the interlayer 130 of the light-emitting device 10 may be extracted toward the outside through the first electrode 110, which may be a semi-transmissive electrode or a transmissive electrode, and through the first capping layer. Light generated in an emission layer of the interlayer 130 of the light-emitting device 10 may be extracted toward the outside through the second electrode 150, which may be a semi-transmissive electrode or a transmissive electrode, and the through second capping layer.

The first capping layer and the second capping layer may each increase external emission efficiency according to the principle of constructive interference. Accordingly, the light extraction efficiency of the light-emitting device 10 may be increased, so that the emission efficiency of the light-emitting device 10 may be improved.

The first capping layer and the second capping layer may each include a material having a refractive index equal to or greater than about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include carbocyclic compounds, heterocyclic compounds, amine group-containing compounds, porphyrin derivatives, phthalocyanine derivatives, naphthalocyanine derivatives, alkali metal complexes, alkaline earth metal complexes, or any combination thereof. The carbocyclic compound, the heterocyclic compound, and the amine group-containing compound may each be optionally substituted with a substituent containing O, N, S, Se, Si, F, Cl, Br, I, or any combination thereof.

In an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

In an embodiment, at least one of the first capping layer and the second capping layer may each independently include one of Compounds HT28 to HT33, one of Compounds CP1 to CP6, β-NPB, or any combination thereof:

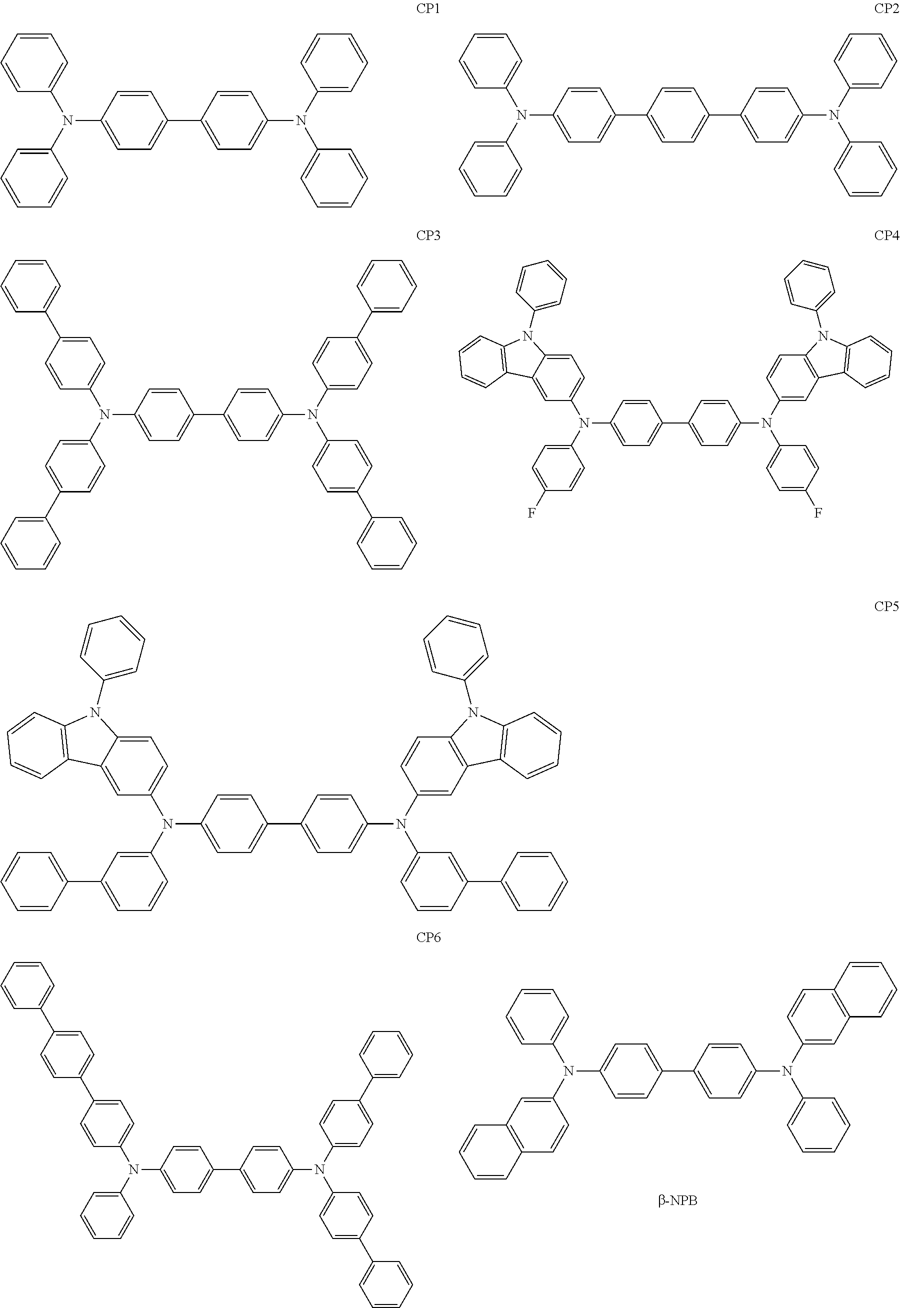

[Film]

The condensed cyclic compound represented by Formula 1 may be included in various films. Therefore, according to embodiments, a film may include the condensed cyclic compound represented by Formula 1. The film may be, for example, an optical member (or a light control means) (for example, a color filter, a color conversion member, a capping layer, a light extraction efficiency enhancement layer, a selective light absorbing layer, a polarizing layer, or a quantum dot-containing layer), a light-blocking member (for example, a light reflective layer or a light absorbing layer), or a protective member (for example, an insulating layer or a dielectric layer).

[Electronic Apparatus]

The light-emitting device may be included in various electronic apparatuses. For example, an electronic apparatus including the light-emitting device may be a light-emitting apparatus, an authentication apparatus, or the like.

The electronic apparatus (for example, a light-emitting apparatus) may further include, in addition to the light-emitting device, a color filter, a color conversion layer, or a color filter and a color conversion layer. The color filter and/or the color conversion layer may be located in at least one traveling direction of light emitted from the light-emitting device. In an embodiment, the light emitted from the light-emitting device may be blue light or white light. The light-emitting device may be the same as described herein. In an embodiment, the color conversion layer may include a quantum dot. The quantum dot may be, for example, the quantum dot as described in the specification.

The electronic apparatus may include a first substrate. The first substrate may include subpixels, the color filter may include color filter areas respectively corresponding to the subpixels, and the color conversion layer may include color conversion areas respectively corresponding to the subpixels.

A pixel-defining layer may be located between the subpixels to define each subpixel.

The color filter may further include color filter areas and light-shielding patterns located between the color filter areas, and the color conversion layer may include color conversion areas and light-shielding patterns located between the color conversion areas.

The color filter areas (or the color conversion areas) may include a first area emitting first color light, a second area emitting second color light, and/or a third area emitting third color light, and the first color light, the second color light, and/or the third color light may have different maximum emission wavelengths from one another. In an embodiment, the first color light may be red light, the second color light may be green light, and the third color light may be blue light. In an embodiment, the color filter areas (or the color conversion areas) may include quantum dots. For example, the first area may include a red quantum dot, the second area may include a green quantum dot, and the third area may not include a quantum dot. The quantum dot may be the same as described in the specification. The first area, the second area, and/or the third area may each further include a scatterer.

In an embodiment, the light-emitting device may emit a first light, the first area may absorb the first light to emit a first-first color light, the second area may absorb the first light to emit a second-first color light, and the third area may absorb the first light to emit a third-first color light. The first-first color light, the second-first color light, and the third-first color light may each have different maximum emission wavelengths from one another. For example, the first light may be blue light, the first-first color light may be red light, the second-first color light may be green light, and the third-first color light may be blue light.

The electronic apparatus may further include a thin-film transistor (TFT) in addition to the light-emitting device as described above. The TFT may include a source electrode, a drain electrode, and an active layer, wherein any one of the source electrode and the drain electrode may be electrically connected to any one of the first electrode and the second electrode of the light-emitting device.

The TFT may further include a gate electrode, a gate insulating film, etc.

The active layer may include crystalline silicon, amorphous silicon, organic semiconductor, oxide semiconductor, or the like.

The electronic apparatus may further include a sealing portion for sealing the light-emitting device. The sealing portion may be located between the color filter and/or the color-conversion layer, and the light-emitting device. The sealing portion allows light from the light-emitting device to be extracted to the outside, while preventing ambient air and moisture from penetrating into the light-emitting device. The sealing portion may be a sealing substrate including a transparent glass substrate or a plastic substrate. The sealing portion may be a thin-film encapsulation layer including an organic layer and/or an inorganic layer. When the sealing portion is a thin film encapsulation layer, the electronic apparatus may be flexible.

Various functional layers may be additionally disposed on the sealing portion, in addition to the color filter and/or the color conversion layer, according to the intended use of the electronic apparatus. The functional layers may include a touch screen layer and a polarizing layer. The touch screen layer may be a pressure-sensitive touch screen layer, a capacitive touch screen layer, or an infrared touch screen layer.

The authentication apparatus may further include, in addition to the light-emitting device, a biometric information collector. The authentication apparatus may be, for example, a biometric authentication apparatus that authenticates an individual by using biometric information of a living body (for example, fingertips, pupils, etc.).

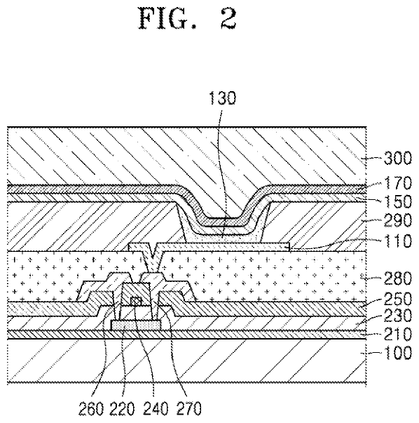

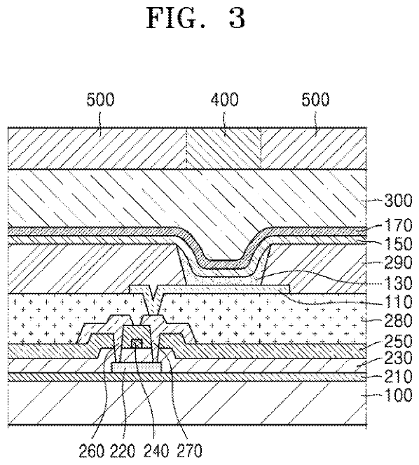

The electronic apparatus may be applied to various displays, light sources, lighting, personal computers (for example, a mobile personal computer), mobile phones, digital cameras, electronic diaries, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

[Description of FIGS. 2 and 3]

FIG. 2 is a schematic cross-sectional view of an electronic apparatus according to an embodiment.

The electronic apparatus (for example, a light-emitting apparatus) of FIG. 2 may include a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be formed on the substrate 100. The buffer layer 210 may prevent penetration of impurities through the substrate 100 and may provide a flat surface on the substrate 100.

A TFT may be disposed on the buffer layer 210. The TFT may include an active layer 220, a gate electrode 240, a source electrode 260, and a drain electrode 270.

The active layer 220 may include an inorganic semiconductor such as silicon or polysilicon, an organic semiconductor, or an oxide semiconductor, and may include a source region, a drain region, and a channel region.

A gate insulating film 230 for insulating the active layer 220 from the gate electrode 240 may be disposed above the active layer 220, and the gate electrode 240 may be disposed above the gate insulating film 230.

An interlayer insulating film 250 may be disposed above the gate electrode 240. The interlayer insulating film 250 may be placed between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be disposed on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

The TFT is electrically connected to a light-emitting device to drive the light-emitting device, and is covered by a passivation layer 280. The passivation layer 280 may include an inorganic insulating film, an organic insulating film, or a combination thereof. A light-emitting device is provided on the passivation layer 280. The light-emitting device includes a first electrode 110, an interlayer 130, and a second electrode 150.

The first electrode 110 may be disposed on the passivation layer 280. The passivation layer 280 may not completely cover the drain electrode 270 and may expose a portion of the drain electrode 270. The first electrode 110 may be electrically connected to the exposed portion of the drain electrode 270.

A pixel-defining layer 290 containing an insulating material may be disposed on the first electrode 110. The pixel-defining layer 290 may expose a region of the first electrode 110, and an interlayer 130 may be formed in the exposed region of the first electrode 110. The pixel-defining layer 290 may be a polyimide or polyacrylic organic film. Although not shown in FIG. 2, at least some layers of the interlayer 130 may extend beyond the upper portion of the pixel-defining layer 290 to be provided in the form of a common layer.

The second electrode 150 may be disposed on the interlayer 130, and a capping layer 170 may be further included on the second electrode 150. The capping layer 170 may be formed to cover the second electrode 150.

The encapsulation portion 300 may be disposed on the capping layer 170. The encapsulation portion 300 may be disposed on a light-emitting device to protect the light-emitting device from moisture or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or a combination thereof; or a combination of the inorganic film and the organic film.

FIG. 3 is a schematic cross-sectional view of an electronic apparatus according to an embodiment.

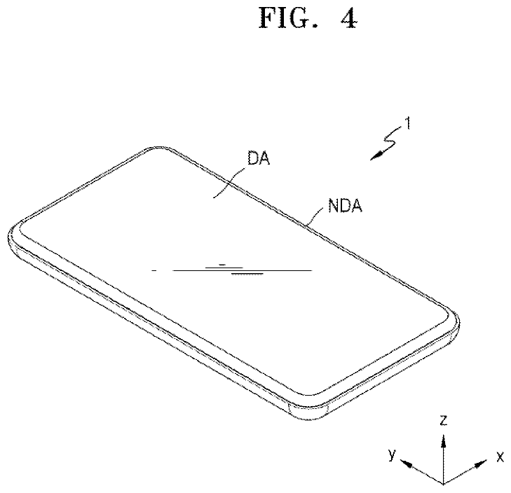

The electronic apparatus (for example, a light-emitting apparatus) of FIG. 3 may differ from the electronic apparatus of FIG. 2, at least in that a light-shielding pattern 500 and a functional region 400 are further included on the encapsulation portion 300. The functional region 400 may be a color filter area, a color conversion area, or a combination of the color filter area and the color conversion area. In an embodiment, the light-emitting device included in the electronic apparatus of FIG. 3 may be a tandem light-emitting device.

[Description of FIG. 4]

FIG. 4 is a schematic perspective view of an electronic device 1 including a light-emitting device, according to an embodiment.

The electronic device 1 may be an apparatus that displays a moving image or a still image, and may be a portable electronic device, such as a mobile phone, a smart phone, a tablet personal computer (PC), a mobile communication terminal, an electronic diary, an electronic book, a portable multimedia player (PMP), a navigation system, or an ultra mobile PC (UMPC), as well as various products, such as a television, a laptop, a monitor, a billboard, or Internet of things (IOT), or the electronic device 1 may be a part thereof.

In an embodiment, the electronic device 1 may be a wearable device, such as a smart watch, a watch phone, a glasses-type display, or a head mounted display (HMD), or part thereof. However, the disclosure is not limited thereto.

In an embodiment, the electronic device 1 may be a dashboard of a vehicle, a center information display (CID) arranged on a center fascia or dashboard of a vehicle, a room mirror display instead of a side-view mirror of a vehicle, an entertainment for the back seat of a vehicle or a display arranged on the back of the front seat of a vehicle, a head up display (HUD) installed on the front of a vehicle or projected on a front window glass, or a computer generated hologram augmented reality head up display (CGH AR HUD). For convenience of explanation, FIG. 4 shows an embodiment where the electronic device 1 is a smart phone.

The electronic device 1 may include a display area DA and a non-display area NDA outside the display area DA. A display apparatus may implement an image through a two-dimensional array of pixels that are arranged in the display area DA.

The non-display area NDA is an area that does not display an image, and may surround the display area DA. A driver for providing an electrical signal or electric power to display devices arranged in the display area DA and the like may be arranged in the non-display area NDA. A pad, which is an area to which an electronic device or a printed circuit board may be electrically connected, may be arranged in the non-display area NDA.

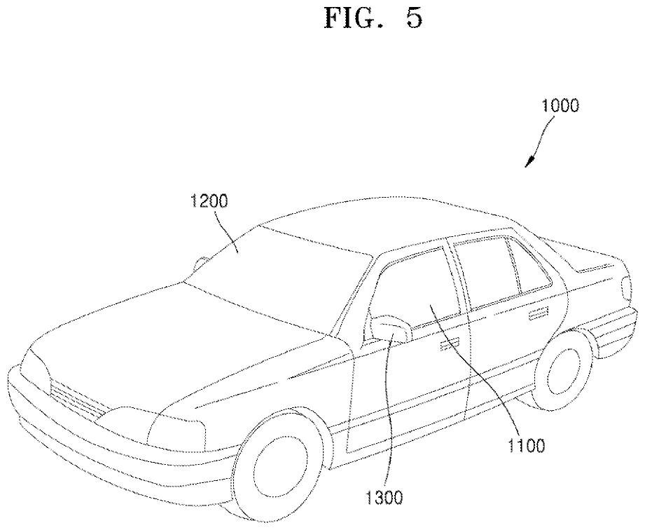

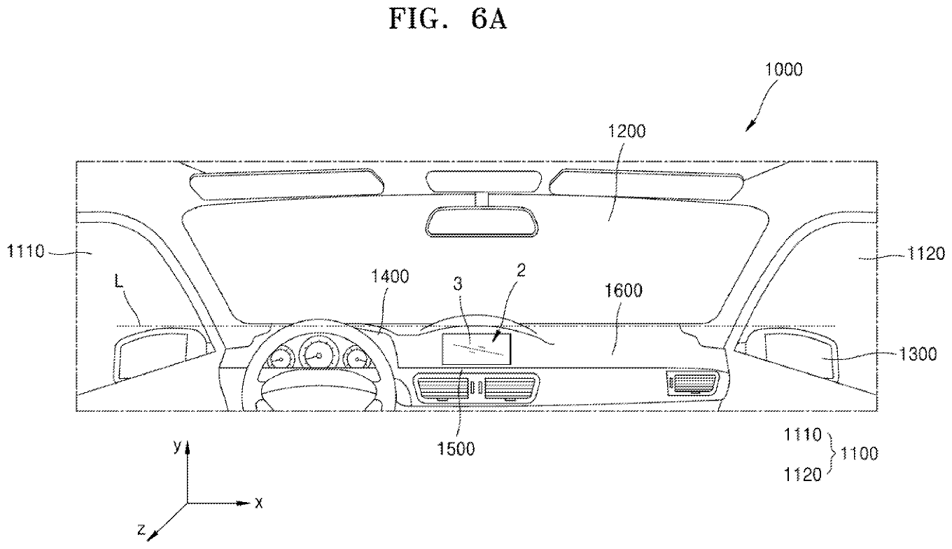

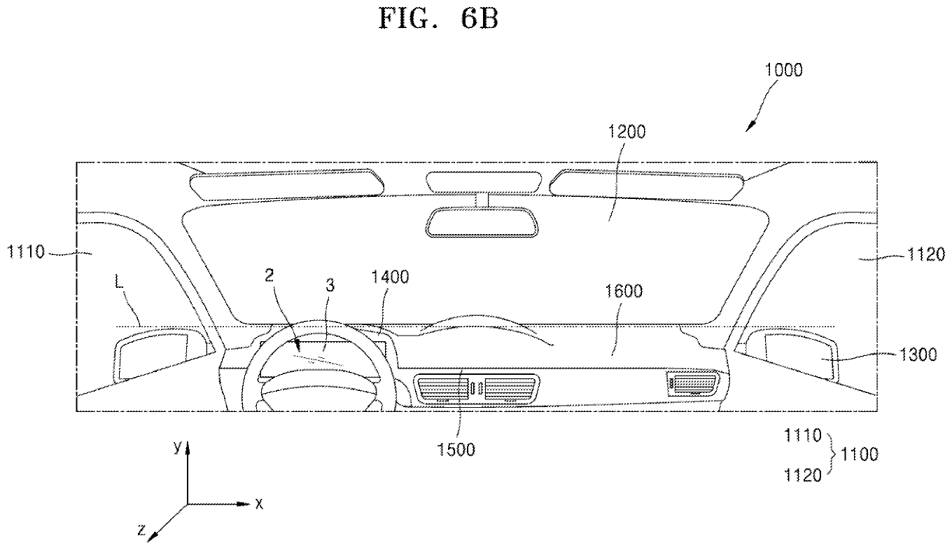

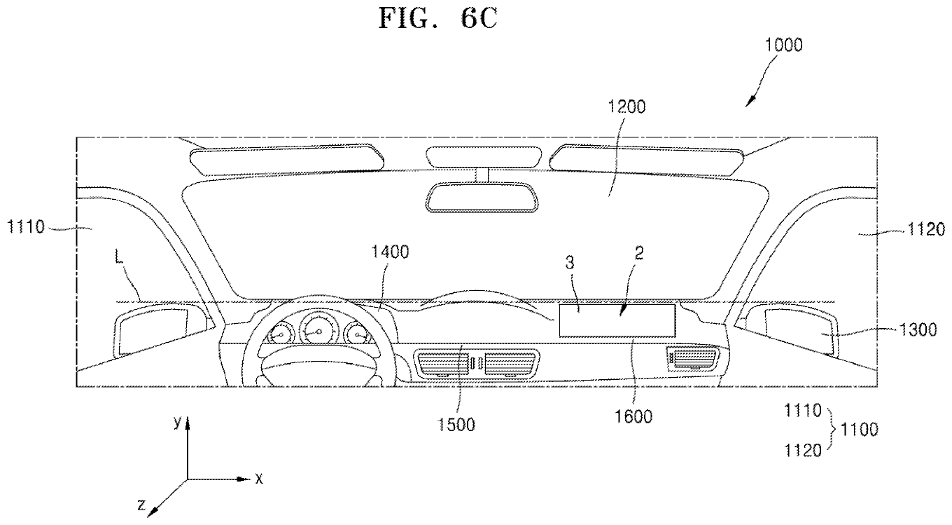

The electronic device 1 may have different lengths in an x-axis direction and a y-axis direction. For example, as shown in FIG. 4, a length in the x-axis direction may be less than a length in the y-axis direction. As another example, a length in the x-axis direction and a length in the y-axis direction may be identical to each other. As another example, a length in the x-axis direction may be greater than a length in the y-axis direction.

[Descriptions of FIGS. 5 and 6A to 6C]

FIG. 5 is a schematic perspective view of an exterior of a vehicle 1000 as an electronic device including a light-emitting device, according to an embodiment. FIGS. 6A to 6C are each a schematic diagram of an interior of the vehicle 1000, according to various embodiments.

Referring to FIGS. 5, 6A, 6B, and 6C, the vehicle 1000 may refer to various apparatuses for moving a subject to be transported, such as a person, an object, or an animal, from a departure point to a destination. Examples of the vehicle 1000 may include a vehicle traveling on a road or track, a vessel moving over a sea or river, and an airplane flying in the sky using the action of air.

The vehicle 1000 may travel on a road or track. The vehicle 1000 may move in a given direction (e.g., a predetermined or a selectable direction) according to the rotation of at least one wheel. For example, the vehicle 1000 may include a three-wheeled or four-wheeled vehicle, a construction vehicle, a two-wheeled vehicle, a prime mover apparatus, a bicycle, and a train traveling on a track.

The vehicle 1000 may include a body having an interior and an exterior, and a chassis that is a portion excluding the body in which mechanical apparatuses necessary for driving are installed. The exterior of the body may include a pillar provided at a boundary between a front panel, a bonnet, a roof panel, a rear panel, a trunk, and a door. The chassis of the vehicle 1000 may include a power generating apparatus, a power transmitting apparatus, a driving apparatus, a steering apparatus, a braking apparatus, a suspension apparatus, a transmission apparatus, a fuel apparatus, and front, rear, left, and right wheels.

The vehicle 1000 may include a side window glass 1100, a front window glass 1200, a side-view mirror 1300, a cluster 1400, a center fascia 1500, a front passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on a side of the vehicle 1000. In an embodiment, the side window glass 1100 may be installed on a door of the vehicle 1000. The side window glass 1100 may include multiple side window glasses 1100 which may face each other. In an embodiment, the side window glass 1100 may include a first side window glass 1110 and a second side window glass 1120. In an embodiment, the first side window glass 1110 may be arranged adjacent to the cluster 1400, and the second side window glass 1120 may be arranged adjacent to the front passenger seat dashboard 1600.

In an embodiment, the side window glasses 1100 may be spaced apart from each other in an x direction or in a −x direction. For example, the first side window glass 1110 and the second side window glass 1120 may be spaced apart from each other in the x direction or in the −x direction. For example, a virtual straight line L connecting the side window glasses 1100 to each other may extend in the x direction or in the −x direction. For example, the virtual straight line L connecting the first side window glass 1110 to the second side window glass 1120 may extend in the x direction or in the −x direction.

The front window glass 1200 may be installed on front of the vehicle 1000. The front window glass 1200 may be arranged between the side window glasses 1100 facing each other.

The side-view mirror 1300 may provide a rear view of the vehicle 1000. The side-view mirror 1300 may be installed on the exterior of the body. In an embodiment, the side-view mirror 1300 may include multiple side-view mirrors 1300. One of the side-view mirrors 1300 may be arranged outside the first side window glass 1110. Another of the side-view mirrors 1300 may be arranged outside the second side window glass 1120.

The cluster 1400 may be located in front of a steering wheel. The cluster 1400 may include a tachometer, a speedometer, a coolant thermometer, a fuel gauge, a turn signal indicator light, a high beam indicator light, a warning light, a seat belt warning light, an odometer, an automatic gear selector lever indicator light, a door open warning light, an engine oil warning light, and/or a low fuel warning light.

The center fascia 1500 may include a control panel on which buttons for adjusting an audio apparatus, an air conditioning apparatus, and a seat heater are arranged. The center fascia 1500 may be arranged on one side of the cluster 1400.

The front passenger seat dashboard 1600 may be spaced apart from the cluster 1400 with the center fascia 1500 therebetween. In an embodiment, the cluster 1400 may be arranged to correspond to a driver's seat (not shown), and the front passenger seat dashboard 1600 may be arranged to correspond to a front passenger seat (not shown). In an embodiment, the cluster 1400 may be adjacent to the first side window glass 1110, and the front passenger seat dashboard 1600 may be adjacent to the second side window glass 1120.

In an embodiment, the display apparatus 2 may include a display panel 3, and the display panel 3 may display an image. The display apparatus 2 may be arranged inside the vehicle 1000. In an embodiment, the display apparatus 2 may be arranged between the side window glasses 1100 facing each other. The display apparatus 2 may be arranged on at least one of the cluster 1400, the center fascia 1500, and the front passenger seat dashboard 1600.

The display apparatus 2 may include an organic light-emitting display, an inorganic electroluminescent (EL) light-emitting display (inorganic light-emitting display), and a quantum dot display. Hereinafter, an organic light-emitting display including a light-emitting device according to an embodiment is described as an example of the display apparatus 2 according to an embodiment, but in embodiments of the disclosure, various types of display apparatuses as described above may be used.

Referring to FIG. 6A, the display apparatus 2 may be arranged on the center fascia 1500. In an embodiment, the display apparatus 2 may display navigation information. In an embodiment, the display apparatus 2 may display information about audio, video, or vehicle settings.

Referring to FIG. 6B, the display apparatus 2 may be arranged on the cluster 1400. The cluster 1400 may express driving information and the like by the display apparatus 2. For example, the cluster 1400 may digitally implement driving information. The digital cluster 1400 may display vehicle information and driving information as images. For example, a tachometer needle, gauges, and various warning lights or icons may be displayed by digital signals.

Referring to FIG. 6C, the display apparatus 2 may be arranged on the front passenger seat dashboard 1600. The display apparatus 2 may be embedded in the front passenger seat dashboard 1600 or may be disposed on the front passenger seat dashboard 1600. In an embodiment, the display apparatus 2 arranged on the front passenger seat dashboard 1600 may display an image related to information displayed on the cluster 1400 and/or information displayed on the center fascia 1500. In an embodiment, the display apparatus 2 arranged on the front passenger seat dashboard 1600 may display information that is different from the information displayed on the cluster 1400 and/or the information displayed on the center fascia 1500.

[Manufacture Method]

Respective layers included in the hole transport region, the emission layer, and respective layers included in the electron transport region may be formed in a selected region by using one or more suitable methods selected from vacuum deposition, spin coating, casting, Langmuir-Blodgett (LB) deposition, ink-jet printing, laser-printing, and laser-induced thermal imaging.

When layers constituting the hole transport region, an emission layer, and layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be included in a layer to be formed and the structure of a layer to be formed.

### Definitions of Terms

The term “C₃-C₆₀ carbocyclic group” as used herein may be a cyclic group consisting of carbon atoms as the only ring-forming atoms and having 3 to 60 carbon atoms, and the term “C₁-C₆₀ heterocyclic group” as used herein may be a cyclic group that has 1 to 60 carbon atoms and further has, in addition to a carbon atom, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, a C₁-C₆₀ heterocyclic group may have 3 to 61 ring-forming atoms.

The term “cyclic group” as used herein may be a C₃-C₆₀ carbocyclic group or a C₁-C₆₀ heterocyclic group.

The term “T₁ electron-rich C₃-C₆₀ cyclic group” as used herein may be a cyclic group that has 3 to 60 carbon atoms and may not include *—N═*′ as a ring-forming moiety, and the term “T₁ electron-deficient nitrogen-containing C₁-C₆₀ cyclic group” as used herein may be a heterocyclic group that has 1 to 60 carbon atoms and may include *—N═*′ as a ring-forming moiety.

In embodiments,
a C₃-C₆₀ carbocyclic group may be a T₁ group T₁ or a group in which two or more T₁ groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T₂ group, a group in which two or more T₂ groups are condensed with each other, or a group in which at least one T₂ group and at least one T₁ group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
a π electron-rich C₃-C₆₀ cyclic group may be a T₁ group, a group in which two or more T₁ groups are condensed with each other, a T₃ group, a group in which two or more T₃ groups are condensed with each other, or a group in which at least one T₃ group and at least one T₁ group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.), and
a π electron-deficient nitrogen-containing C₁-C₆₀ cyclic group may be a T₄ group, a group in which two or more T₄ groups are condensed with each other, a group in which at least one T₄ group and at least one T₁ group are condensed with each other, a group in which at least one T₄ group and at least one T₃ group are condensed with each other, or a group in which at least one T₄ group, at least one T₁ group, and at least one T₃ group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
wherein the T₁ group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,
the T₂ group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T₃ group may be a furan group, a thiophene group, a 1H-pyrrole group, a silole group, or a borole group, and
the T₄ group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₂₀ heterocyclic group”, “π electron-rich C₃-C₆₀ cyclic group”, or “π electron-deficient nitrogen-containing C₁-C₆₀ cyclic group” as used herein may each be a group condensed to any cyclic group, a monovalent group, or a polyvalent group (for example, a divalent group, a trivalent group, a tetravalent group, etc.), depending on the structure of a formula in connection with which the terms are used. For example, a “benzene group” may be a benzo group, a phenyl group, a phenylene group, or the like, which may be readily understood by those of ordinary skill in the art according to the structure of a formula including the “benzene group.”

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₂₀ alkyl group” as used herein may be a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₂₀ alkylene group” as used herein may be a divalent group having a same structure as the C₁-C₂₀ alkyl group.

The term “C₂-C₆₀ alkyl group” as used herein may be a linear or branched aliphatic hydrocarbon monovalent group having 2 to 60 carbon atoms (a C₂-C₂₀ alkyl group may be a linear or branched aliphatic hydrocarbon monovalent group having 2 to 20 carbon atoms), and examples thereof may include an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an isoheptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, and a tert-decyl group. The term “C₂-C₆₀ alkylene group” as used herein may be a divalent group having a same structure as the C₂-C₆₀ alkyl group.

The term “C₂-C₆₀ alkenyl group” as used herein may be a monovalent hydrocarbon group including at least one carbon-carbon double bond in the middle or at a terminus of a C₂-C₆₀ alkyl group (a C₂-C₂₀ alkenyl group may be a monovalent hydrocarbon group including at least one carbon-carbon double bond in the middle or at a terminus of a C₂-C₂₀ alkyl group), and examples thereof may include an ethenyl group, a propenyl group, and a butenyl group. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group including at least one carbon-carbon triple bond in the middle or at a terminus of a C₂-C₆₀ alkyl group (C₂-C₂₀ alkynyl group may be a monovalent hydrocarbon group including at least one carbon-carbon triple bond in the middle or at a terminus of a C₂-C₂₀ alkyl group), and examples thereof may include an ethynyl group and a propynyl group. The term “C₂-C₆₀ alkynylene group” as used herein may be a divalent group having a same structure as the C₂-C₆₀ alkynyl group.

The term “C₁-C₂₀ alkoxy group” as used herein may be a group represented by —O(A₁₀₁) (wherein A₁₀₁ may be C₁-C₆₀ alkyl group), and examples thereof may include a methoxy group, an ethoxy group, and an isopropyloxy group.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group that further includes, in addition to a carbon atom, at least one heteroatom as a ring-forming atom and has 1 to 10 carbon atoms, and examples thereof may include a 1,2,3,4-oxatriazolidinyl group, a tetrahydrofuranyl group, and a tetrahydrothiophenyl group. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has 3 to 10 carbon atoms and at least one carbon-carbon double bond in the ring thereof and no aromaticity, and examples thereof may include a cyclopentenyl group, a cyclohexenyl group, and a cycloheptenyl group. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group that has, in addition to a carbon atom, at least one heteroatom as a ring-forming atom, 1 to 10 carbon atoms, and at least one carbon-carbon double bond in the cyclic structure thereof. Examples of a C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system having six to sixty carbon atoms, and the term “C₆-C₆₀ arylene group” as used herein may be a divalent group having a carbocyclic aromatic system having six to sixty carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the respective rings may be condensed with each other.

The term “C₁-C₂₀ heteroaryl group” as used herein may be a monovalent group having a heterocyclic aromatic system that has, in addition to a carbon atom, at least one heteroatom as a ring-forming atom, and 1 to 60 carbon atoms. The term “C₁-C₆₀ heteroarylene group” as used herein may be a divalent group having a heterocyclic aromatic system that has, in addition to a carbon atom, at least one heteroatom as a ring-forming atom, and 1 to 60 carbon atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the respective rings may be condensed with each other.

The term “monovalent non-aromatic condensed polycyclic group” as used herein may be a monovalent group having two or more rings condensed to each other, only carbon atoms (for example, having 8 to 60 carbon atoms) as ring-forming atoms, and non-aromaticity in its molecular structure when considered as a whole. Examples of a monovalent non-aromatic condensed polycyclic group may include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein may be a divalent group having a same structure as a monovalent non-aromatic condensed polycyclic group.

The term “monovalent non-aromatic condensed heteropolycyclic group” as used herein may be a monovalent group having two or more rings condensed to each other, at least one heteroatom other than carbon atoms (for example, having 1 to 60 carbon atoms), as a ring-forming atom, and non-aromaticity in its molecular structure when considered as a whole. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein may be a divalent group having a same structure as a monovalent non-aromatic condensed heteropolycyclic group.

The term “C₆-C₆₀ aryloxy group” as used herein may be a group represented by —O(A₁₀₂) (wherein A₁₀₂ may be a C₆-C₆₀ aryl group), and the term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by -(A₁₀₆)(A₁₀₇) (wherein A₁₀₆ may be a C₁-C₅₉ alkylene group, and A₁₀₇ may be a C₁-C₅₉ heteroaryl group).

In the specification, the group R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₂₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃ and 031 to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₂₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom may include O, S, N, P, Si, B, Ge, Se, or any combination thereof.

The term “third-row transition metal” as used herein may be hafnium (Hf), tantalum (Ta), tungsten (W), rhenium (Re), osmium (Os), iridium (Ir), platinum (Pt), gold (Au), or the like.

In the specification, “Ph” refers to a phenyl group, “Me” refers to a methyl group, “Et” refers to an ethyl group, “tert-Bu” or “Bu^{t}” each refer to a tert-butyl group, and “OMe” refers to a methoxy group.

The term “biphenyl group” as used herein may be a “phenyl group substituted with a phenyl group.” For example, the “biphenyl group” may be a substituted phenyl group having a C₆-C₆₀ aryl group as a substituent.

The term “terphenyl group” as used herein may be a “phenyl group substituted with a biphenyl group”. For example, the “terphenyl group” may be a substituted phenyl group having, as a substituent, a C₆-C₆₀ aryl group substituted with a C₆-C₆₀ aryl group.

In the specification, the terms “x-axis”, “y-axis”, and “z-axis” are not limited to three axes in an orthogonal coordinate system (for example, a Cartesian coordinate system), and may be construed in a broader sense than the aforementioned three axes in an orthogonal coordinate system. For example, the x-axis, the y-axis, and the z-axis may be axes that are orthogonal to each other, or may be axes that are in different directions that are not orthogonal to each other.

The symbols *, *′, and *″ as used herein, unless defined otherwise, each refer to a binding site to a neighboring atom in a corresponding formula or moiety.

Hereinafter, compounds according to embodiments and light-emitting devices according to embodiments will be described in detail with reference to the Synthesis Examples and the Examples. The wording “B was used instead of A” used in describing Synthesis Examples means that an identical molar equivalent of B was used in place of A.

### EXAMPLES

### Synthesis Example 1. Synthesis of Compound 7

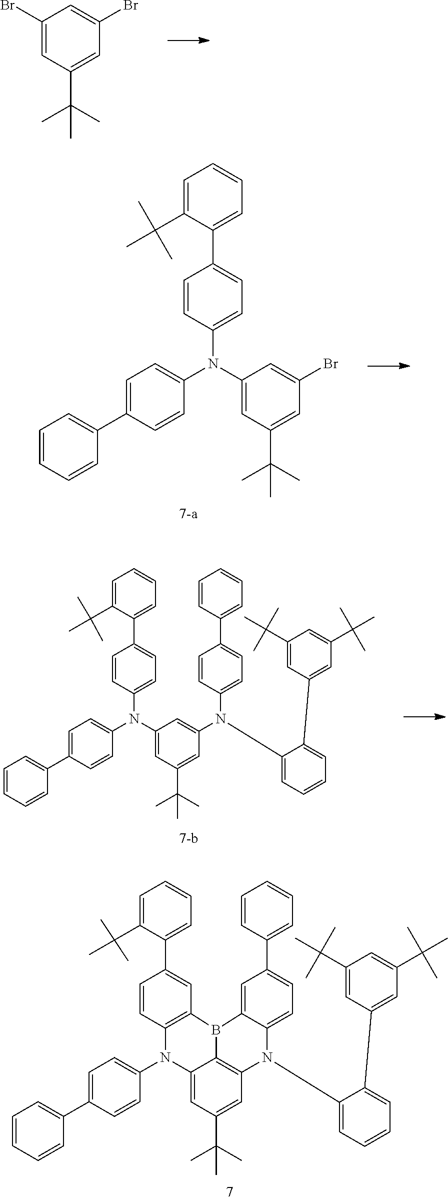 [SMILES: CC(C)(C)c1cc(Br)cc(Br)c1 ; CC(C)(C)c1cc(Br)cc(N(c2ccc(-c3ccccc3)cc2)c2ccc(-c3ccccc3C(C)(C)C)cc2)c1 ; CC(C)(C)c1cc(N(c2ccc(-c3ccccc3)cc2)c2ccc(-c3ccccc3C(C)(C)C)cc2)cc(N(c2ccc(-c3ccccc3)cc2)c2ccccc2-c2cc(C(C)(C)C)cc(C(C)(C)C)c2)c1 ; CC(C)(C)c1cc(-c2ccccc2N2c3ccc(-c4ccccc4)cc3B3c4cc(-c5ccccc5C(C)(C)C)ccc4N(c4ccc(-c5ccccc5)cc4)c4cc(C(C)(C)C)cc2c43)cc(C(C)(C)C)c1]

Synthesis of Intermediate 7-a

N-([1,1′-biphenyl]-4-yl)-2′-(tert-butyl)-[1,1′-biphenyl]-4-amine (15.1 g, 40 mmol), 1,3-dibromo-5-(tert-butyl)benzene (17.5 g, 60 mmol), pd₂dba₃ (1.8 g, 2.0 mmol), tris-tert-butyl phosphine (1.9 ml, 4.0 mmol), and sodium tert-butoxide (7.7 g, 80 mmol) were put into a 2 L flask under argon condition and dissolved in 700 ml of toluene, and the reaction solution was stirred at 80° C. for 12 hours. After cooling, water (1 L) and ethylacetate (300 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 7-a (white solid, 17.0 g, 28.8 mmol, 72%). By ESI-LCMS, the obtained compound was identified as Compound 7-a.

ESI-LCMS: [M]⁺: C₃₈H₃₈BrN. 587.22

### Synthesis of Intermediate 7-b

Intermediate compound 7-a (17.0 g, 28.8 mmol), N-([1,1′-biphenyl]-4-yl)-3′,5′-di-tert-butyl-[1,1′-biphenyl]-2-amine (15.0 g, 34.6 mmol), pd₂dba₃ (1.3 g, 1.4 mmol), tris-tert-butyl phosphine (1.3 ml, 2.9 mmol), and sodium tert-butoxide (5.5 g, 57.6 mmol) were put into a 2 L flask under argon condition and dissolved in 300 ml of o-xylene, and the reaction solution was stirred at 140° C. for 12 hours. After cooling, water (300 ml) and ethylacetate (200 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 7-b (white solid, 21.7 g, 23.0 mmol, 80%). By ESI-LCMS, the obtained compound was identified as Compound 7-b.

ESI-LCMS: [M]⁺: C₇₀H₇₂N₂. 941.36.

### Synthesis of Compound 7

Compound 86-c (10.0 g, 11.6 mmol) was put into a 500 ml flask under argon atmosphere and dissolved in 200 ml of o-dichlorobenzene, followed by cooling using water-ice, BBr₃ (5 equiv.) was slowly added dropwise thereto, and the reaction solution was stirred at 180° C. for 12 hours. After cooling, triethylamine (5 equiv.) was added thereto to terminate the reaction, and water/CH₂Cl₂ were used for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Compound 7 (yellow solid, 4.3 g, 4.5 mmol, 39%). By ¹H-NMR and ESI-LCMS, the obtained compound was identified as Compound 7.

ESI-LCMS: [M]⁺: C₇₀H69BN₂. 948.56.

### Synthesis Example 2. Synthesis of Compound 25

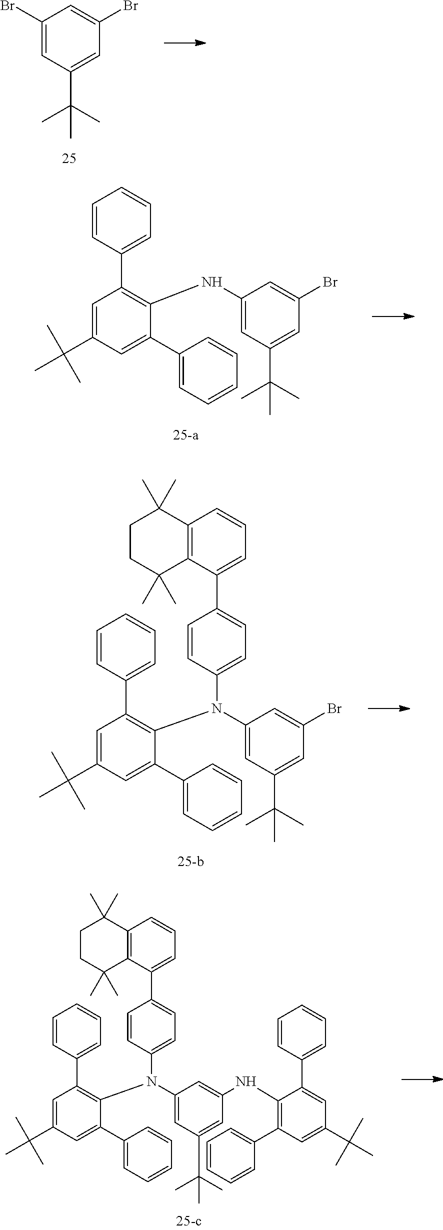 [SMILES: CC(C)(C)c1cc(Br)cc(Br)c1 ; CC(C)(C)c1cc(Br)cc(Nc2c(-c3ccccc3)cc(C(C)(C)C)cc2-c2ccccc2)c1 ; CC(C)(C)c1cc(Br)cc(N(c2ccc(-c3cccc4c3C(C)(C)CCC4(C)C)cc2)c2c(-c3ccccc3)cc(C(C)(C)C)cc2-c2ccccc2)c1 ; CC(C)(C)c1cc(Nc2c(-c3ccccc3)cc(C(C)(C)C)cc2-c2ccccc2)cc(N(c2ccc(-c3cccc4c3C(C)(C)CCC4(C)C)cc2)c2c(-c3ccccc3)cc(C(C)(C)C)cc2-c2ccccc2)c1]

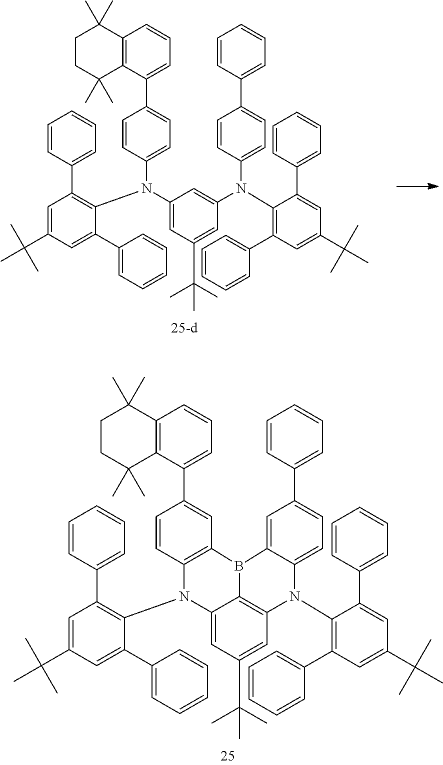

### Synthesis of Intermediate 25-a

5′-(tert-butyl)[1,1′:3′,1″-terphenyl]-2′-amine (15.1 g, 50 mmol), 1,3-dibromo-5-(tert-butyl)benzene (21.9 g, 75 mmol), pd₂dba₃ (2.3 g, 2.5 mmol), tris-tert-butyl phosphine (2.3 ml, 5.0 mmol), and sodium tert-butoxide (9.6 g, 100 mmol) were put into a 2 L flask under argon condition and dissolved in 700 ml of toluene, and the reaction solution was stirred at 80° C. for 12 hours. After cooling, water (1 L) and ethylacetate (300 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 25-a (white solid, 18.2 g, 35.5 mmol, 71%). By ESI-LCMS, the obtained compound was identified as Compound 25-a.

ESI-LCMS: [M]⁺: C₃₂H34BrN. 513.19.

### Synthesis of Intermediate 25-b

Compound 25-a (18.2 g, 35.5 mmol), 5-(4-bromophenyl)-1,1,4,4-tetramethyl-1,2,3,4-tetrahydronaphthalene (61.1 g, 177.5 mmol), pd₂dba₃ (3.3 g, 3.6 mmol), tris-tert-butyl phosphine (3.3 ml, 7.1 mmol), and sodium tert-butoxide (17.1 g, 177.5 mmol) were put into a 1 L flask under argon condition and dissolved in 300 ml of o-xylene, and the reaction solution was stirred at 140° C. for 72 hours. After cooling, water (600 ml) and ethylacetate (400 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 25-b (white solid, 18.2 g, 23.4 mmol, 66%). By ESI-LCMS, the obtained compound was identified as Compound 25-b.

ESI-LCMS: [M]⁺: C₅₂H₅₆BrN. 773.36.

### Synthesis of Intermediate 25-c

5′-(tert-butyl)[1,1′:3′,1″-terphenyl]-2′-amine (8.5 g, 28.1 mmol), Compound 25-b (18.2 g, 23.4 mmol), pd₂dba₃ (1.1 g, 1.2 mmol), tris-tert-butyl phosphine (1.1 ml, 2.3 mmol), and sodium tert-butoxide (4.5 g, 46.8 mmol) were put into a 2 L flask under argon condition and dissolved in 300 ml of toluene, and the reaction solution was stirred at 100° C. for 12 hours. After cooling, water (300 ml) was added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 25-c (white solid, 20.7 g, 20.8 mmol, 89%). By ESI-LCMS, the obtained compound was identified as Compound 25-c.

ESI-LCMS: [M]⁺: C₇₄H₇₈N₂. 994.62.

### Synthesis of Intermediate 25-d

Compound 25-c (20.7 g, 20.8 mmol), 4-iodo-1,1′-biphenyl (29.1 g, 104 mmol), pd₂dba₃ (1.9 g, 2.1 mmol), tris-tert-butyl phosphine (1.9 ml, 4.2 mmol), and sodium tert-butoxide (10.0 g, 104 mmol) were put into a 1 L flask under argon condition and dissolved in 200 ml of o-xylene, and the reaction solution was stirred at 140° 0 for 72 hours. After cooling, water (400 ml) and ethylacetate (200 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 25-d (white solid, 15.5 g, 13.5 mmol, 65%). By ESI-LCMS, the obtained compound was identified as Compound 25-d.

ESI-LCMS: [M]⁺: C₈₆H₈₆N₂. 1146.68.

### Synthesis of Compound 25

Compound 25-d (10.0 g, 8.7 mmol) was put into a 500 ml flask under argon atmosphere and dissolved in 200 ml of o-dichlorobenzene, followed by cooling using water-ice, BBr₃ (5 equiv.) was slowly added dropwise thereto, and the reaction solution was stirred at 180° C. for 12 hours. After cooling, triethylamine (5 equiv.) was added thereto to terminate the reaction, and water/CH₂Cl₂ were used for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Compound 25 (yellow solid, 3.0 g, 2.6 mmol, 30%). By ¹H-NMR and ESI-LCMS, the obtained compound was identified as Compound 25.

ESI-LCMS: [M]⁺: C₈₆H83BN₂. 1154.66.

### Synthesis Example 3. Synthesis of Compound 69

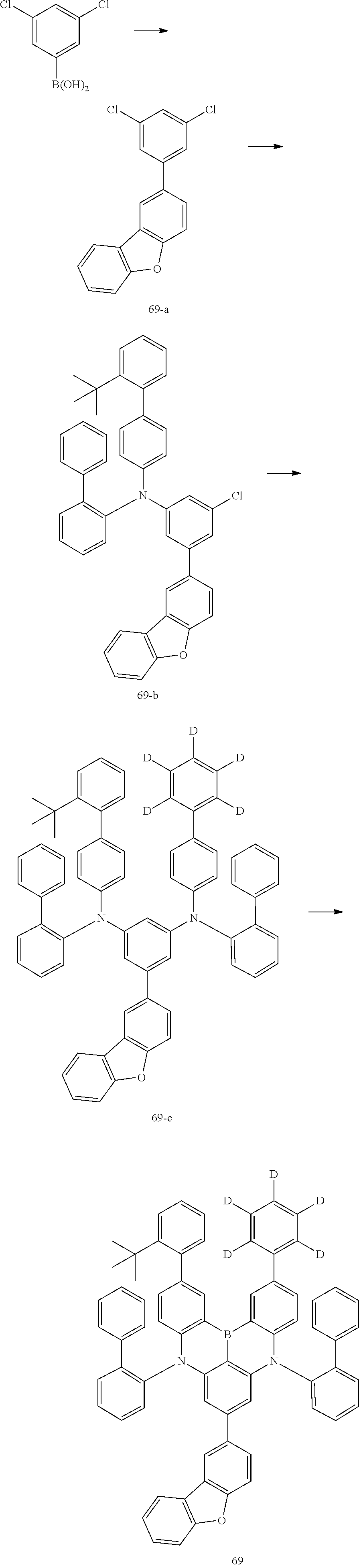 [SMILES: OB(O)c1cc(Cl)cc(Cl)c1 ; Clc1cc(Cl)cc(-c2ccc3oc4ccccc4c3c2)c1 ; CC(C)(C)c1ccccc1-c1ccc(N(c2cc(Cl)cc(-c3ccc4oc5ccccc5c4c3)c2)c2ccccc2-c2ccccc2)cc1 ; [2H]c1c([2H])c([2H])c(-c2ccc(N(c3cc(-c4ccc5oc6ccccc6c5c4)cc(N(c4ccc(-c5ccccc5C(C)(C)C)cc4)c4ccccc4-c4ccccc4)c3)c3ccccc3-c3ccccc3)cc2)c([2H])c1[2H] ; [2H]c1c([2H])c([2H])c(-c2ccc3c(c2)B2c4cc(-c5ccccc5C(C)(C)C)ccc4N(c4ccccc4-c4ccccc4)c4cc(-c5ccc6oc7ccccc7c6c5)cc(c42)N3c2ccccc2-c2ccccc2)c([2H])c1[2H]]

### Synthesis of Intermediate 69-a

(3,5-dichlorophenyl)boronic acid (9.5 g, 50.0 mmol), 2-bromodibenzo[b,d]furan (14.8 g, 60.0 mmol), pd(PPh₃)₄ (2.9 g, 2.5 mmol), and potassium carbonate (13.8 g, 100 mmol) were put into a 2 L flask under argon atmosphere and dissolved in 500 ml of toluene and 200 ml of H₂O, and the reaction solution was stirred at 100° C. for 12 hours. After cooling, water (300 ml) was added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 69-a (white solid, 11.7 g, 37.5 mmol, 75%). By ESI-LCMS, the obtained compound was identified as Compound 69-a.

ESI-LCMS: [M]⁺: C₁₈H₁₀Cl₂O. 312.01.

### Synthesis of Intermediate 69-b

N-(2′-(tert-butyl)-[1,1′-biphenyl]-4-yl)-[1,1′-biphenyl]-2-amine (11.8 g, 31.3 mmol), Compound 69-a (11.7 g, 37.5 mmol), pd₂dba₃ (1.4 g, 1.6 mmol), tris-tert-butyl phosphine (1.5 ml, 3.1 mmol), and sodium tert-butoxide (6.0 g, 62.6 mmol) were put into a 1 L flask under argon condition and dissolved in 400 ml of toluene, and the reaction solution was stirred at 80° C. for 12 hours. After cooling, water (500 ml) was added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 69-b (white solid, 13.9 g, 21.3 mmol, 68%). By ESI-LCMS, the obtained compound was identified as Compound 69-b.

ESI-LCMS: [M]⁺: C₄₆H₃₆ClNO. 653.25

### Synthesis of Intermediate 69-c

N-([1,1′-biphenyl]-4-yl-2′,3′,4′,5′,6′-d5)-[1,1′-biphenyl]-2-amine (8.3 g, 25.6 mmol), Compound 69-b (13.9 g, 21.3 mmol), pd₂dba₃ (0.98 g, 1.1 mmol), tris-tert-butyl phosphine (0.99 ml, 2.1 mmol), and sodium tert-butoxide (4.1 g, 42.6 mmol) were put into a 1 L flask under argon condition and dissolved in 300 ml of toluene, and the reaction solution was stirred at 100° C. for 12 hours. After cooling, water (500 ml) was added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 69-c (white solid, 14.3 g, 15.1 mmol, 71%). By ESI-LCMS, the obtained compound was identified as Compound 69-c.

ESI-LCMS: [M]⁺: C₇₀H₄₉D₅N₂O. 943.45

### Synthesis of Compound 69

Compound 69-c (14.3 g, 15.1 mmol) was put into a 500 ml flask under argon atmosphere and dissolved in 250 ml of o-dichlorobenzene, followed by cooling using water-ice, BBr₃ (5 equiv.) was slowly added dropwise thereto, and the reaction solution was stirred at 180° C. for 12 hours. After cooling, triethylamine (5 equiv.) was added thereto to terminate the reaction, and water/CH₂Cl₂ were used for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Compound 69 (yellow solid, 5.5 g, 5.7 mmol, 38%). By ¹H-NMR and ESI-LCMS, the obtained compound was identified as Compound 69.

ESI-LCMS: [M]⁺: C₇₀H₄₆D₅BN₂O. 951.44.

### Synthesis Example 4. Synthesis of Compound 86

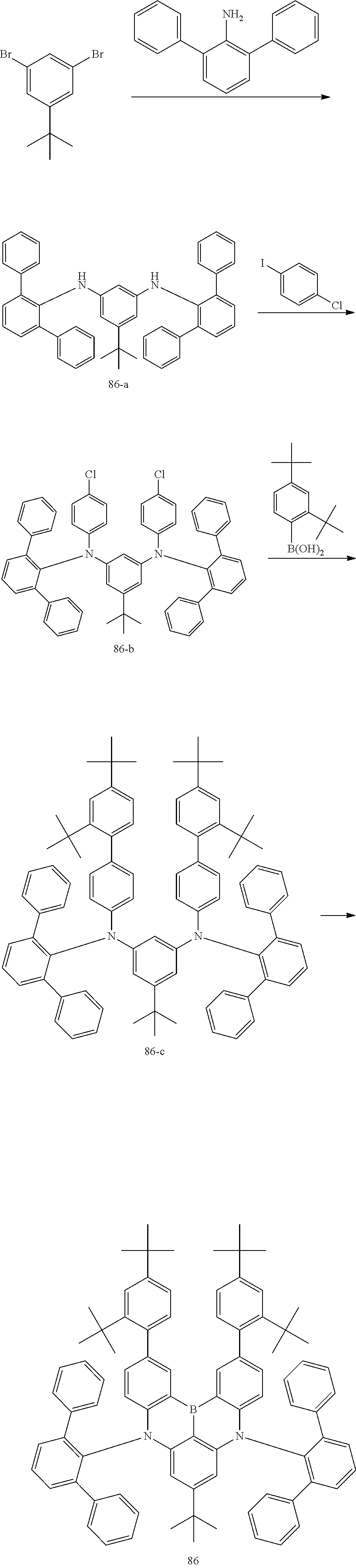

### Synthesis of Intermediate 86-a

[1,1′:3′,1″-terphenyl]-2′-amine (18 g, 74 mmol), 1,3-dibromo-5-(tert-butyl)benzene (10.8 g, 37 mmol), pd₂dba₃ (1.7 g, 1.9 mmol), tris-tert-butyl phosphine (1.7 ml, 3.7 mmol), and sodium tert-butoxide (10.7 g, 111 mmol) were put into a 2 L flask under argon condition and dissolved in 700 ml of o-xylene, and the reaction solution was stirred at 140° C. for 12 hours. After cooling, water (1 L) and ethylacetate (300 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 86-a (white solid, 18.6 g, 30 mmol, 81%). By ESI-LCMS, the obtained compound was identified as Compound 86-a.

ESI-LCMS: [M]⁺: C₄₆H₄₀N₂. 620.32.

### Synthesis of Intermediate 86-b

Compound 86-a (18.6 g, 30 mmol), 4-chloroiodobenzene (35.8 g, 150 mmol), pd₂dba₃ (1.4 g, 1.5 mmol), tris-tert-butyl phosphine (1.4 ml, 3.0 mmol), and sodium tert-butoxide (8.6 g, 90 mmol) were put into a 1 L flask under argon condition and dissolved in 300 ml of o-xylene, and the reaction solution was stirred at 140° C. for 72 hours. After cooling, water (600 ml) and ethylacetate (400 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 86-b (white solid, 17.2 g, 20.4 mmol, 68%). By ESI-LCMS, the obtained compound was identified as Compound 86-b.

ESI-LCMS: [M]⁺: C₅₈H₄₆Cl₂N₂. 840.30.

### Synthesis of Intermediate 86-c

Compound 86-b (17.2 g, 20.4 mmol), (2,4-di-tert-butylphenyl)boronic acid (5.7 g, 24.5 mmol), pd(PPh₃)₄ (1.2 g, 1.0 mmol), and potassium carbonate (8.5 g, 61.2 mmol) were put into a 1 L flask under argon atmosphere and dissolved in 210 ml of toluene and 70 ml of H₂O, and the reaction solution was stirred at 100° C. for 12 hours. After cooling, water (500 ml) and ethylacetate (300 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 86-c (white solid, 13.4 g, 11.6 mmol, 57%). By ESI-LCMS, the obtained compound was identified as Compound 86-c.

ESI-LCMS: [M]⁺: C₈₆H₈₈N₂. 1148.69.

### Synthesis of Compound 86

Compound 86-c (13.4 g, 11.6 mmol) was put into a 500 ml flask under argon atmosphere and dissolved in 200 ml of o-dichlorobenzene, followed by cooling using water-ice, BBr₃ (5 equiv.) was slowly added dropwise thereto, and the reaction solution was stirred at 180° C. for 12 hours. After cooling, triethylamine (5 equiv.) was added thereto to terminate the reaction, and water/CH₂Cl₂ were used for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Compound 86 (yellow solid, 4.7 g, 4.1 mmol, 35%). By ¹H-NMR and ESI-LCMS, the obtained compound was identified as Compound 86.

ESI-LCMS: [M]⁺: C₈₆H₈₅BN₂. 1156.68.

### Synthesis Example 5. Synthesis of Compound 105

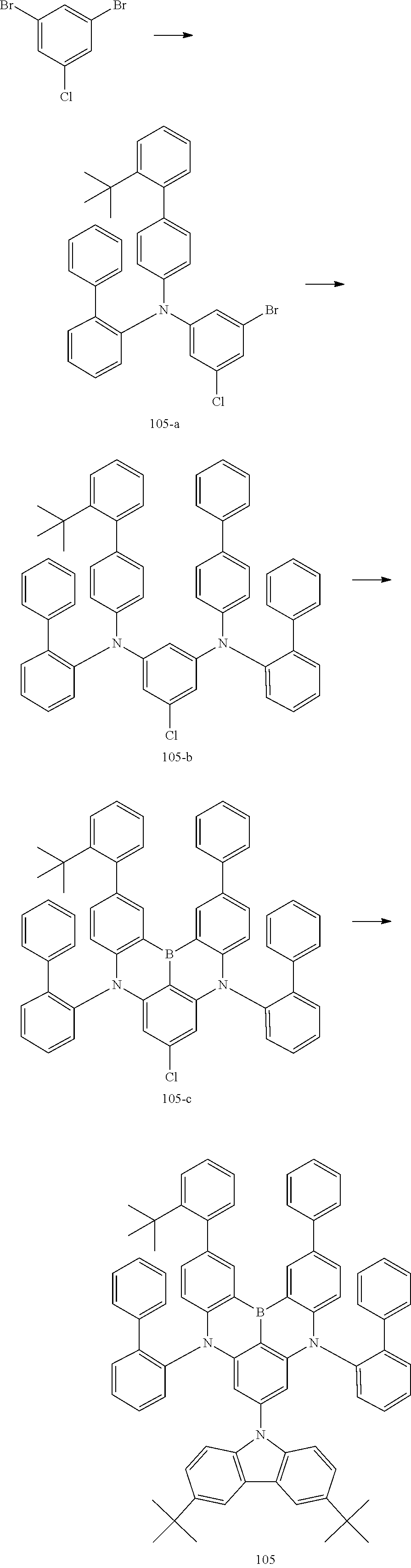 [SMILES: Clc1cc(Br)cc(Br)c1 ; CC(C)(C)c1ccccc1-c1ccc(N(c2cc(Cl)cc(Br)c2)c2ccccc2-c2ccccc2)cc1 ; CC(C)(C)c1ccccc1-c1ccc(N(c2cc(Cl)cc(N(c3ccc(-c4ccccc4)cc3)c3ccccc3-c3ccccc3)c2)c2ccccc2-c2ccccc2)cc1 ; CC(C)(C)c1ccccc1-c1ccc2c(c1)B1c3cc(-c4ccccc4)ccc3N(c3ccccc3-c3ccccc3)c3cc(Cl)cc(c31)N2c1ccccc1-c1ccccc1 ; CC(C)(C)c1ccc2c(c1)c1cc(C(C)(C)C)ccc1n2-c1cc2c3c(c1)N(c1ccccc1-c1ccccc1)c1ccc(-c4ccccc4C(C)(C)C)cc1B3c1cc(-c3ccccc3)ccc1N2c1ccccc1-c1ccccc1]

### Synthesis of Intermediate 105-a

1,3-dibromo-5-chlorobenzene (16.2 g, 60 mmol), N-(2′-(tert-butyl)-[1,1′-biphenyl]-4-yl)-[1,1′-biphenyl]-2-amine (15.1 g, 40 mmol), pd₂dba₃ (1.8 g, 2.0 mmol), tris-tert-butyl phosphine (1.9 ml, 4.0 mmol), and sodium tert-butoxide (7.7 g, 80 mmol) were put into a 2 L flask under argon condition and dissolved in 700 ml of toluene, and the reaction solution was stirred at 80° C. for 12 hours. After cooling, water (600 ml) was added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 105-a (white solid, 14.7 g, 26.0 mmol, 65%). By ESI-LCMS, the obtained compound was identified as Compound 105-a.

ESI-LCMS: [M]⁺: C₃₄H₂₃BrClN. 567.12.

### Synthesis of Intermediate 105-b

Compound 105-a (14.7 g, 26.0 mmol), N-([1,1′-biphenyl]-4-yl)-[1,1′-biphenyl]-2-amine (10.0 g, 31.2 mmol), pd₂dba₃ (1.2 g, 1.3 mmol), tris-tert-butyl phosphine (1.2 ml, 2.6 mmol), and sodium tert-butoxide (5.0 g, 52 mmol) were put into a 1 L flask under argon condition and dissolved in 300 ml of toluene, and the reaction solution was stirred at 100° C. for 12 hours. After cooling, water (300 ml) was added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 105-b (white solid, 15.5 g, 19.2 mmol, 74%). By ESI-LCMS, the obtained compound was identified as Compound 105-b.

ESI-LCMS: [M]⁺: C₅₈H₄₇ClN₂. 806.34.

### Synthesis of Intermediate 105-c

Compound 105-b (15.5 g, 19.2 mmol) was put into a 1 L flask under argon atmosphere and dissolved in 300 ml of o-dichlorobenzene, followed by cooling using water-ice, BBr₃ (5 equiv.) was slowly added dropwise thereto, and the reaction solution was stirred at 180° C. for 12 hours. After cooling, triethylamine (5 equiv.) was added thereto to terminate the reaction, and water/CH₂Cl₂ were used for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 105-c (yellow solid, 6.1 g, 7.5 mmol, 39%). By ESI-LCMS, the obtained compound was identified as Compound 105-c.

ESI-LCMS: [M]⁺: C₅₈H₄₄BClN₂. 814.33.

### Synthesis of Compound 105

Compound 105-c (6.1 g, 7.5 mmol), 3,6-di-tert-butyl-9H-carbazole (2.5 g, 9.0 mmol), pd₂dba₃ (0.34 g, 0.38 mmol), tris-tert-butyl phosphine (0.35 ml, 0.75 mmol), and sodium tert-butoxide (1.4 g, 15 mmol) were put into a 500 ml flask under argon condition and dissolved in 100 ml of o-xylene, and the reaction solution was stirred at 150° C. for 12 hours. After cooling, water (200 ml) and ethylacetate (100 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Compound 105 (yellow solid, 5.6 g, 5.3 mmol, 70%). By ¹H-NMR and ESI-LCMS, the obtained compound was identified as Compound 105.

ESI-LCMS: [M]⁺: C₇₈H₆₈BN₃. 1057.55.

### Synthesis Example 6. Synthesis of Compound 109

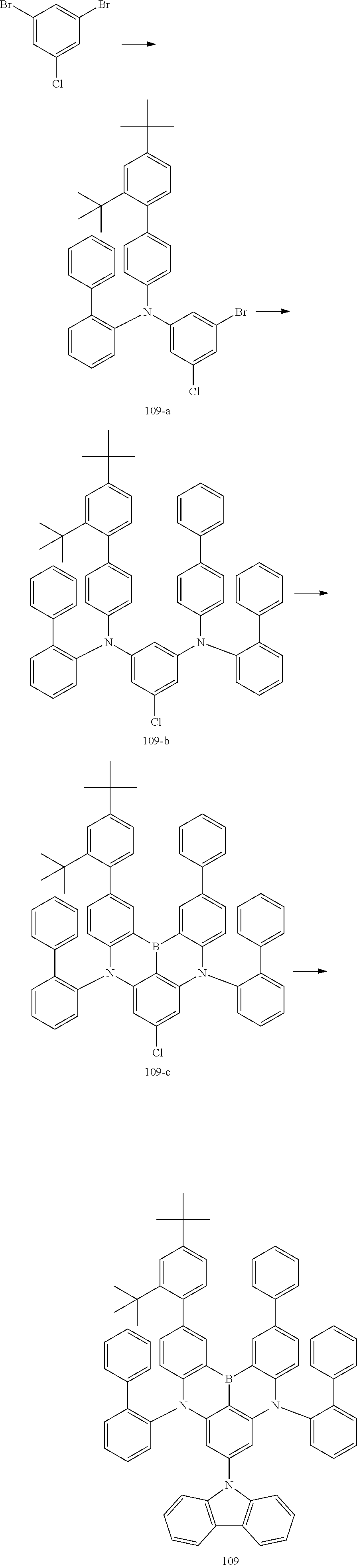 [SMILES: Clc1cc(Br)cc(Br)c1 ; CC(C)(C)c1ccc(-c2ccc(N(c3cc(Cl)cc(Br)c3)c3ccccc3-c3ccccc3)cc2)c(C(C)(C)C)c1 ; CC(C)(C)c1ccc(-c2ccc(N(c3cc(Cl)cc(N(c4ccc(-c5ccccc5)cc4)c4ccccc4-c4ccccc4)c3)c3ccccc3-c3ccccc3)cc2)c(C(C)(C)C)c1 ; CC(C)(C)c1ccc(-c2ccc3c(c2)B2c4cc(-c5ccccc5)ccc4N(c4ccccc4-c4ccccc4)c4cc(Cl)cc(c42)N3c2ccccc2-c2ccccc2)c(C(C)(C)C)c1 ; CC(C)(C)c1ccc(-c2ccc3c(c2)B2c4cc(-c5ccccc5)ccc4N(c4ccccc4-c4ccccc4)c4cc(-n5c6ccccc6c6ccccc65)cc(c42)N3c2ccccc2-c2ccccc2)c(C(C)(C)C)c1]

### Synthesis of Intermediate 109-a

1,3-dibromo-5-chlorobenzene (16.2 g, 60 mmol), N-(2′,4′-di-tert-butyl-[1,1′-biphenyl]-4-yl)-[1,1′-biphenyl]-2-amine (17.3 g, 40 mmol), pd₂dba₃ (1.8 g, 2.0 mmol), tris-tert-butyl phosphine (1.9 ml, 4.0 mmol), and sodium tert-butoxide (7.7 g, 80 mmol) were put into a 2 L flask under argon condition and dissolved in 700 ml of toluene, and the reaction solution was stirred at 80° C. for 12 hours. After cooling, water (600 ml) was added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 109-a (white solid, 16.7 g, 26.8 mmol, 67%). By ESI-LCMS, the obtained compound was identified as Intermediate compound 109-a. ESI-LCMS: [M]⁺: C₃₈H₃₇BrClN. 623.18.

### Synthesis of Intermediate 109-b

Intermediate compound 109-a (16.7 g, 26.8 mmol), N-([1,1′-biphenyl]-4-yl)-[1,1′-biphenyl]-2-amine (10.3 g, 32.2 mmol), pd₂dba₃ (1.2 g, 1.3 mmol), tris-tert-butyl phosphine (1.3 ml, 2.7 mmol), and sodium tert-butoxide (5.2 g, 53.6 mmol) were put into a 1 L flask under argon condition and dissolved in 500 ml of toluene, and the reaction solution was stirred at 100° C. for 12 hours. After cooling, water (500 ml) was added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 109-b (white solid, 18.5 g, 21.4 mmol, 80%). By ESI-LCMS, the obtained compound was identified as Compound 109-b.

ESI-LCMS: [M]⁺: C₆₂H₅₅ClN₂. 862.41.

### Synthesis of Intermediate 109-c

Compound 109-b (10.0 g, 11.6 mmol) was put into a 1 L flask under argon atmosphere and dissolved in 200 ml of o-dichlorobenzene, followed by cooling using water-ice, BBr₃ (5 equiv.) was slowly added dropwise thereto, and the reaction solution was stirred at 180° C. for 12 hours. After cooling, triethylamine (5 equiv.) was added thereto to terminate the reaction, and water/CH₂Cl₂ were used for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Intermediate compound 109-c (yellow solid, 3.5 g, 4.1 mmol, 35%). By ESI-LCMS, the obtained compound was identified as Compound 109-c.

ESI-LCMS: [M]⁺: C₅₈H₄₄BClN₂. 814.33.

### Synthesis of Compound 109

Compound 109-c (3.5 g, 4.1 mmol), 9H-carbazole (0.82 g, 4.9 mmol), pd₂dba₃ (0.19 g, 0.21 mmol), tris-tert-butyl phosphine (0.19 ml, 0.41 mmol), and sodium tert-butoxide (0.79 g, 8.2 mmol) were put into a 500 ml flask under argon condition and dissolved in 100 ml of o-xylene, and the reaction solution was stirred at 150° C. for 12 hours. After cooling, water (200 ml) and ethylacetate (100 ml) were added thereto for extraction and collection of an organic layer which was dried using MgSO₄ and filtered. The filtered solution was decompressed to remove the solvent therefrom, and a solid thus obtained was subjected to silica gel column chromatography using CH₂Cl₂ and hexane as developing solvents for purification and separation, to thereby obtain Compound 109 (yellow solid, 2.8 g, 2.8 mmol, 68%). By ¹H-NMR and ESI-LCMS, the obtained compound was identified as Compound 109.

ESI-LCMS: [M]⁺: C₇₄H₆₀BN₃. 1001.49.

¹H NMR measurement results of the compounds synthesized according to the Synthesis Examples above are shown in Table 1. Synthesis methods of compounds other than the compounds of the Synthesis Examples may be readily recognized by those of ordinary skill in the art by referring to the synthesis paths and source materials.

TABLE 1

| Com- | |
|---|---|
| pound | ¹H NMR (CDCl₃, 500 MHz) |
| 7 | 9.02 (s, 1H), 8.99 (s, 1H), 7.88-7.84 (m, 3H), 7.76-7.70 (m, |
| | 9H), 7.56-7.49 (m, 8H), 7.24-7.20 (m, 6H), 7.14-7.12 (m, 4H), |
| | 7.02-7.01 (m, 2H), 1.28 (s, 9H), 1.20 (s, 18H), 1.15 (s, 9H) |
| 25 | 8.91 (s, 1H), 8.87 (s, 1H), 7.63 (s, 4H), 7.21-7.18 (m, 4H), |
| | 7.15-7.13 (m, 5H), 7.08-7.04 (m, 11H), 7.02 (d, 2H) 7.00-6.92 |
| | (m, 13H), 6.35 (s, 2H), 1.90-1.81 (m, 4H) 1.49(s, 6H), 1.32 |
| | (s, 6H), 1.25 (s, 9H), 1.19 (s, 18H) |
| 69 | 8.98 (s, 1H), 8.96 (s, 1H), 7.97 (d, 2H), 7.75-7.69 (m, 9H), |
| | 7.56-7.49 (m, 12H), 7.24-7.20 (m, 6H), 7.14-7.12 (m, 4H), |
| | 6.97-6.95 (m, 2H), 1.21 (s, 9H) |
| 86 | 8.87 (s, 2H), 7.60 (d, 4H), 7.50-7.43 (m, 4H), 7.32 (t, 2H), |
| | 7.20-7.11 (m, 5H), 7.05-6.96 (m, 12H), 6.94-6.87 (m, 10H), |
| | 6.30 (s, 2H), 1.38 (s, 18H), 1.35 (s, 18H), 1.32(s, 9H) |
| 105 | 9.03 (s, 1H), 9.02 (s, 1H), 8.11 (s, 2H), 7.47 (d, 2H), 7.42 |
| | (d, 2H), 7.37-7.32 (m, 4H), 7.30-7.26 (m, 5H), 7.22-7.14 (m, |
| | 10H), 7.10-7.02 (m, 12H), 6.30 (s, 2H), 1.35 (s, 18H), 1.25 |
| | (s, 9H) |
| 109 | 9.01 (s, 1H), 8.90 (s, 1H), 8.08 (d, 2H), 7.46 (d, 2H), 7.41 |
| | (d, 2H), 7.38-7.33 (m, 4H), 7.30-7.26 (m, 4H), 7.22-7.14 (m, |
| | 12H), 7.12-7.04 (m, 12H), 6.21 (s, 2H), 1.35 (s, 9H), 1.25 |
| | (s, 9H) |

### Example 1

As an anode, a glass substrate (available from Corning Co., Ltd), on which an ITO electrode (15 Ω/cm²) having a thickness of 1,200 Å was formed, was cut to a size of 50 mm×50 mm×0.7 mm, sonicated in isopropyl alcohol and pure water for 5 minutes in each solvent, cleaned by irradiation of ultraviolet rays and exposure of ozone thereto for 30 minutes, and was mounted on a vacuum deposition apparatus.

NPB was deposited on the anode to form a hole injection layer having a thickness of 300 Å, Compound HT6 was deposited on the hole injection layer to form a hole transport layer having a thickness of 200 Å, and CzSi was deposited on the hole transport layer to form an emission auxiliary layer having a thickness of 100 Å.

Compounds HTH53 and ETH85 (at a weight ratio of 5:5) as hosts, Compound PD40 as a sensitizer, and Compound 69 as a luminescent material were co-deposited at a weight ratio of 82:15:3 on the emission auxiliary layer to form an emission layer having a thickness of 200 Å.

TSPO1 was deposited on the emission layer to form a hole blocking layer having a thickness of 200 Å, TPBI was deposited on the hole blocking layer to form an electron transport layer having a thickness of 300 Å, LiF was deposited on the electron transport layer to form an electron injection layer having a thickness of 10 Å, Al was deposited on the electron injection layer to form a LiF/AI cathode having a thickness of 3,000 Å, and HT28 was deposited on the cathode to form a capping layer having a thickness of 700 Å, thereby completing the manufacture of a light-emitting device.

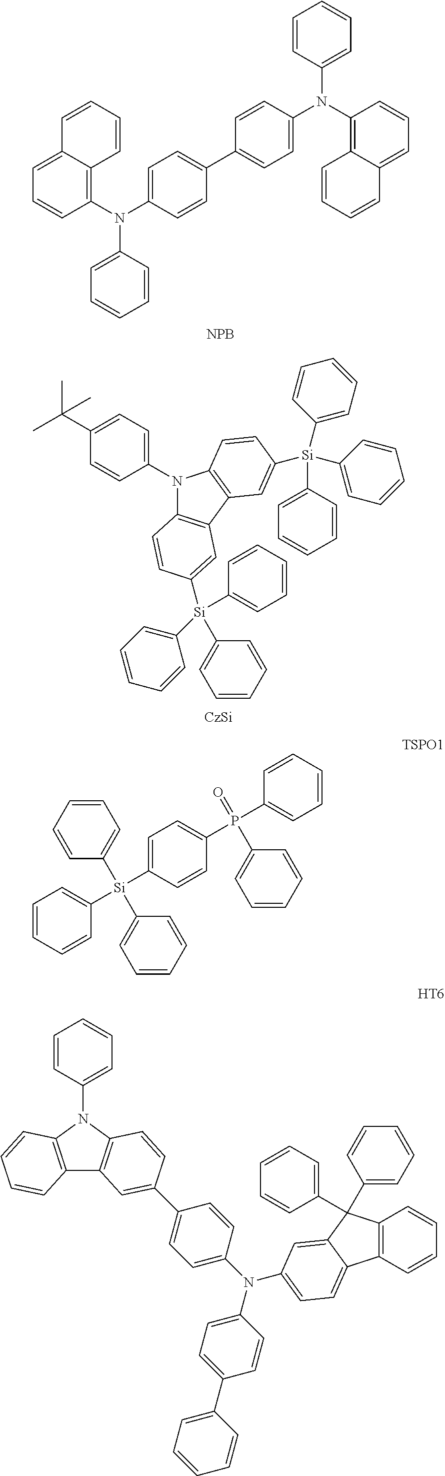

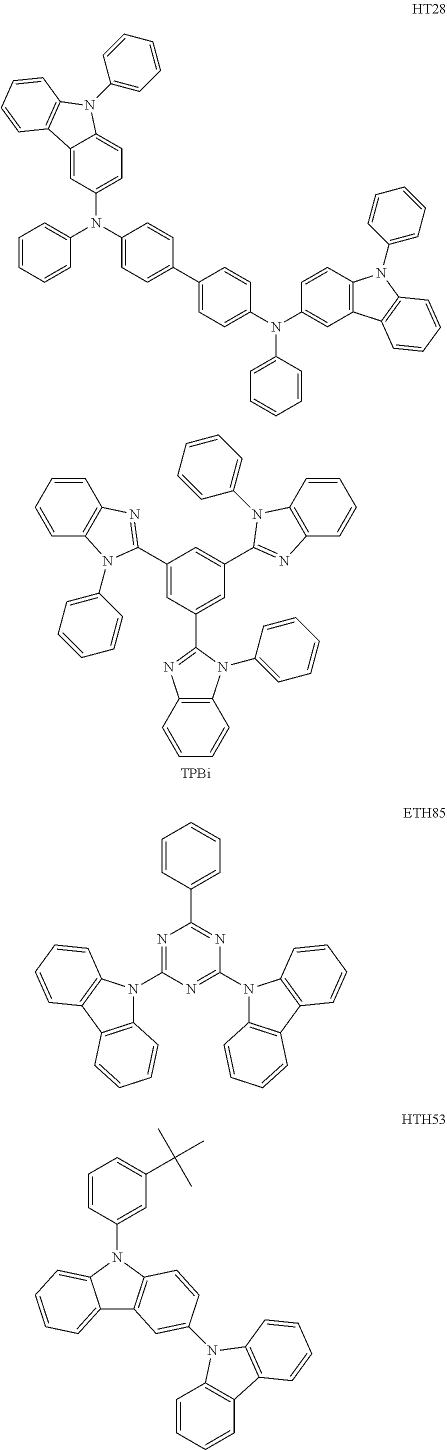

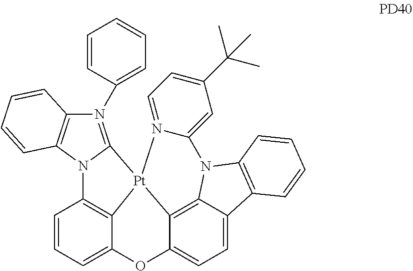

### Examples 2 to 6 and Comparative Examples 1 to 5

Light-emitting devices were manufactured in the same manner as in Example 1, except that compounds shown in Table 2 were used as the luminescent material in forming the emission layer.

### Evaluation Example 1

To evaluate characteristics of the light-emitting devices manufactured in Examples 1 to 6 and Comparative Examples 1 to 5, driving voltage at current density of 10 mA/cm² and efficiency (cd/A) were measured, and the lifespan ratio (T₉₅) was measured by comparing, with Comparative Example 1, the amount of time taken when the luminance becomes 50% of the initial luminance value when the device was continuously driven at current density of 10 mA/cm². Results thereof are shown in Table 2.

TABLE 2

| | Hole | | | | Driving | | Emission | |
|---|---|---|---|---|---|---|---|---|
| | transport | | Sensitizer | Luminescent | voltage | Efficiency | wavelength | Lifespan |
| | layer | Host (5:5) | (15%) | material (3%) | (V) | (cd/A) | (nm) | ratio (T₉₅) |
| Example 1 | HT6 | HTH53/ETH85 | PD40 | 7 | 4.4 | 28.8 | 460 | 4.3 |
| Example 2 | HT6 | HTH53/ETH85 | PD40 | 25 | 4.5 | 28.5 | 458 | 4.5 |
| Example 3 | HT6 | HTH53/ETH85 | PD40 | 69 | 4.3 | 29.1 | 459 | 5.0 |
| Example 4 | HT6 | HTH53/ETH85 | PD40 | 86 | 4.1 | 28.9 | 457 | 5.8 |
| Example 5 | HT6 | HTH53/ETH85 | PD40 | 105 | 4.5 | 25.3 | 456 | 4.8 |
| Example 6 | HT6 | HTH53/ETH85 | PD40 | 109 | 4.2 | 27.2 | 456 | 4.7 |
| Comparative | HT6 | HTH53/ETH85 | PD40 | Compound A | 4.8 | 15.5 | 457 | 1 |
| Example 1 | | | | | | | | |
| Comparative | HT6 | HTH53/ETH85 | PD40 | Compound B | 4.7 | 21.9 | 466 | 2.1 |
| Example 2 | | | | | | | | |
| Comparative | HT6 | HTH53/ETH85 | PD40 | Compound C | 4.7 | 16.1 | 460 | 0.3 |
| Example 3 | | | | | | | | |
| Comparative | HT6 | HTH53/ETH85 | PD40 | Compound D | 4.6 | 19.8 | 451 | 1.1 |
| Example 4 | | | | | | | | |
| Comparative | HT6 | HTH53/ETH85 | PD40 | Compound E | 4.8 | 15.2 | 460 | 2.3 |
| Example 5 | | | | | | | | |

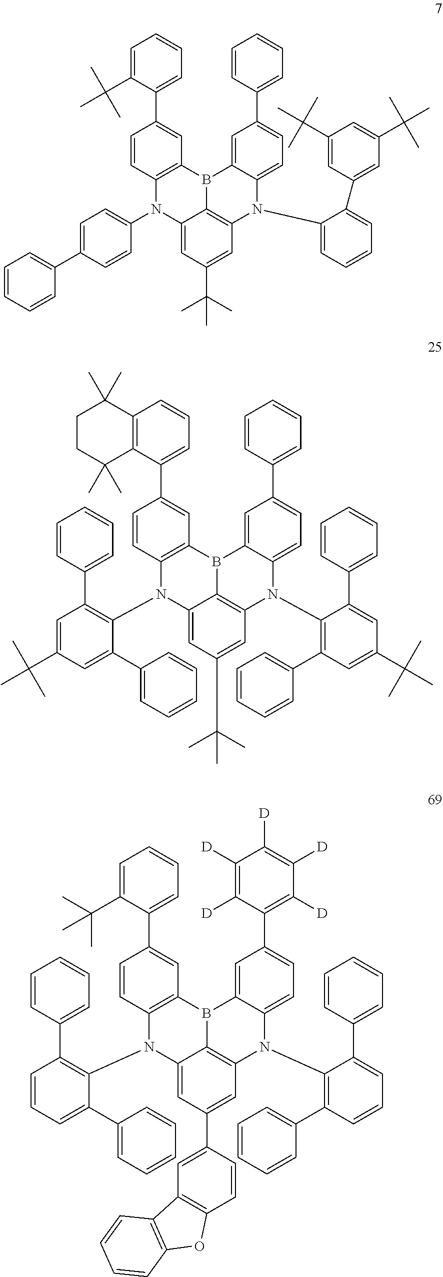

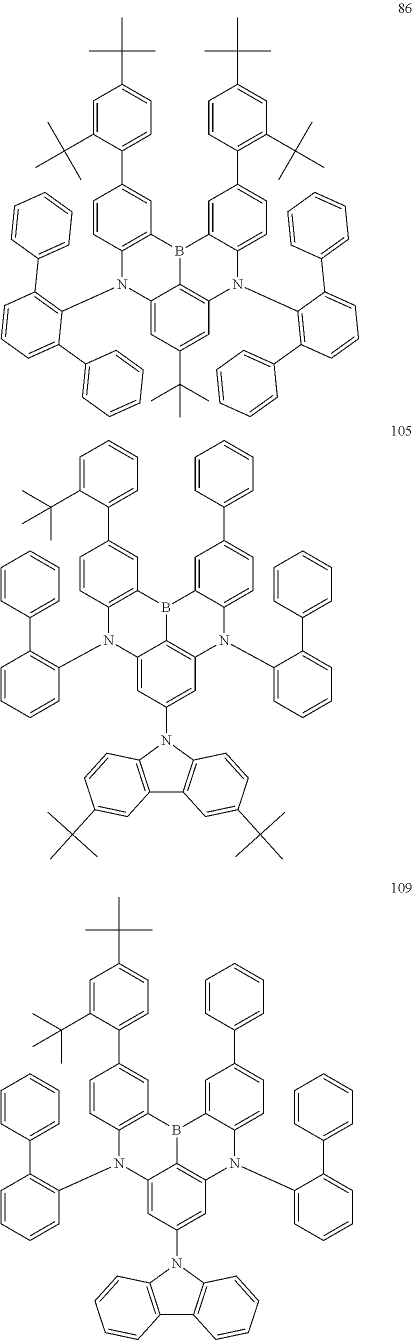

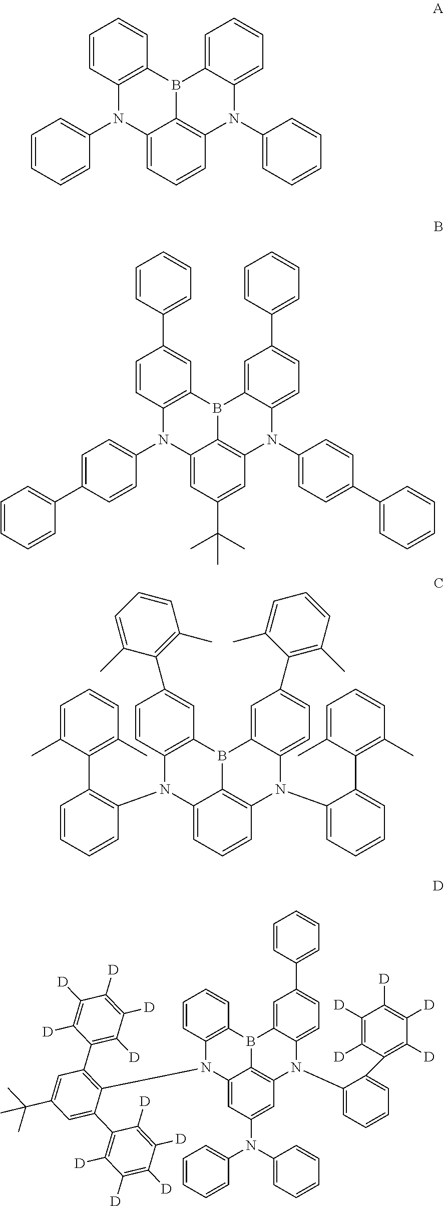

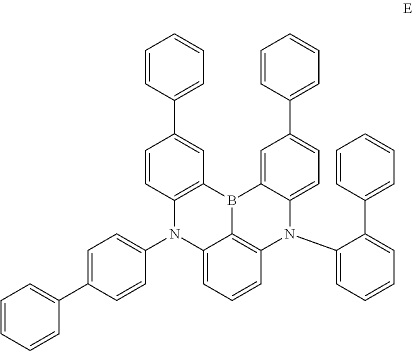 [SMILES: c1ccc(-c2ccc(N3c4ccc(-c5ccccc5)cc4B4c5cc(-c6ccccc6)ccc5N(c5ccccc5-c5ccccc5)c5cccc3c54)cc2)cc1]

From Table 2, it could be confirmed that the light-emitting devices of Examples 1 to 6 had lower driving voltages, better luminescence efficiencies, and longer lifespans than the light-emitting devices of Comparative Examples 1 to 5.

The condensed cyclic compound has excellent chemical stability and excellent color purity, and a light-emitting device and an electronic apparatus, each including the condensed cyclic compound, may have high luminescence efficiency and long lifespan.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A light-emitting device comprising:
a first electrode;
a second electrode facing the first electrode;
an interlayer between the first electrode and the second electrode and comprising an emission layer; and
at least one condensed cyclic compound represented by Formula 1: 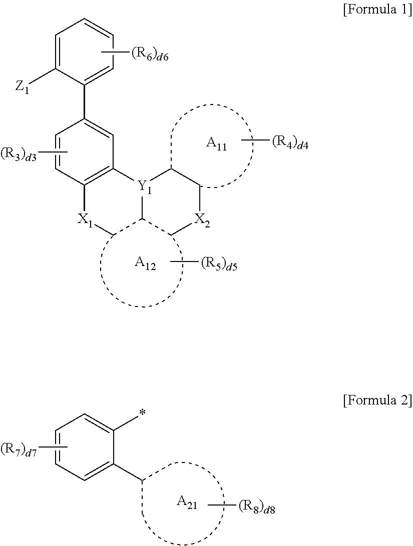
wherein in Formulae 1 and 2,
X₁ is O, S, Se, C(E₁₁)(E₁₂), Si(E₁₁)(E₁₂), or N(E₁₁),
X₂ is O, S, Se, C(E₂₁)(E₂₂), Si(E₂₁)(E₂₂), or N(E₂₁),
Y₁ is N, B, P(═O), or P(═S),
A₁₁, A₁₂, and A₂₁ are each independently a C₅-C₃₀ carbocyclic group or a C₂-C₃₀ heterocyclic group,
E₁₁ is *′-(L₁₁)ₙ₁₁-R₁₁,
E₁₂ is *′-(L₁₂)ₙ₁₂-R₁₂,
E₂₁ is *′-(L₂₁)ₙ₂₁-R₂₁,
E₂₂ is *′-(L₂₂)ₙ₂₂-R₂₂,
L₁₁, L₁₂, L₂₁, and L₂₂ are each independently a C₅-C₃₀ carbocyclic group that is unsubstituted or substituted with at least one R₁₀ₐ or a C₂-C₃₀ heterocyclic group that is unsubstituted or substituted with at least one R₁₀ₐ,
n11, n12, n21, and n22 are each independently an integer from 0 to 3,
R₃ to R₈, R₁₁, R₁₂, R₂₁, and R₂₂ are each independently hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —Si(Q₁)(Q₂)(Q₃), —B(Q₁)(Q₂), —C(═O)(Q₁), —S(═O)₂(Q₁), —O (Q₁), —S(Q₁), —Se(Q₁), —P(═O)(Q₁)(Q₂), or a group represented by Formula 2,
d3 is an integer from 0 to 3,
d4, d5, and d8 are each independently an integer from 0 to 10,
d6 and d7 are each independently an integer from 0 to 4,
Z₁ is a C₂-C₆₀ alkyl group that is unsubstituted or substituted with at least one R₁₀ₐ, a C₂-C₆₀ alkenyl group that is unsubstituted or substituted with at least one R₁₀ₐ, or a C₂-C₆₀ alkynyl group that is unsubstituted or substituted with at least one R₁₀ₐ,
two or more groups of Z₁, R₃ in the number of d3, R₄ in the number of d4, R₅ in the number of d5, R₆ in the number of d6, R₇ in the number of d7, R₈ in the number of d8, R₁₁, R₁₂, R₂₁, and R₂₂ are optionally bonded together to form a C₅-C₃₀ carbocyclic group that is unsubstituted or substituted with at least one R₁₀ₐ or a C₂-C₃₀ heterocyclic group that is unsubstituted or substituted with at least one R₁₀ₐ,
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —O (Q₁₁), —S(Q₁₁), —Se(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group; each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —O (Q₂₁), —S(Q₂₁), —Se(Q₂₁), —P(═O)(Q₂₁)(Q₂₂), or a combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —O (Q₃₁), —S(Q₃₁), —Se(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₂₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or a combination thereof, and
the condensed cyclic compound represented by Formula 1 satisfies at least one of Condition 1 and Condition 2:
[Condition 1]
X₁ is N(E₁₁), and R₁₁ is a group represented by Formula 2;
[Condition 2]
X₂ is N(E₂₁), and R₂₁ is a group represented by Formula 2.

2. The light-emitting device of claim 1, wherein
the first electrode is an anode,
the second electrode is a cathode,
the interlayer comprises the condensed cyclic compound,
the interlayer further comprises:
a hole transport region between the first electrode and the emission layer; and
an electron transport region between the emission layer and the second electrode,
the hole transport region comprises a hole injection layer, a hole transport layer, an emission auxiliary layer, an electron blocking layer, or a combination thereof, and
the electron transport region comprises a hole blocking layer, an electron transport layer, an electron injection layer, or a combination thereof.

3. The light-emitting device of claim 1, wherein the emission layer comprises the condensed cyclic compound.

4. The light-emitting device of claim 3, wherein an amount of the condensed cyclic compound is in a range of about 0.01 parts by weight to about 49.99 parts by weight based on 100 parts by weight of the emission layer.

5. The light-emitting device of claim 3, wherein
the emission layer further comprises:
a first compound; and
a second compound,
the first compound is a hole transport compound comprising at least one electron donating group, and
the second compound is an electron transport compound comprising at least one electron withdrawing group.

6. The light-emitting device of claim 3, wherein
the emission layer further comprises a third compound, and
the third compound is a metal-containing compound.

7. The light-emitting device of claim 3, wherein the emission layer emits light having a maximum emission wavelength in a range of about 400 nm to about 500 nm.

8. An electronic apparatus comprising the light-emitting device of claim 1.

9. The electronic apparatus of claim 8, further comprising:
a thin-film transistor, wherein
the thin-film transistor comprises a source electrode and a drain electrode, and
the first electrode of the light-emitting device is electrically connected to at least one of the source electrode and the drain electrode.

10. The electronic apparatus of claim 8, further comprising a color filter, a color conversion layer, a touch screen layer, a polarizing layer, or a combination thereof.

11. The electronic apparatus of claim 8, further comprising:
a thin-film transistor; and
a color filter, a color conversion layer, a touch screen layer, a polarizing layer, or a combination thereof, wherein
the thin-film transistor comprises a source electrode and a drain electrode, and
the first electrode of the light-emitting device is electrically connected to the source electrode or the drain electrode.

12. An electronic device comprising the light-emitting device of claim 1, wherein the electronic device is a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

13. A condensed cyclic compound represented by Formula 1: 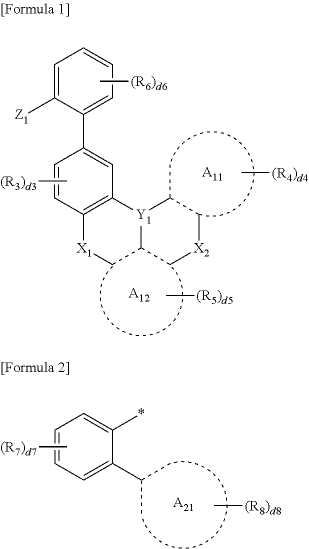
wherein in Formulae 1 and 2,
X₁ is O, S, Se, C(E₁₁)(E₁₂), Si(E₁₁)(E₁₂), or N(E₁₁),
X₂ is O, S, Se, C(E₂₁)(E₂₂), Si(E₂₁)(E₂₂), or N(E₂₁),
Y₁ is N, B, P(═O), or P(═S),
A₁₁, A₁₂, and A₂₁ are each independently a C₅-C₃₀ carbocyclic group or a C₂-C₃₀ heterocyclic group,
E₁₁ is *′-(L₁₁)ₙ₁₁-R₁₁,
E₁₂ is *′-(L₁₂)ₙ₁₂-R₁₂,
E₂₁ is *′-(L₂₁)ₙ₂₁-R₂₁,
E₂₂ is *′-(L₂₂)ₙ₂₂-R₂₂,
L₁₁, L₁₂, L₂₁, and L₂₂ are each independently a C₅-C₃₀ carbocyclic group that is unsubstituted or substituted with at least one R₁₀ₐ or a C₂-C₃₀ heterocyclic group that is unsubstituted or substituted with at least one R₁₀ₐ,
n11, n12, n21, and n22 are each independently an integer from 0 to 3,
R₃ to R₈, R₁₁, R₁₂, R₂₁, and R₂₂ are each independently hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —Si(Q₁)(Q₂)(Q₃), —B(Q₁)(Q₂), —C(═O)(Q₁), —S(═O)₂(Q₁), —O(Q₁), —S(Q₁), —Se(Q₁), —P(═O)(Q₁)(Q₂), or a group represented by Formula 2,
d3 is an integer from 0 to 3,
d4, d5, and d8 are each independently an integer from 0 to 10,
d6 and d7 are each independently an integer from 0 to 4,
Z₁ is a C₂-C₆₀ alkyl group that is unsubstituted or substituted with at least one R₁₀ₐ, a C₂-C₆₀ alkenyl group that is unsubstituted or substituted with at least one R₁₀ₐ, or a C₂-C₆₀ alkynyl group that is unsubstituted or substituted with at least one R₁₀ₐ,
two or more groups of Z₁, R₃ in the number of d3, R₄ in the number of d4, R₅ in the number of d5, R₆ in the number of d6, R₇ in the number of d7, R₈ in the number of d8, R₁₁, R₁₂, R₂₁, and R₂₂ are optionally bonded together to form a C₅-C₃₀ carbocyclic group that is unsubstituted or substituted with at least one R₁₀ₐ or a C₂-C₃₀ heterocyclic group that is unsubstituted or substituted with at least one R₁₀ₐ,
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —O(Q₁₁), —S(Q₁₁), —Se(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group; each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —O(Q₂₁), —S(Q₂₁), —Se(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —O(Q₃₁), —S(Q₃₁), —Se(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₂₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₂₀ alkyl group, a C₁-C₂₀ alkoxy group, a phenyl group, a biphenyl group, or a combination thereof, and
the condensed cyclic compound represented by Formula 1 satisfies at least one of Condition 1 and Condition 2:
[Condition 1]
X₁ is N(E₁₁), and R₁₁ is a group represented by Formula 2;
[Condition 2]
X₂ is N(E₂₁), and R₂₁ is a group represented by Formula 2.

14. The condensed cyclic group of claim 13, wherein the condensed cyclic compound represented by Formula 1 is represented by one of Formulae 1-1 to 1-3: 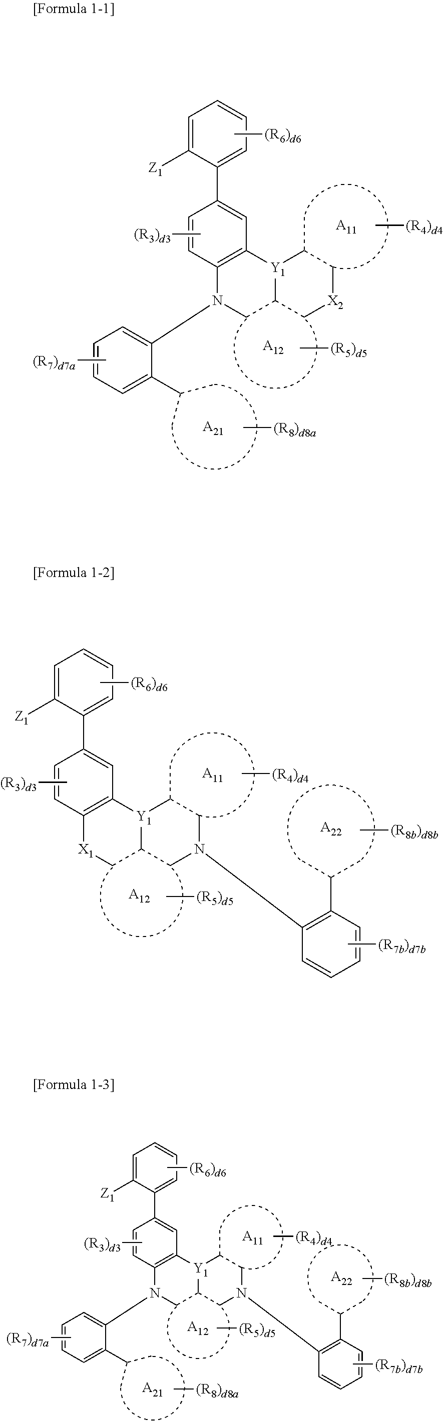
wherein in Formulae 1-1 to 1-3,
A₁₁, A₁₂, A₂₁, X₁, X₂, Y₁, Z₁, R₃ to R₆, and d3 to d6 are each independently the same as defined in Formula 1,
A₂₂ is independently the same as defined in connection with A₂₁ in Formula 1,
R₇ₐ and R_{7b} are each independently the same as defined in connection with R₇ in Formula 1,
R₈ₐ and R_{8b} are each independently the same as defined in connection with R₈ in Formula 1,
d7a and d7b are each independently the same as defined in connection with d7 in Formula 1, and
d8a and d8b are each independently the same as defined in connection with d8 in Formula 1.

15. The condensed cyclic group of claim 13, wherein the group represented by Formula 2 is a group represented by one of Formulae 2-1 to 2-16: 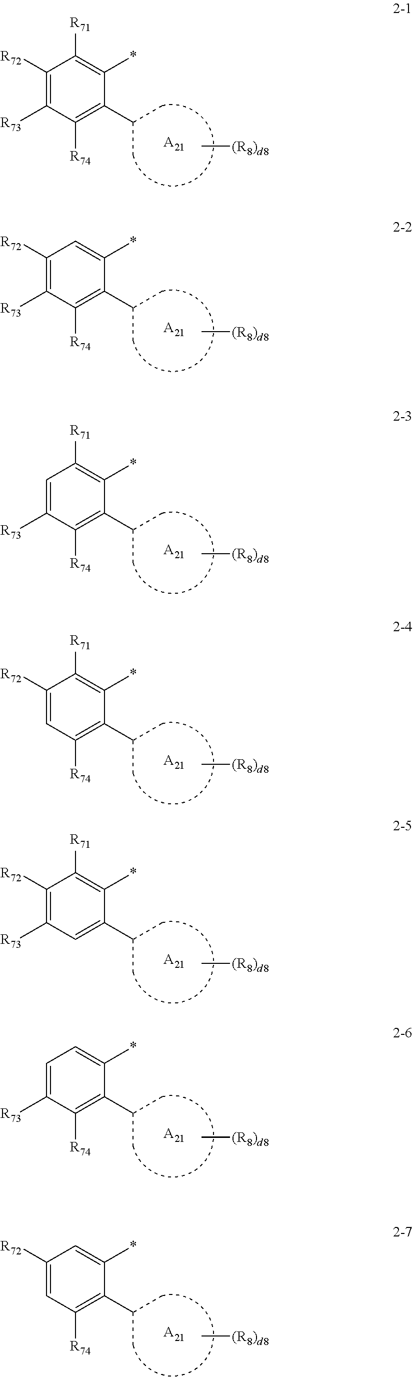 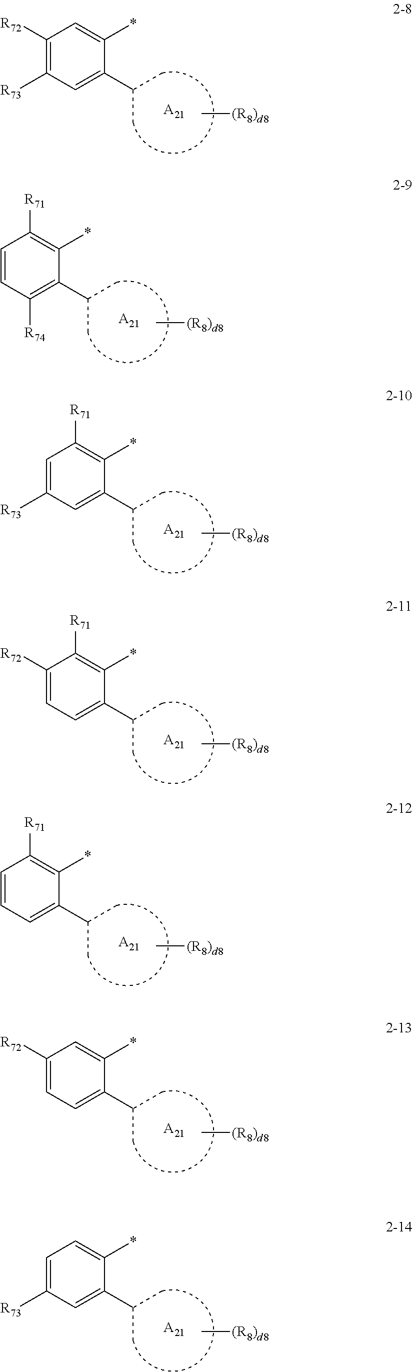 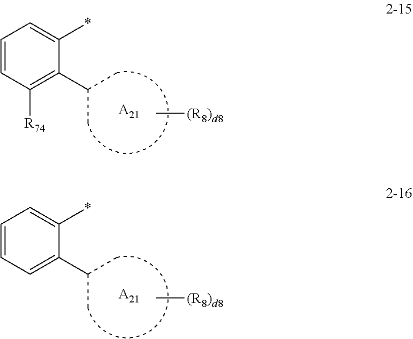
wherein, in Formulae 2-1 to 2-16,
A₂₁, R₈, and d8 are each independently the same as defined in Formula 2,
R₇₁ to R₇₄ are each independently the same as defined in connection with R₇ in Formula 2, and are each not hydrogen, and
* indicates a binding site to a neighboring atom.

16. The condensed cyclic group of claim 13, wherein in Formula 1, a moiety represented by 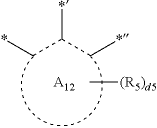
is a moiety represented by one of Formulae 3-1 to 3-8: 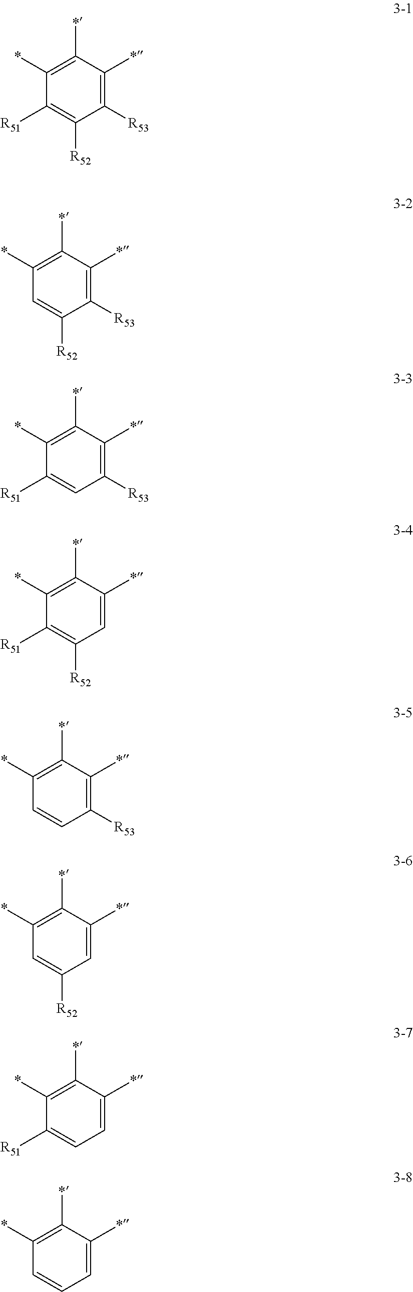
wherein in Formulae 3-1 to 3-8,
R₅₁ to R₅₃ are each independently the same as defined in connection with R₅ in Formula 1, and are each not hydrogen, and
*, *′, and *″ each indicate a binding site to a neighboring atom.

17. The condensed cyclic group of claim 13, wherein Z₁ is: a C₂-C₆₀ alkyl group, a C₂-C₆₀ alkenyl group, or a C₂-C₆₀ alkynyl group;
a C₂-C₂₀ alkyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or a combination thereof;
a C₂-C₂₀ alkenyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or a combination thereof; or
a C₂-C₂₀ alkynyl group that is substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or a combination thereof.

18. The condensed cyclic group of claim 13, wherein in Formula 1, a moiety represented by 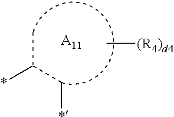
is a moiety represented by one of Formulae 4-1 to 4-16: 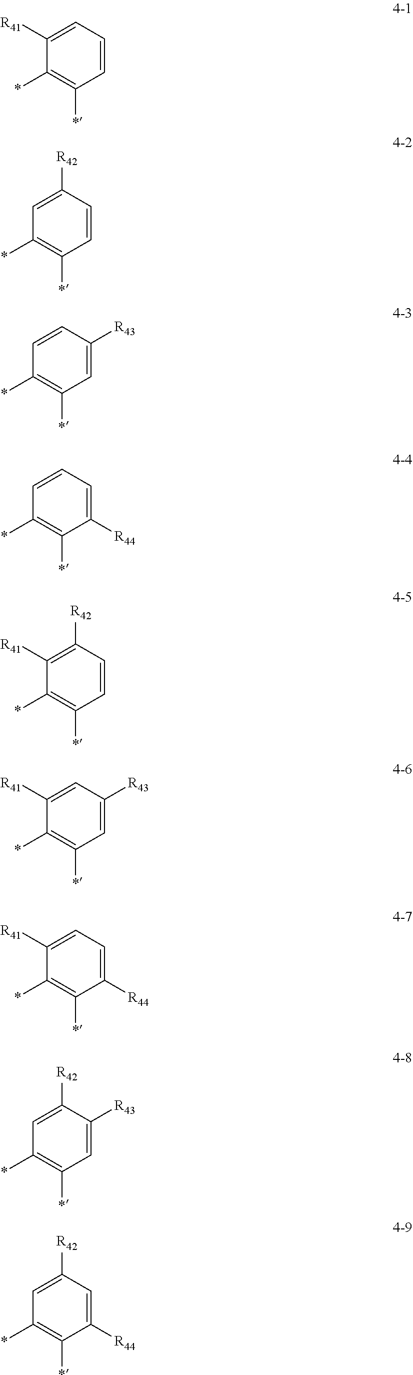 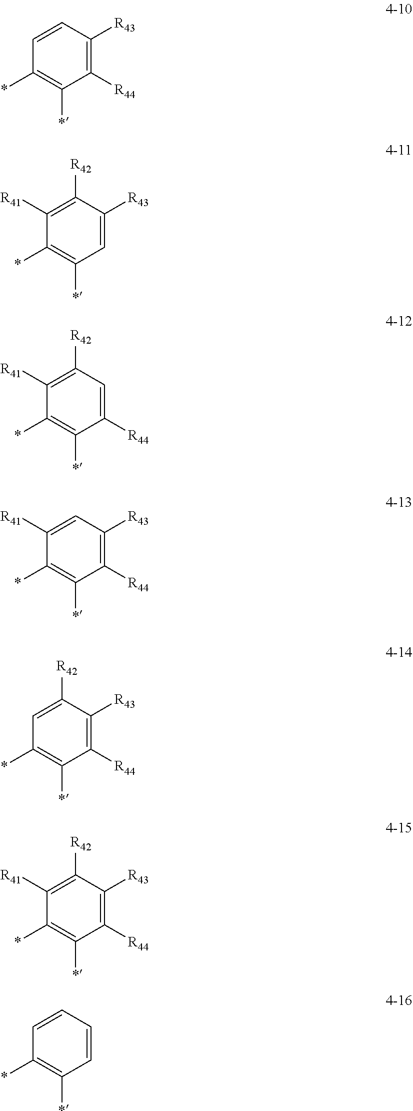
wherein in Formulae 4-1 to 4-16,
R₄₁ to R₄₄ are each independently the same as defined in connection with R₄ in Formula 1, and are each not hydrogen, and
* and *′ each indicate a binding site to a neighboring atom.

19. The condensed cyclic group of claim 13, wherein in Formula 1, a moiety represented by 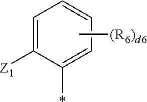
is a moiety represented by one of Formulae 5-1 to 5-3: 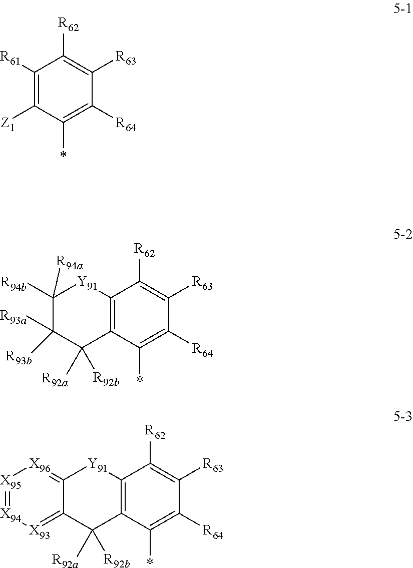
wherein in Formulae 5-1 to 5-3,
X₉₃ is N or C(R₉₃),
X₉₄ is N or C(R₉₄),
X₉₅ is N or C(R₉₅),
X₉₆ is N or C(R₉₆),
Y₉₁ is a single bond, O, S, Se, C(R₉₁ₐ)(R_{91b}), Si(R₉₁ₐ)(R_{91b}), or N(R₉₁ₐ),
R₆₁ to R₆₄, R₉₁ₐ, R_{91b}, R₉₂ₐ, R_{92b}, R₉₃ₐ, R_{93b}, R₉₄ₐ, R_{94b}, and R₉₃ to R₉₆ are each independently the same as defined in connection with R₆ in Formula 1,
Z₁ is the same as defined in Formula 1, and
* indicates a binding site to a neighboring atom.

20. The condensed cyclic group of claim 13, wherein the condensed cyclic compound is one of Compounds 1 to 109: 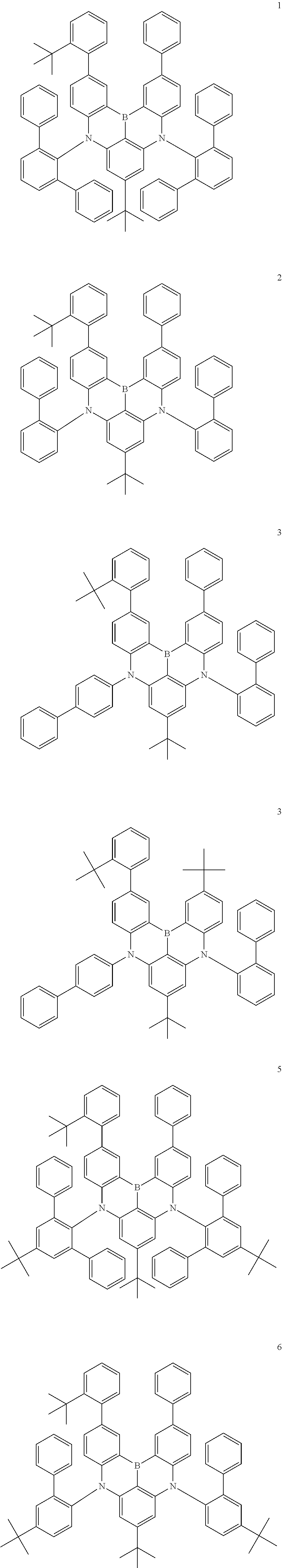 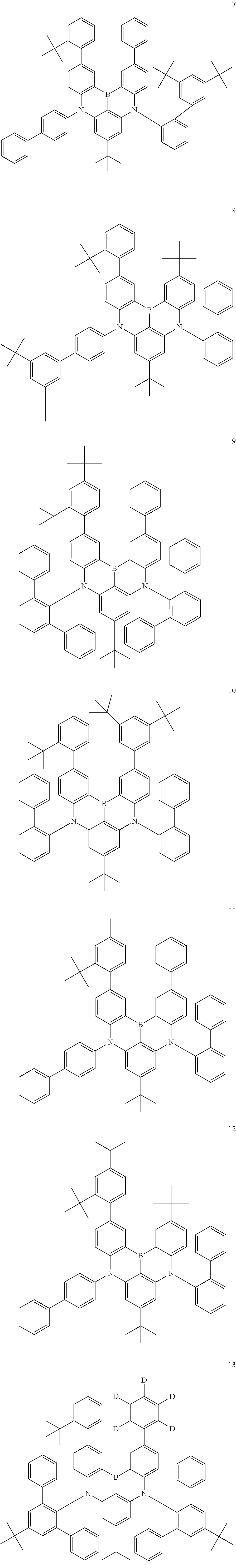 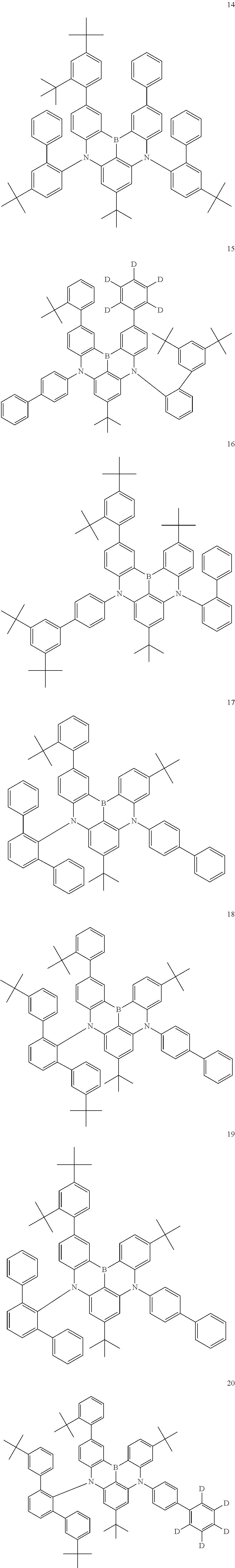 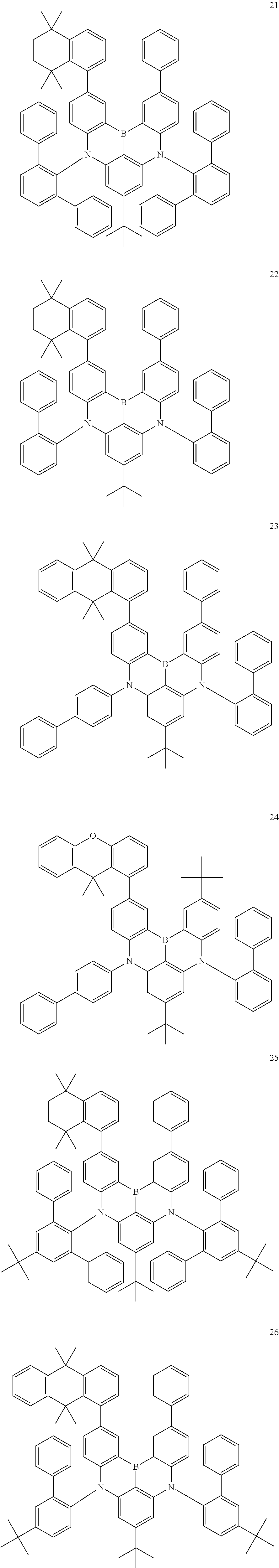 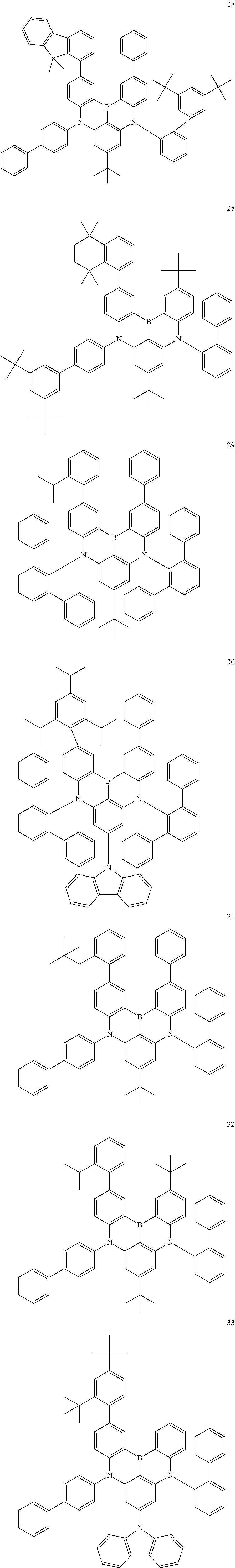 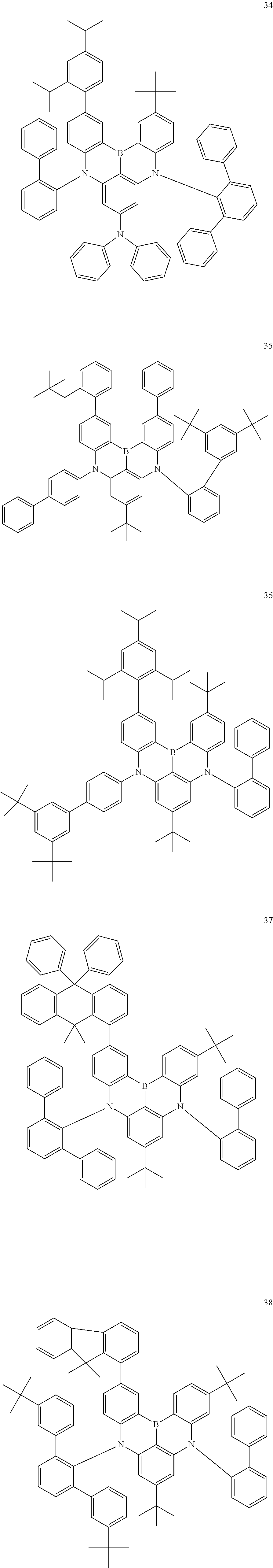 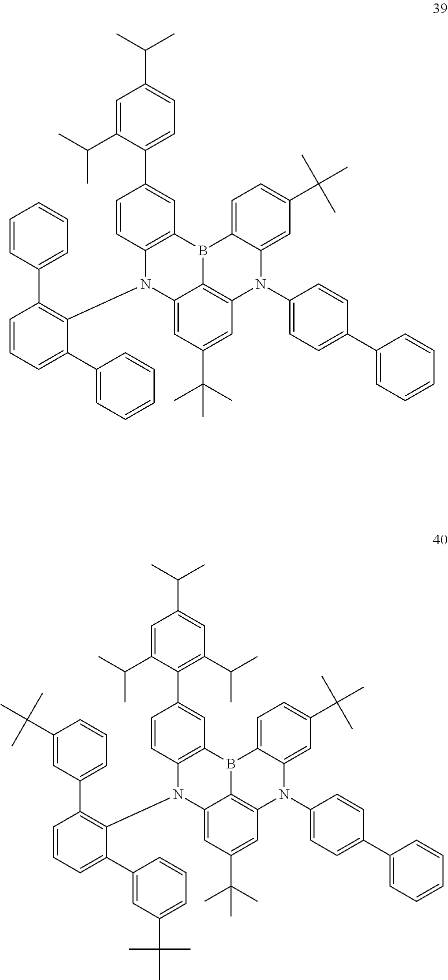 [SMILES: CC(C)c1ccc(-c2ccc3c(c2)B2c4ccc(C(C)(C)C)cc4N(c4ccc(-c5ccccc5)cc4)c4cc(C(C)(C)C)cc(c42)N3c2c(-c3ccccc3)cccc2-c2ccccc2)c(C(C)C)c1 ; CC(C)c1cc(C(C)C)c(-c2ccc3c(c2)B2c4ccc(C(C)(C)C)cc4N(c4ccc(-c5ccccc5)cc4)c4cc(C(C)(C)C)cc(c42)N3c2c(-c3cccc(C(C)(C)C)c3)cccc2-c2cccc(C(C)(C)C)c2)c(C(C)C)c1] 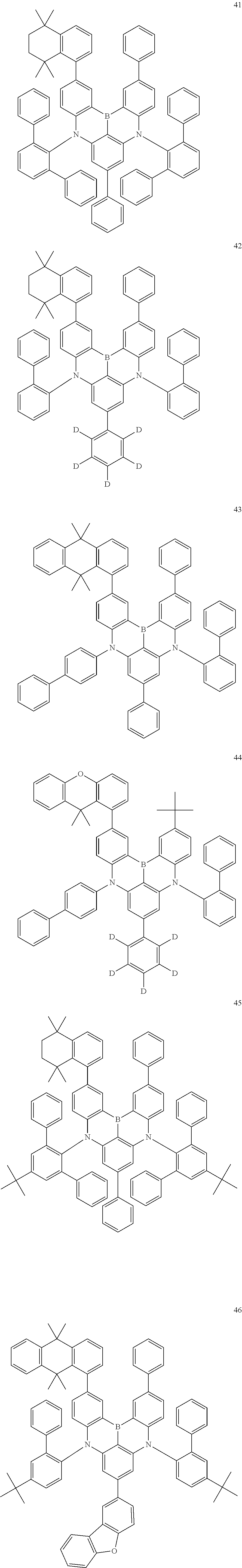 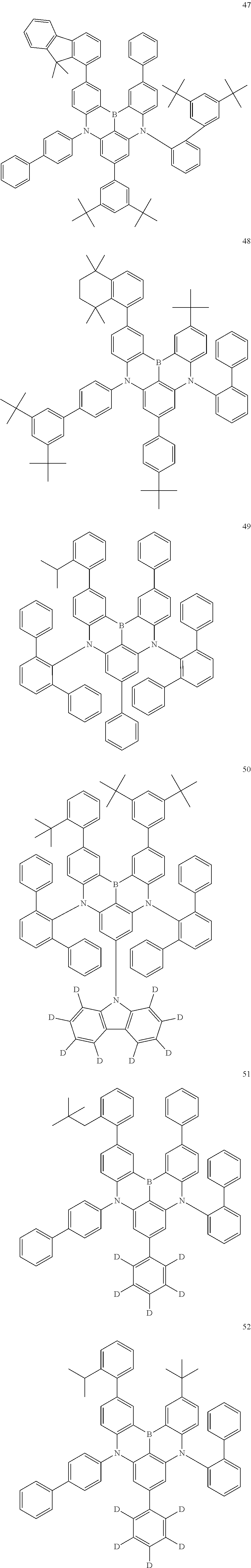 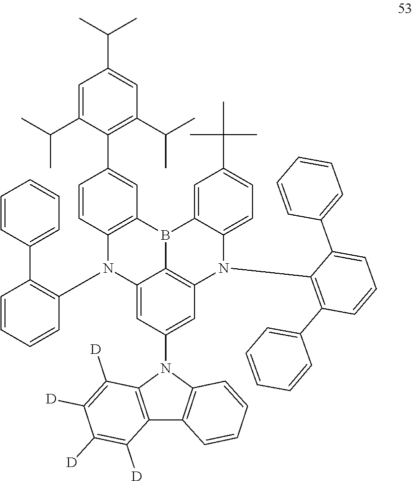 [SMILES: [2H]c1c([2H])c([2H])c2c(c1[2H])c1ccccc1n2-c1cc2c3c(c1)N(c1c(-c4ccccc4)cccc1-c1ccccc1)c1ccc(C(C)(C)C)cc1B3c1cc(-c3c(C(C)C)cc(C(C)C)cc3C(C)C)ccc1N2c1ccccc1-c1ccccc1] 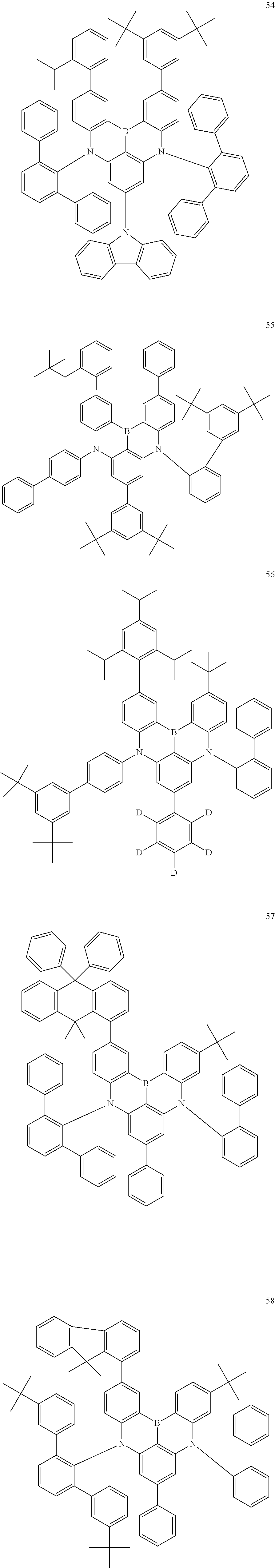 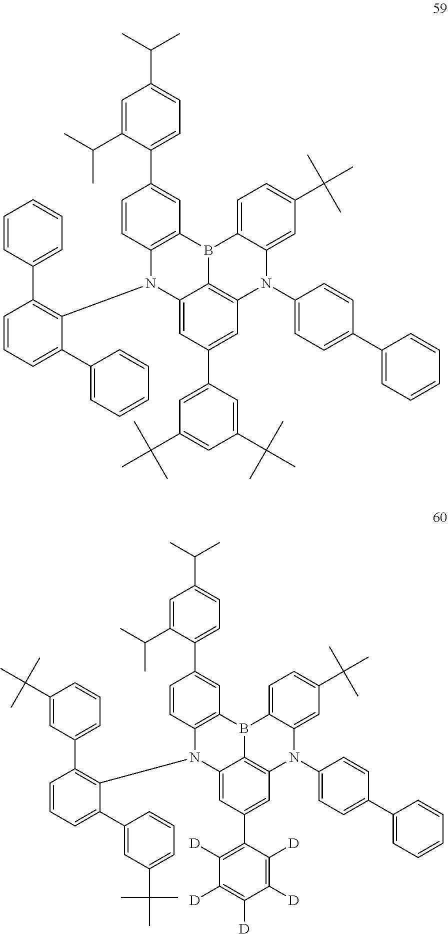 [SMILES: CC(C)c1ccc(-c2ccc3c(c2)B2c4ccc(C(C)(C)C)cc4N(c4ccc(-c5ccccc5)cc4)c4cc(-c5cc(C(C)(C)C)cc(C(C)(C)C)c5)cc(c42)N3c2c(-c3ccccc3)cccc2-c2ccccc2)c(C(C)C)c1 ; [2H]c1c([2H])c([2H])c(-c2cc3c4c(c2)N(c2c(-c5cccc(C(C)(C)C)c5)cccc2-c2cccc(C(C)(C)C)c2)c2ccc(-c5ccc(C(C)C)cc5C(C)C)cc2B4c2ccc(C(C)(C)C)cc2N3c2ccc(-c3ccccc3)cc2)c([2H])c1[2H]] 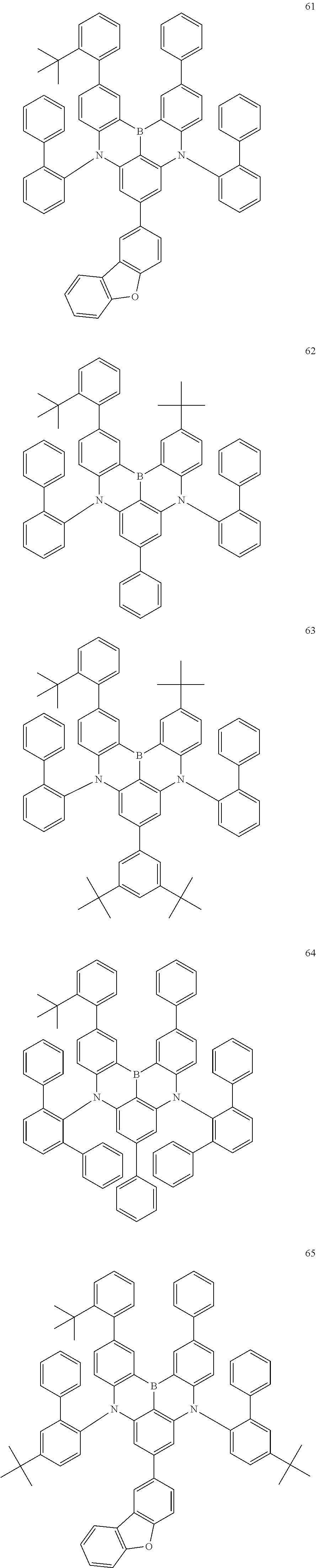 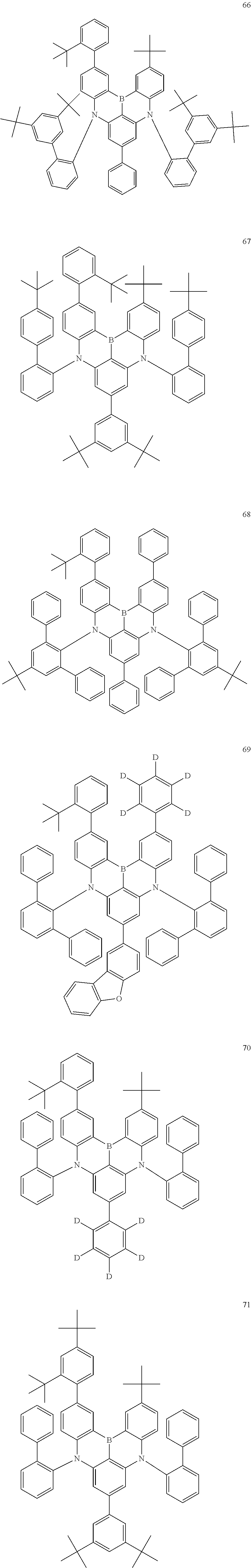 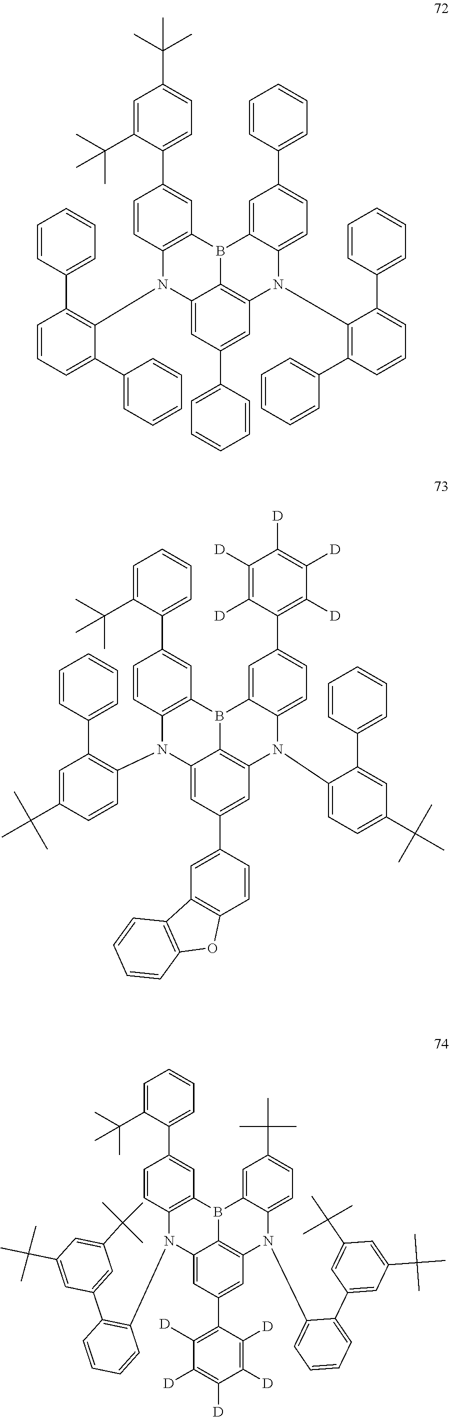 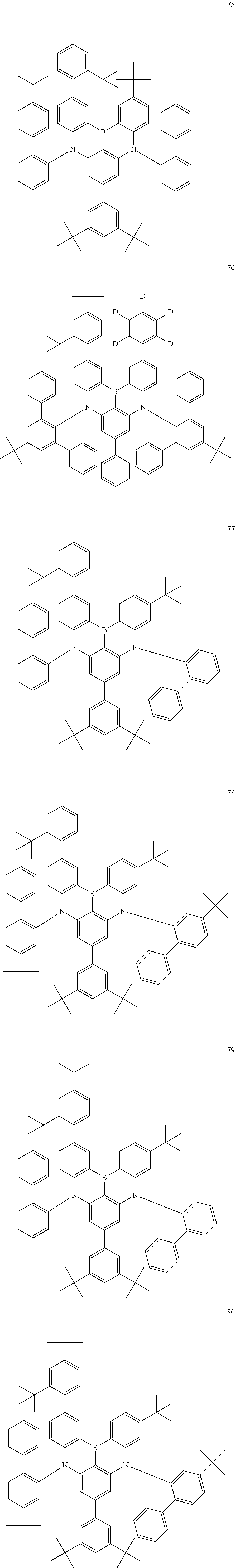 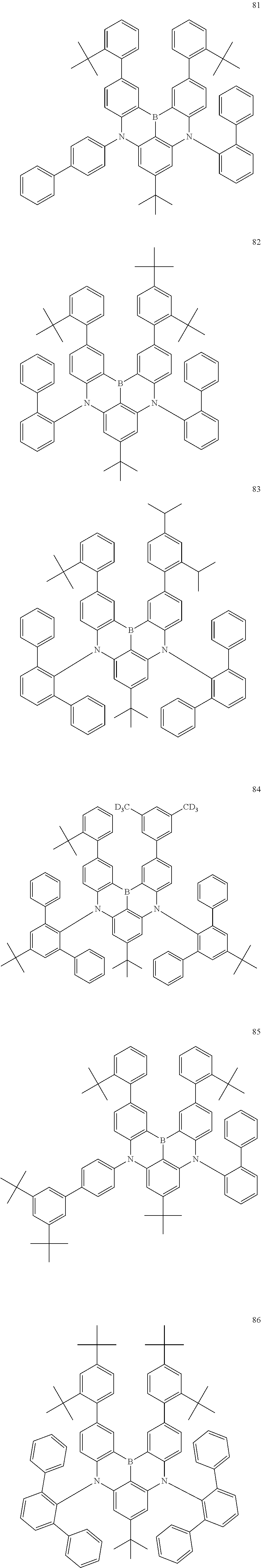 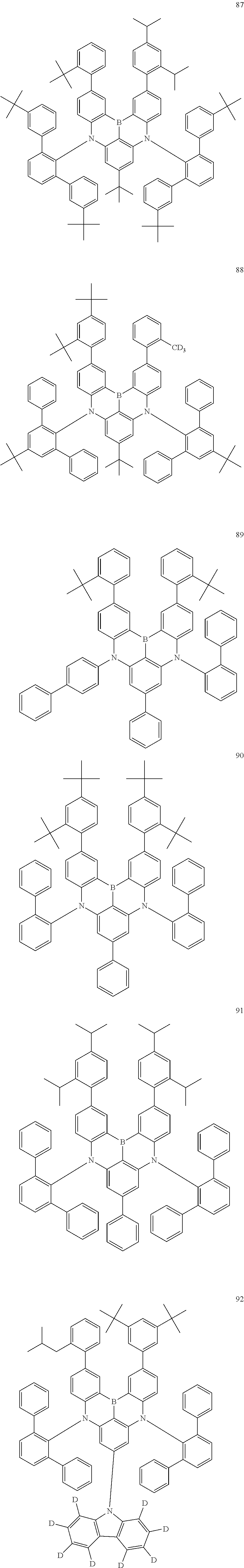 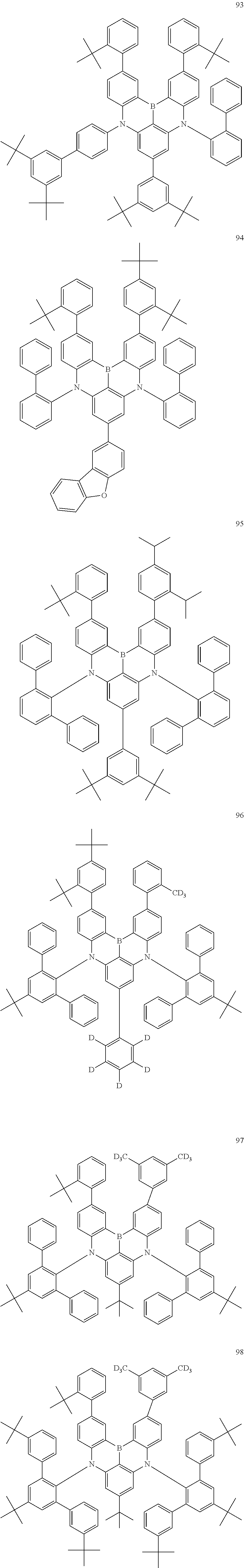 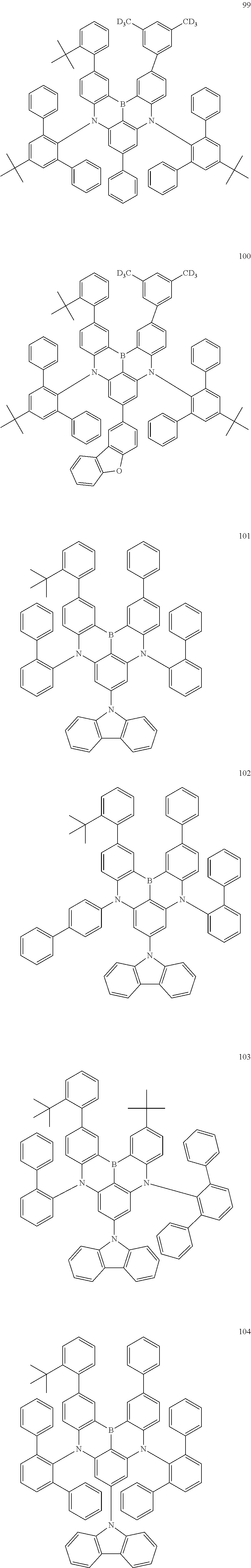 [chemical structure]
